(19) United States
(12) Patent Application Publication
(10) Pub. No.: US 2025/0275471 A1
(43) Pub. Date: Aug. 28, 2025

(54) BENZOPHENANTHRENE-CONTAINING ORGANIC COMPOUNDS AND USES THEREOF IN ORGANIC OPTOELECTRONIC DEVICES

(71) Applicant: Zhejiang Brilliant Optoelectronic Technology Co.,Ltd., Taizhou (CN)

(72) Inventors: Xiaoye WANG, Taizhou (CN); Hao ZHANG, Taizhou (CN); Chengzhuo DU, Taizhou (CN); Junyou PAN, Taizhou (CN)

(73) Assignee: Zhejiang Brilliant Optoelectronic Technology Co.,Ltd., Taizhou (CN)

(21) Appl. No.: 19/207,653

(22) Filed: May 14, 2025

Related U.S. Application Data
(63) Continuation of application No. PCT/CN2023/131804, filed on Nov. 15, 2023.

(30) Foreign Application Priority Data
Nov. 15, 2022 (CN) 202211429395.8

(51) Int. Cl. H10K 85/60; C07F 5/02; C09K 11/06; H10K 50/12; H10K 101/30

(52) U.S. Cl. CPC H10K 85/636; C07F 5/027; C09K 11/06; H10K 85/654; H10K 85/6572; C09K 2211/1007; C09K 2211/1011; C09K 2211/1018; H10K 50/12; H10K 85/658; H10K 2101/30

(57) ABSTRACT

Disclosed are benzophenanthrene-containing organic compounds including a structure of formula (I). Also disclosed are formulations containing the benzophenanthrene-containing organic compounds, and at least one organic solvent. Further disclosed are color conversion layers containing an emitter, the emitter includes the benzophenanthrene-containing organic compound with chirality. The organic compound including benzophenanthrene according to the present disclosure can be used as an organic photoelectric material. A rigid benzophenanthrene structure unit is introduced into a BN-type compound, so that a stable organic light-emitting material can be obtained, thus providing a material solution for organic photoelectric devices.

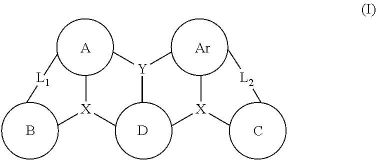

### CROSS-REFERENCE TO RELATED APPLICATIONS

The present application is a continuation of International Application No. PCT/CN2023/131804, filed on Nov. 15, 2023, which claims priority to Chinese Patent Application No. 202211429395.8, filed on Nov. 15, 2022. All of the aforementioned applications are incorporated herein by reference in their entireties.

### TECHNICAL FIELD

The present disclosure relates to the field of organic electronic material and device technology, and in particular to a benzophenanthrene-containing organic compound, a formulation, and the applications thereof in organic optoelectronic devices, particularly in organic electroluminescent devices.

### BACKGROUND

Due to the diversity of the synthesis, the low manufacturing cost, and the excellent optical and electrical properties, the organic light-emitting diodes (OLEDs) show great potential for optoelectronic device applications, such as flat-panel displays and lighting.

Up to now, a variety of multi-resonance fluorescence emitting material systems based on BN fused-ring materials have been developed so far. In blue-emitting layer materials, the benzophenanthrene groups have high stability and have been widely used in luminescent host materials, so compared with BN fused-ring type multi-resonance luminescent dopant materials, the emission spectrum will be further narrowed and the thermal stability will be improved by connecting benzophenanthrene groups to them. Therefore, more BN-based multi-resonance luminescent materials containing a benzophenanthrene group need to be developed, which will have a great significance for OLED devices.

For multi-resonance narrow-spectrum light-emitting devices, the dopant material performance determines the efficiency and lifetime of the light-emitting device. Currently, the commonly used BN-based dopant materials are multi-resonance BN-based organic compounds, which still have disadvantages such as high thermal stability of the material due to their structural specificity, while the limited optoelectronic stability of such materials leads to short device lifetime. In order to further improve the stability of the dopant material, the multiple resonance effect of the molecules is realized by introducing the boron/nitrogen heterocyclic fused-ring unit in the prior art. This forms a good rigid structure to get material with high thermal stability to achieve narrow emission spectrum. The present disclosure finds that the introduction of benzophenanthrene groups into BN-based fused ring structures can further improve the stability of the materials without reducing their multiple resonance effects. Such benzophenanthrene-containing boron hetero-aza organic compounds can be applied in fluorescent dopant materials, which provide basic structural units with high performance for the development of multi-resonance fluorescent emitting materials.

Therefore, the existing technologies, especially the material solutions, still need to be improved and developed.

### SUMMARY

In one aspect, the present disclosure provides a benzophenanthrene-containing organic compound comprising a structure of formula (I):

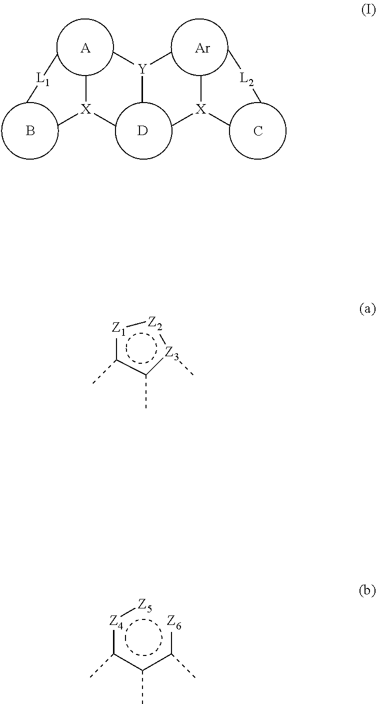

Where A, B, C, and D are each independently selected from a substituted/unsubstituted C₆-C₆₀ aromatic ring, a substituted/unsubstituted C₅-C₆₀ heteroaromatic ring, or a substituted/unsubstituted C₁₀-C₆₀ fused-ring structural unit, and at least one of A, B, and C is a benzophenanthrene. Each of X and Y is independently N or B, and X is different from Y Ar is selected from formula (a) or formula (b), each dotted line independently represents a bonding position, when Ar is formula (a), each of L₁ and L₂ is independently selected from null or a single bond, and when Ar is formula (b), each of L₁ and L₂ is a single bond. Z₁, Z₂, Z₃, Z₄, Z₅, and Z₆ are each independently selected from CR₁, NR₁, N, O, S, S═O, S(═O)₂, or C═O, such that formula (a) is a five-membered heteroaromatic ring, and formula (b) is a six-membered aromatic or heteroaromatic ring, where any two adjacent substituents of Z₁-Z₆ may form a monocyclic or polycyclic aliphatic or aromatic ring system with each other and/or with the rings bonded thereto.

R₁ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof.

The benzophenanthrene-containing organic compound according to formula (I) may be further arbitrarily substituted with Rs; R at each occurrence is independently selected from a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof.

In another aspect, the present disclosure also provides a polymer comprising at least one repeating unit, the at least one repeating unit comprises a structure corresponding to a benzophenanthrene-containing organic compound as described herein.

In yet another aspect, the present disclosure further provides a mixture comprising a benzophenanthrene-containing organic compound as described herein, and at least one organic functional material, the at least one organic functional material is selected from a hole-injection material, a hole-transport material, an electron-transport material, an electron-injection material, an electron-blocking material, a hole-blocking material, a light-emitting material, or a host material.

In yet another aspect, the present disclosure further provides to a formulation comprising a benzophenanthrene-containing organic compound or a polymer or a mixture as described herein, and at least one organic solvent.

In yet another aspect, the present disclosure further provides an organic optoelectronic device comprising at least one benzophenanthrene-containing organic compound or polymer or mixture as described herein.

In yet another aspect, the present disclosure further provides a color conversion layer comprising an emitter, the emitter is a chiral molecule. Further, the emitter is a benzophenanthrene-containing organic compound with chirality as described herein.

Beneficial effect: the benzophenanthrene-containing organic compound can obtain stable organic emitting materials by introducing benzophenanthrene structural units into BN-based compounds, resulting in light-emitting devices with high efficiency and long lifetime. The benzophenanthrene-containing organic compound as described herein can be used as a functional material in OLED devices, which can be combined with other suitable functional materials to improve their luminous efficiency and prolong their lifetime as OLED devices, thereby providing a material for the light-emitting devices with high efficiency and long lifetime.

### BRIEF DESCRIPTION OF THE DRAWINGS

FIG. 1 shows absorption and emission spectrums of compound 1 in 0.5 mol/L of toluene solution.

### DETAILED DESCRIPTION OF THE EMBODIMENTS

The present disclosure provides a benzophenanthrene-containing organic compound, a formulation, and the application thereof in organic optoelectronic devices, aiming to solve the problem of insufficient performance in the existing blue-emitting materials.

In order to make the objects, the technical solutions and the effects of the present disclosure more clear and definite, the present disclosure is further described in detail below. It should be understood that the embodiments described herein are only intended to explain the present disclosure and are not intended to limit the present disclosure.

As used herein, the term “substituted” means that a hydrogen atom of the compound is substituted.

As used herein, “the number of ring atoms” means that the number of atoms constituting the ring itself of a structural compound (e.g., a monocyclic compound, a fused ring compound, a cross-linked compound, a carbocyclic compound, and a heterocyclic compound) by covalent bonding. When the ring is substituted with a substituent, the atoms contained in the substituent are not included in the ring atoms. The above rule applies for all cases without further specific description. For example, the number of ring atoms of a benzene ring is 6, the number of ring atoms of a naphthalene ring is 10, and the number of ring atoms of a thienyl group is 5.

The term “aromatic group” refers to a hydrocarbon group containing an aromatic ring. The term “heteroaromatic group” refers to an aromatic hydrocarbon group containing at least one heteroatom. The heteroatoms are preferably selected from Si, N, P, O, S and/or Ge, particularly preferably selected from Si, N, P, O and/or S. The term “fused-ring aromatic group” refers to an aromatic group containing two or more rings, in which two carbon atoms are shared by the adjacent two rings, i.e., fused rings. The term “fused heterocyclic aromatic group” refers a fused aromatic hydrocarbon group containing at least one heteroatom. For the purposes of the present disclosure, the aromatic groups or heteroaromatic groups comprise not only aromatic ring systems, but also non-aromatic ring systems. Therefore, systems such as pyridine, thiophene, pyrrole, pyrazole, triazole, imidazole, oxazole, oxadiazole, thiazole, tetrazole, pyrazine, pyridazine, pyrimidine, triazine, carbene, and the like is also considered be aromatic groups or heterocyclic aromatic groups for the purposes of this disclosure. For the purposes of the present disclosure, the fused-ring aromatic or fused heterocyclic aromatic ring systems contain not only aromatic or heteroaromatic systems, but also have a plurality of aromatic or heterocyclic aromatic groups linked by short non-aromatic units (<10% of non-H atoms, preferably <5% of non-H atoms, such as C, N or O atoms). Therefore, a system such as 9,9′-spirobifluorene, 9,9-diarylfluorene, triarylamine, diaryl ether, and the like is also considered to be fused-ring aromatic ring systems for the purposes of this disclosure.

In embodiments of the present disclosure, the energy level structure of the organic materials, singlet energy level (S₁), triplet energy level (T₁), highest occupied molecular orbital (HOMO), and lowest unoccupied molecular orbital (LUMO) play key roles. The determination of these energy levels is introduced as follows.

HOMO and LUMO energy levels can be measured by optoelectronic effect, for example, by XPS (X-ray photoelectron spectroscopy), UPS (UV photoelectron spectroscopy), or by cyclic voltammetry (hereinafter referred to as CV). Recently, quantum chemical methods, such as density functional theory (hereinafter referred to as DFT), are becoming effective methods for calculating the molecular orbital energy levels.

The singlet energy level S₁ of the organic materials can be determined by the emission spectrum. The triplet energy level T₁ of the organic materials can be measured by low-temperature time-resolved spectroscopy. S₁ and T₁ can also be calculated by quantum simulation (for example, by time-dependent DFT), for instance with the commercial software Gaussian 09W (Gaussian Inc.), the specific simulation method can be found in WO2011141110 or as described in the following embodiments. ΔE_{ST} is defined as (S₁-T₁).

It should be noted that the absolute values of HOMO, LUMO, S₁ and T₁ may depend on the measurement method or calculation method used. Even for the same method, different ways of evaluation, for example, using either the onset or peak value of a CV curve as reference, may result in different HOMO/LUMO values. Therefore, reasonable and meaningful comparison should be carried out by employing the same measurement and evaluation methods. In the embodiments of the present disclosure, the values of HOMO, LUMO, S₁ and T₁ are based on the time-dependent DFT simulation, which however should not exclude the applications of other measurement or calculation methods.

In the present disclosure, (HOMO−1) stands for the energy level of the second highest occupied molecular orbital, (HOMO−2) stands for the energy level of the third highest occupied molecular orbital, and so on. (LUMO+1) stands for the energy level of the second lowest unoccupied molecular orbital, (LUMO+2) stands for the energy level of the third lowest occupied molecular orbital, and so on.

In one aspect, the present disclosure provides a benzophenanthrene-containing organic compound comprising a structure of formula (I):

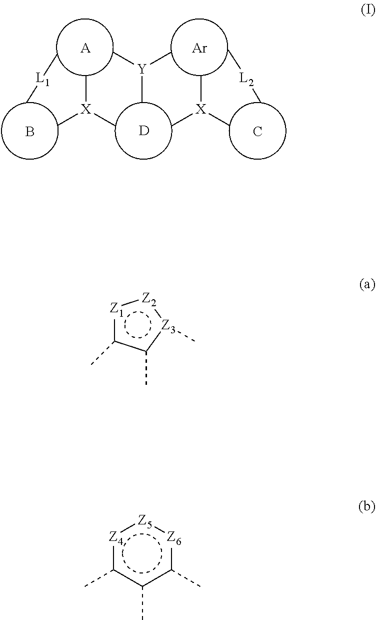

Where A, B, C, and D are each independently selected from a substituted/unsubstituted C₆-C₆₀ aromatic ring, a substituted/unsubstituted C₅-C₆₀ heteroaromatic ring, or a substituted/unsubstituted C₁₀-C₆₀ fused-ring structural unit, and at least one of A, B, and C is a benzophenanthrene; each of X and Y is independently N or B, and X is different from Y; Ar is selected from formula (a) or formula (b), each dotted line independently represents a bonding position, when Ar is formula (a), each of L₁ and L₂ is independently selected from null or a single bond, and when Ar is formula (b), each of L₁ and L₂ is a single bond. Z₁, Z₂, Z₃, Z₄, Z₅, and Z₆ are each independently selected from CR₁, NR₁, N, O, S, S═O, S(═O)₂, or C═O, such that formula (a) is a five-membered heteroaromatic ring, and formula (b) is a six-membered aromatic or heteroaromatic ring, where any two adjacent substituents of Z₁-Z₆ may form a monocyclic or polycyclic aliphatic or aromatic ring system with each other and/or with the rings bonded thereto.

R₁ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof.

The benzophenanthrene-containing organic compound according to formula (I) may be further arbitrarily substituted with Rs; R at each occurrence is independently selected from a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof.

In some embodiments, A, B, C, and D are each independently selected from a substituted/unsubstituted C₆-C₅₀ aromatic ring, a substituted/unsubstituted C₅-C₅₀ heteroaromatic ring, or a substituted/unsubstituted C₁₀-C₅₀ fused-ring structural unit, and at least one of A, B, and C is a benzophenanthrene. In some embodiments, A, B, C, and D are each independently selected from a substituted/unsubstituted C₆-C₄₀ aromatic ring, a substituted/unsubstituted C₅-C₄₀ heteroaromatic ring, or a substituted/unsubstituted C₁₀-C₄₀ fused-ring structural unit, and at least one of A, B, and C is a benzophenanthrene. In some embodiments, A, B, C, and D are each independently selected from a substituted/unsubstituted C₆-C₃₀ aromatic ring, a substituted/unsubstituted C₅-C₃₀ heteroaromatic ring, or a substituted/unsubstituted C₁₀-C₃₀ fused-ring structural unit, and at least one of A, B, and C is a benzophenanthrene. In some embodiments, A, B, C, and D are each independently selected from a substituted/unsubstituted C₆-C₂₀ aromatic ring, a substituted/unsubstituted C₅-C₂₀ heteroaromatic ring, or a substituted/unsubstituted C₁₀-C₂₀ fused-ring structural unit, and at least one of A, B, and C is a benzophenanthrene.

In some embodiments, A, B, and C are each independently selected from benzene or benzophenanthrene, and at least one of A, B, and C is benzophenanthrene. In some embodiments, A, B, and C are each independently selected from benzene or benzophenanthrene, and at least two of A, B, and C are benzophenanthrene. In some embodiments, each of A, B, and C is benzophenanthrene.

In some embodiments, D is a group with large steric hindrance structures, where the term “large steric hindrance group” refers to a group which can significantly improve the molecular planarity, so that the introduction of the large steric hindrance group can greatly enhance the planarity of the overall molecular structure and reduce the accumulation. The term “planarity” refers to a difference between a molecule and an ideal plane, the overall molecular planarity can be measured by theoretically calculating the molecular planarity parameter (MPP) value, thus a smaller MPP value represents a higher molecular planarity, and the MPP value is 0, which represents an ideal plane.

In some embodiments, the benzophenanthrene-containing organic compound comprises a structure of one of formulas (I-1)-(I-14):

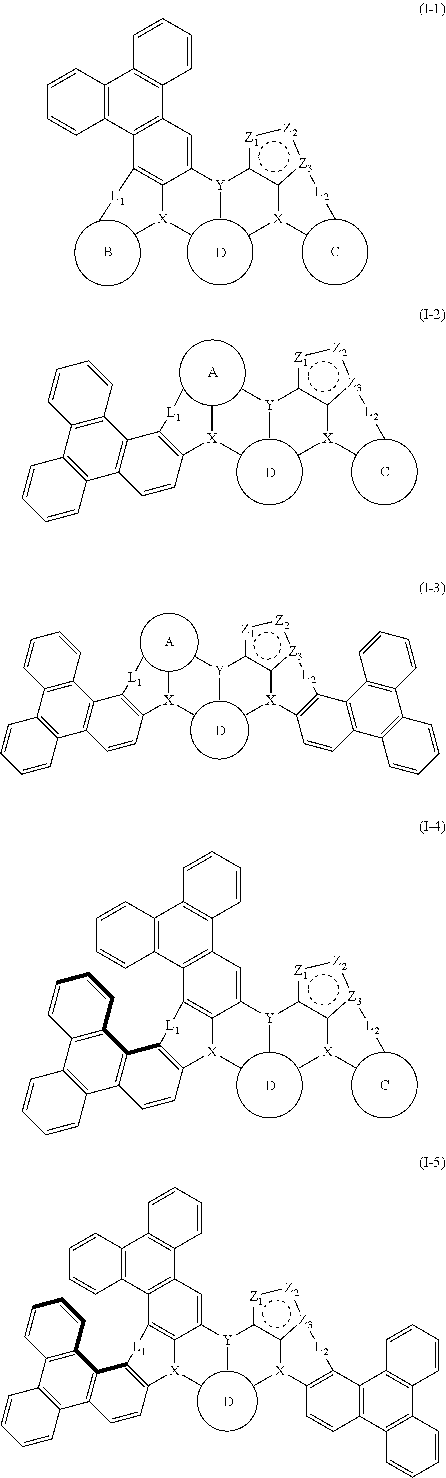

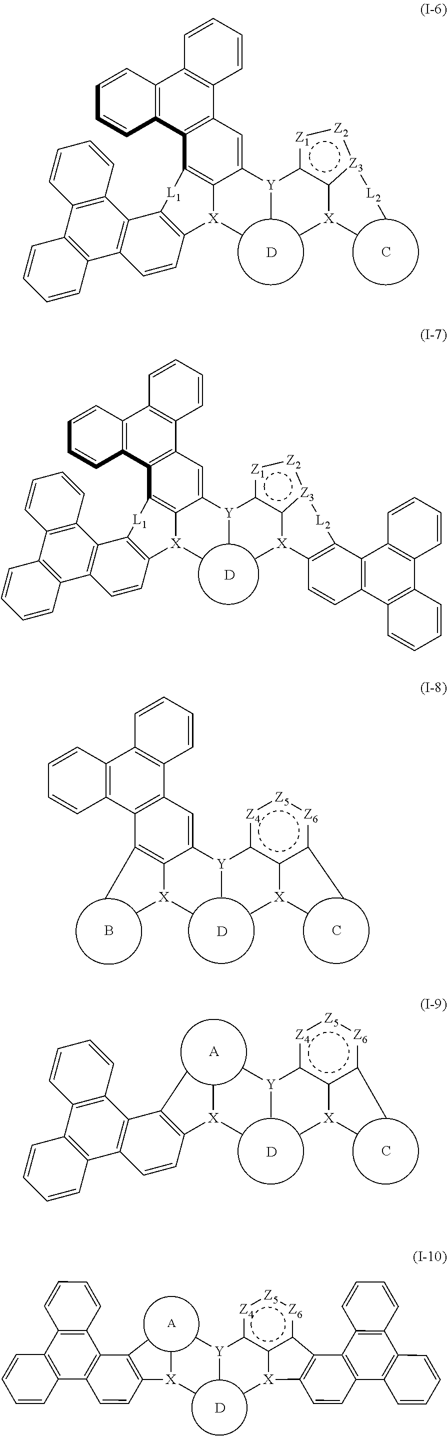

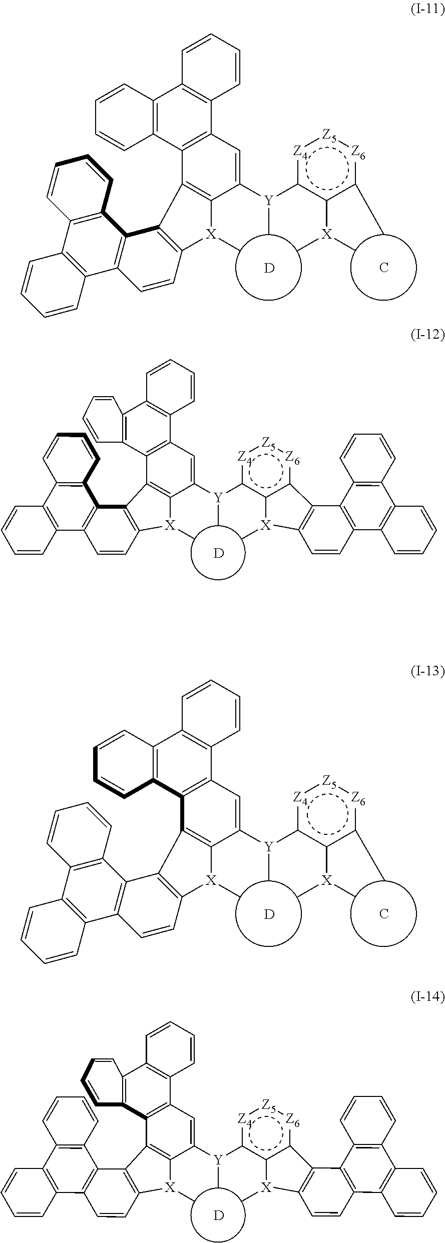

Where L₁-L₂, Z₁-Z₆, A, B, C, D, X, and Y are identically defined as described herein.

In some embodiments, when only one of A, B, and C is a benzophenanthrene, the benzophenanthrene-containing organic compound is not a structure of the following formulas:

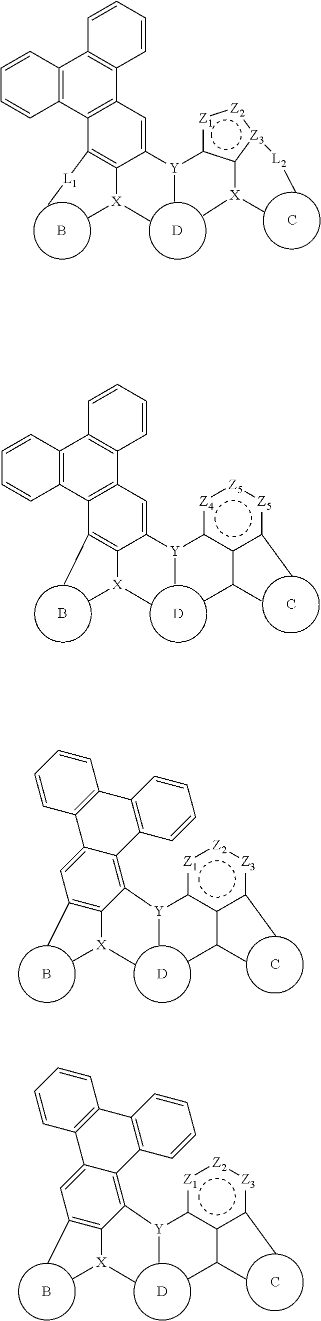

Where L₁-L₂, Z₁-Z₆, B, C, D, X, and Y are identically defined as described herein.

In some embodiments, when only two of A, B, and C are benzophenanthrene, the benzophenanthrene-containing organic compound is not a structure of the following formulas:

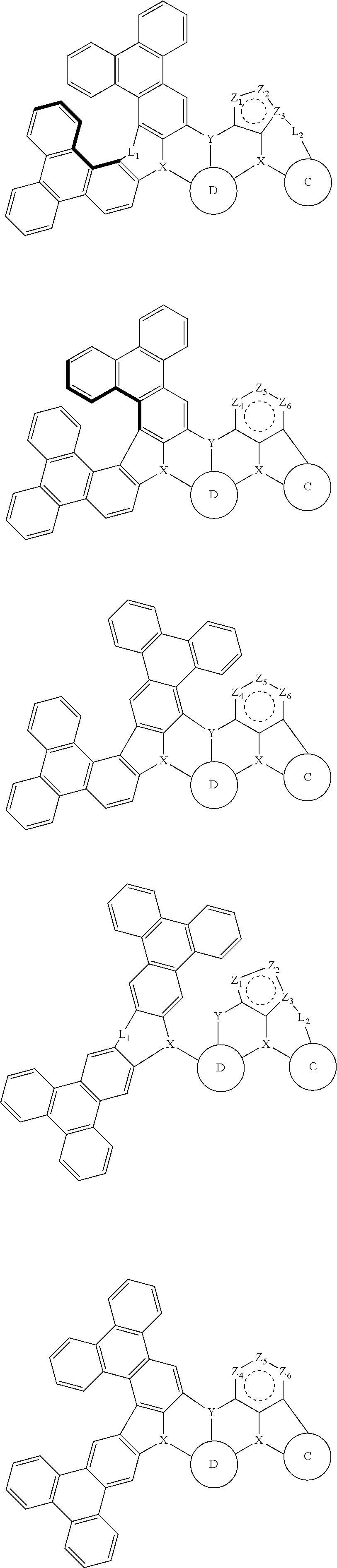

Where L₁-L₂, Z₁-Z₆, C, D, X, and Y are identically defined as described herein.

In some embodiments, the benzophenanthrene-containing organic compound is a structure of formula (Ia-1)-formula (Ia-13), formula (Ib-1)-formula (Ib-37):

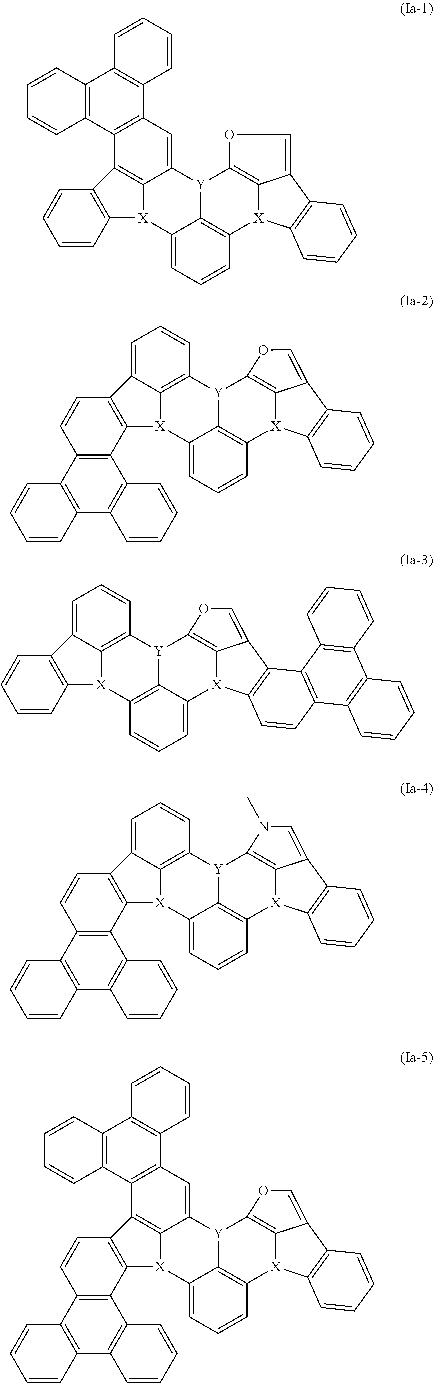

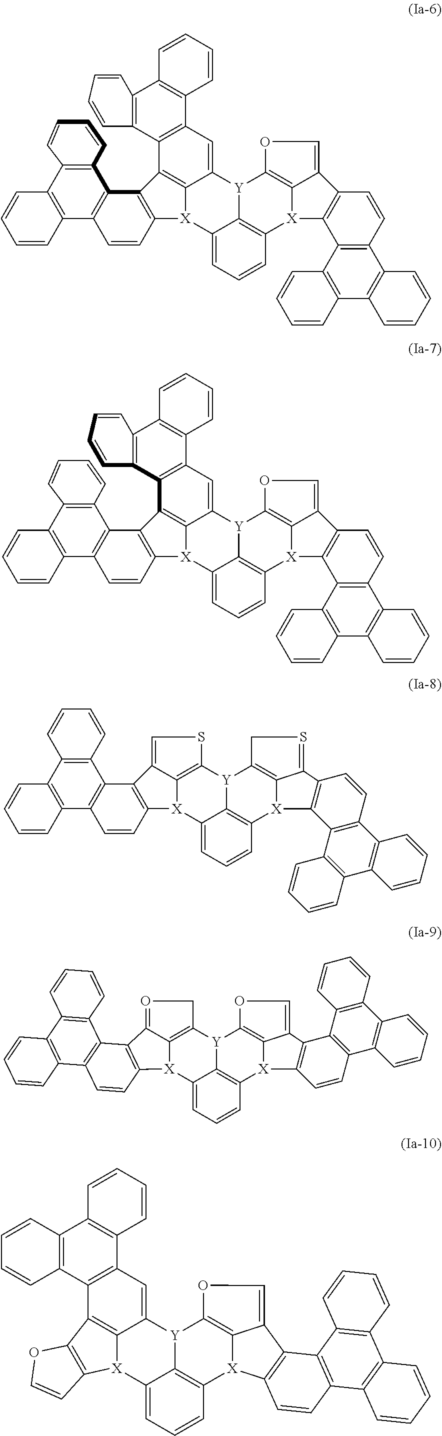

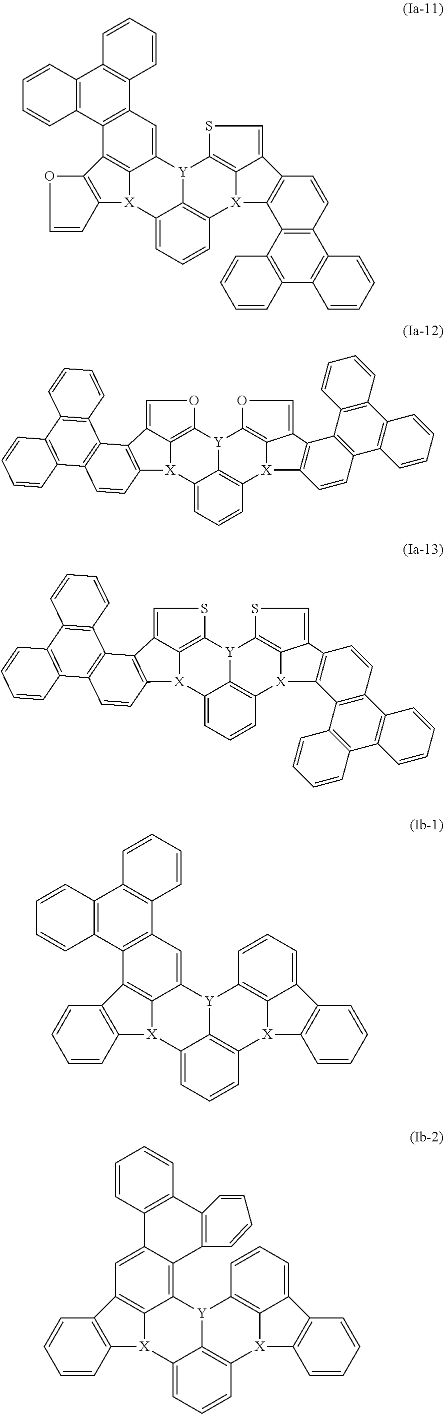

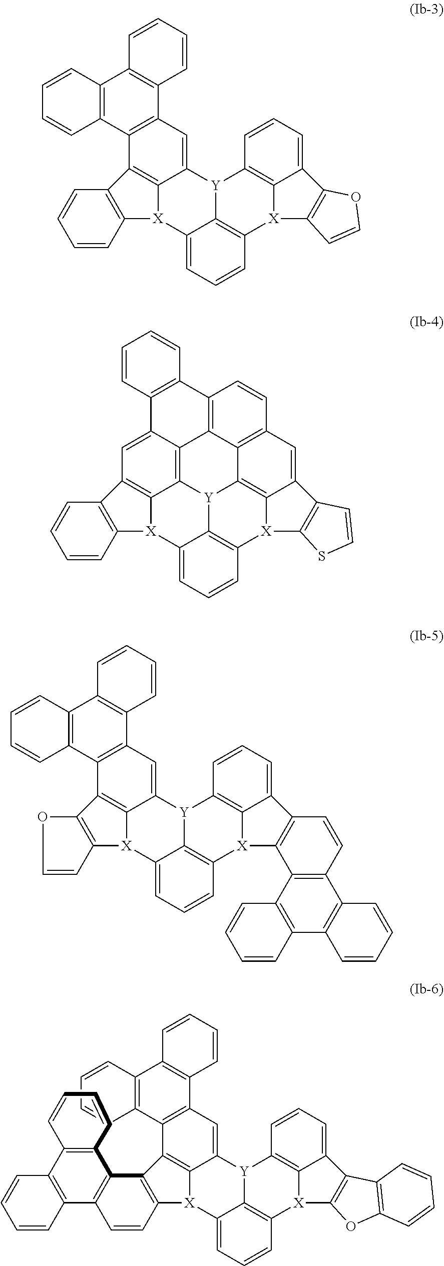

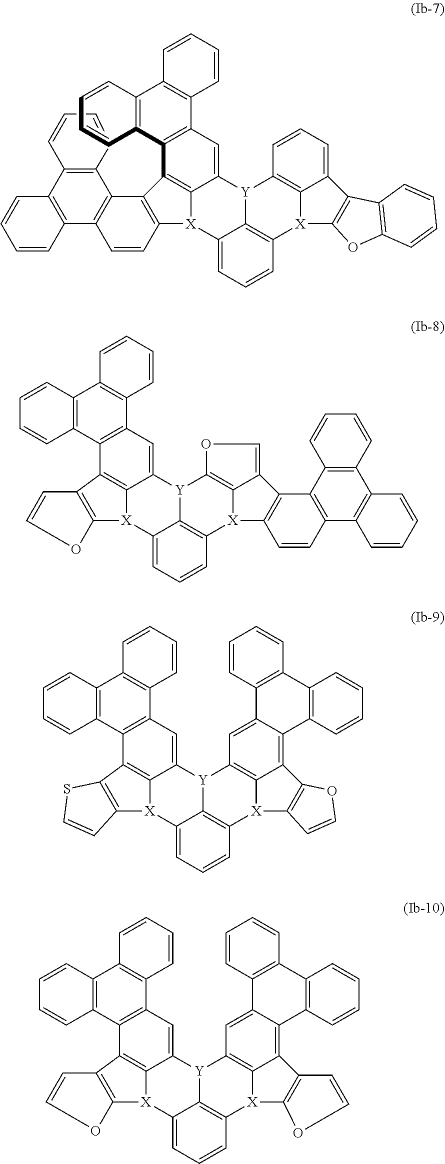

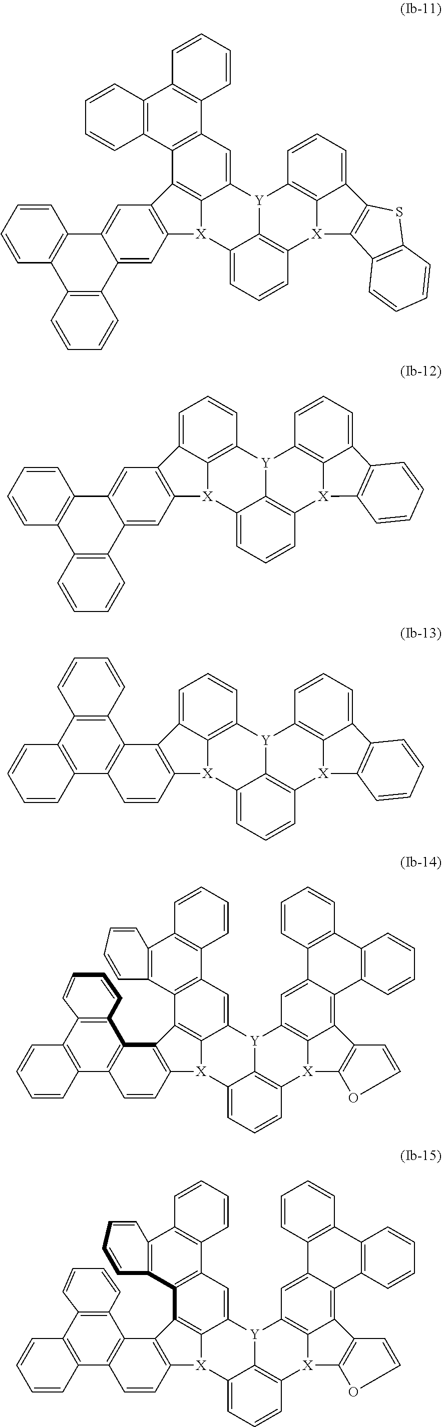

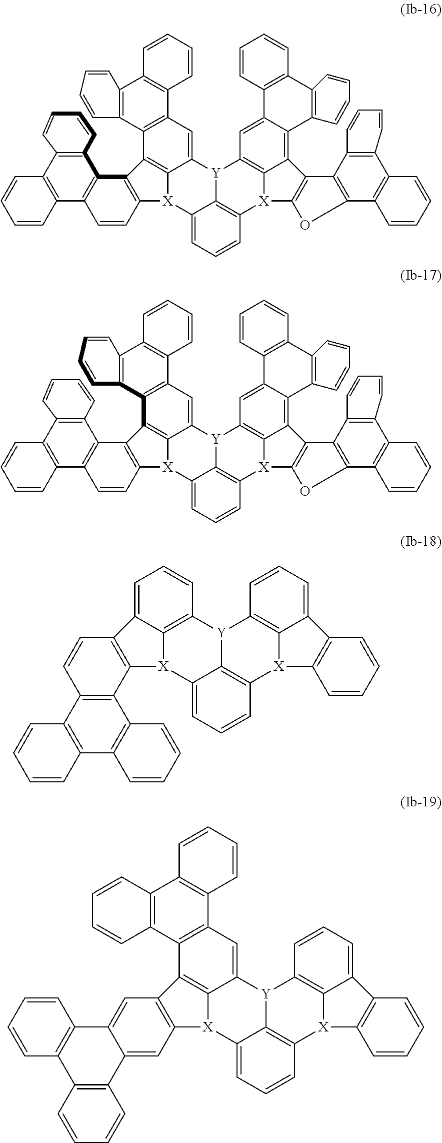

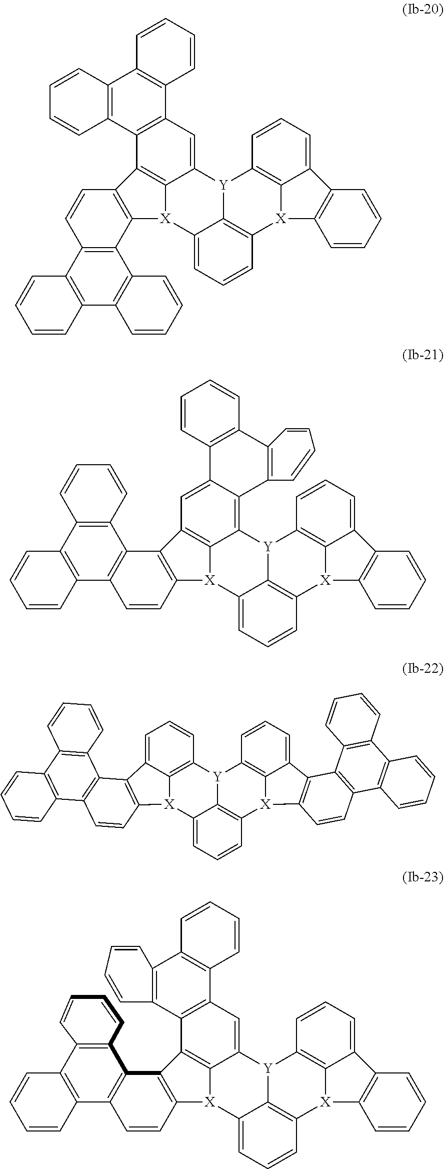

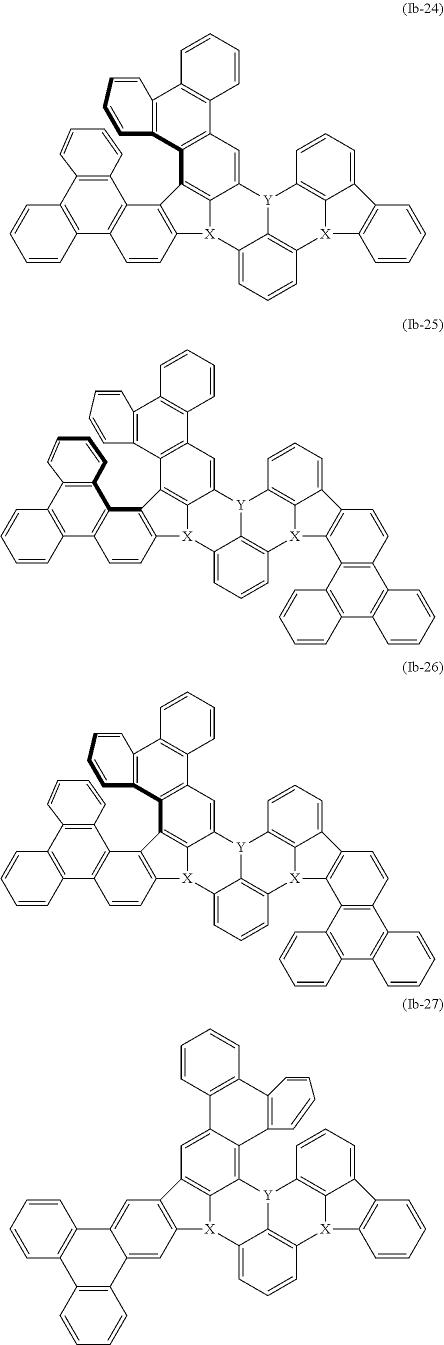

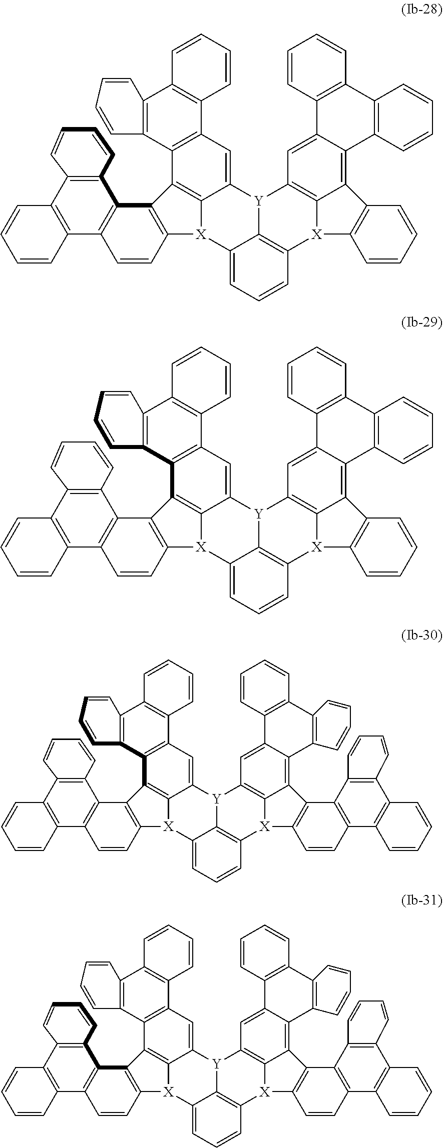

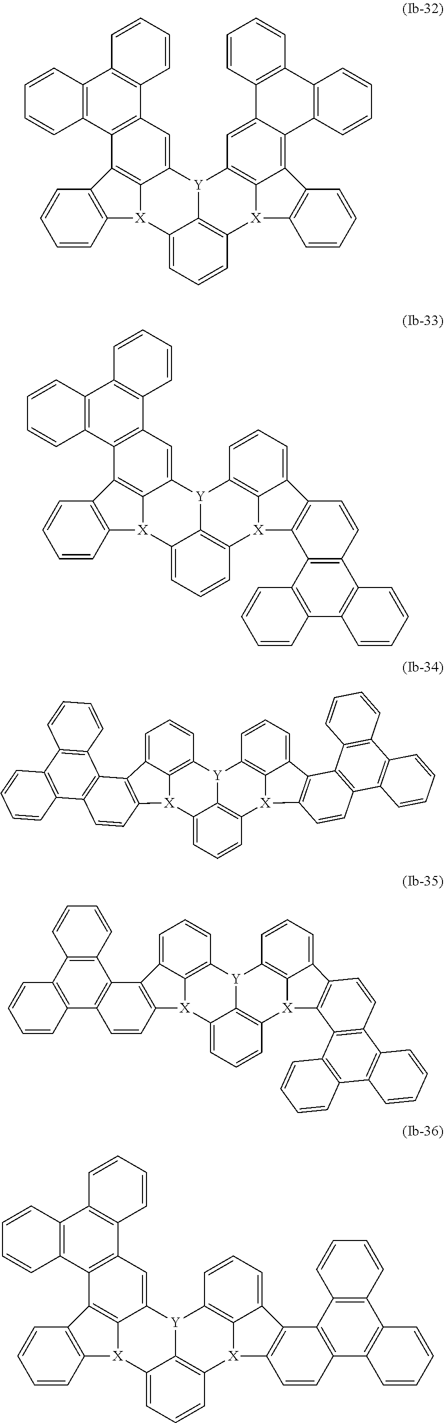

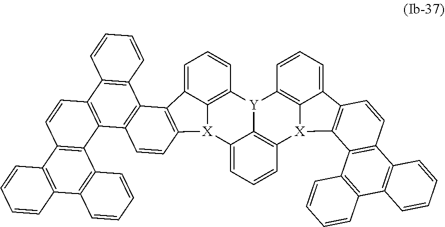

Where X and Y are identically defined as described herein.

In some embodiments, the benzophenanthrene-containing organic compound is a structure of formula (IIa-1)-formula (IIa-7), formula (IIb-1)-formula (IIb-31):

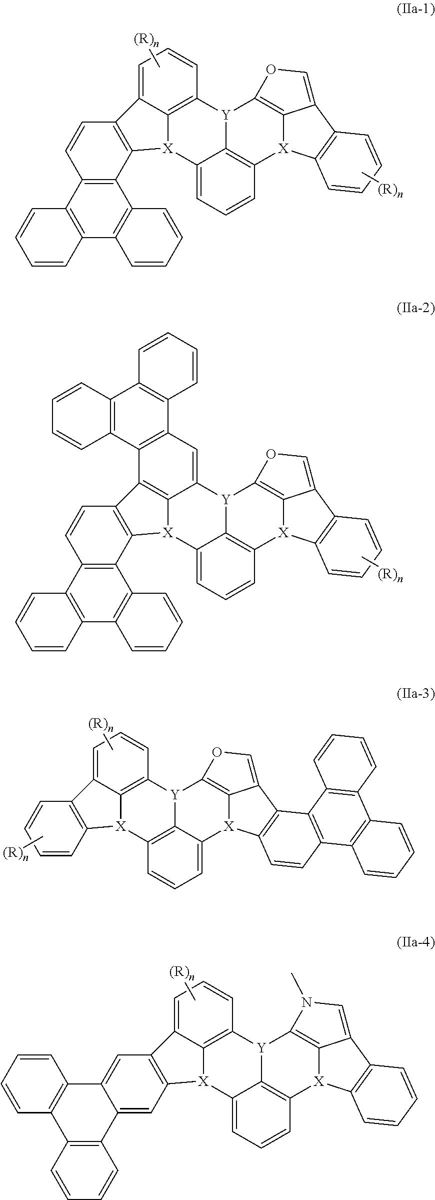

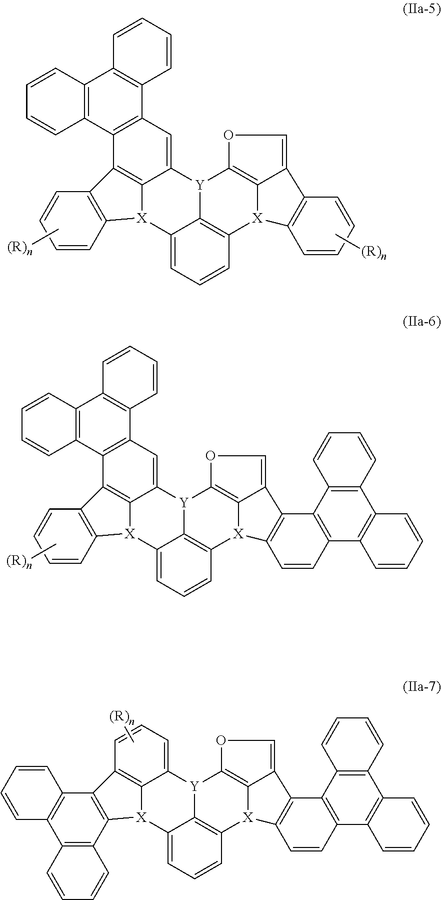

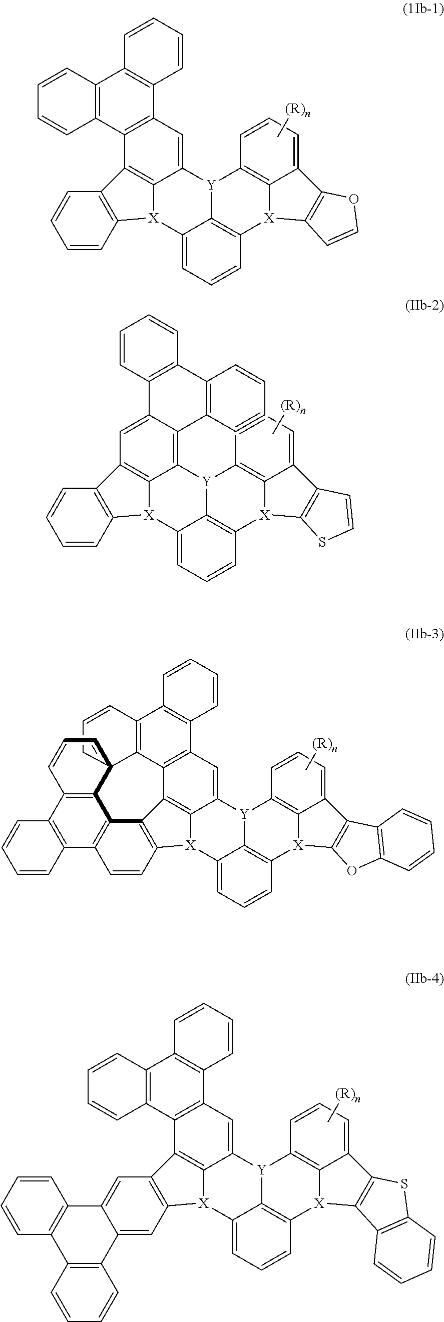

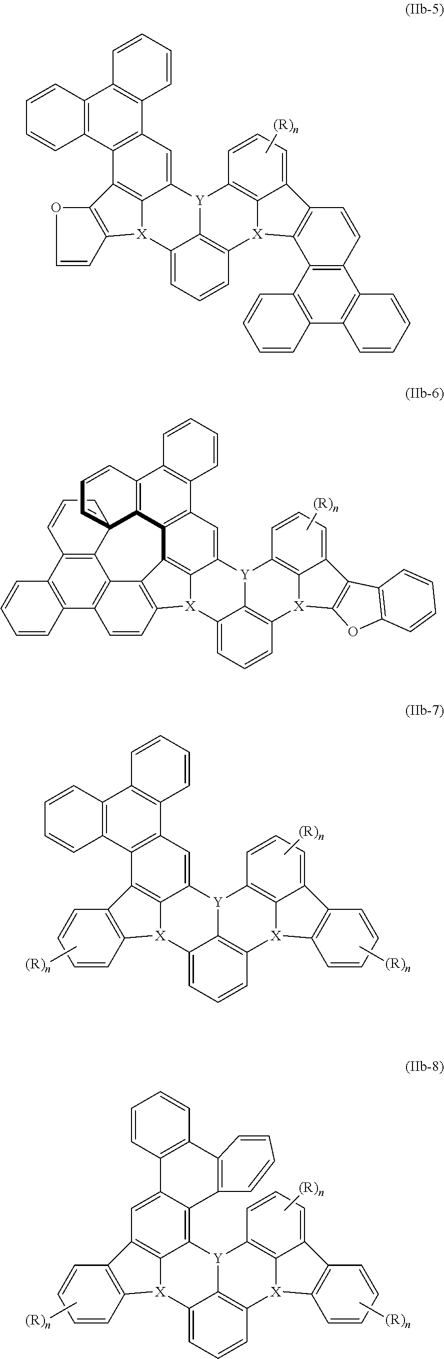

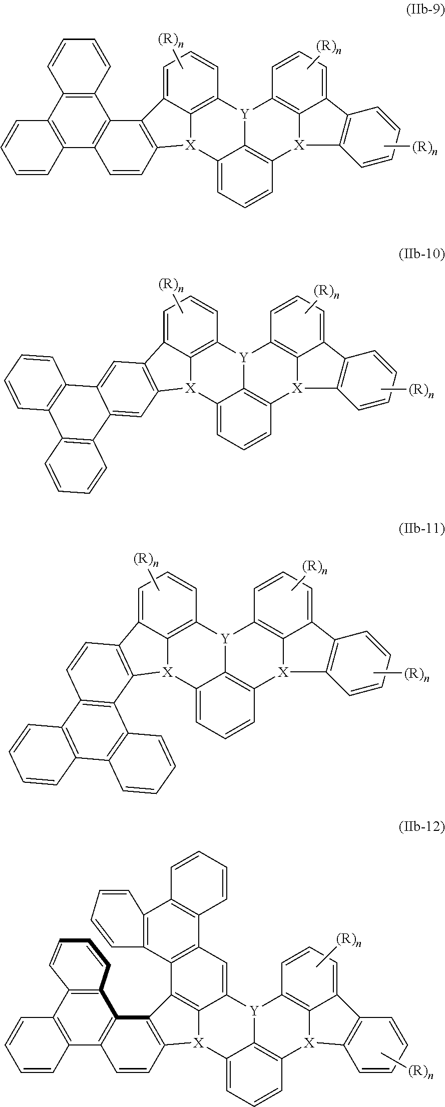

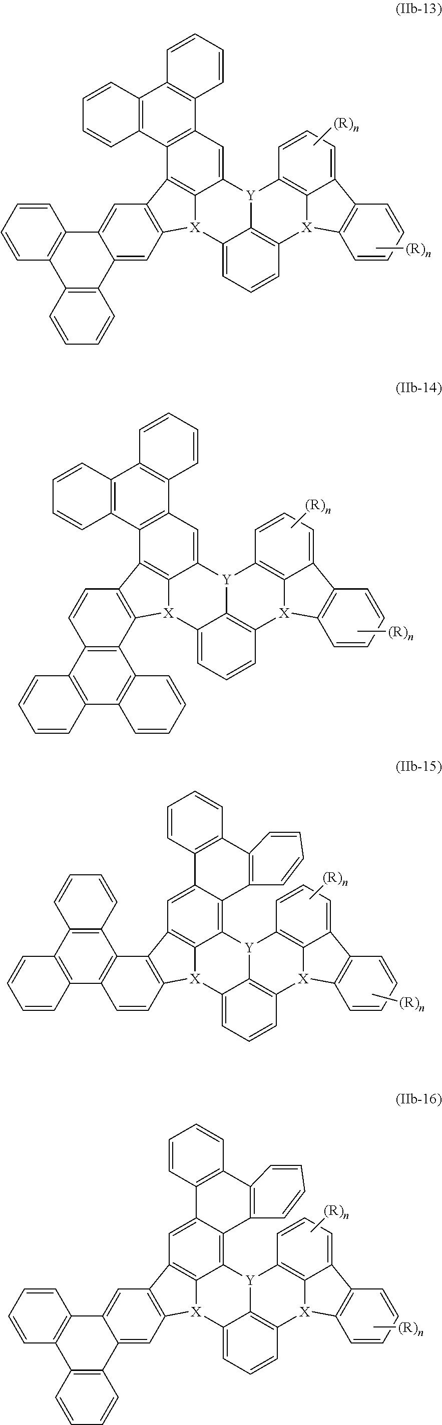

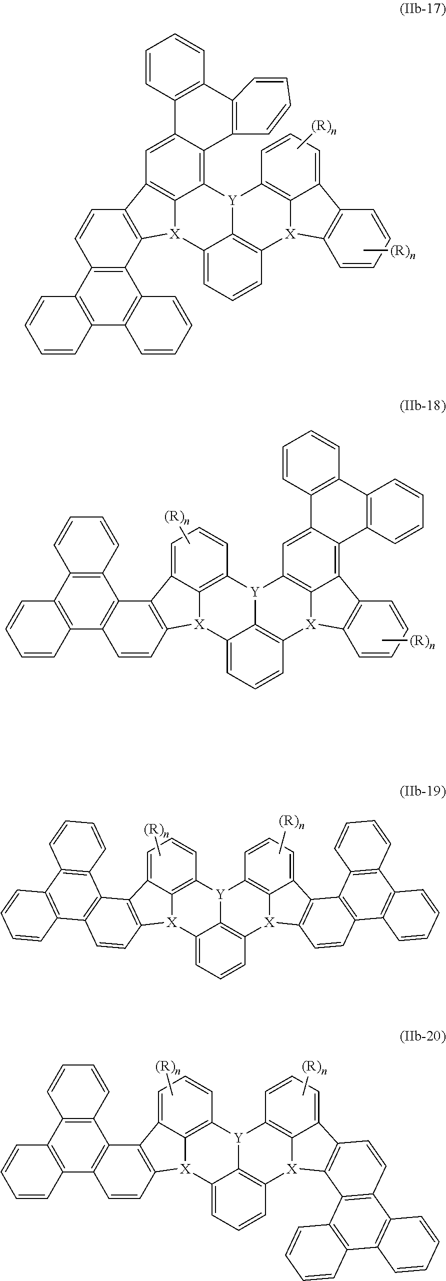

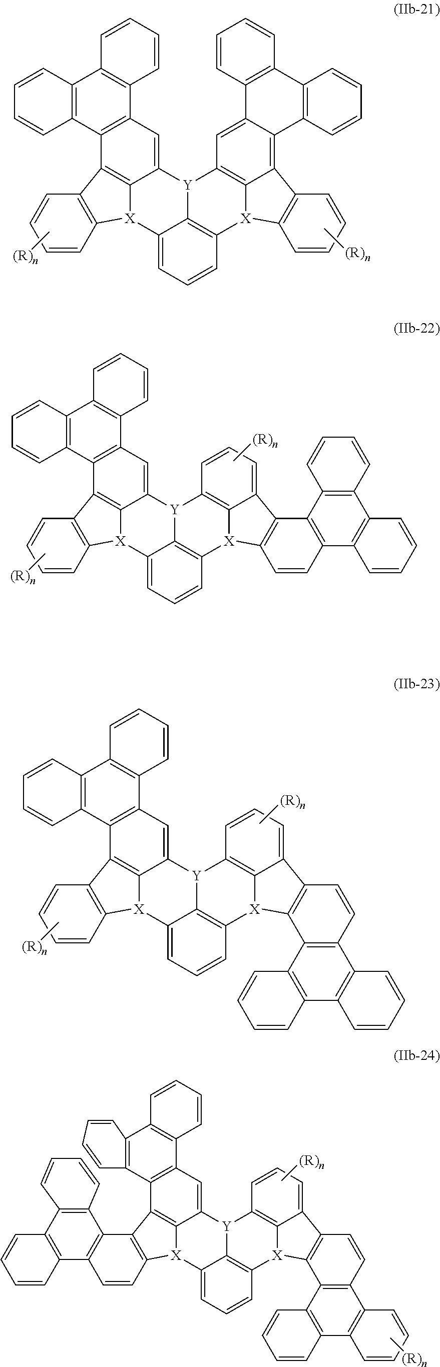

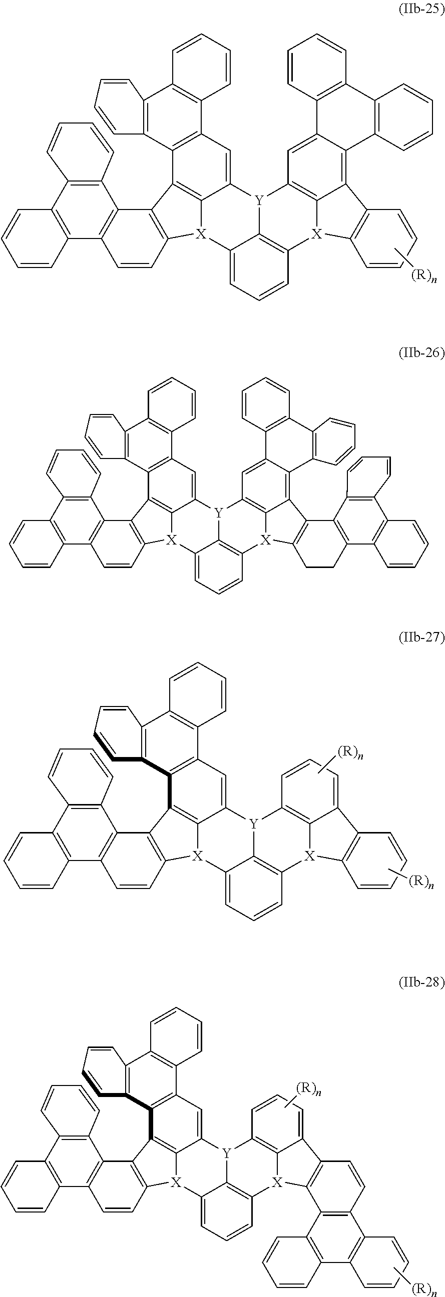

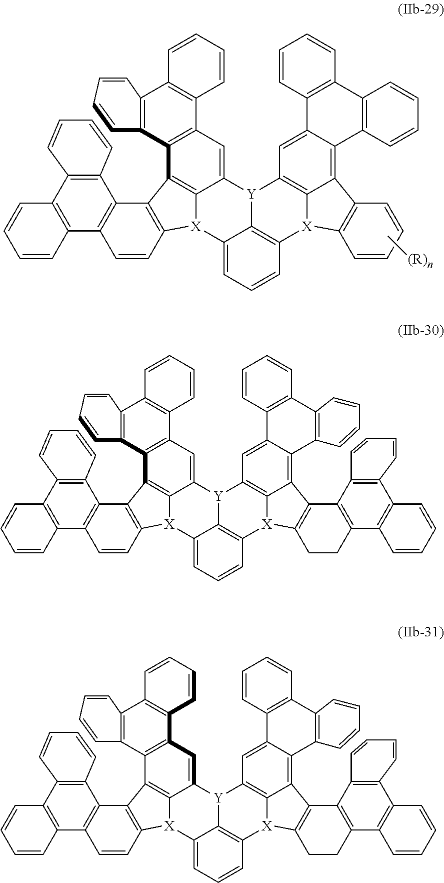

Where X, Y, and R are identically defined as described herein, n is an integer from 0 to 4.

In some embodiments, each of A, B, C, and D at each occurrence is independently selected from the following groups:

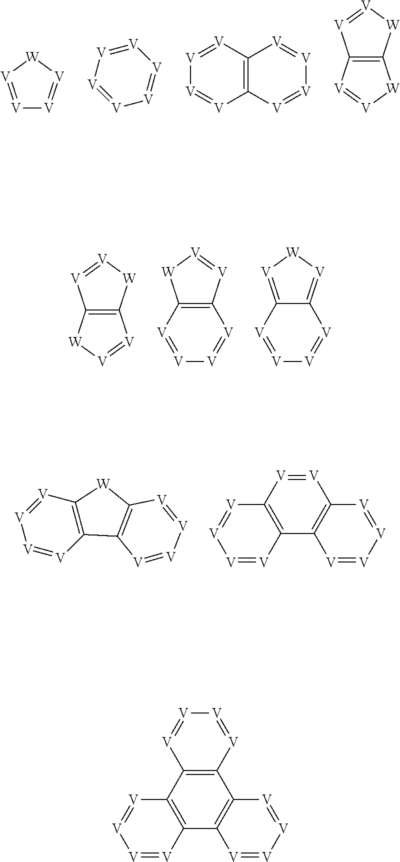

Where w at each occurrence is independently selected from CR¹R², NR¹, O, S, SiR¹R², PR¹, P(═O)R¹, S═O, S(═O)₂, or C═O; v at each occurrence is independently selected from CR³ or N; each of R¹ to R³ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 60 ring atoms, an aryloxy or heteroaryloxy group containing 5 to 60 ring atoms, or any combination thereof.

In some embodiments, the aromatic group or heteroaromatic group is selected from the following groups:

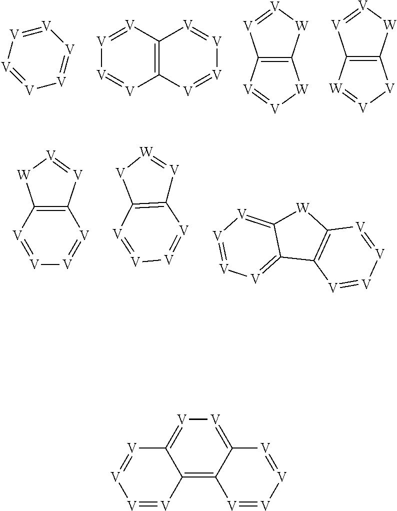

Where w and v are identically defined as described herein.

More preferably, the aromatic group or heteroaromatic group is selected from the group consisting of:

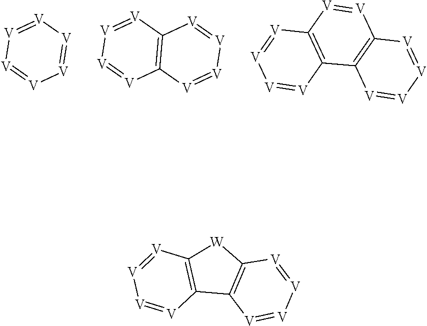

Where w and v are identically defined as described herein.

Further, the aromatic group is selected from the group consisting of: benzene, naphthalene, anthracene, fluoranthene, phenanthrene, benzophenanthrene, perylene, tetracene, pyrene, benzopyrene, acenaphthylene, fluorene, and derivatives thereof, etc.; the heteroaromatic group is selected from the group consisting of: benzofuran, benzothiophene, indole, carbazole, pyrroloimidazole, pyrrolopyrrole, thienopyrrole, thienothiophene, furopyrrole, furofuran, thienofuran, benzisoxazole, benzoisothiazole, benzimidazole, quinoline, isoquinoline, o-diazanaphthalene, quinoxaline, phenanthridine, perimidine, quinazoline, benzoyleneurea, and derivatives thereof, etc.

In some embodiments, each of A, B, C, and D is independently selected from the following groups:

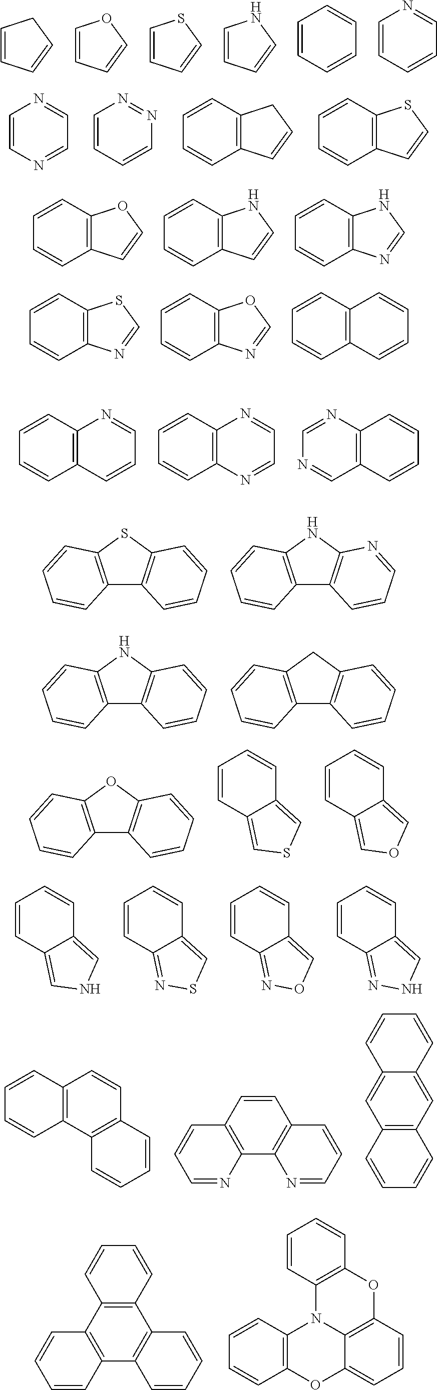

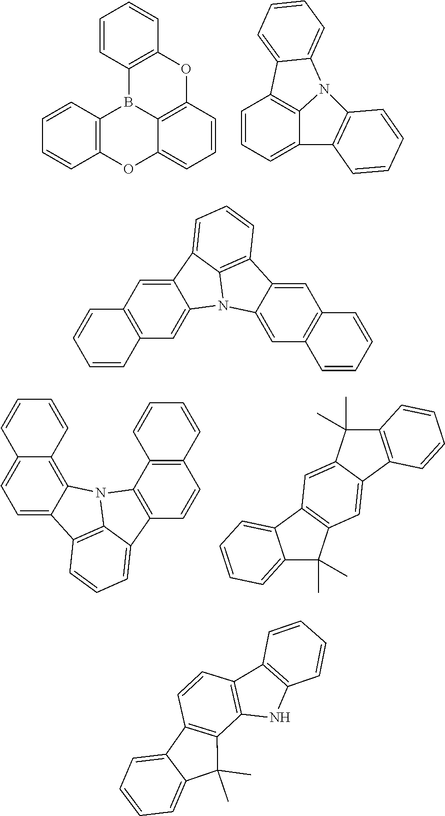

Where H atoms on the ring may be further substituted.

In some embodiments, in the benzophenanthrene-containing organic compound as described herein, each of A, B, C, and D at each occurrence can be further selected from the following groups or any combination thereof:

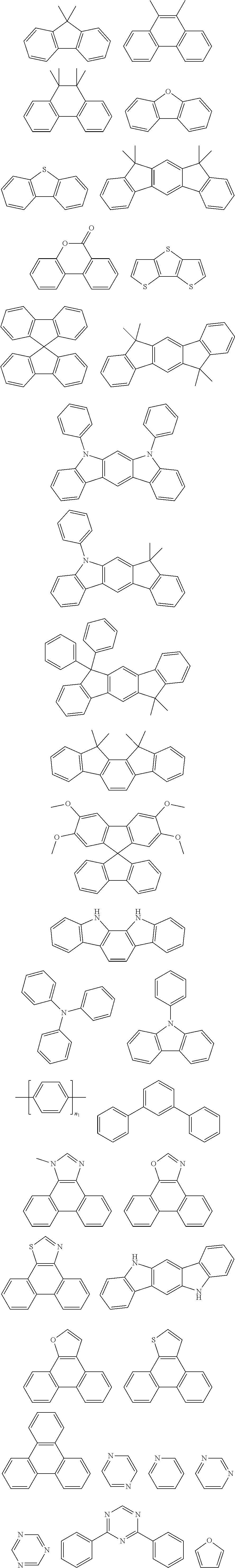

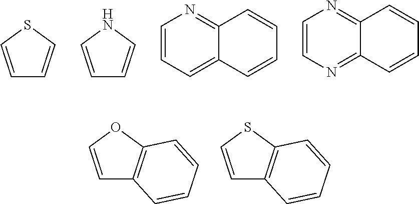

Where n₁ is an integer from 1 to 4.

In some embodiments, R at each occurrence is independently selected from the following groups:

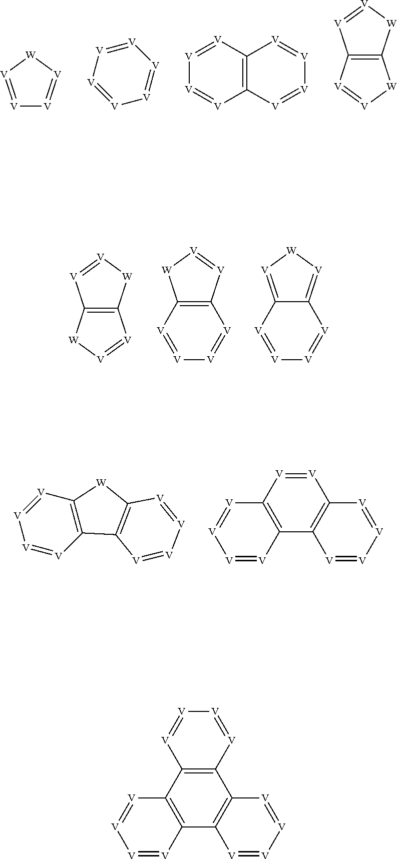

Where w and v are identically defined as described herein.

In some embodiments, the benzophenanthrene-containing organic compound is a structure of formula (IIc-1)-formula (IIc-31), where the planar configuration is distorted by introducing a large steric hindrance group (Z). The π-π mutual attraction caused by the introduction of the benzene ring can be weakened by adjusting the different substituents on the large steric hindrance group, further reducing the intermolecular forces and so as to reduce the adverse effect of concentration quenching on efficiency. At the same time, the introduction of the large steric hindrance group can reduce the accumulation in favor of keeping the PL spectrum stable.

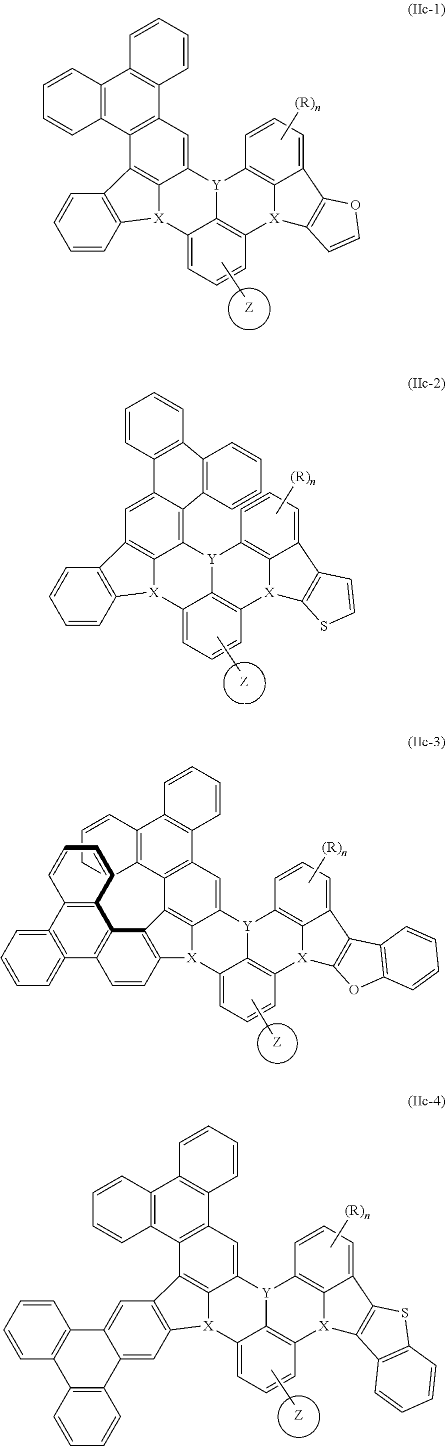

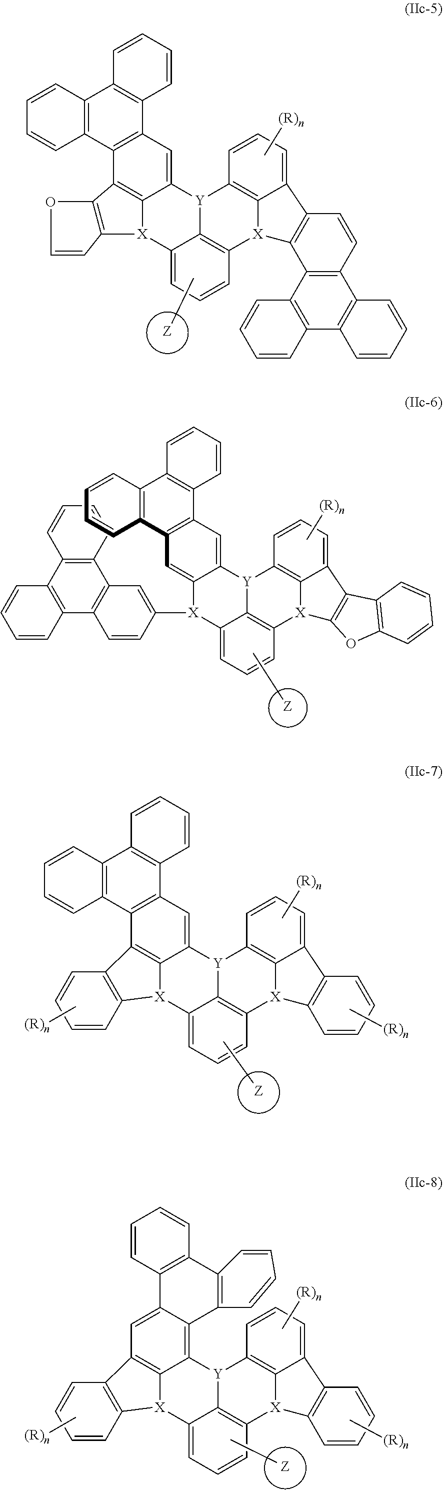

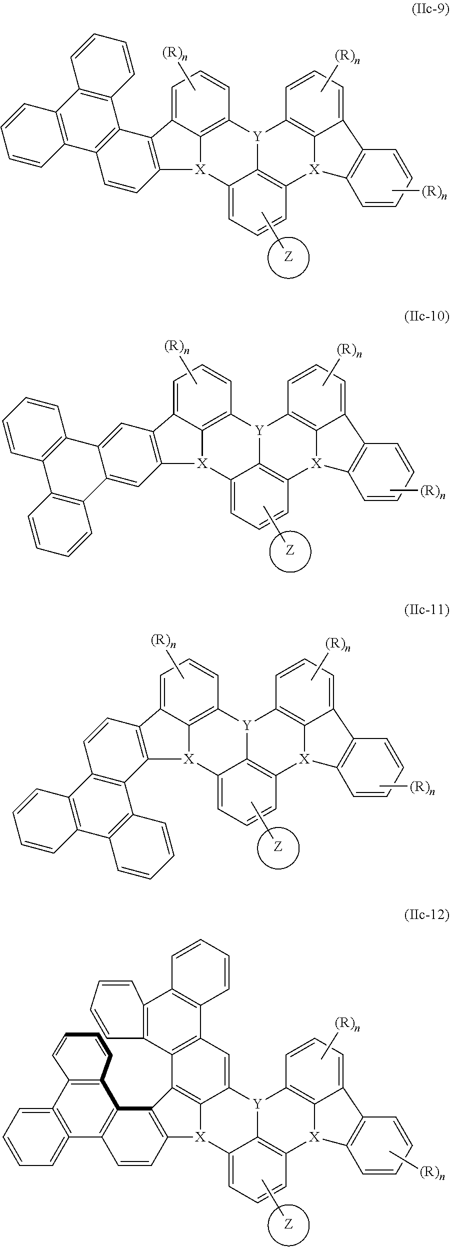

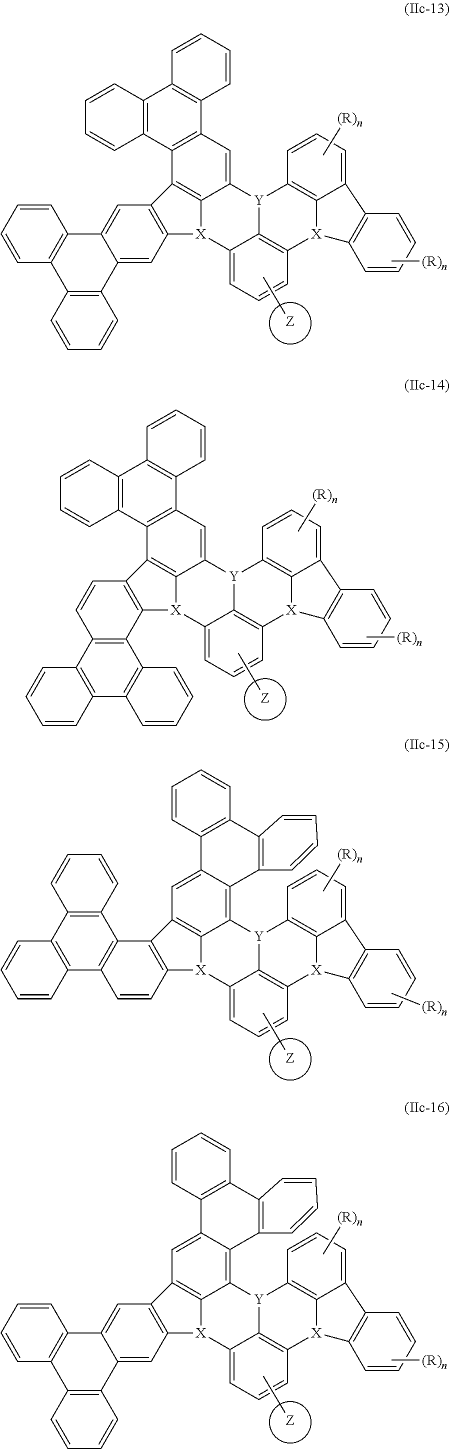

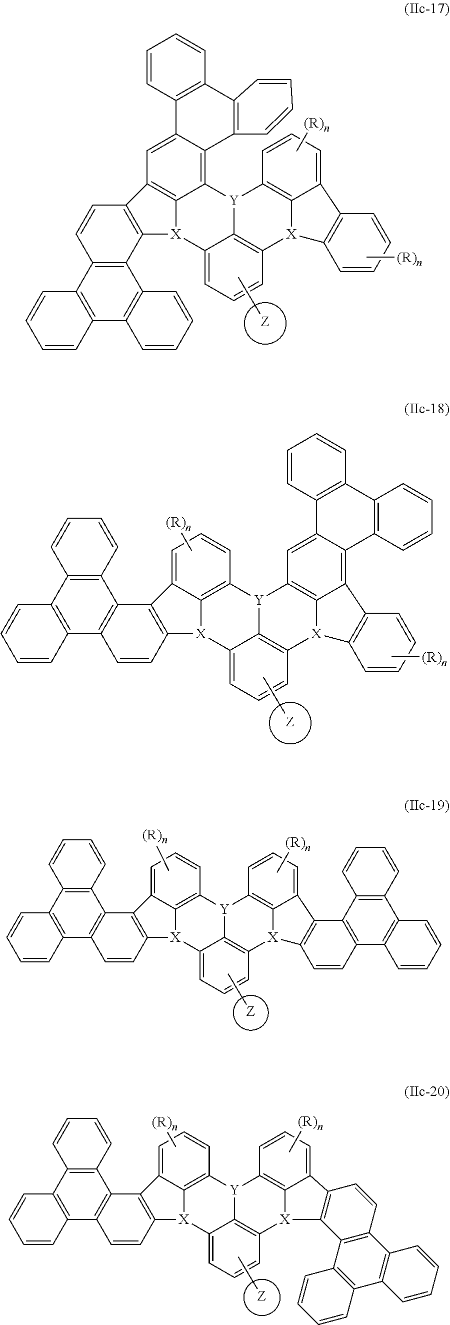

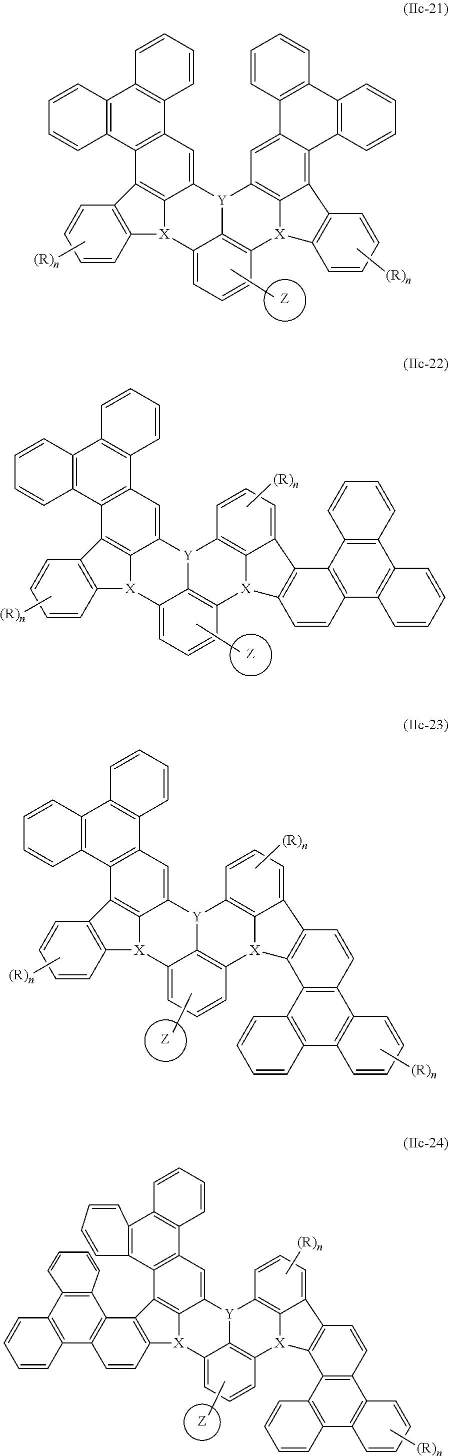

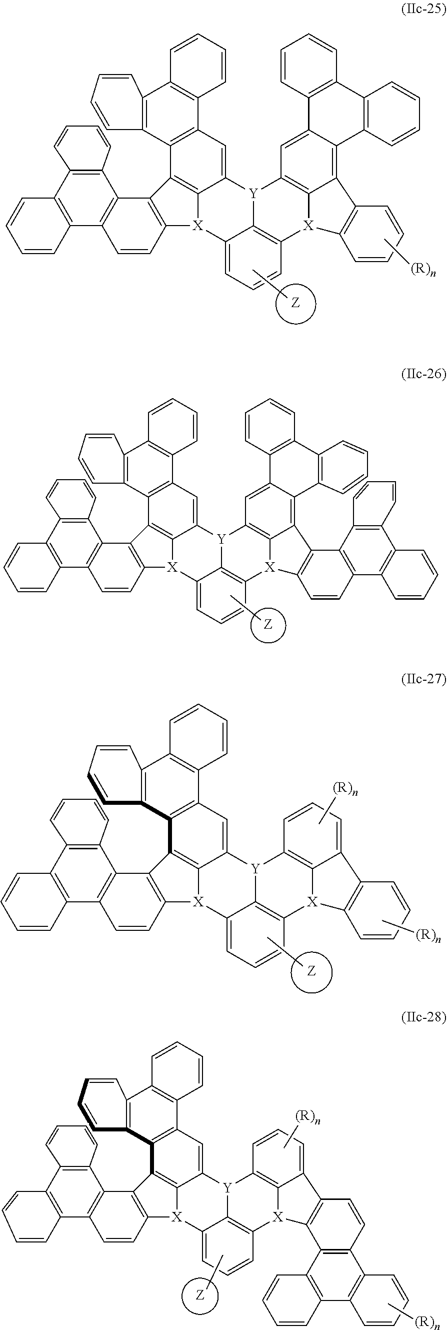

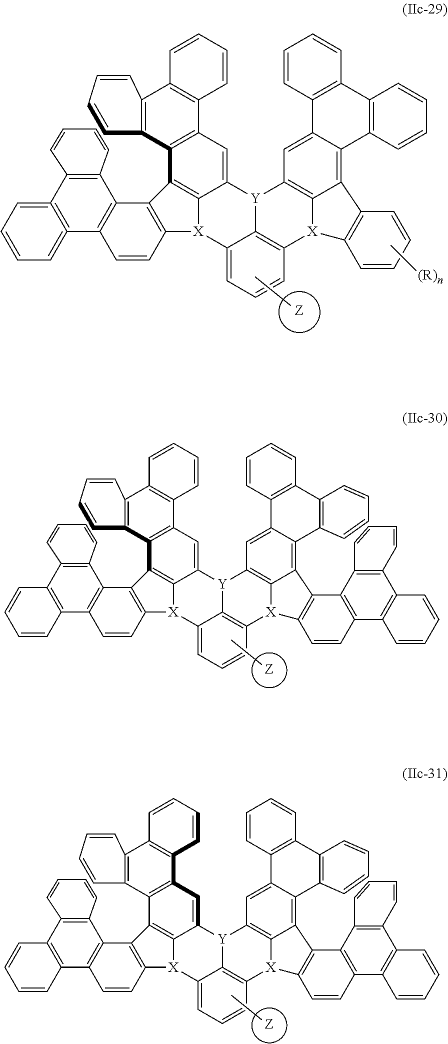

Where X, Y, R, and n are identically defined as described herein.

In some embodiments, each D is independently selected from a C₆-C₆₀ aromatic ring, a C₅-C₆₀ heteroaromatic ring, or a C₁₀-C₆₀ fused-ring structural unit, which is substituted with Zs.

In some embodiments, each Z is a large bulky group of formula (IIIa) or formula (IIIb):

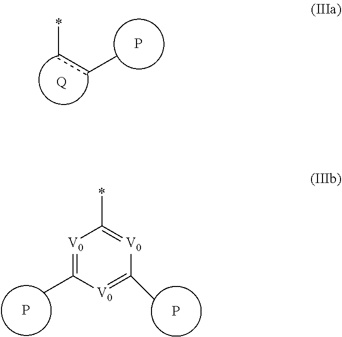

Where the linkage site of P with relative to Q is o-position, each of P and Q is independently selected from a substituted/unsubstituted C₆-C₆₀ aromatic ring, a substituted/unsubstituted C₅-C₆₀ heteroaromatic ring, or a substituted/unsubstituted C₁₀-C₆₀ fused-ring structural unit; V₀ at each occurrence is independently selected from CR⁴ or N; each R⁴ is identically defined as the above-mentioned R¹, and each * independently represents a linkage site (the site where the host is fused to D).

In some embodiments, at least one V₀ in formula (IIIb) is N atom; in some embodiments, at least two V₀s in formula (IIIb) are N atoms; in some embodiments, each V₀ in formula (IIIb) is N atom.

In some embodiments, P and Q are each independently selected from the following structures.

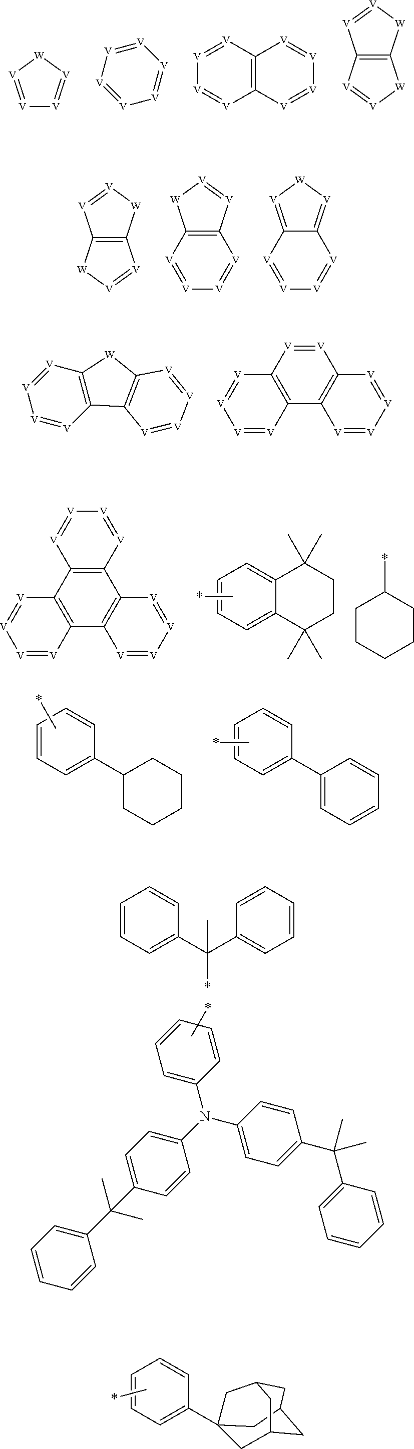

Where w and v are identically defined as described herein.

In some embodiments, each Z is independently selected from the following large steric hindrance groups:

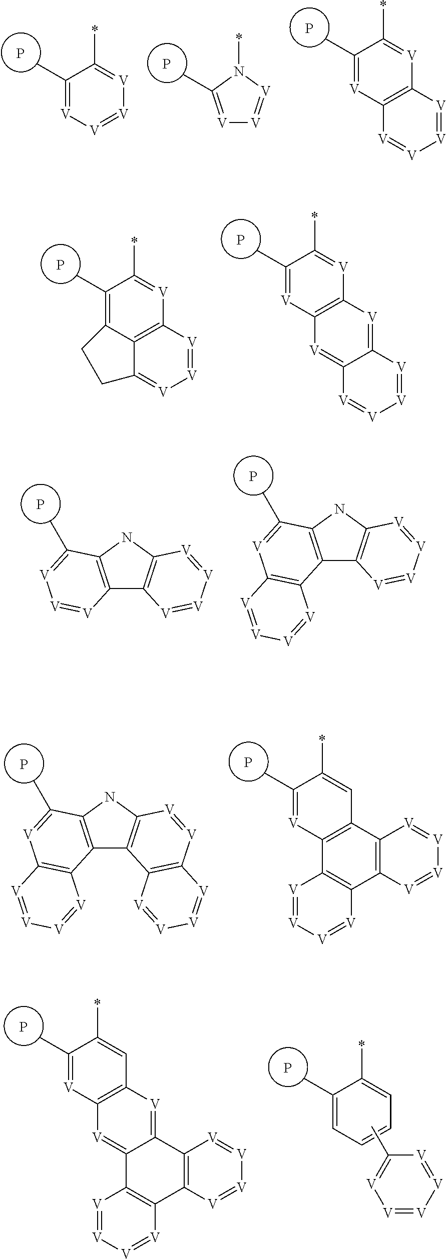

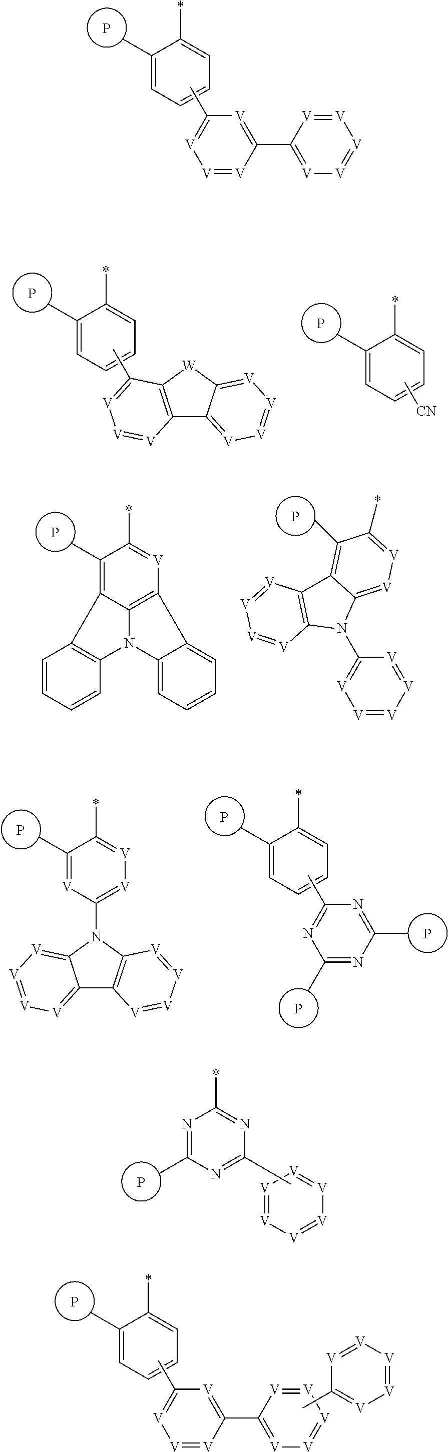

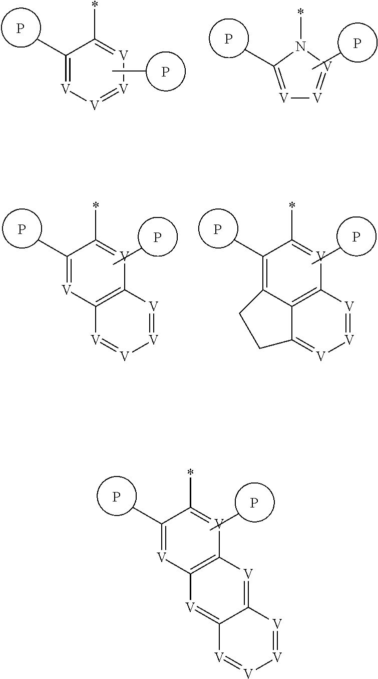

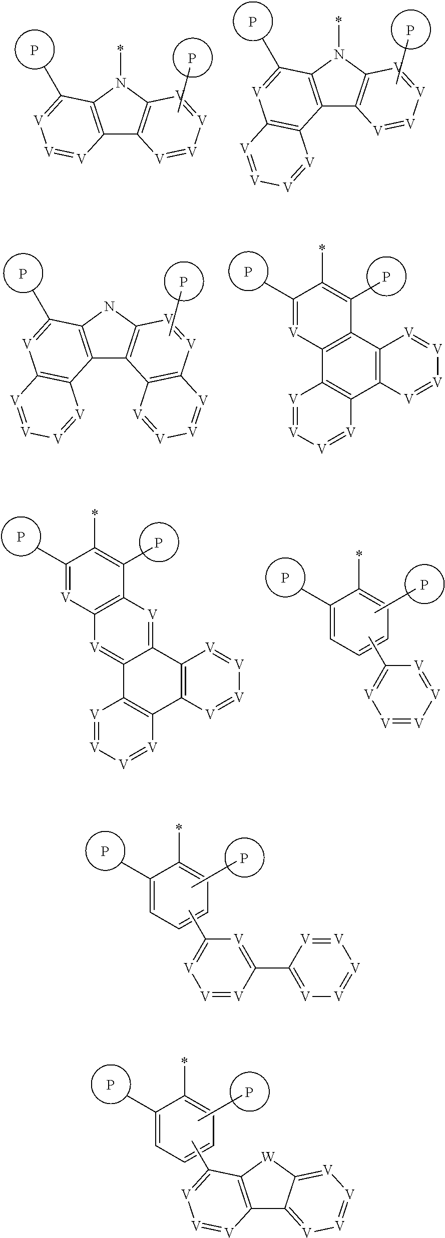

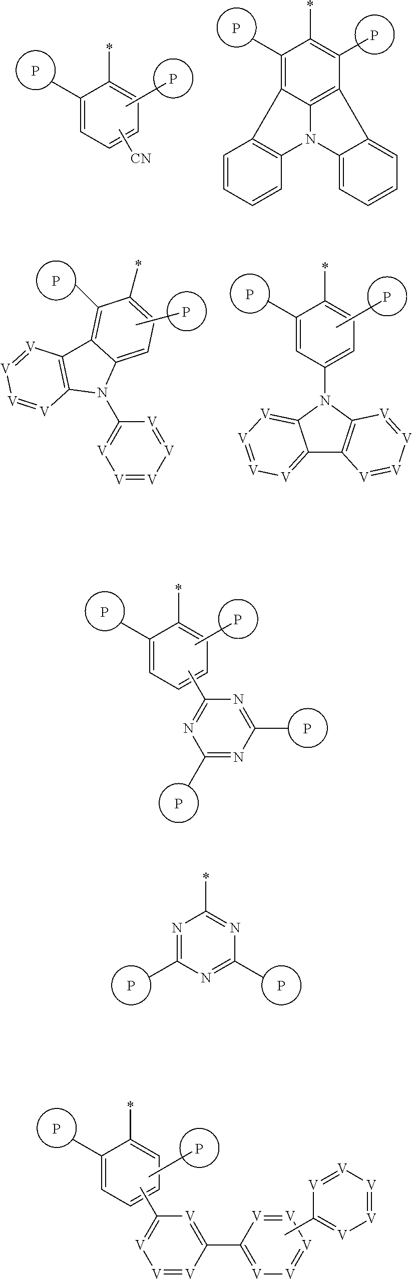

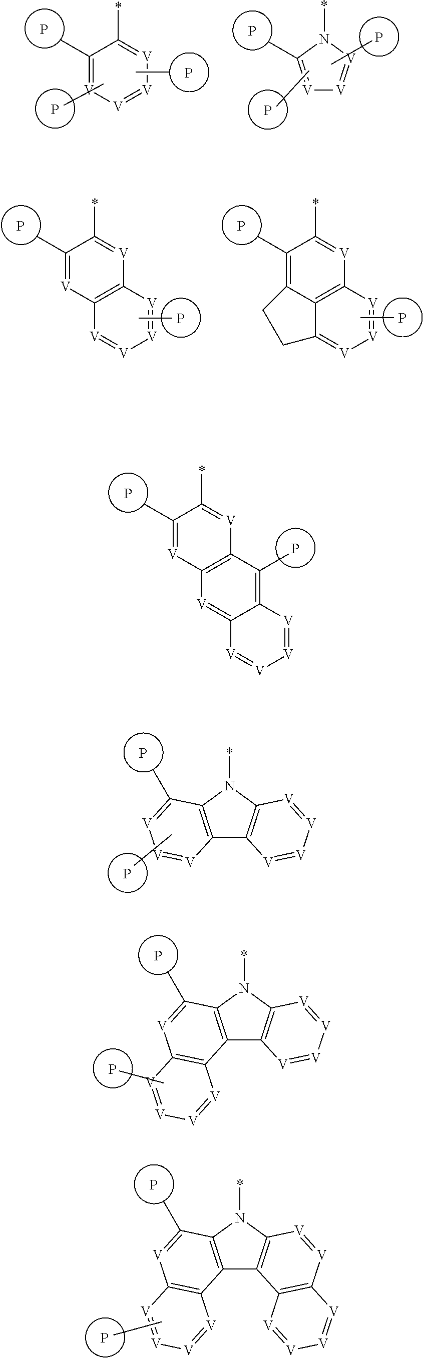

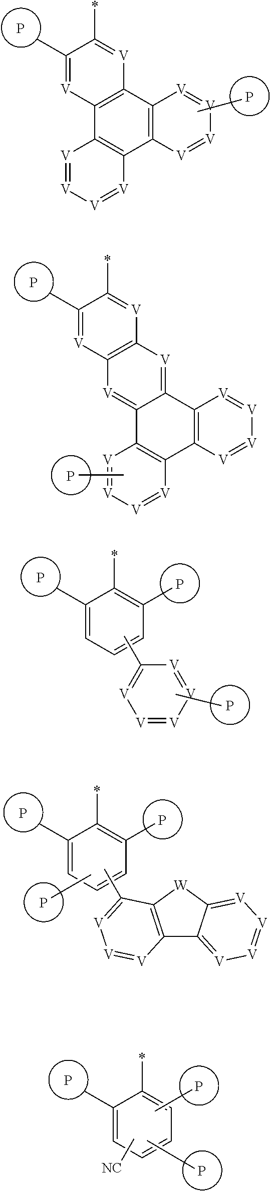

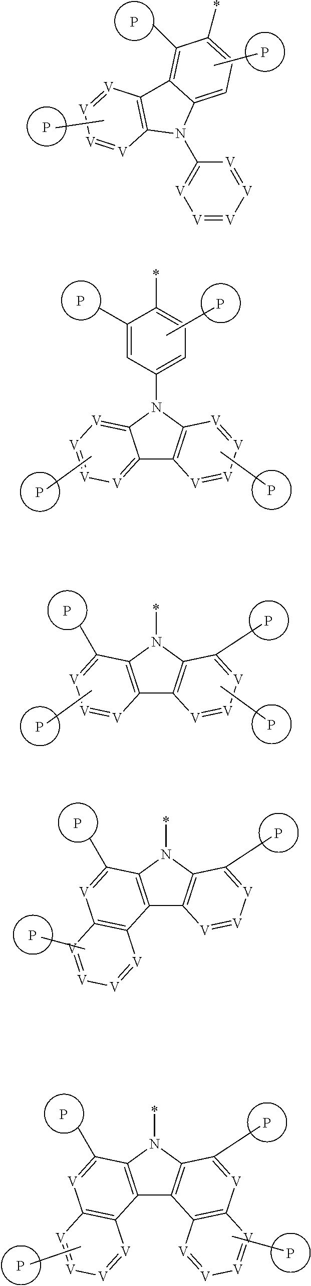

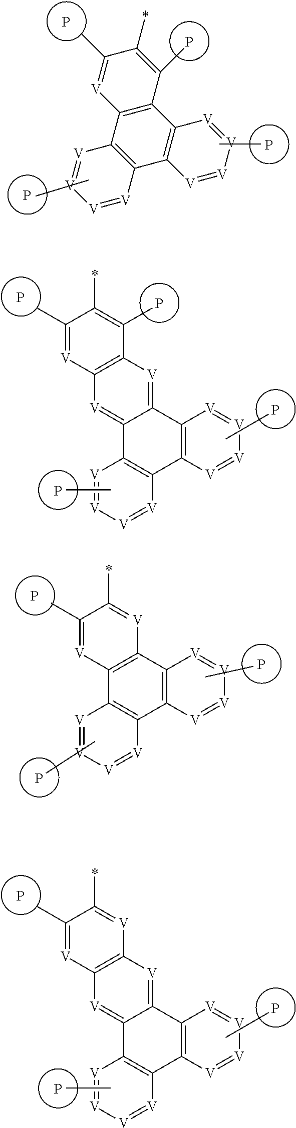

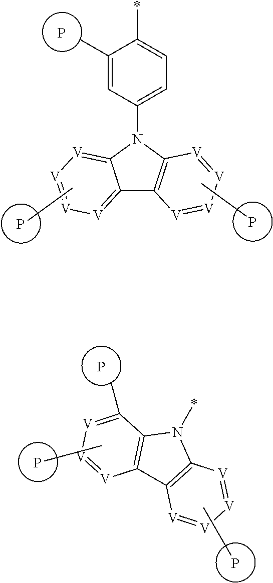

Where w and v are identically defined as described herein. As a substituent, P can substituted any H on the ring, and in the above-mentioned groups with large steric hindrance structures, when P is arbitrarily substituted, at least one v is CR⁵ in the corresponding ring, and each R⁵ is H.

Specifically: taking structural formula

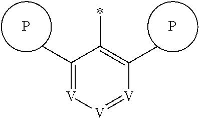

as an example, the partial combinations thereof are as follows:

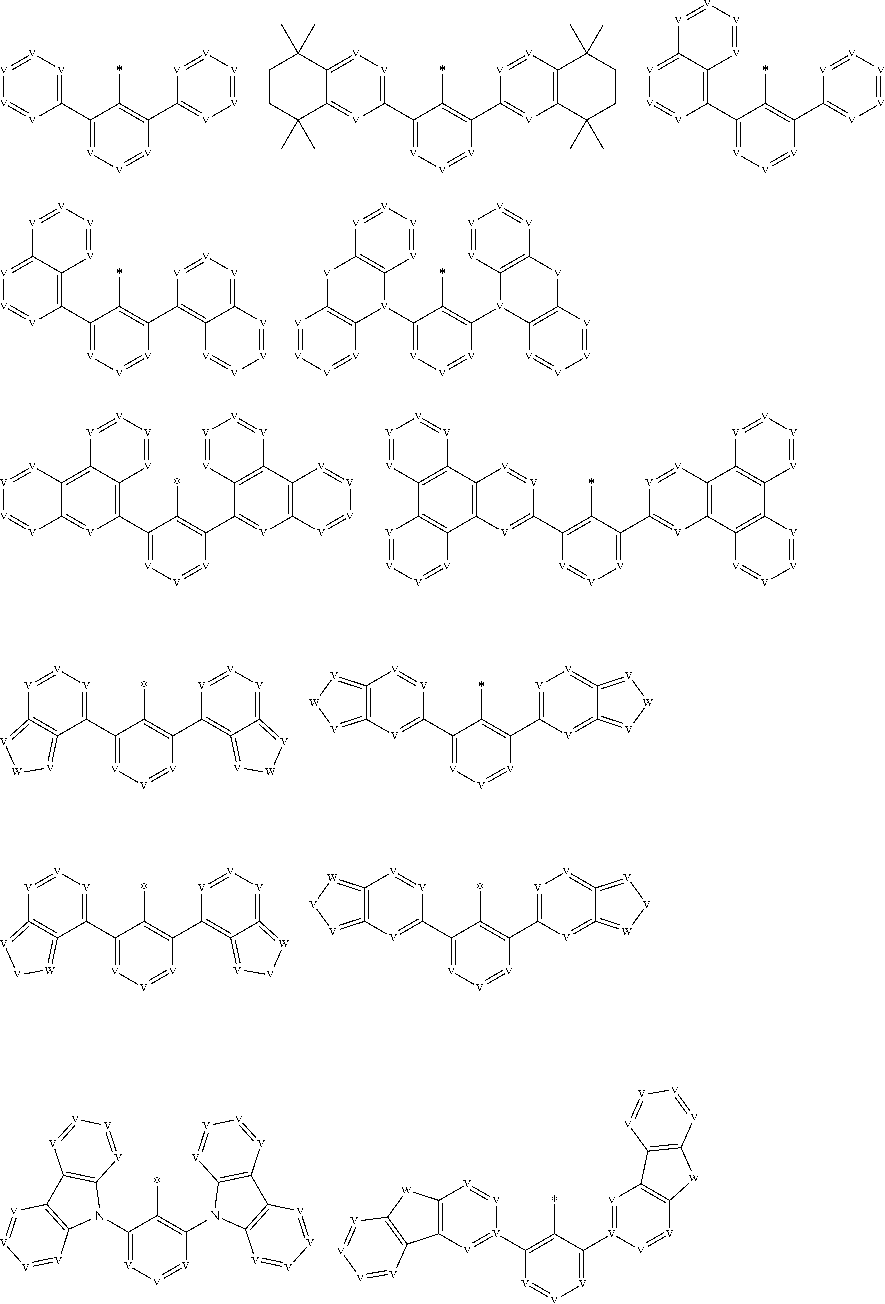

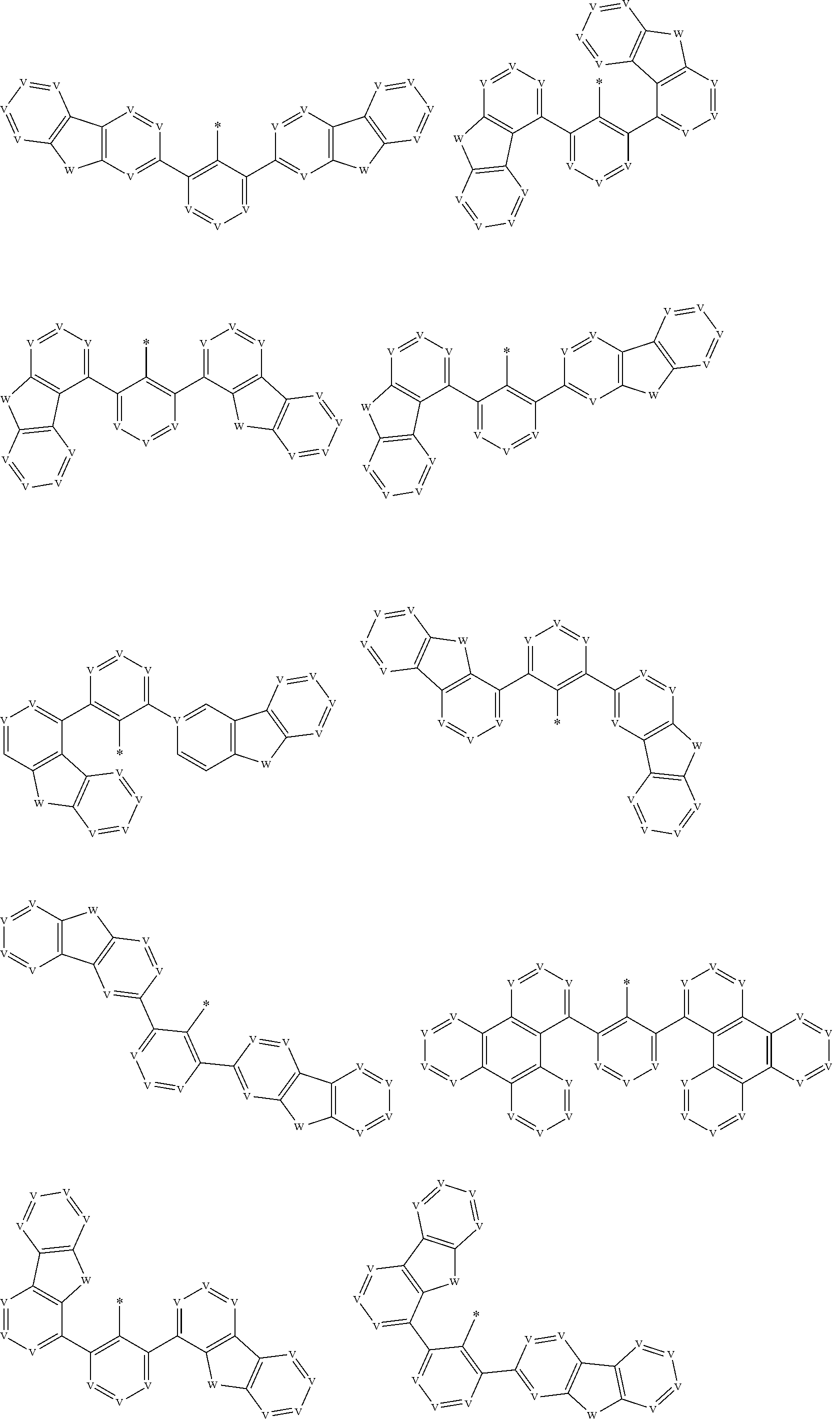

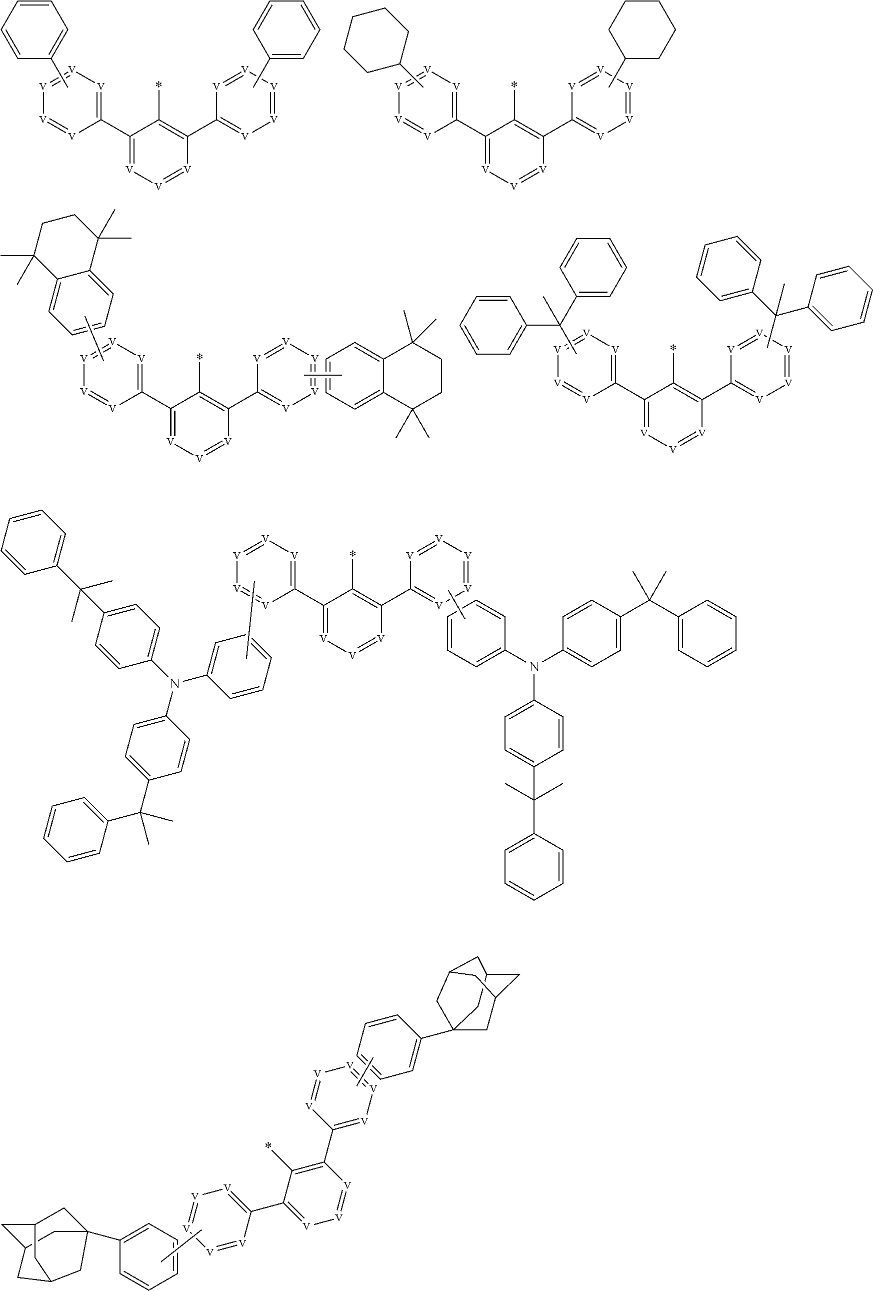

Where each * independently represents a linkage site; w and v are identically defined as described herein.

In some embodiments, each R is benzene or naphthalene.

In some embodiments, each R is a heteroaromatic group.

In some embodiments, the benzophenanthrene-containing organic compound is partially deuterated; preferably 10% or more of total H, more preferably 20% or more of total H, further preferably 30% or more of total H, and most preferably 40% or more of total H, are deuterated.

In some embodiments, the benzophenanthrene-containing organic compound is a chiral molecule, and the preferred spin mode thereof is a P-type chiral molecule; in some embodiments, the benzophenanthrene-containing organic compound is a M-type chiral molecule.

The general method for separating chiral molecules is as follows: the chiral compounds are dissolved in an organic solvent, then P-, M-type chiral compounds are split and purified by chiral split column chromatography.

Preferably, the benzophenanthrene-containing organic compound with chirality is selected from one of formulas (I-4)-(I-7) and (I-11)-(I-14).

More preferably, the benzophenanthrene-containing organic compound with chirality is selected from one of formulas (Ia-6), (Ia-7), (Ib-6), (Ib-7), (Ib-13), (Ib-14), (Ib-15), (Ib-17), (Ib-23)-(Ib-31).

Specific structures of the benzophenanthrene-containing organic compounds as described herein are listed below, but not limited thereto; where each bold bond is a chiral molecule:

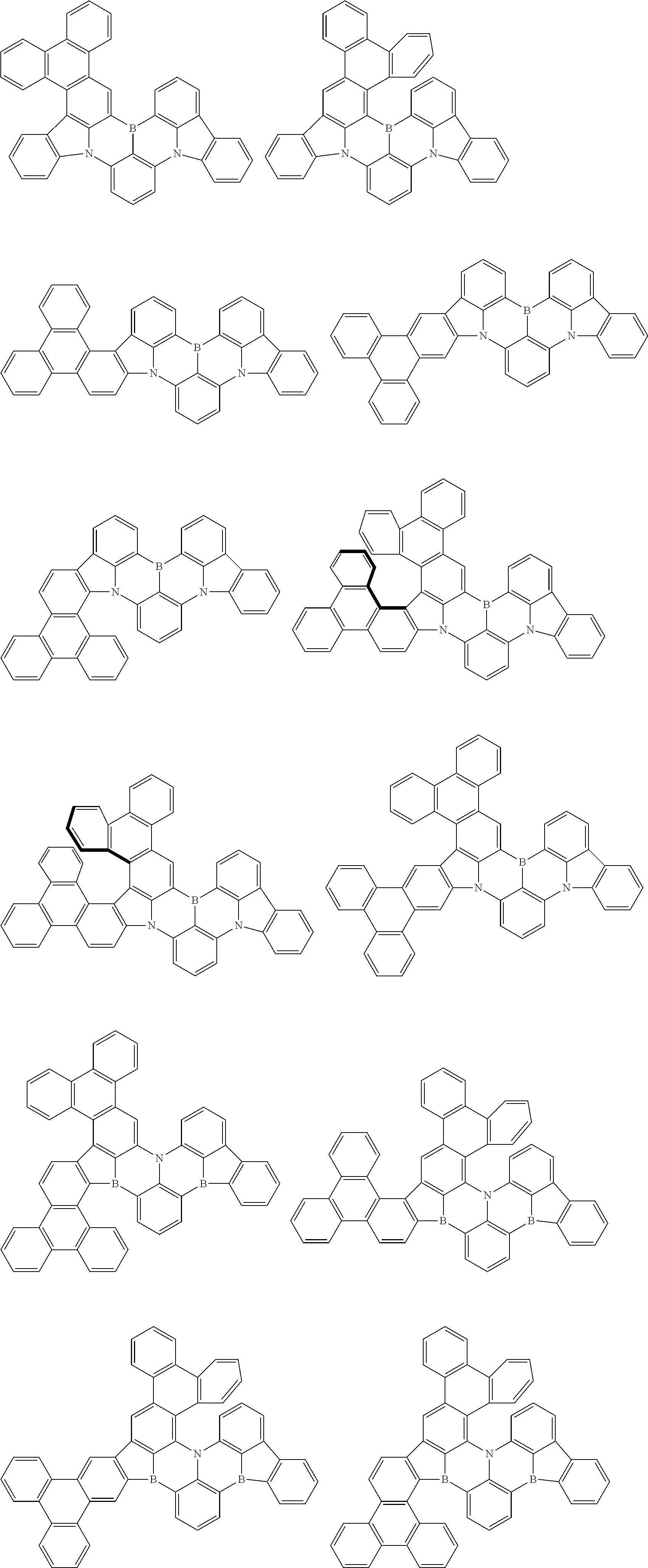

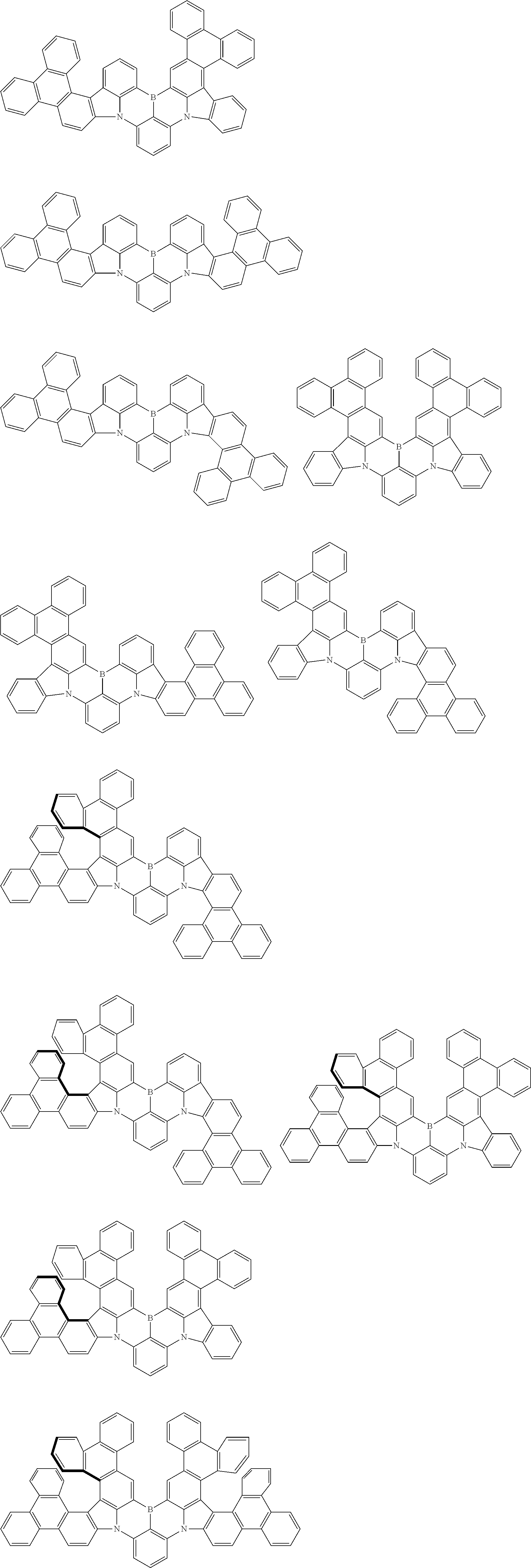

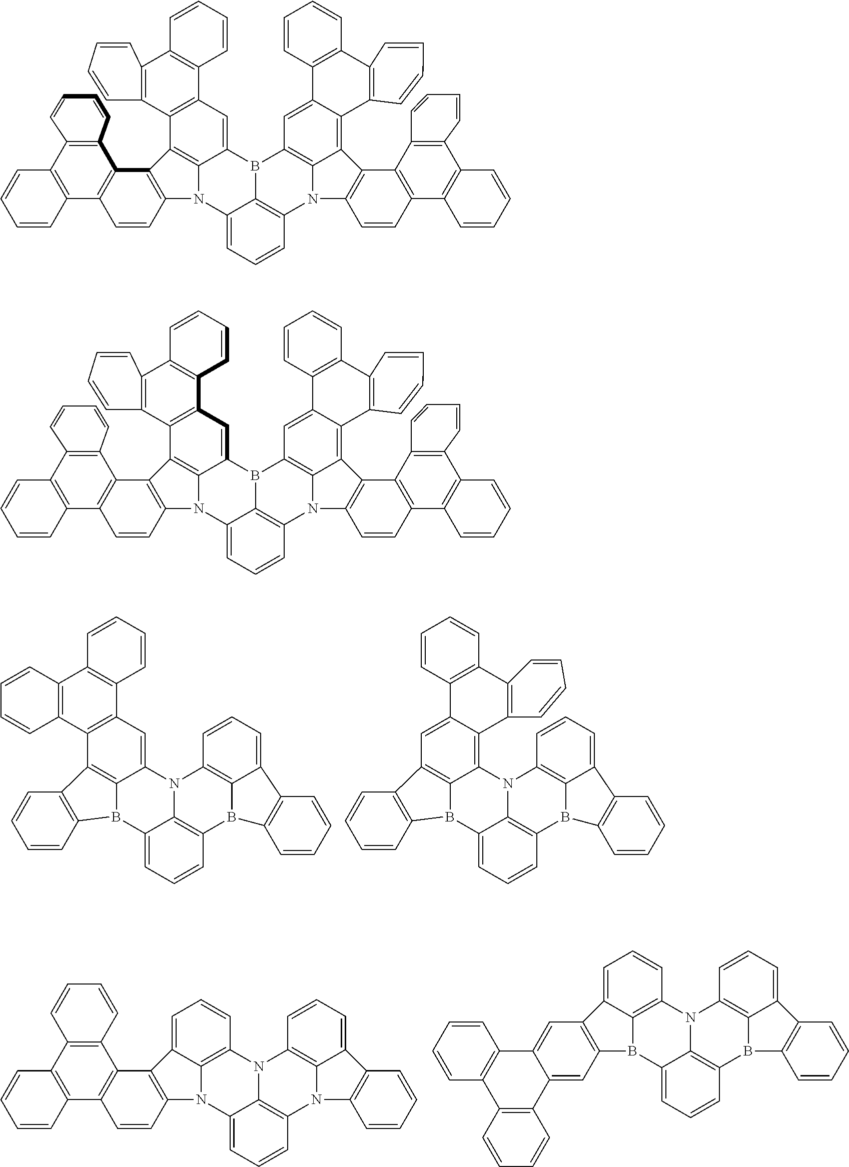

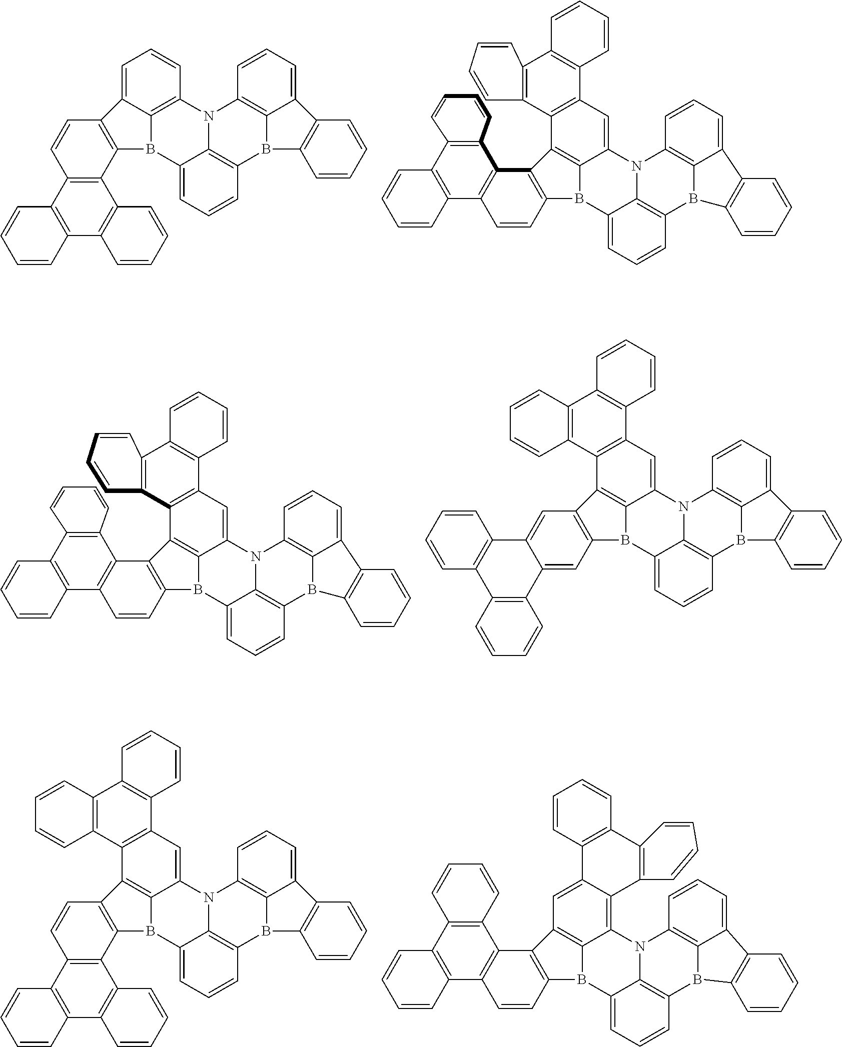

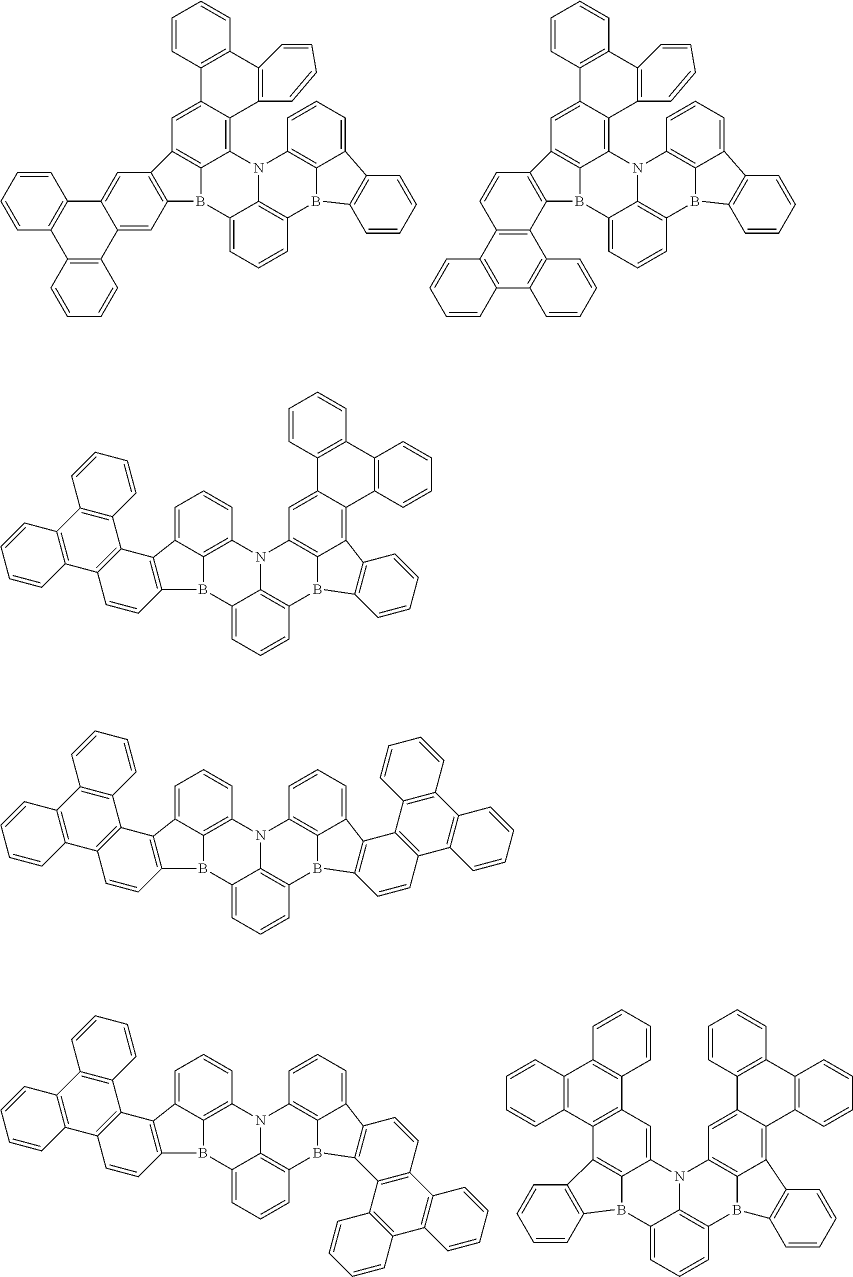

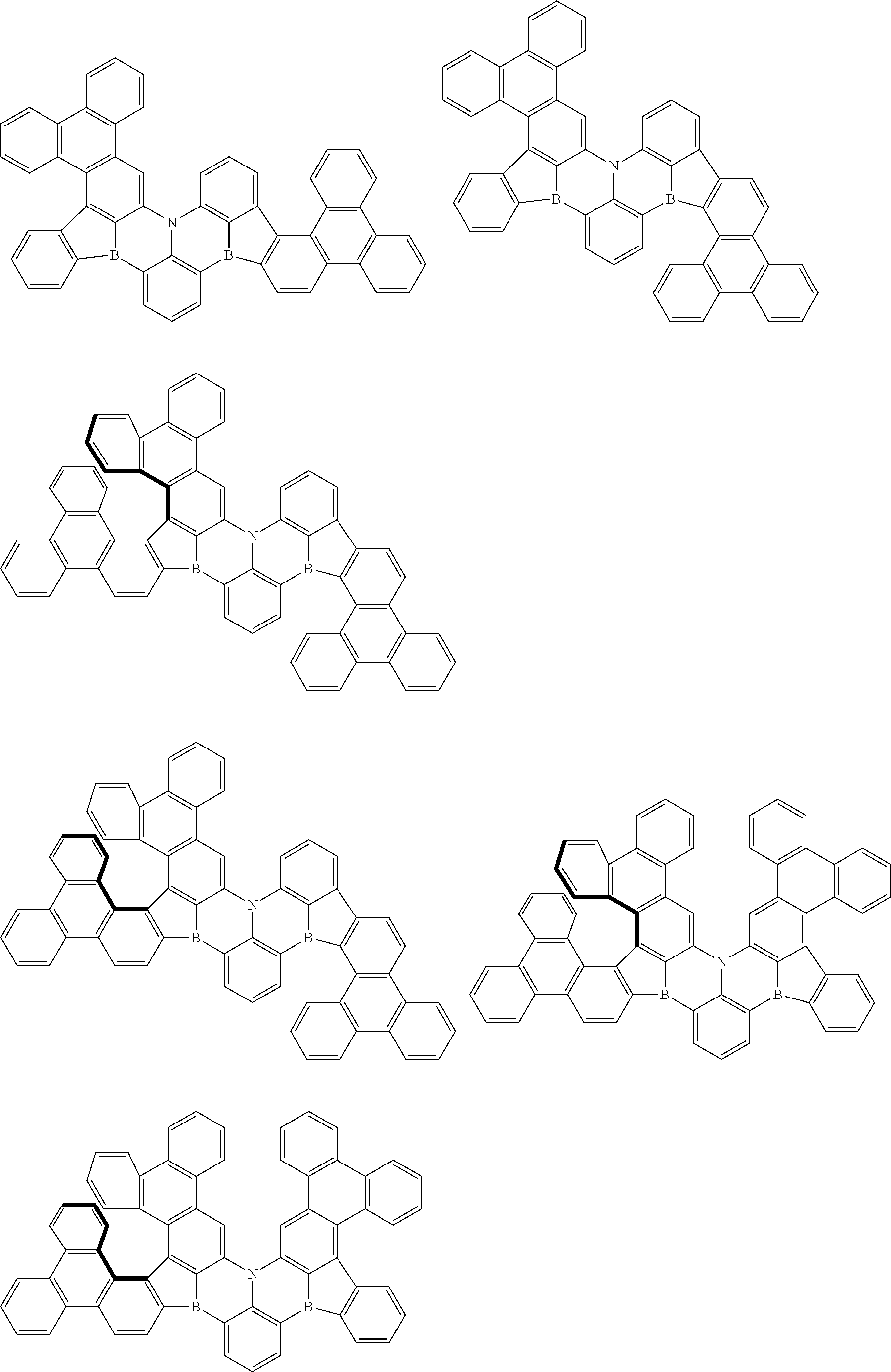

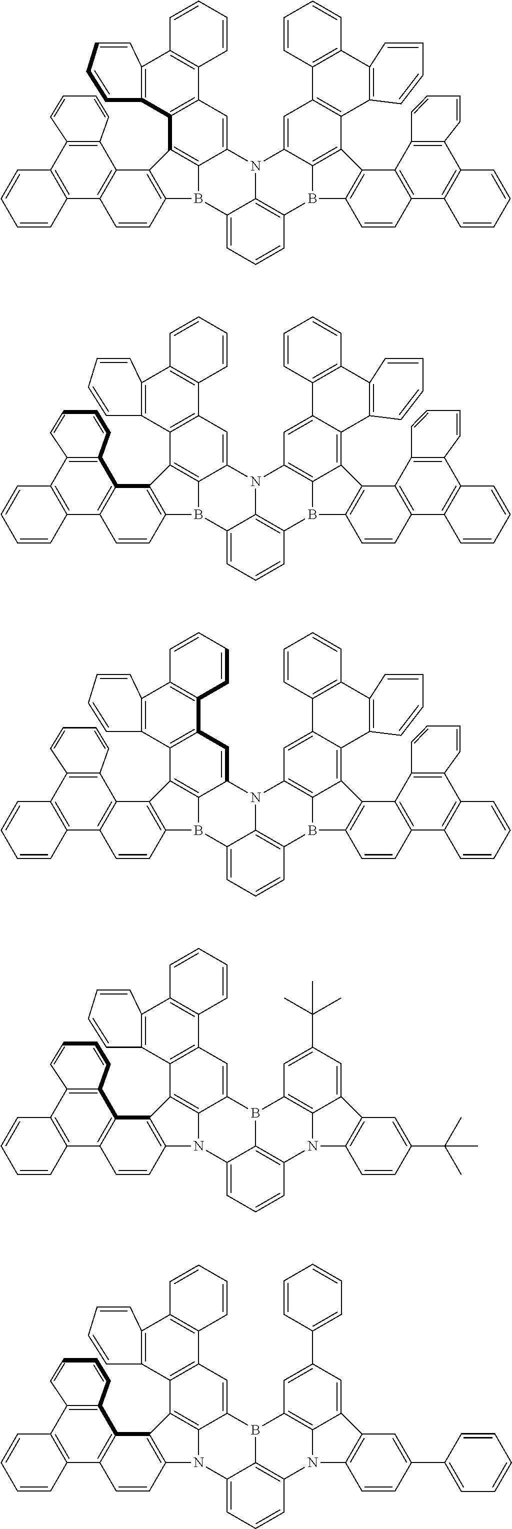

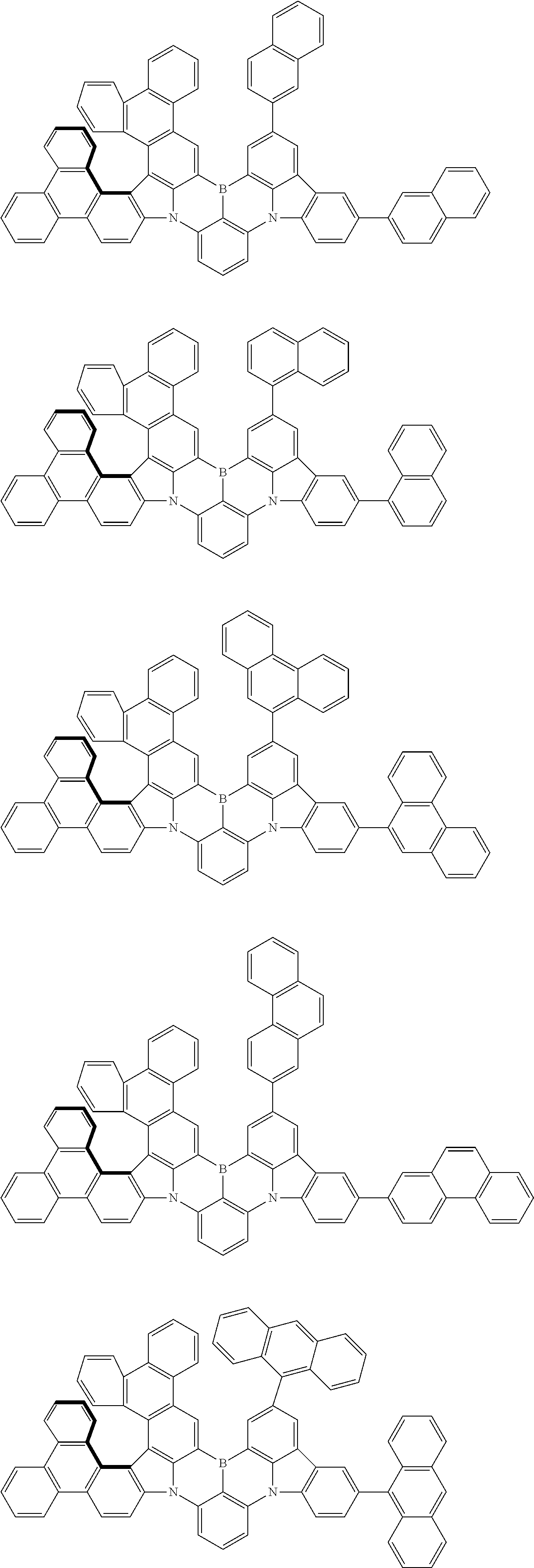

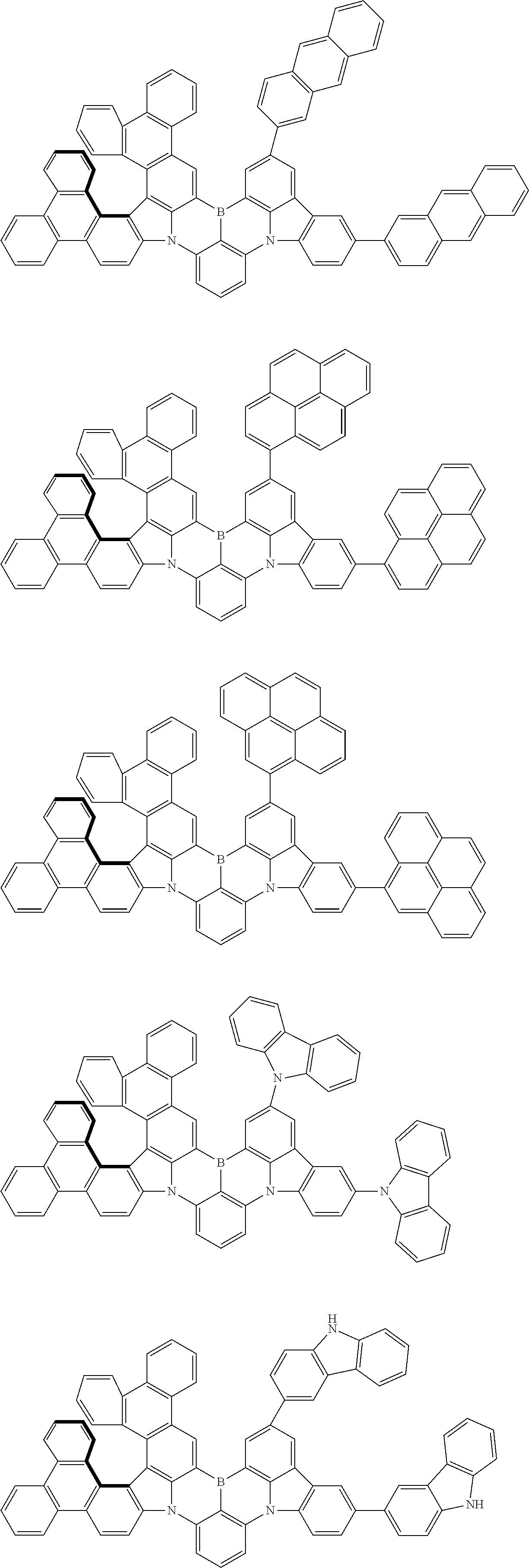

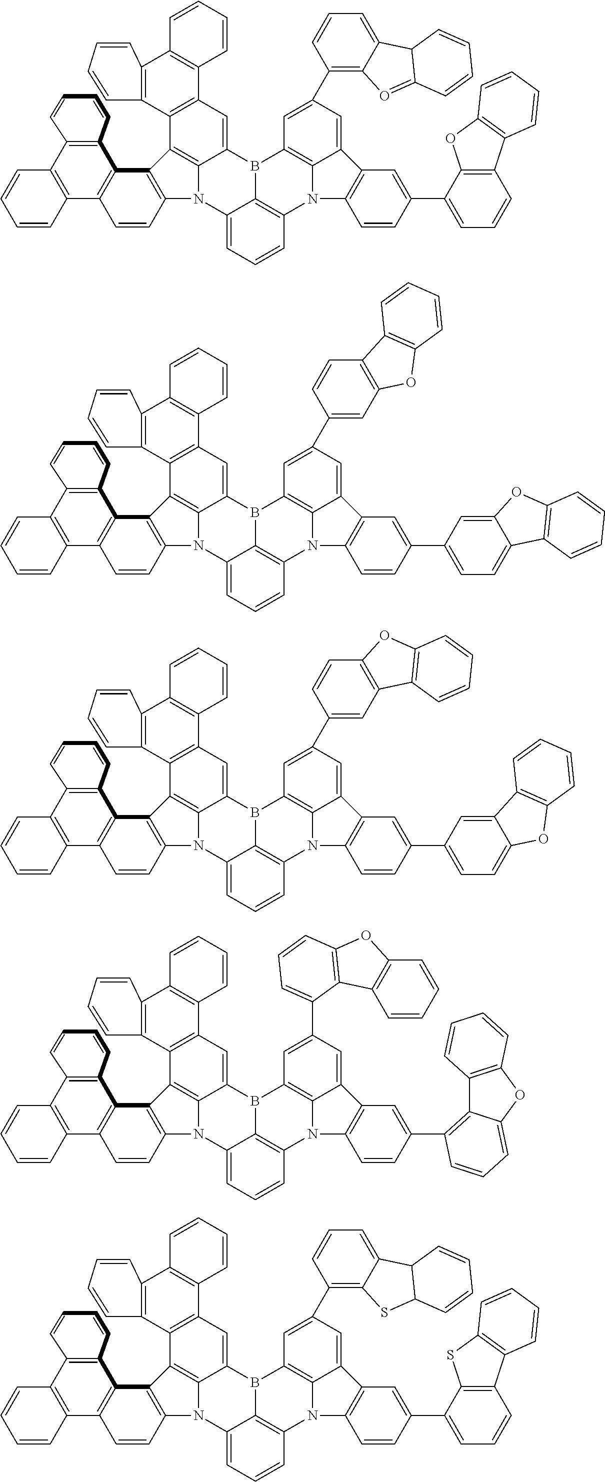

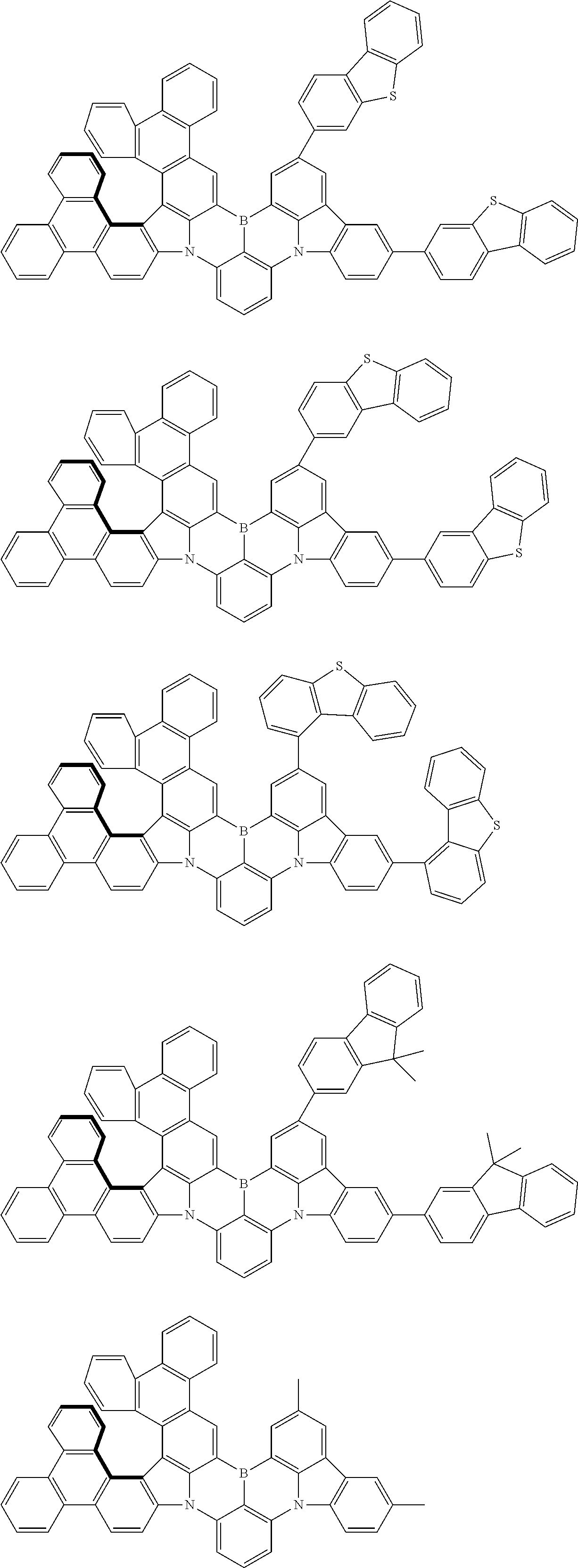

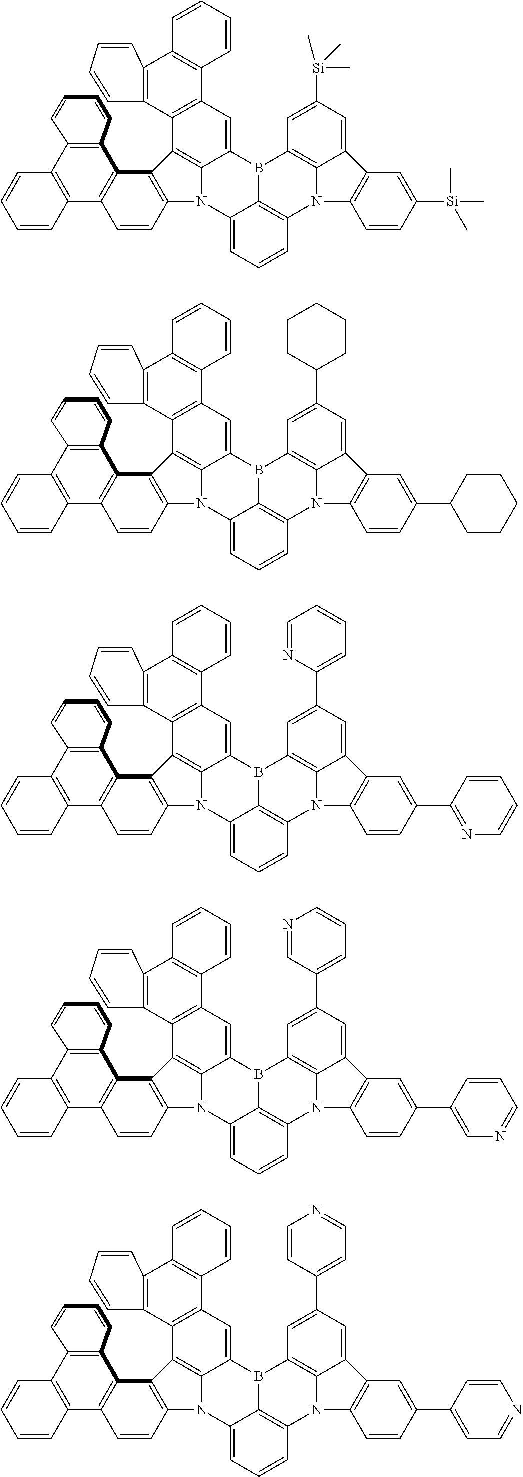

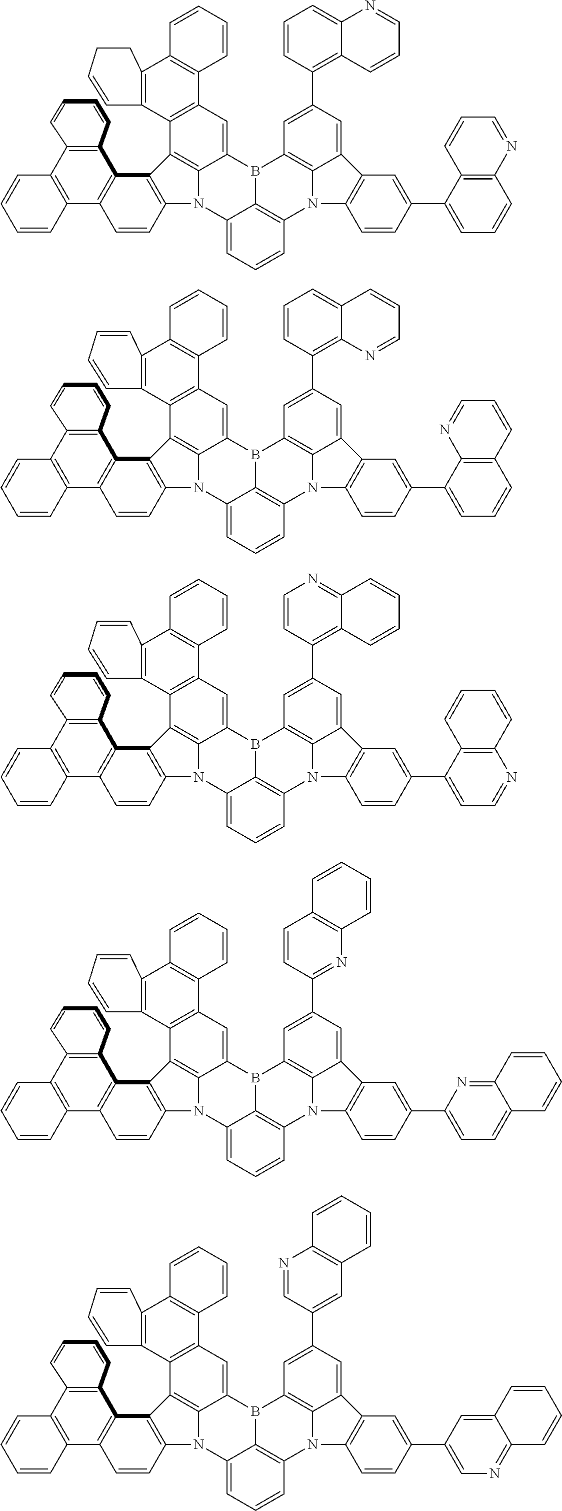

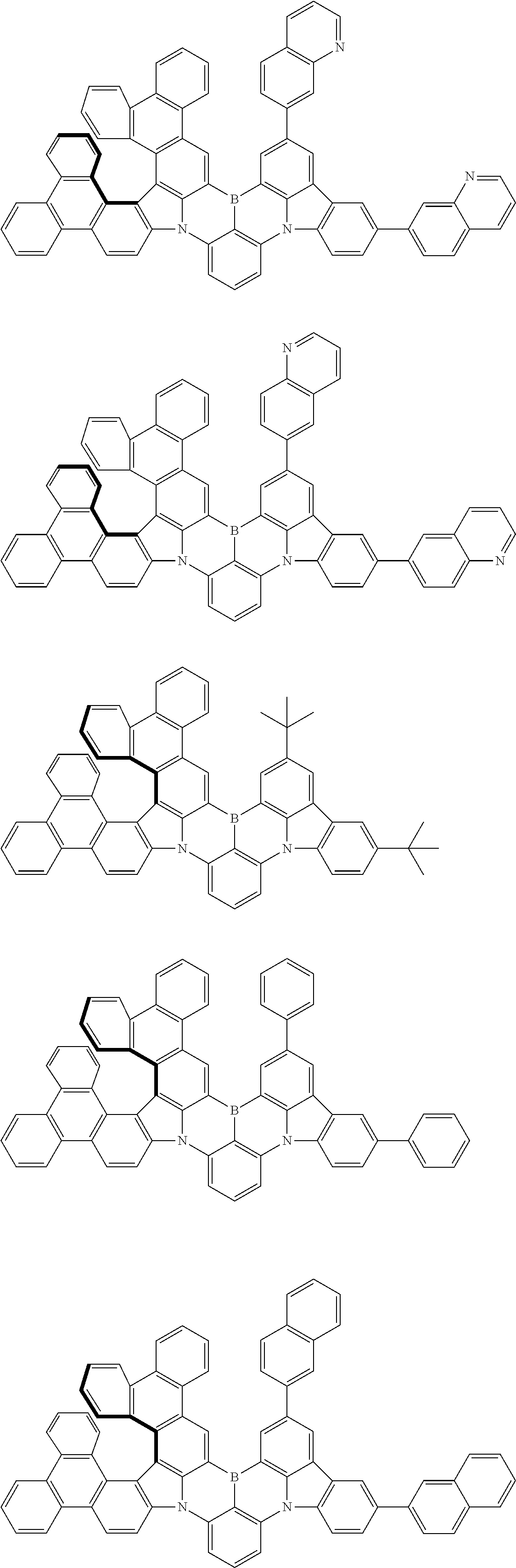

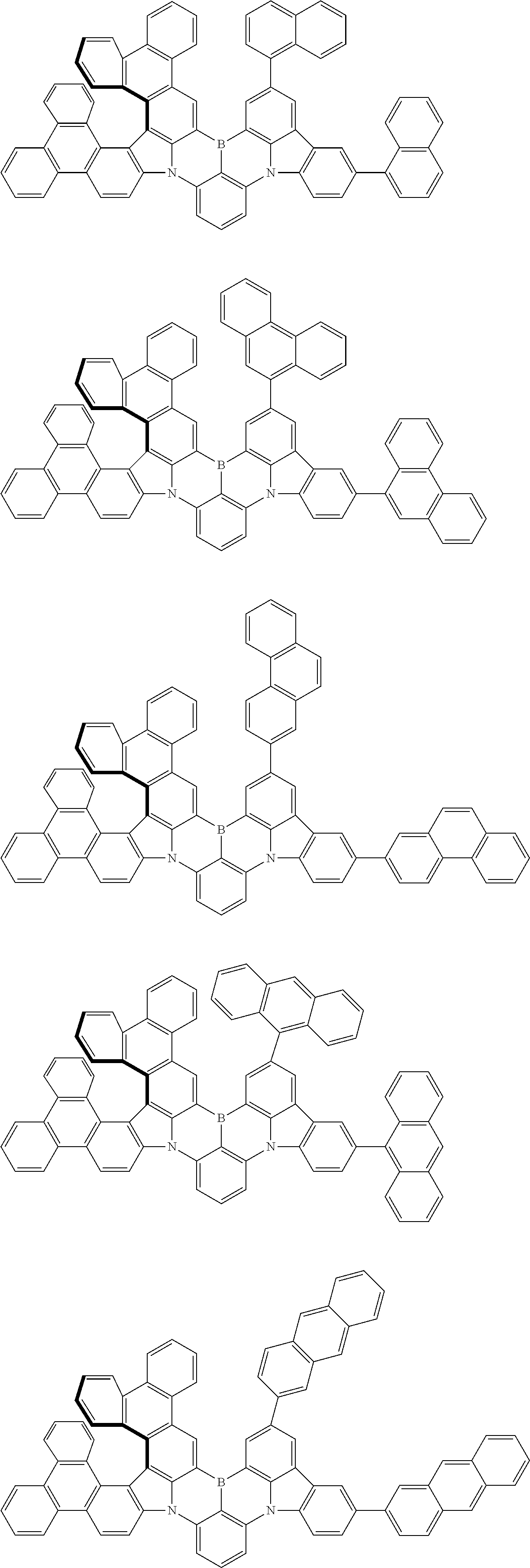

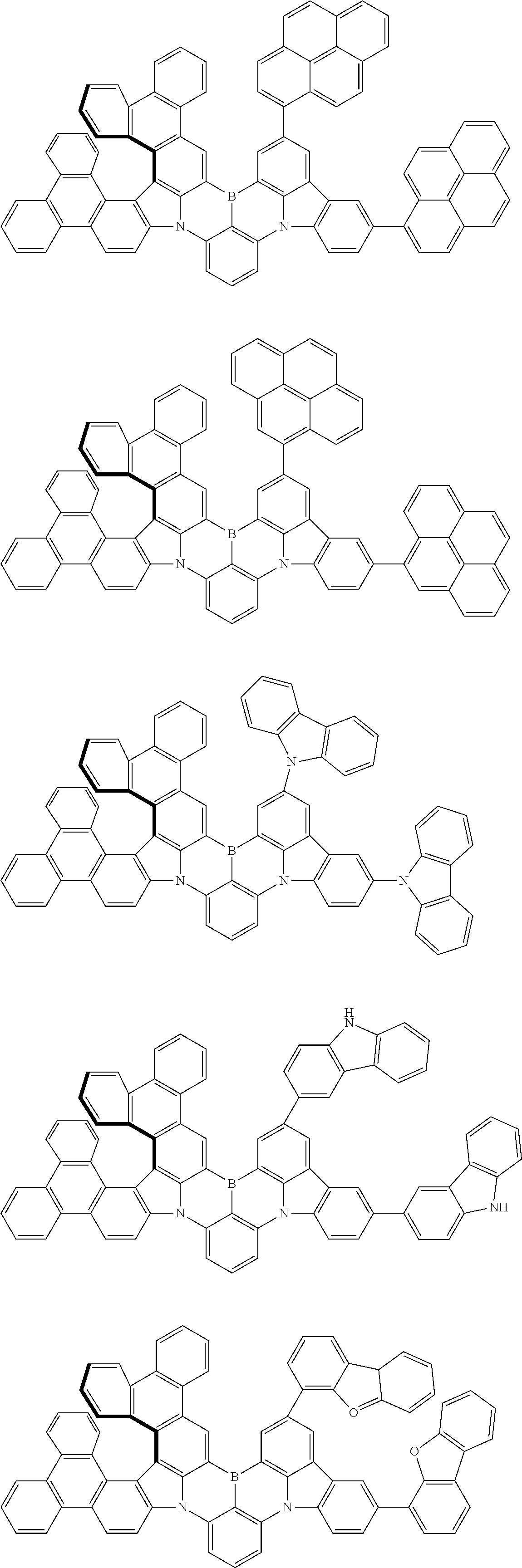

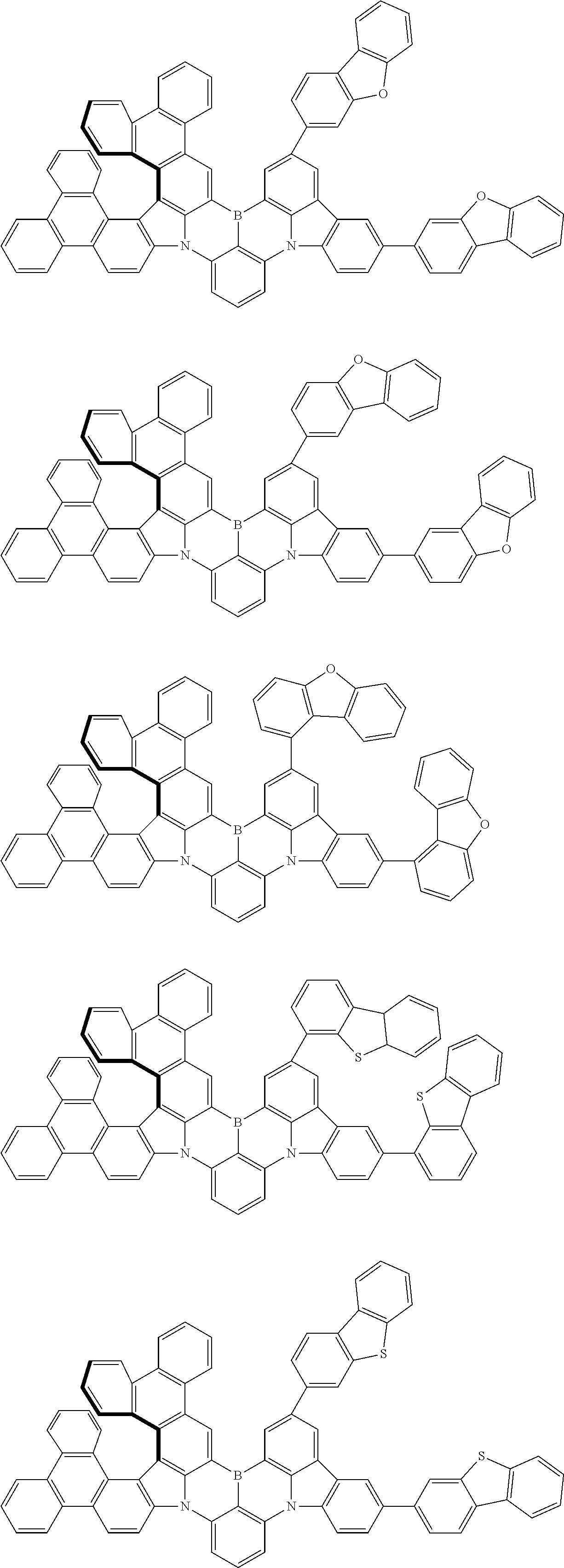

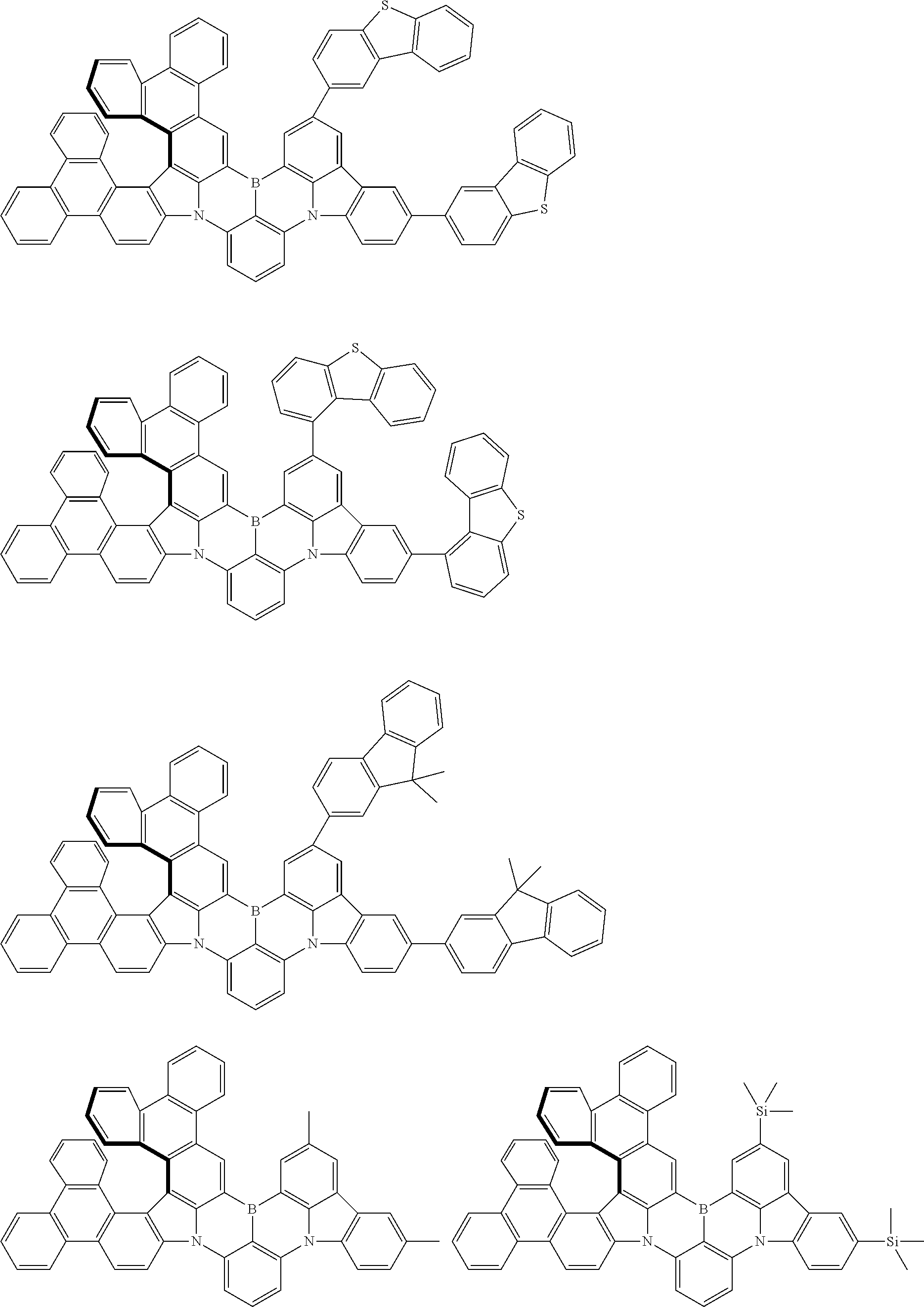

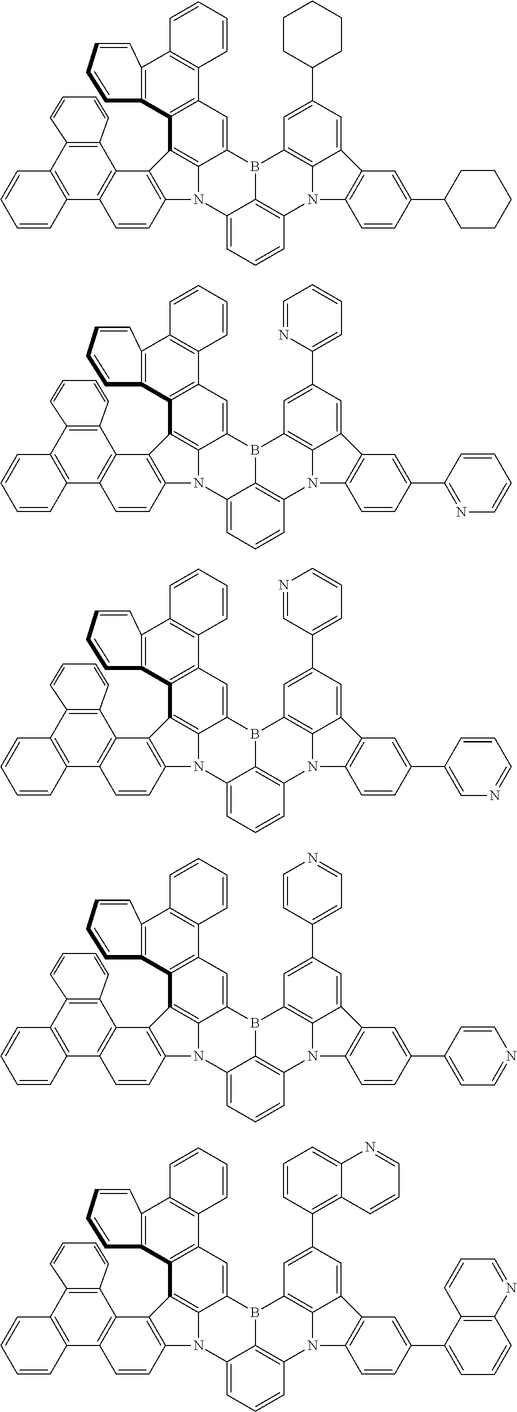

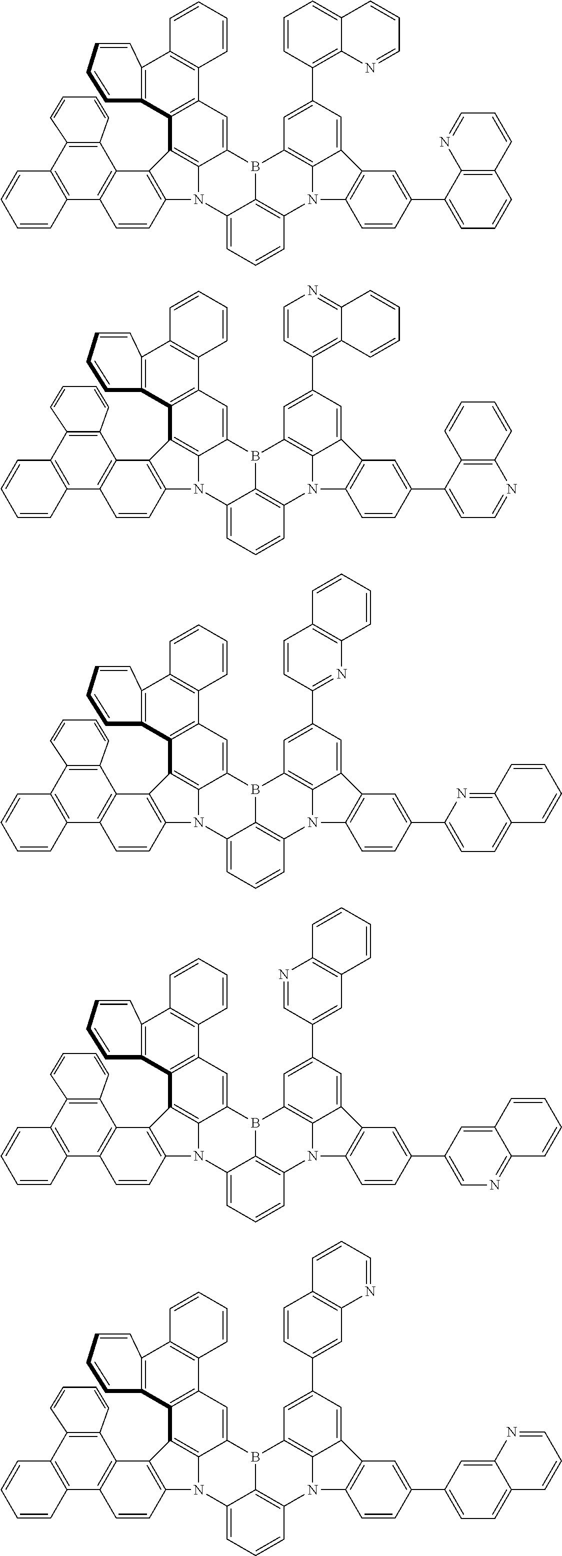

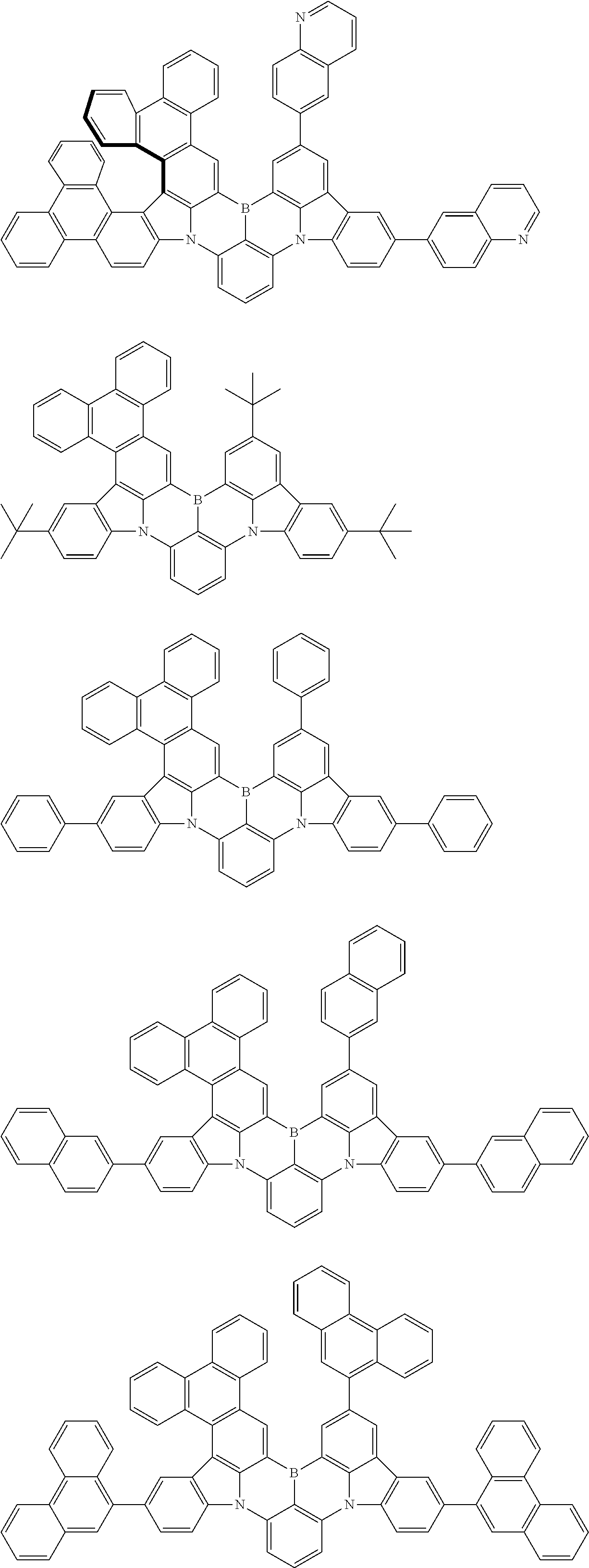

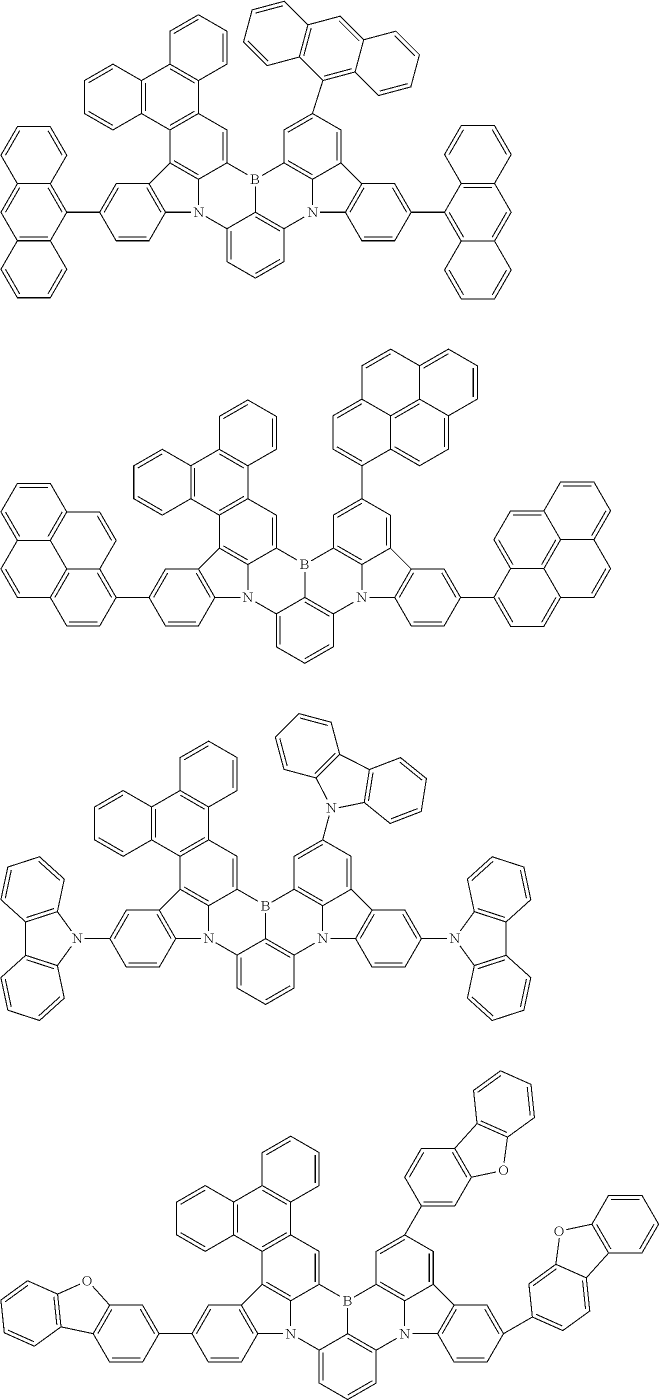

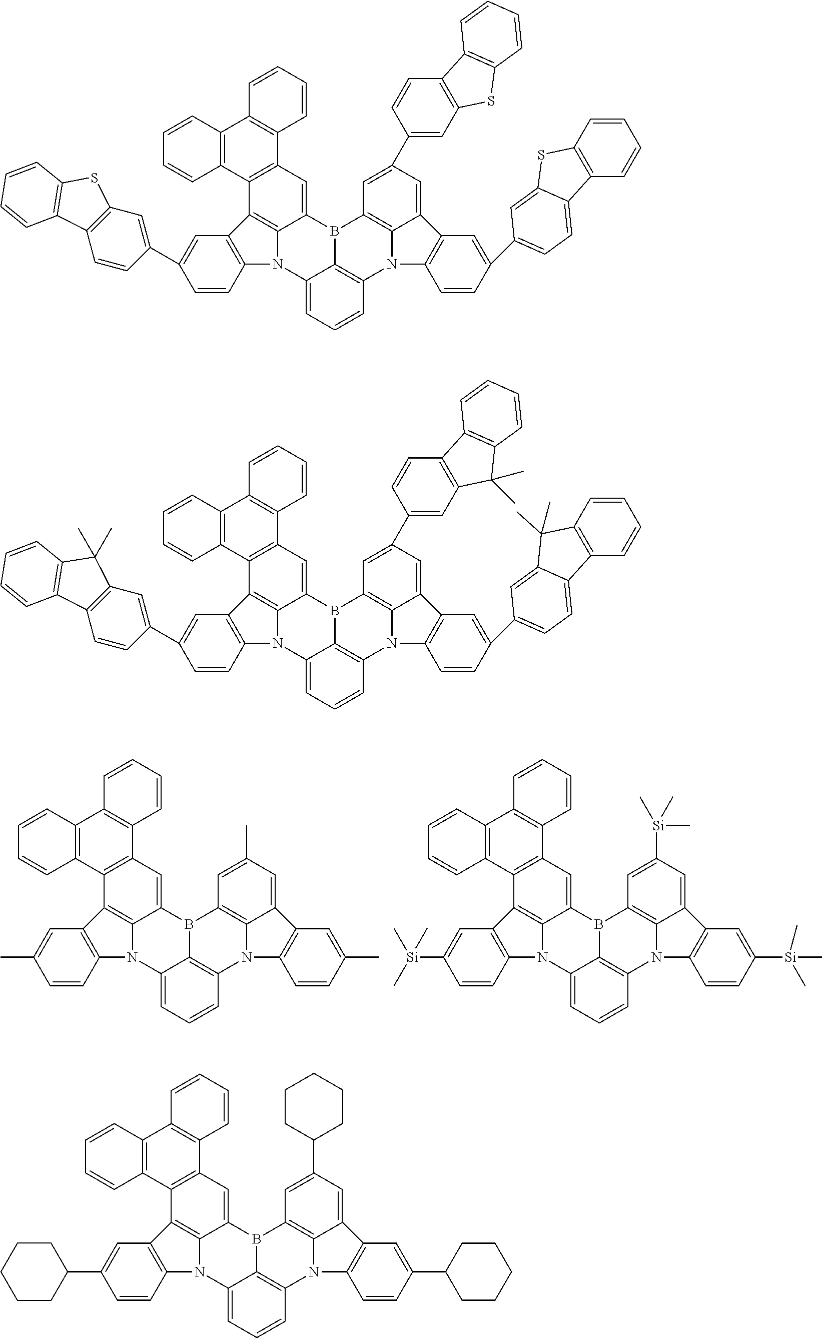

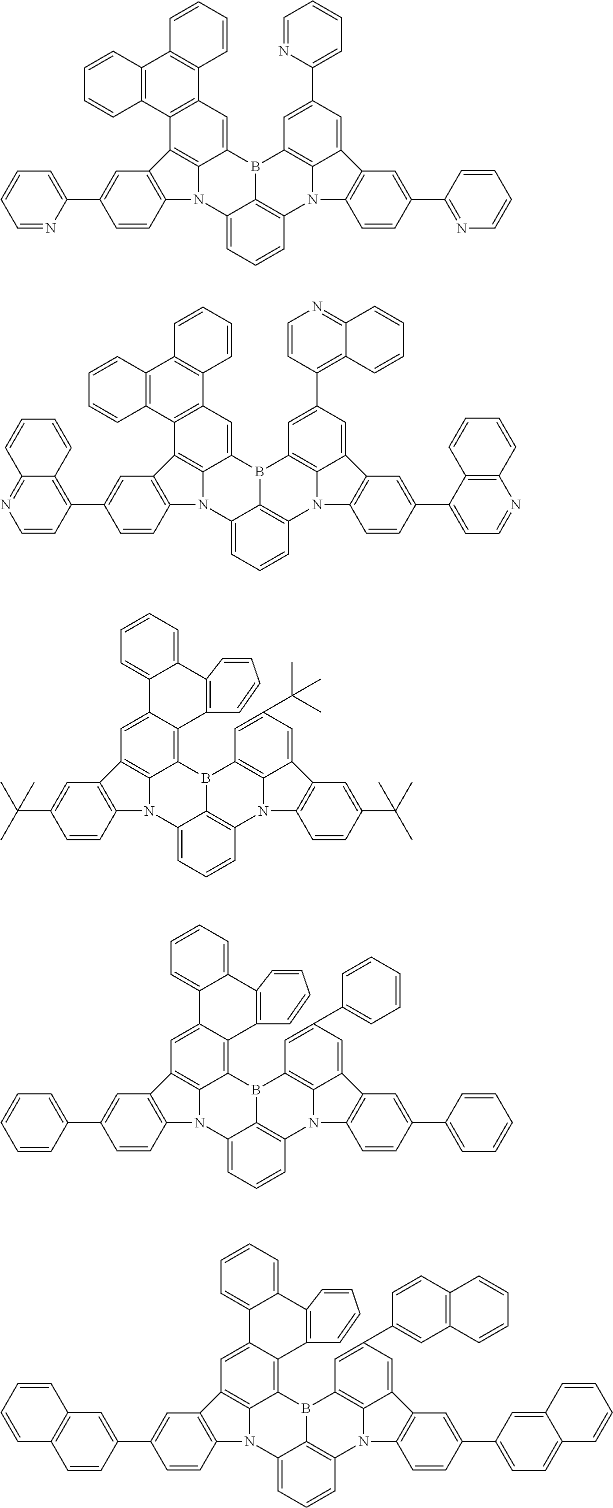

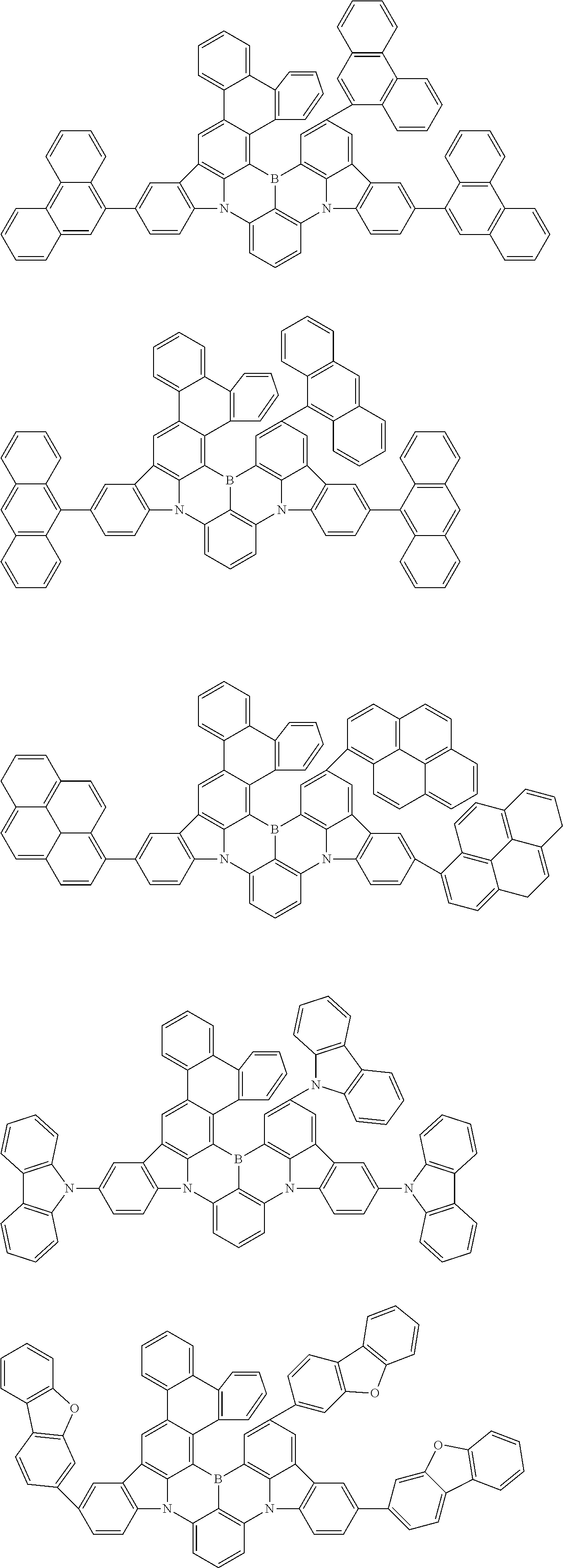

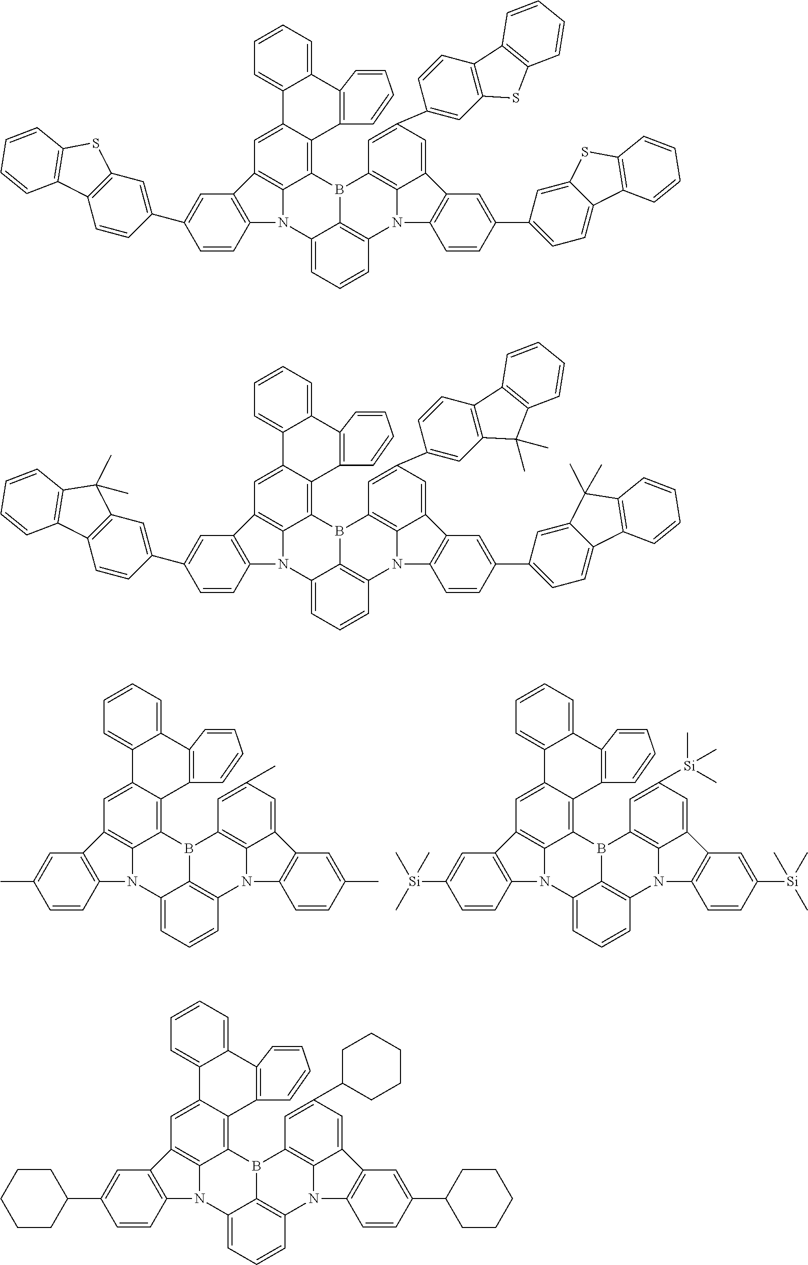

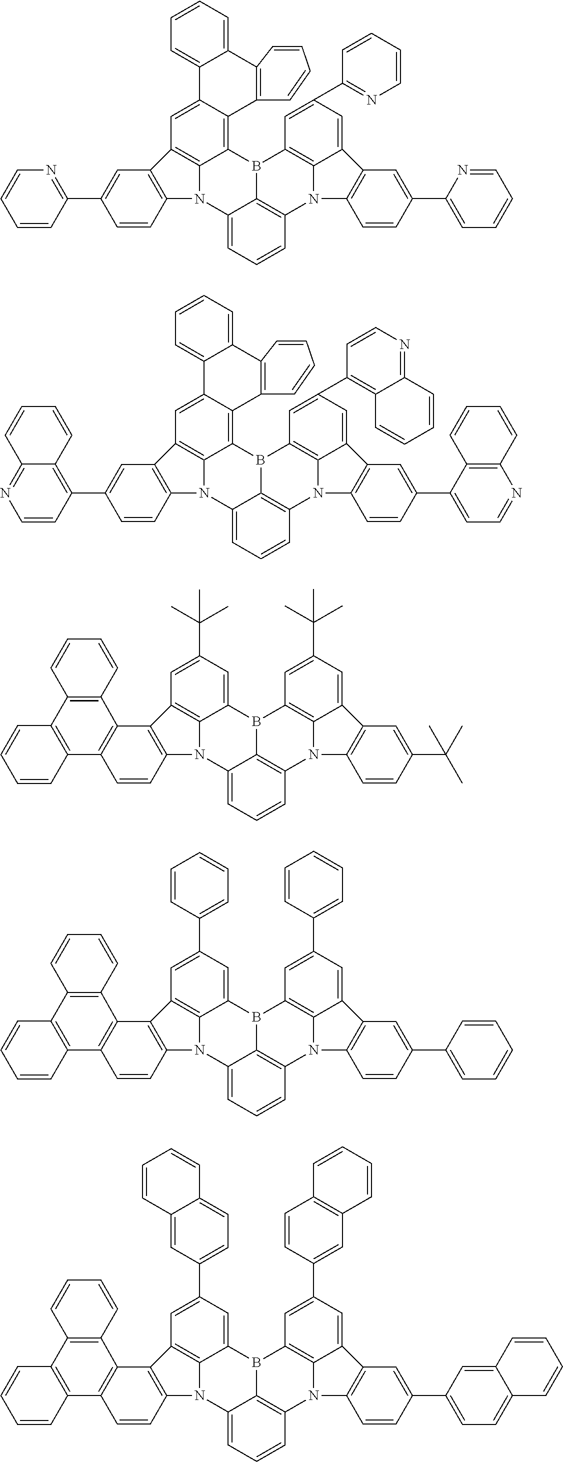

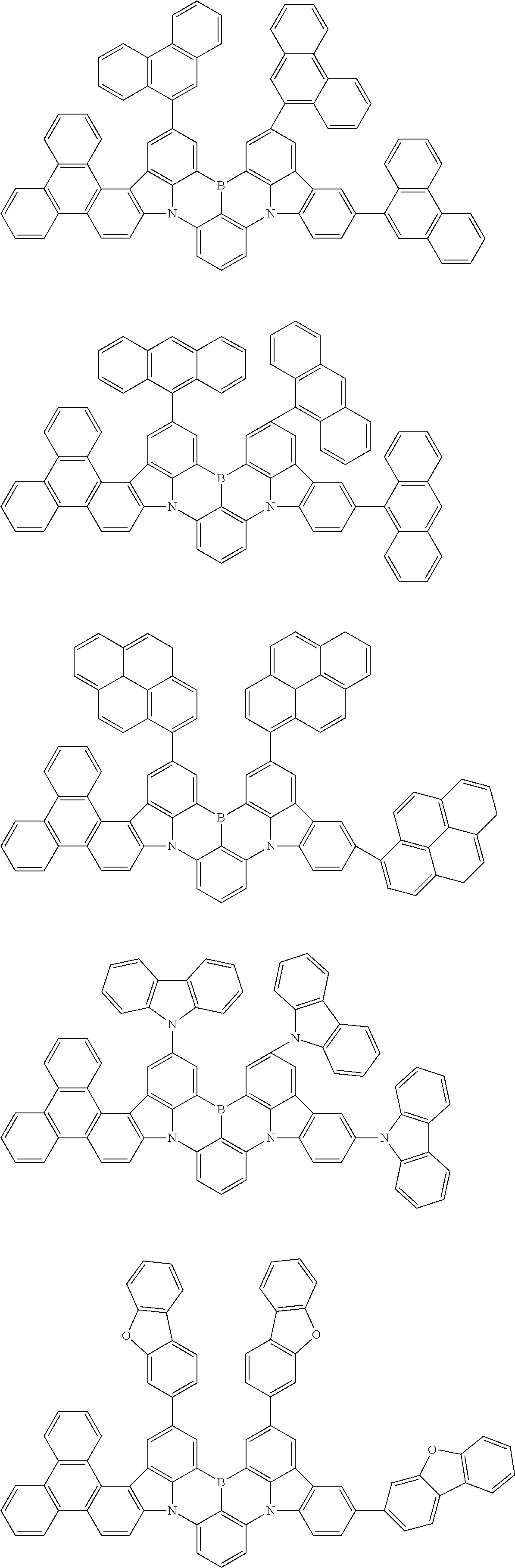

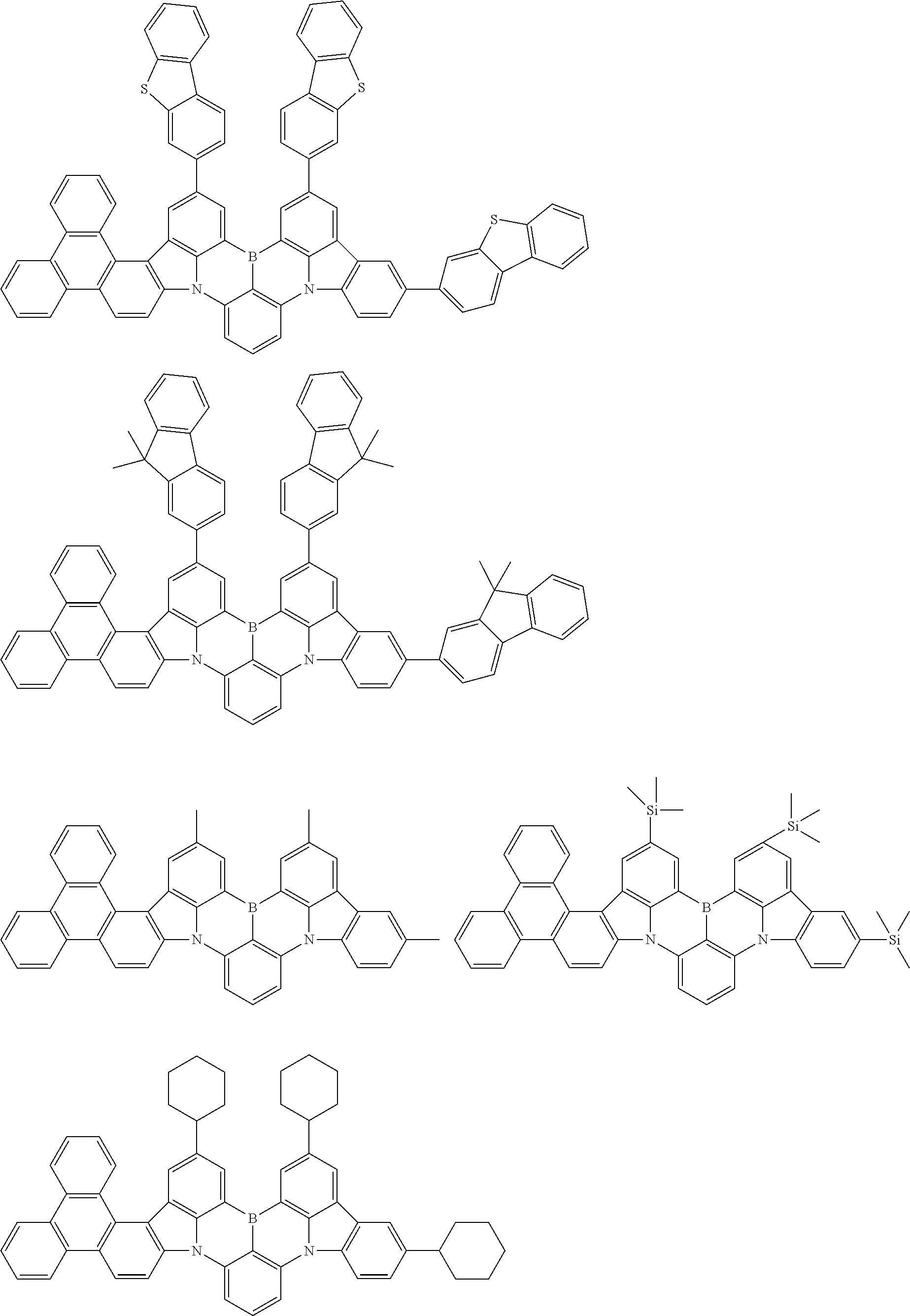

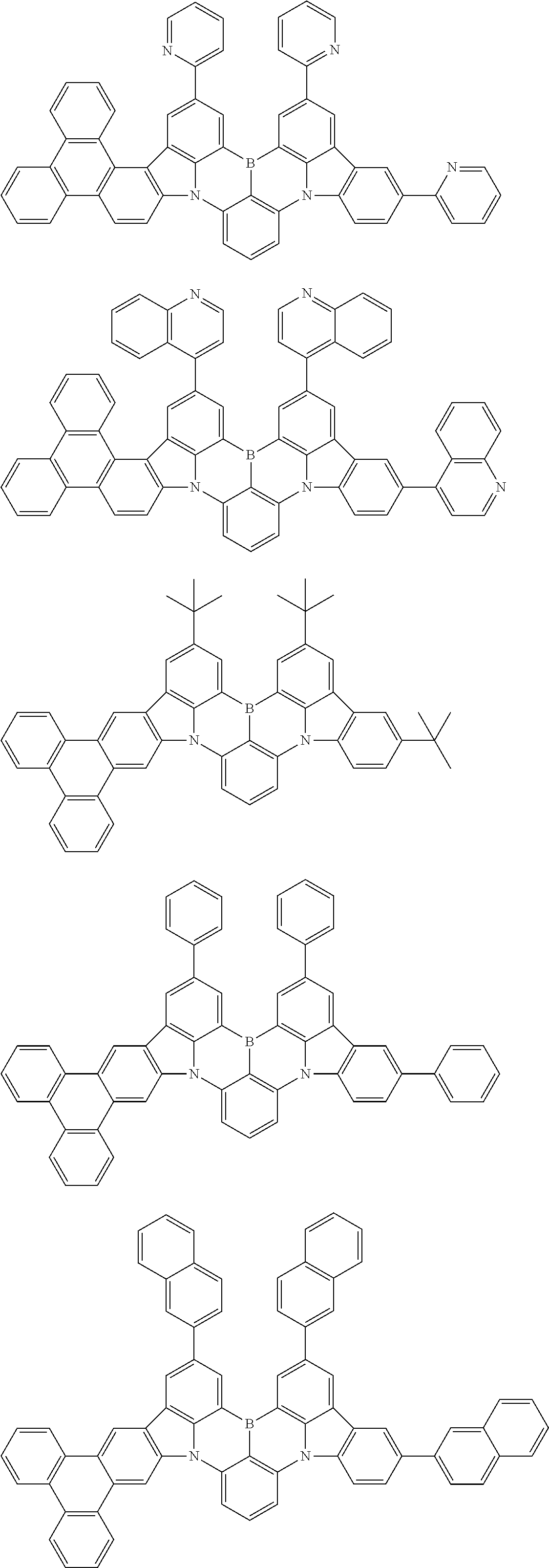

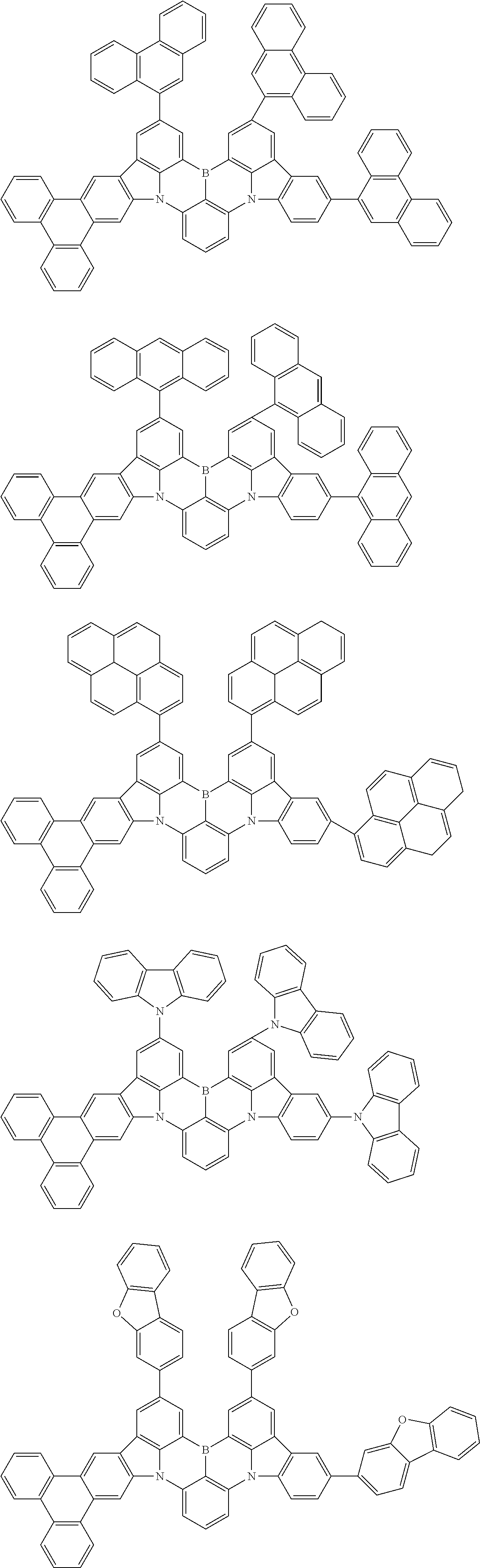

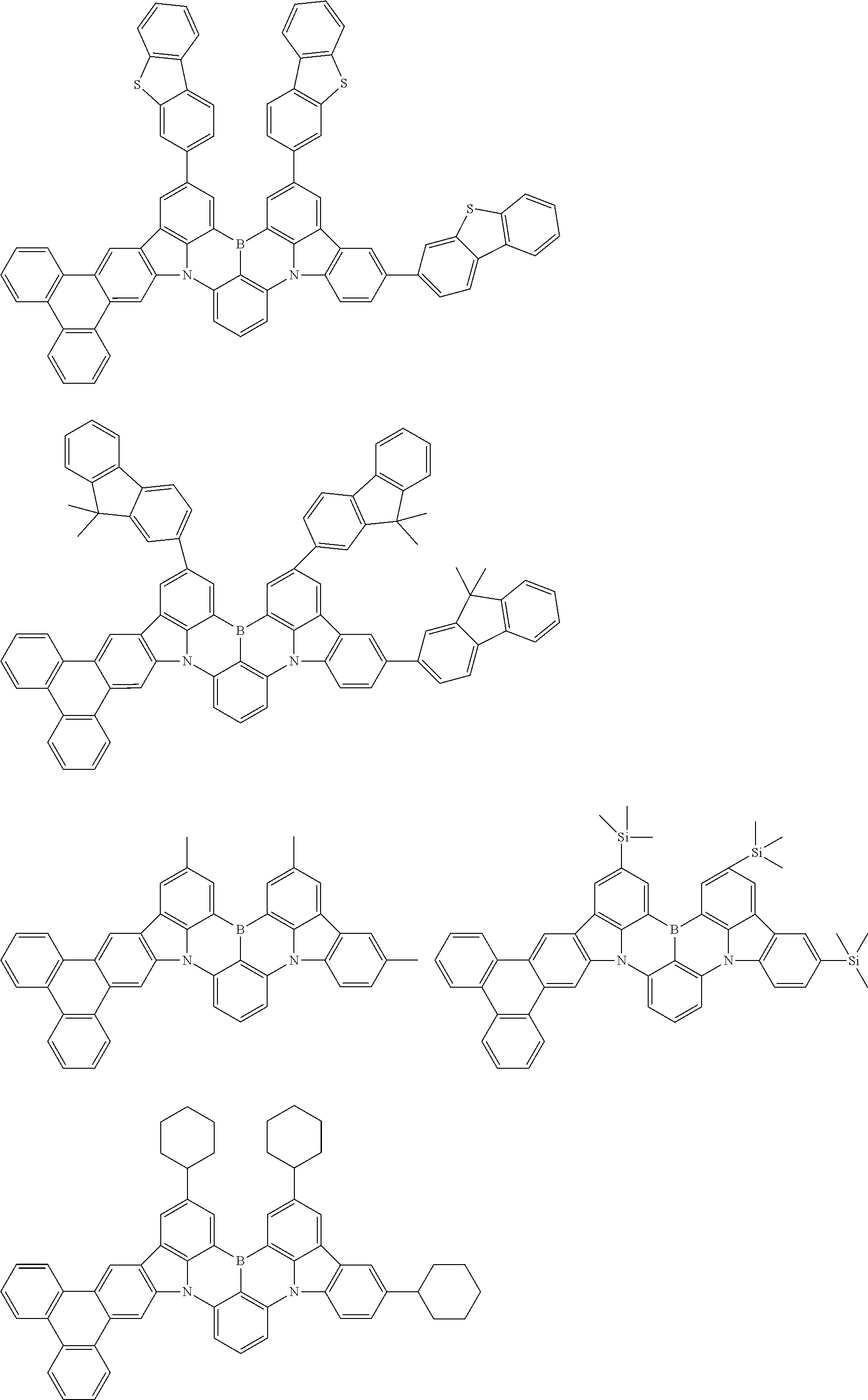

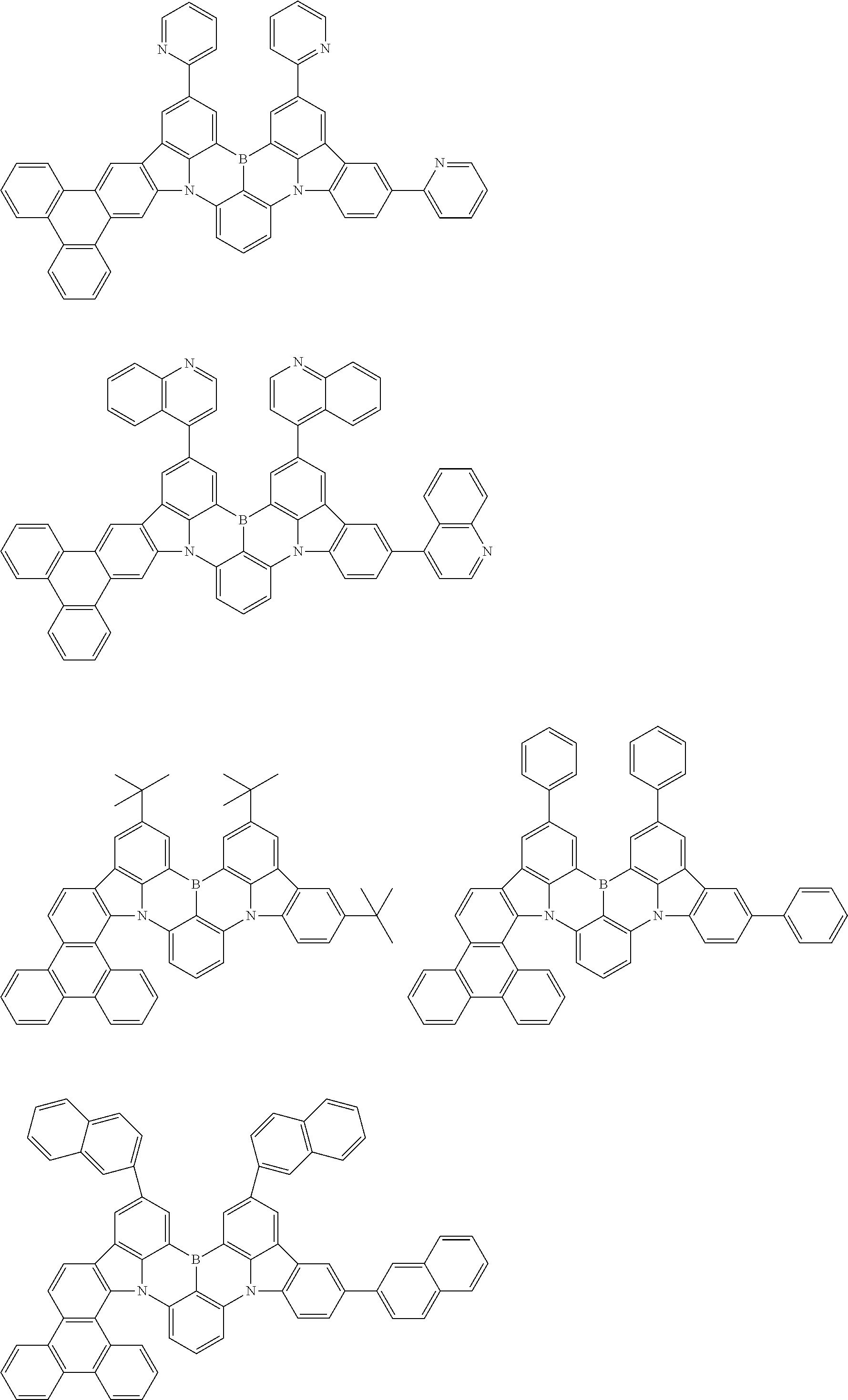

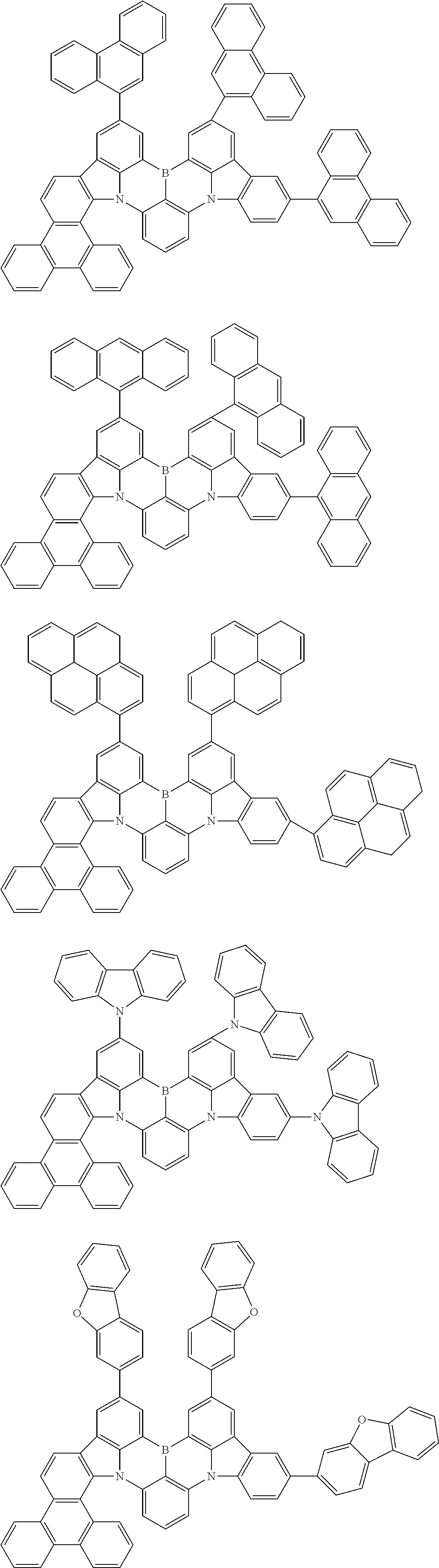

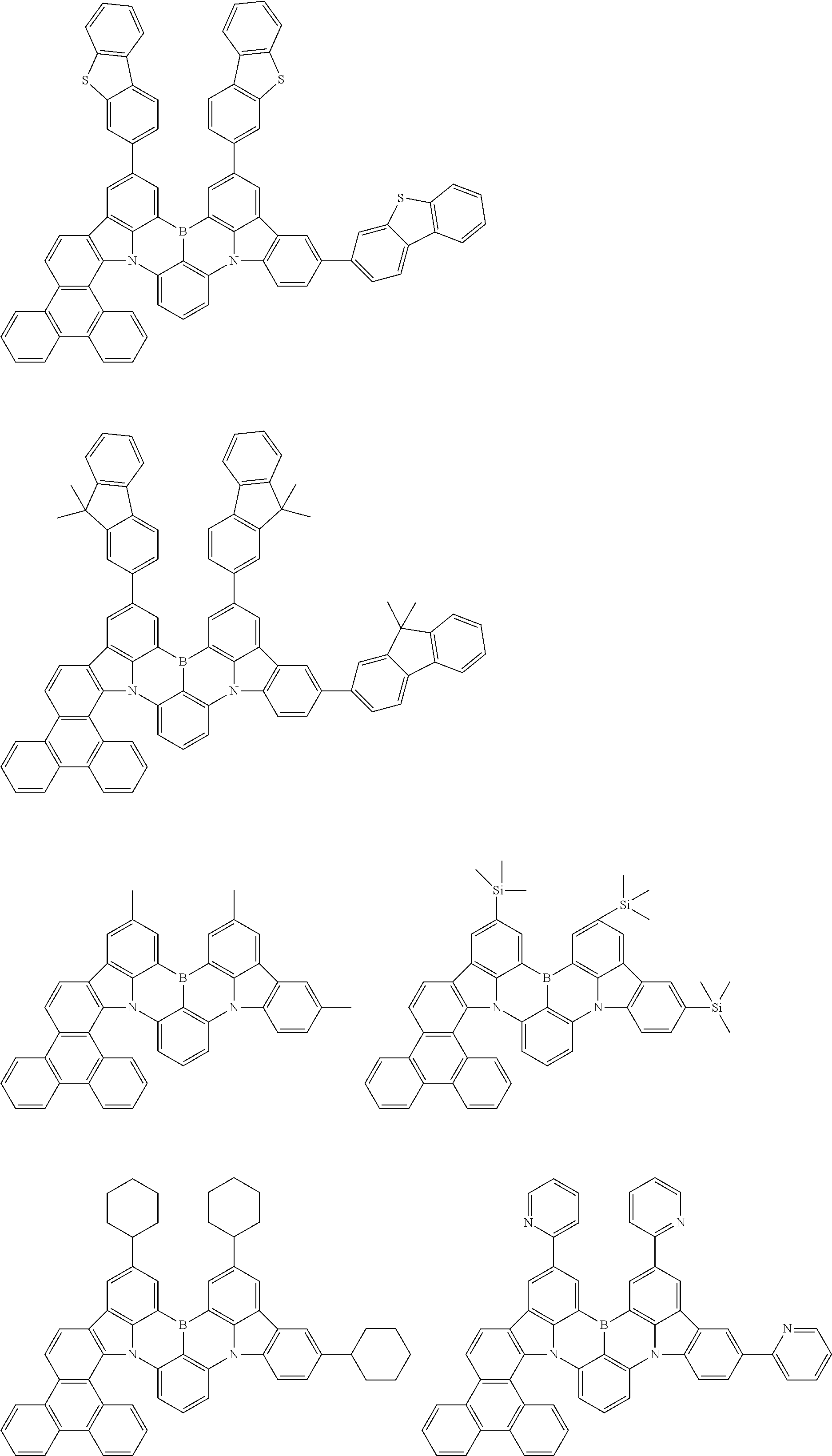

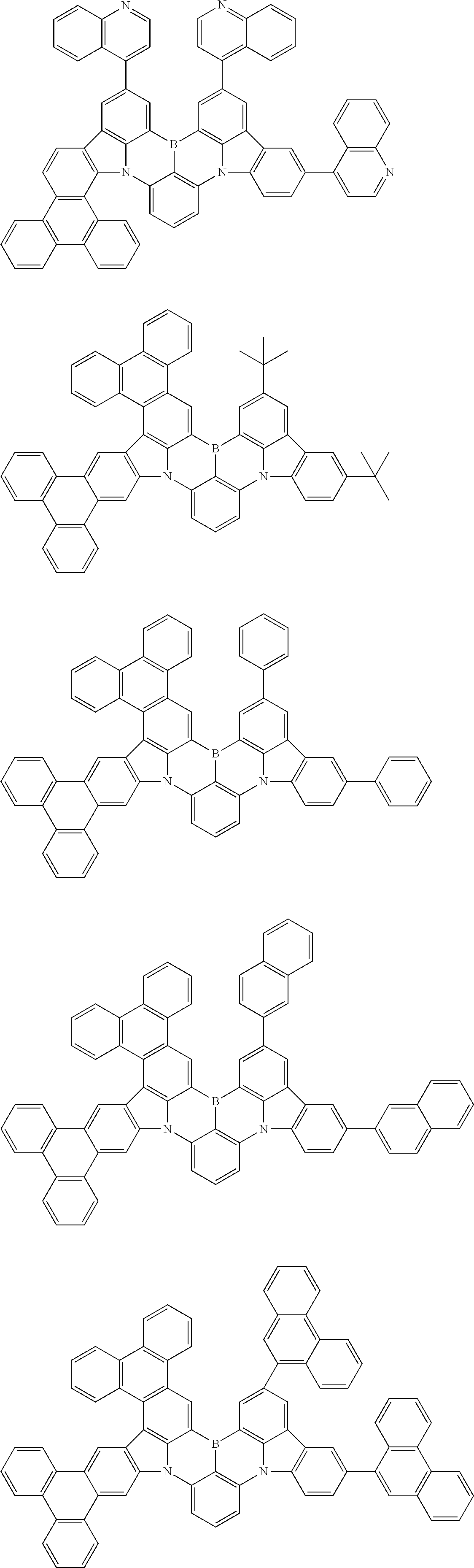

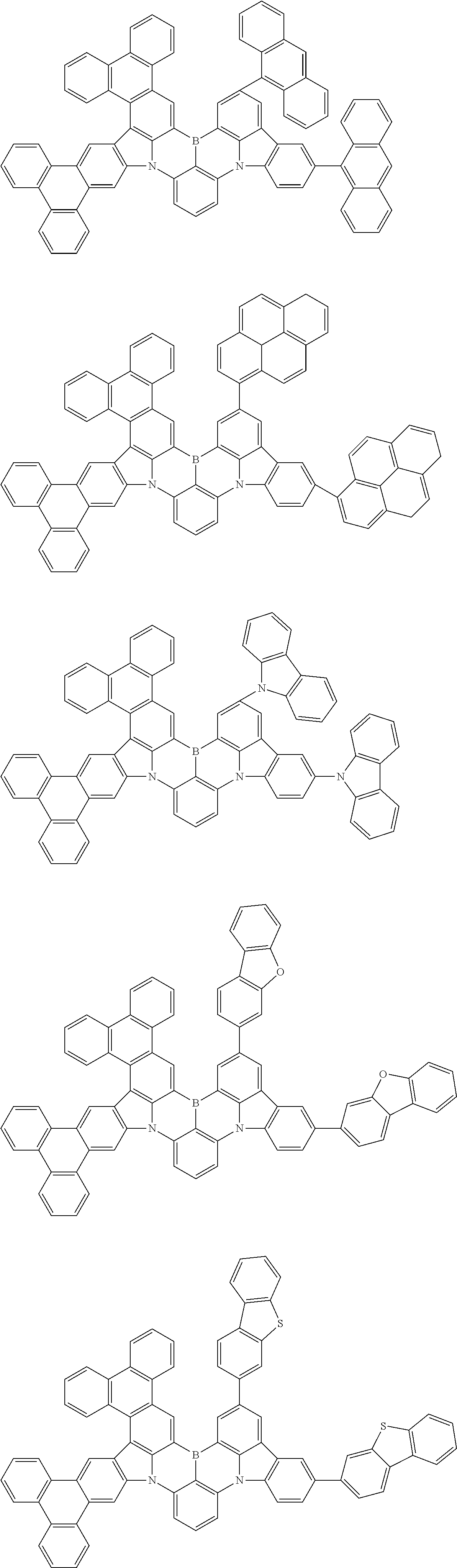

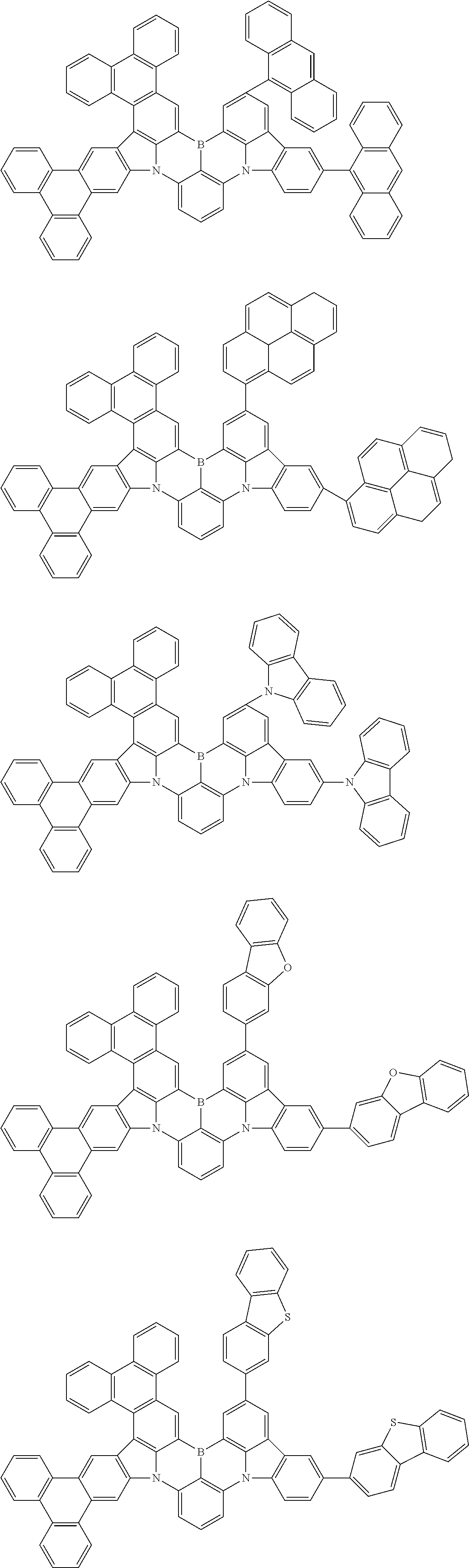

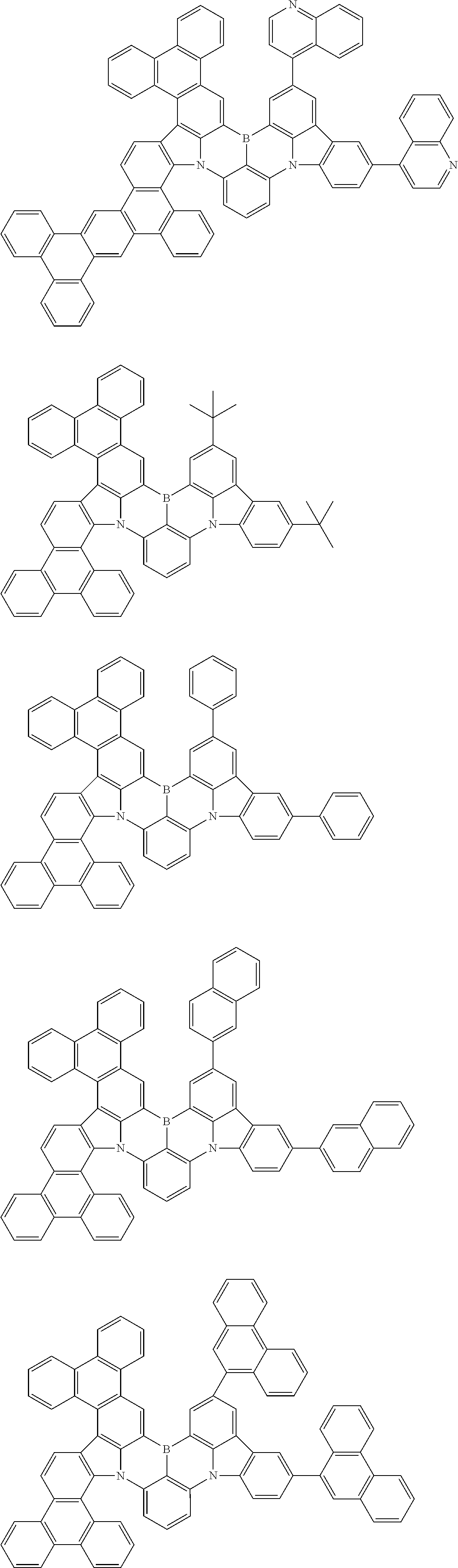

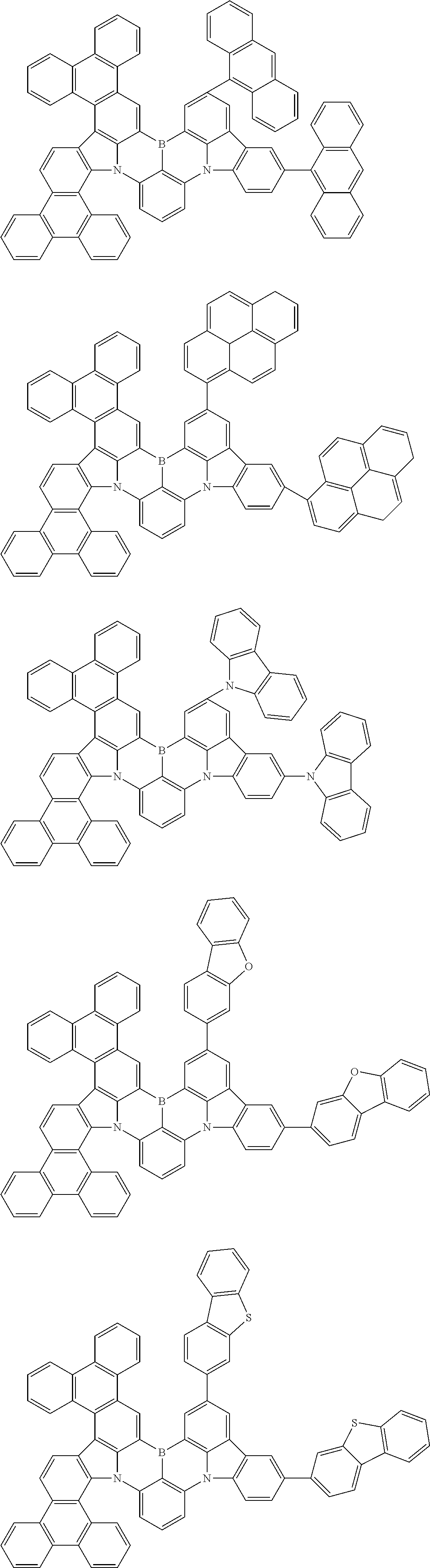

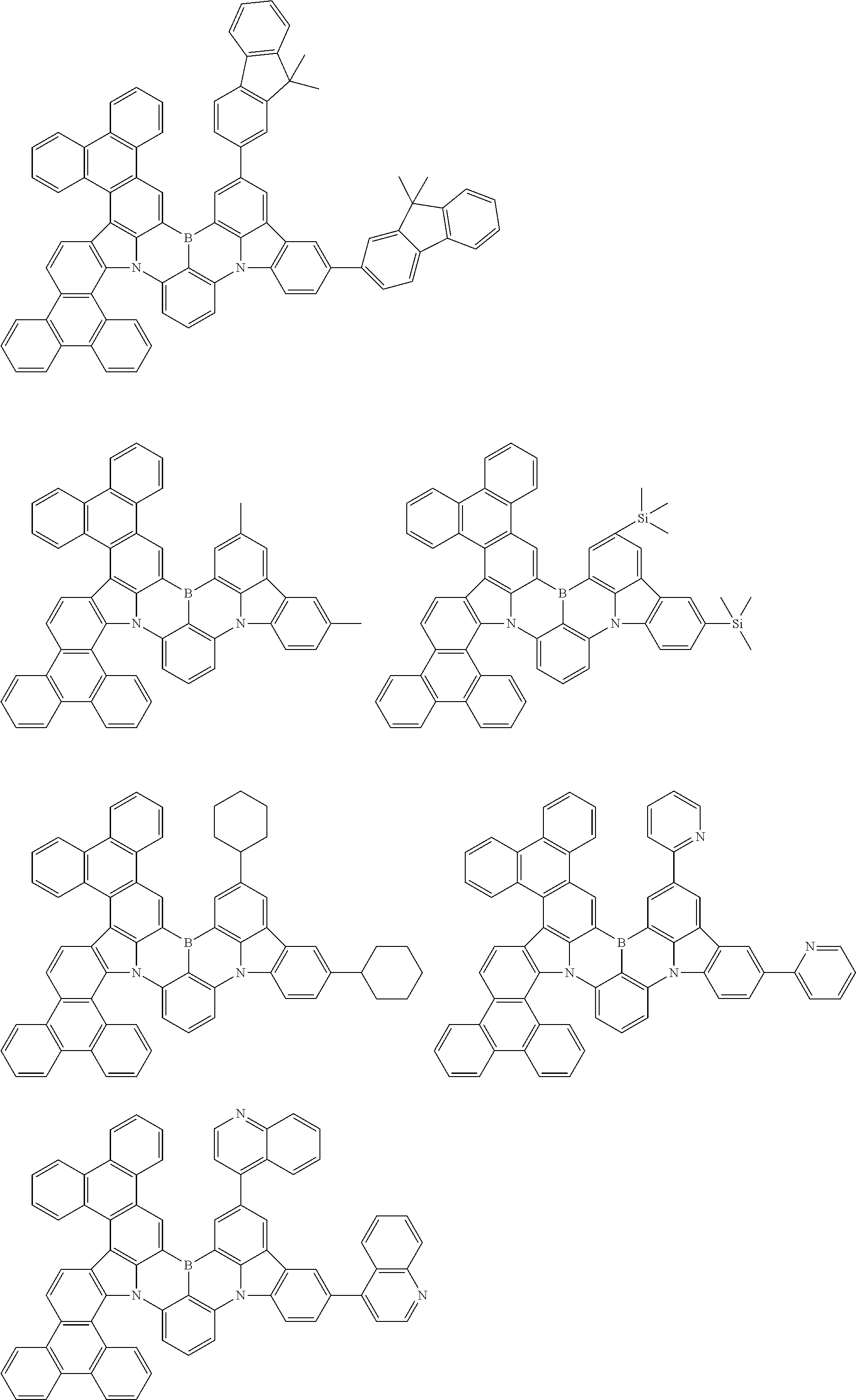

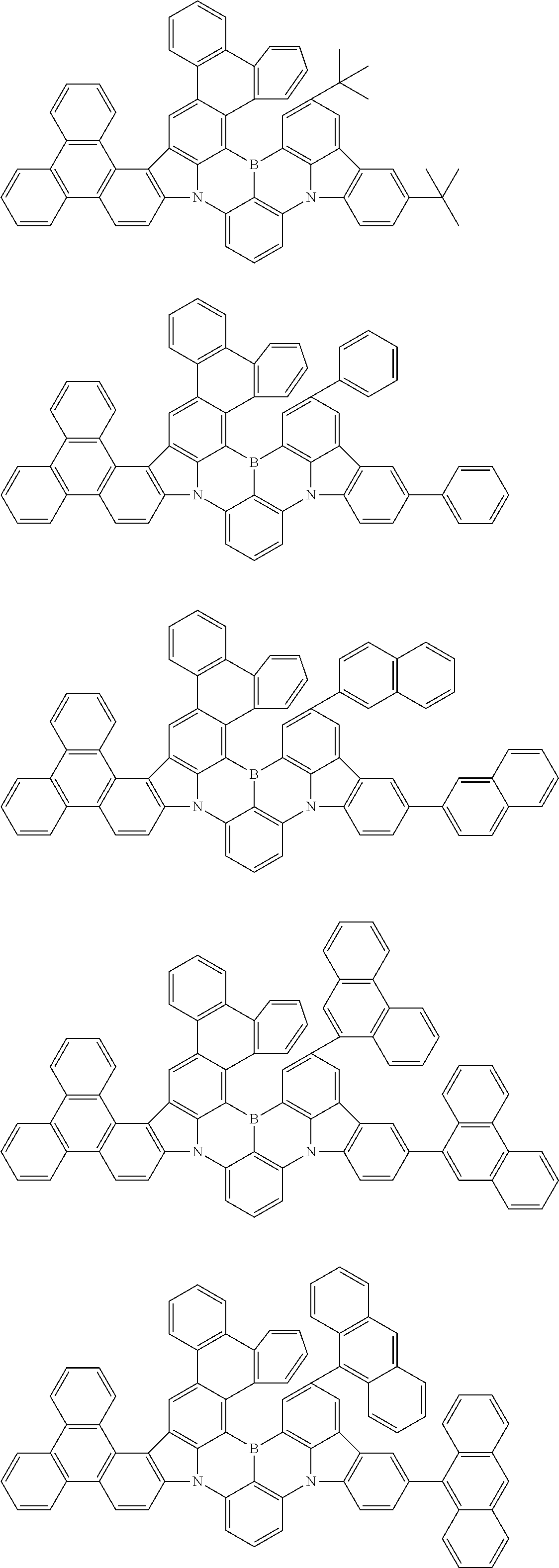

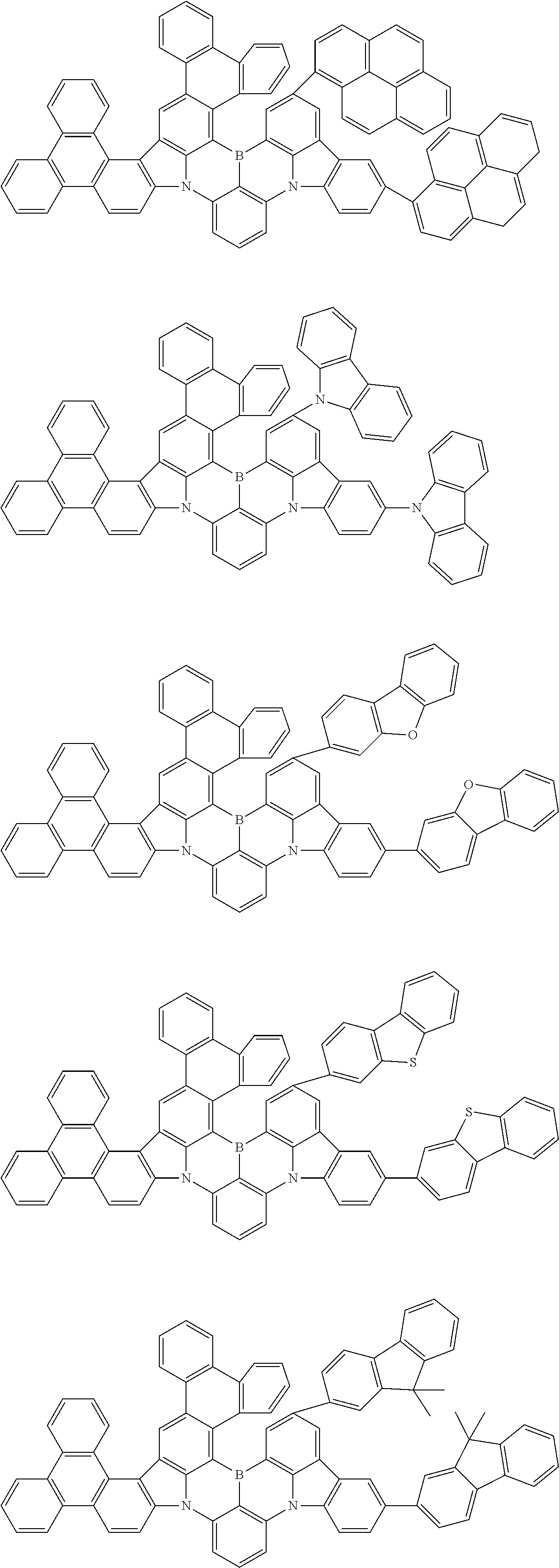

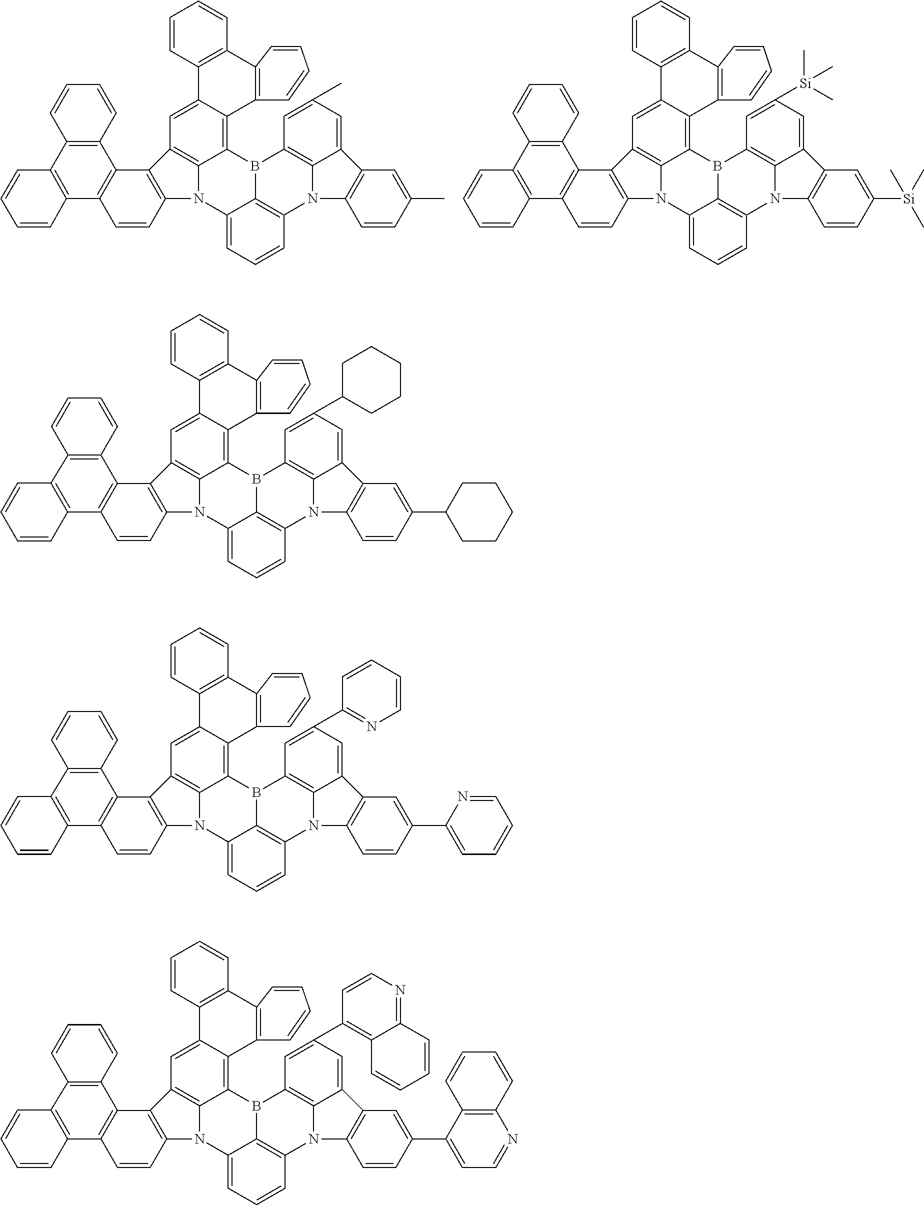

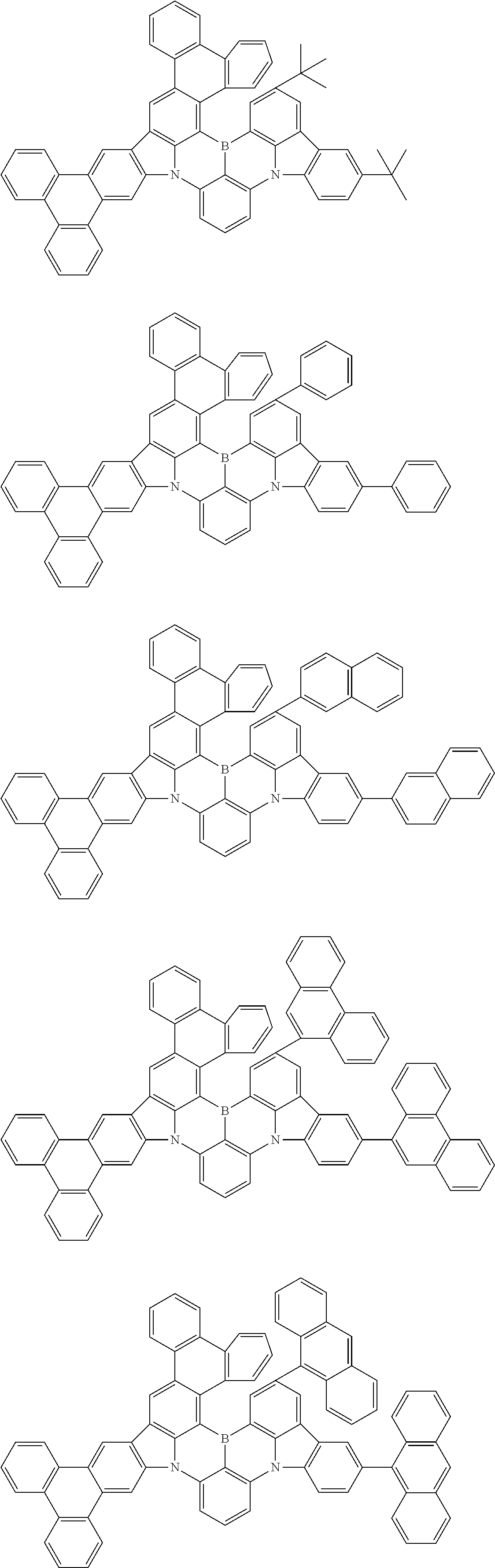

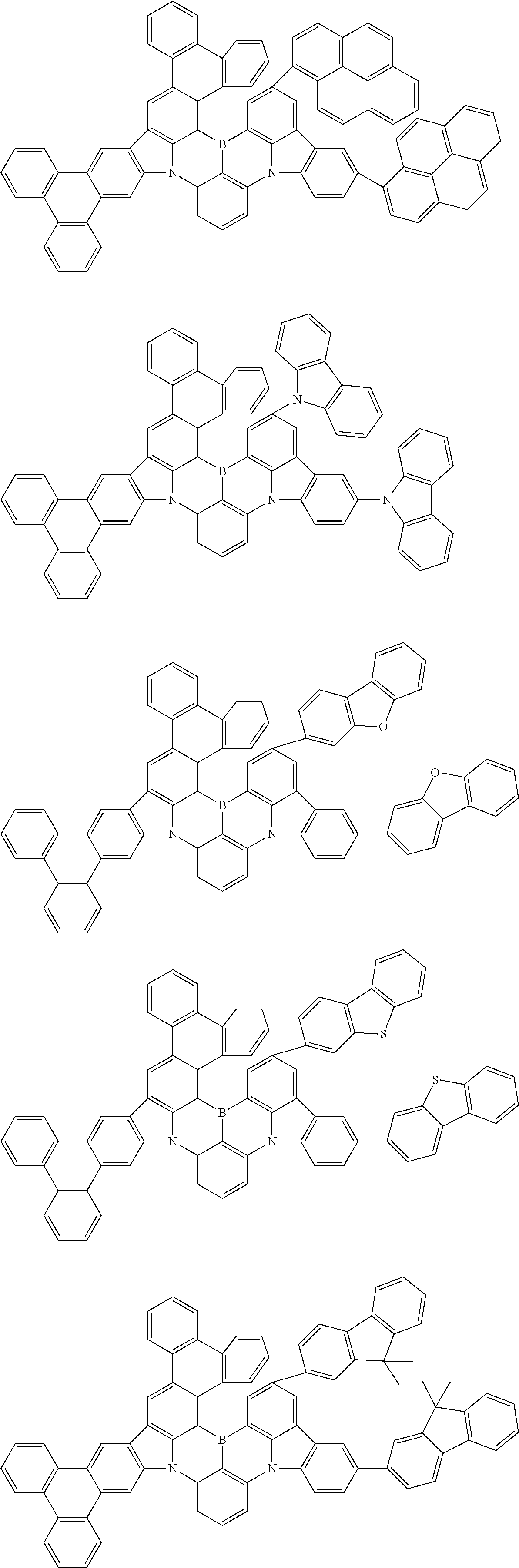

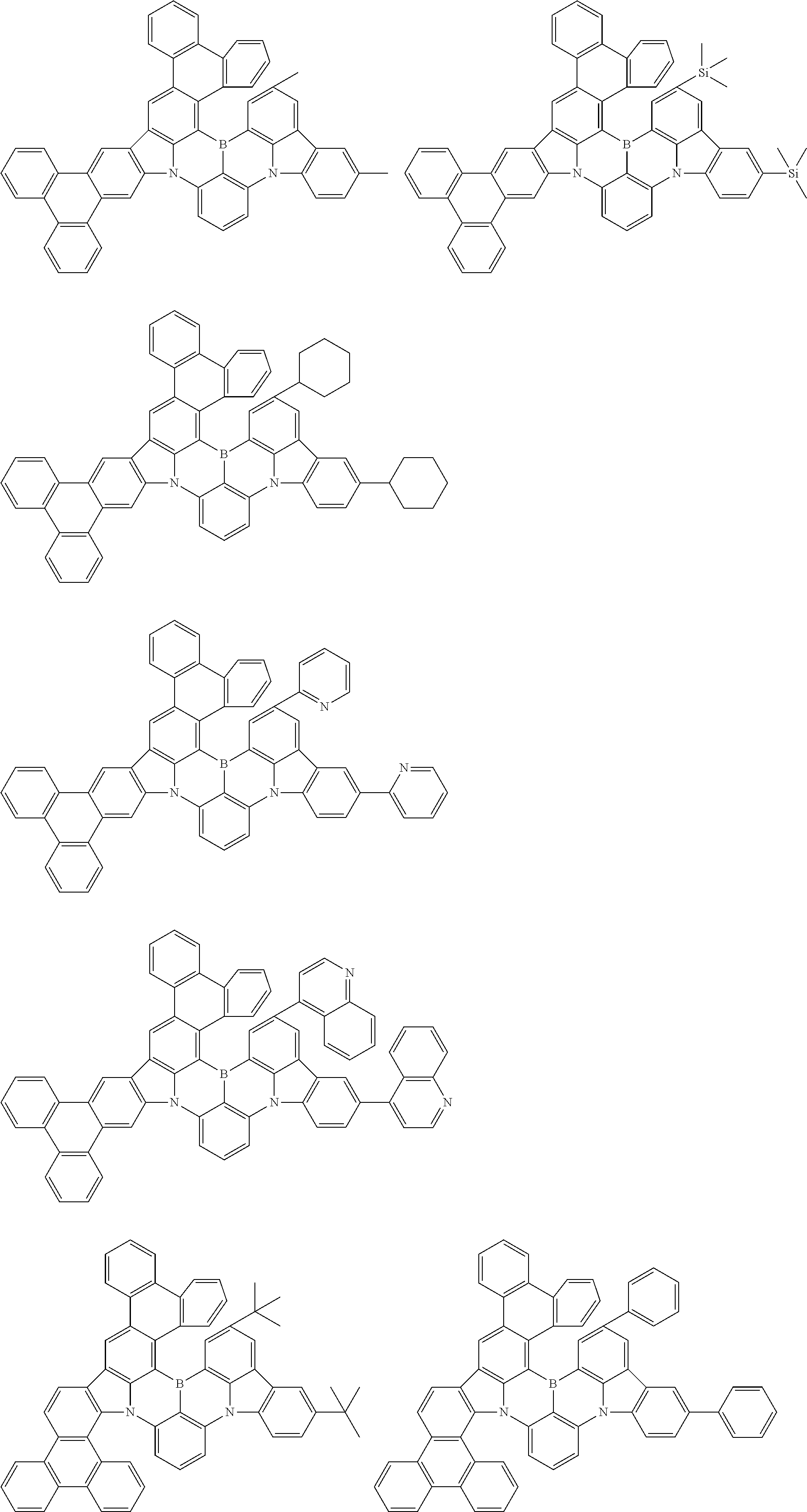

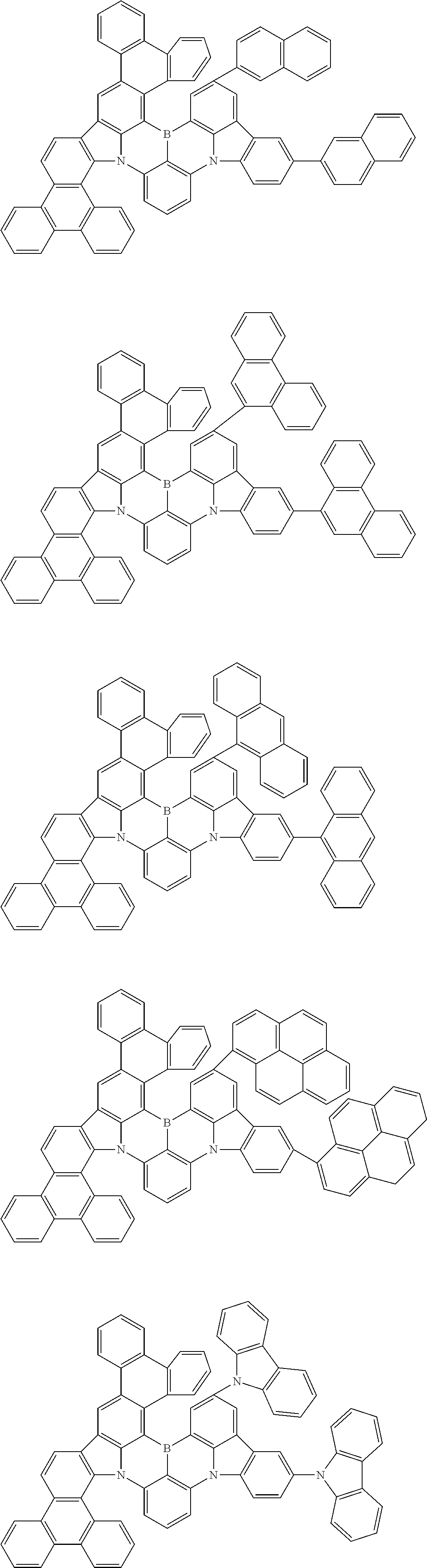

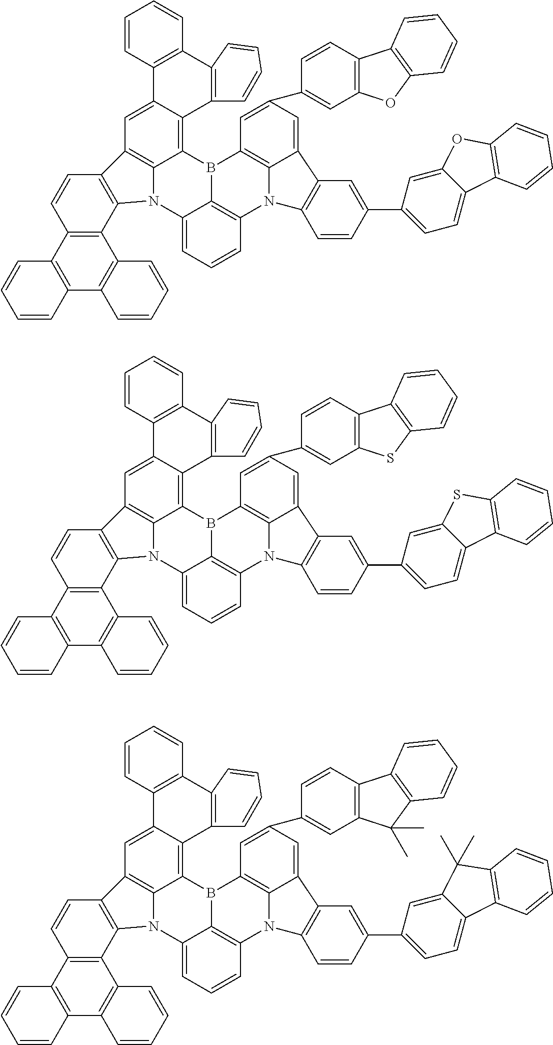

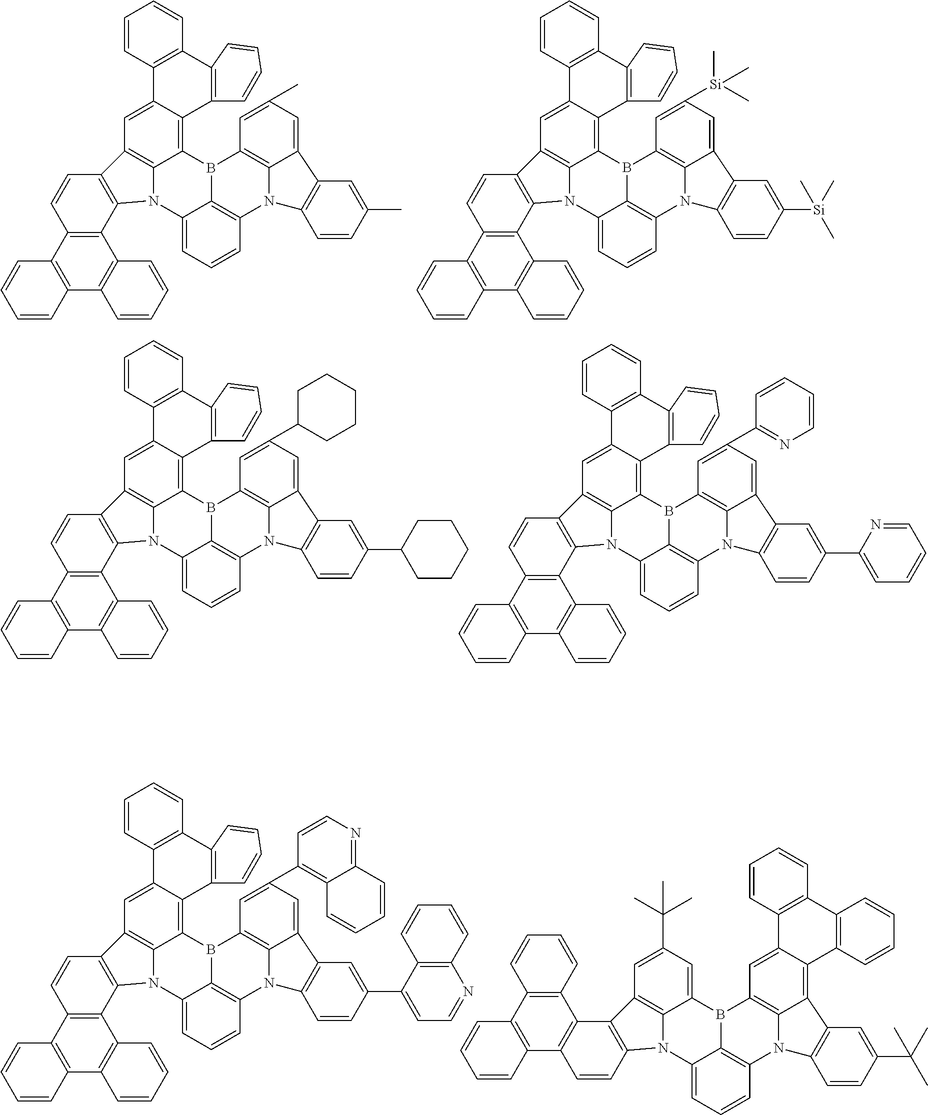

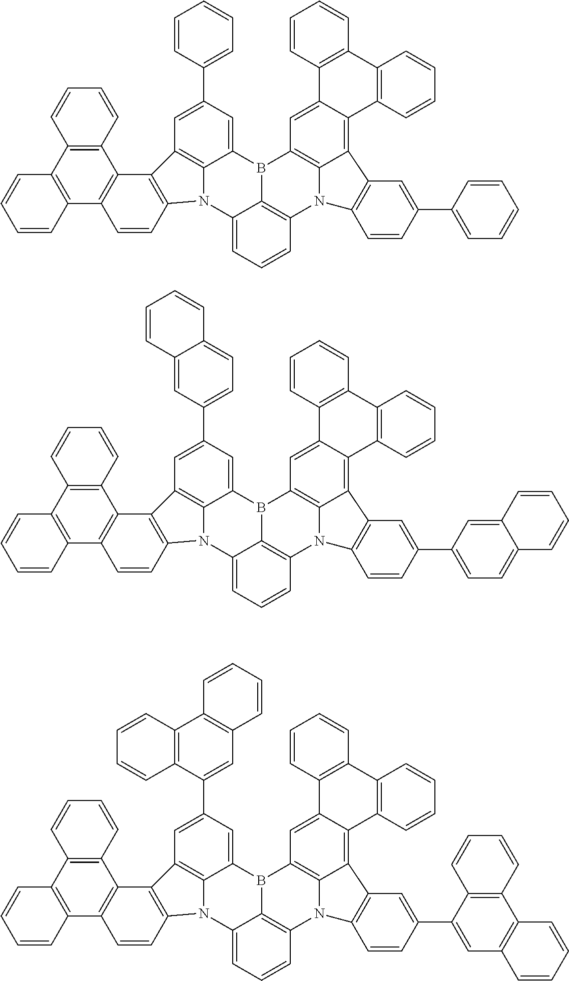 [SMILES: c1ccc(-c2ccc3c(c2)c2c4c5ccccc5c5ccccc5c4cc4c2n3-c2cccc3c2B4c2cc(-c4ccccc4)cc4c5c6c7ccccc7c7ccccc7c6ccc5n-3c24)cc1 ; c1cc2c3c(c1)-n1c4ccc(-c5ccc6ccccc6c5)cc4c4c5c6ccccc6c6ccccc6c5cc(c41)B3c1cc(-c3ccc4ccccc4c3)cc3c4c5c6ccccc6c6ccccc6c5ccc4n-2c13 ; c1cc2c3c(c1)-n1c4ccc(-c5cc6ccccc6c6ccccc56)cc4c4c5c6ccccc6c6ccccc6c5cc(c41)B3c1cc(-c3cc4ccccc4c4ccccc34)cc3c4c5c6ccccc6c6ccccc6c5ccc4n-2c13]

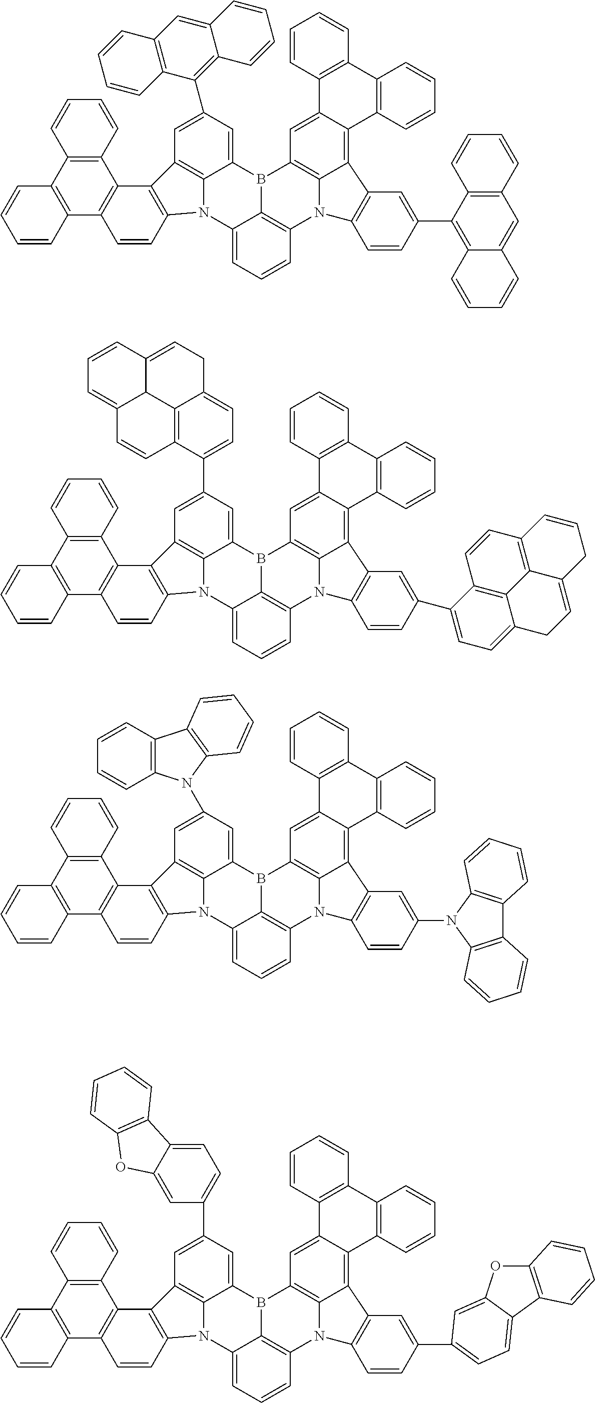

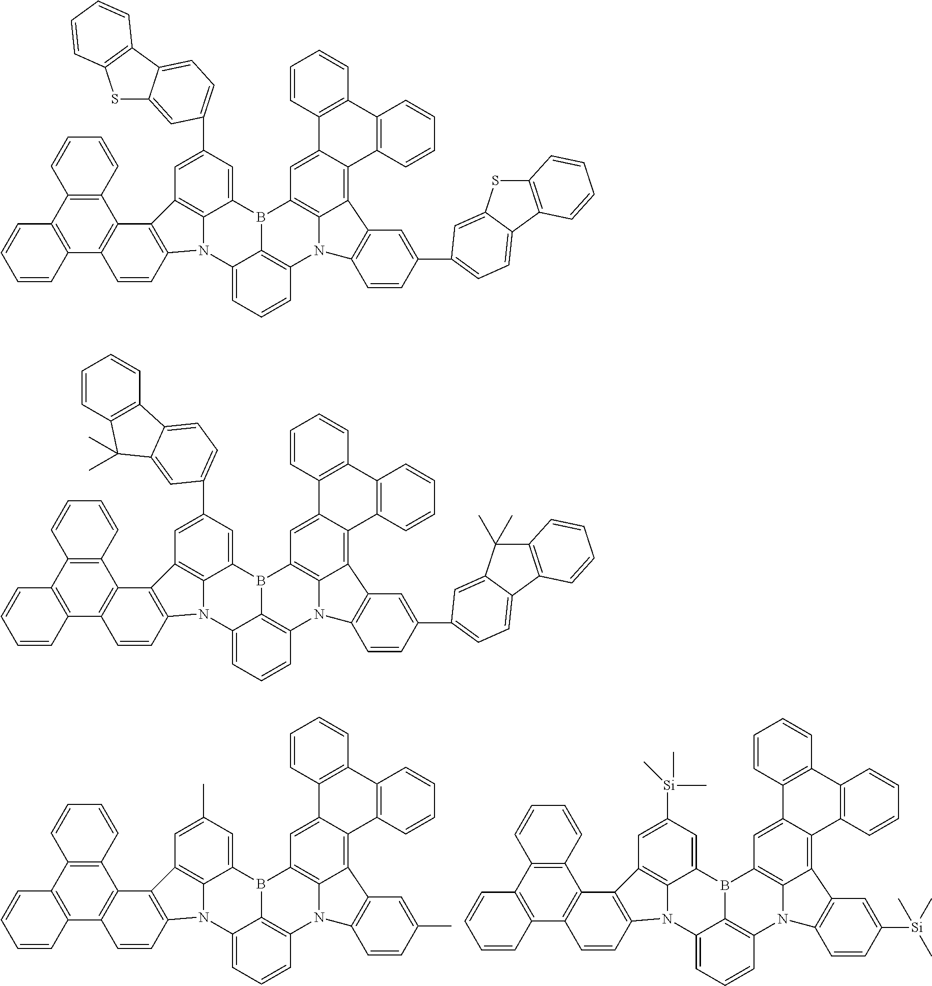

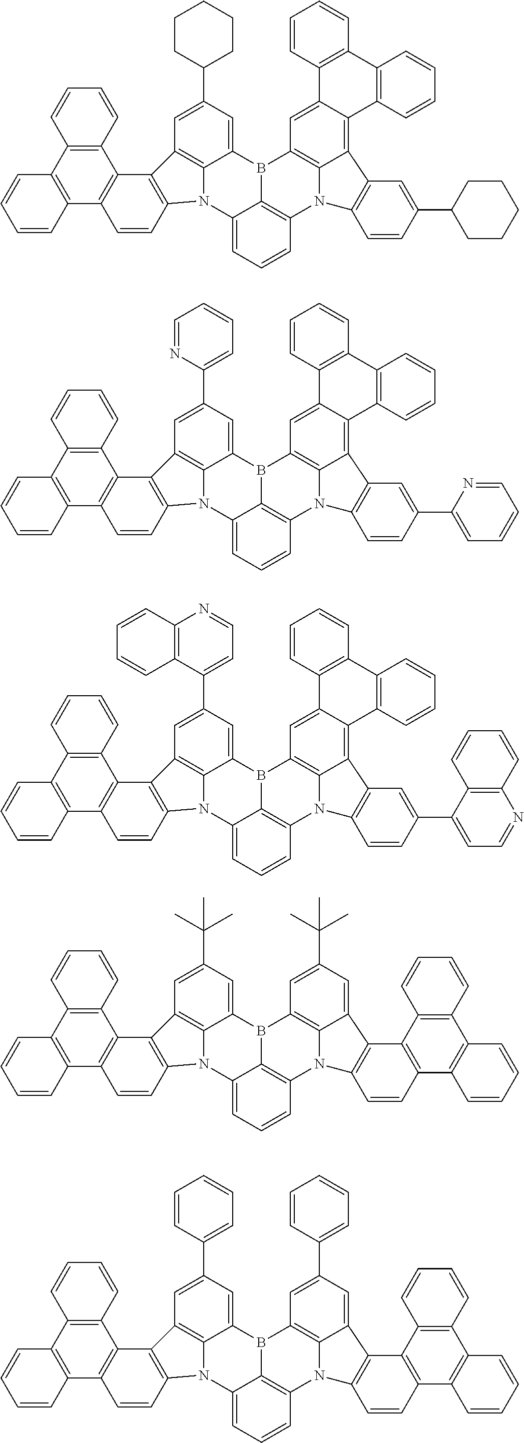

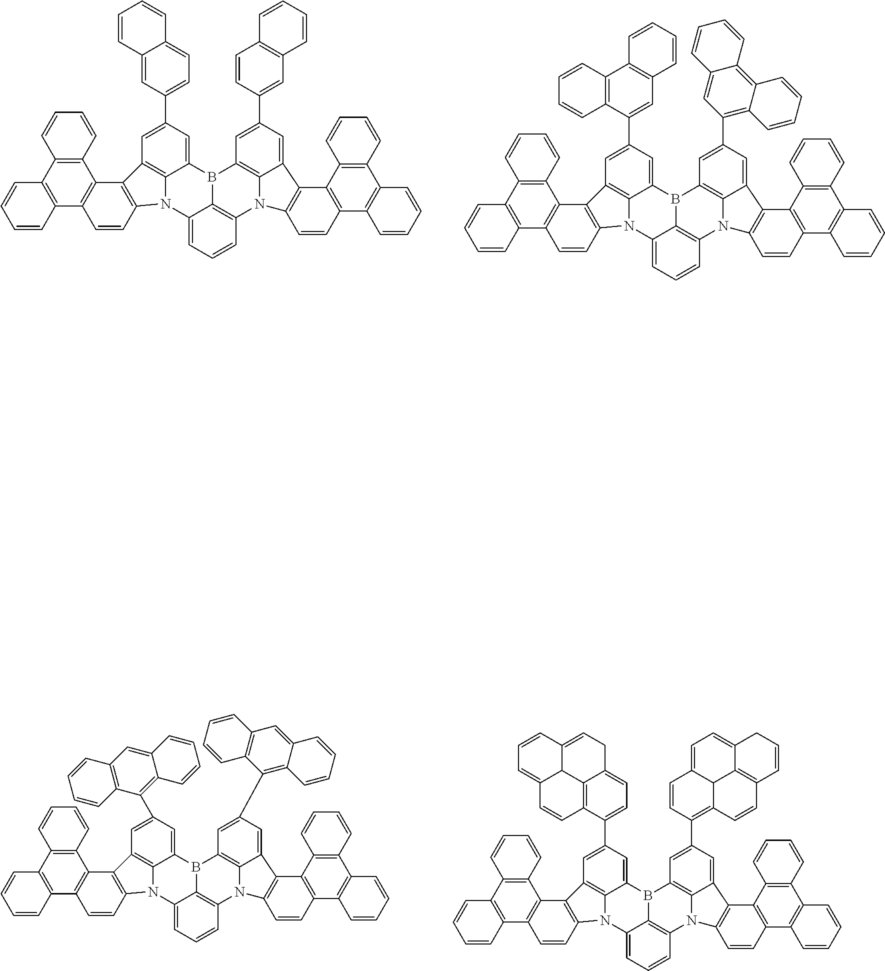

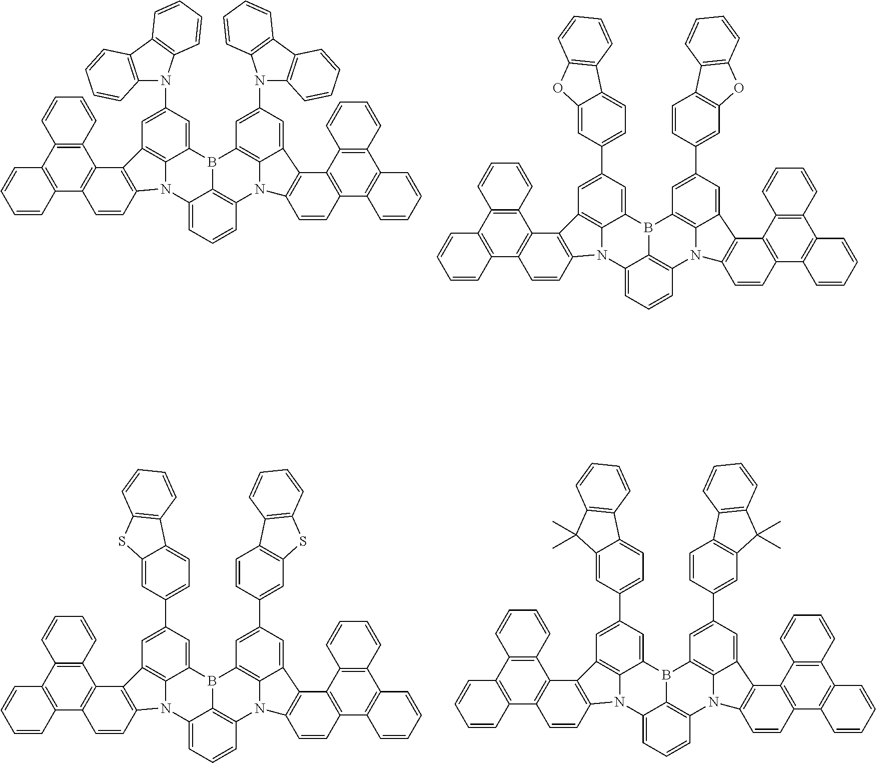

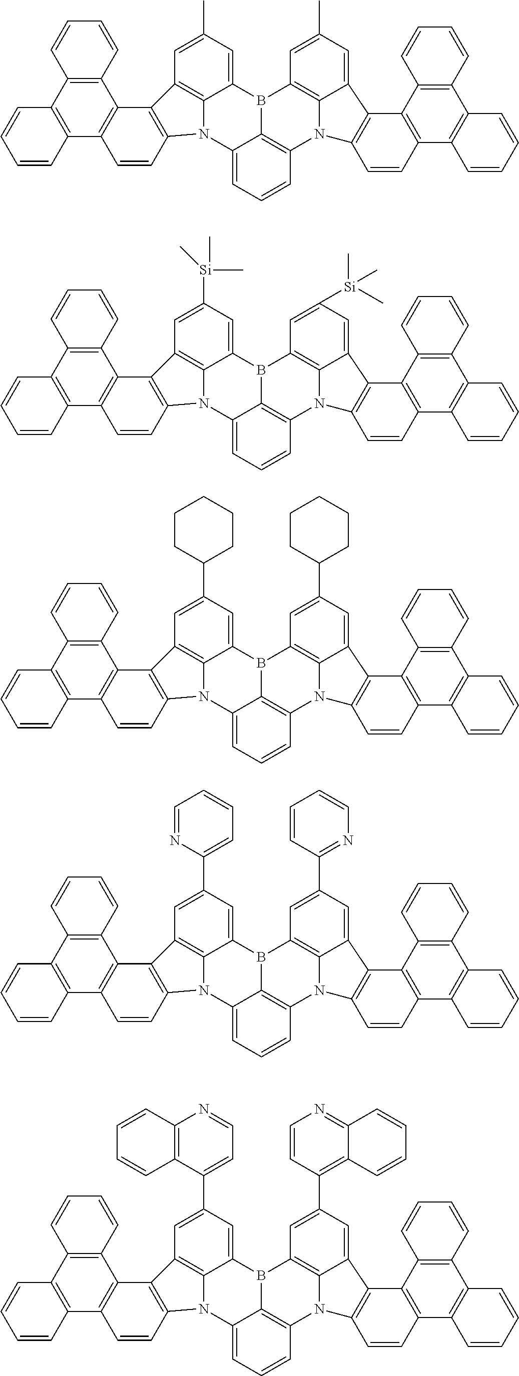

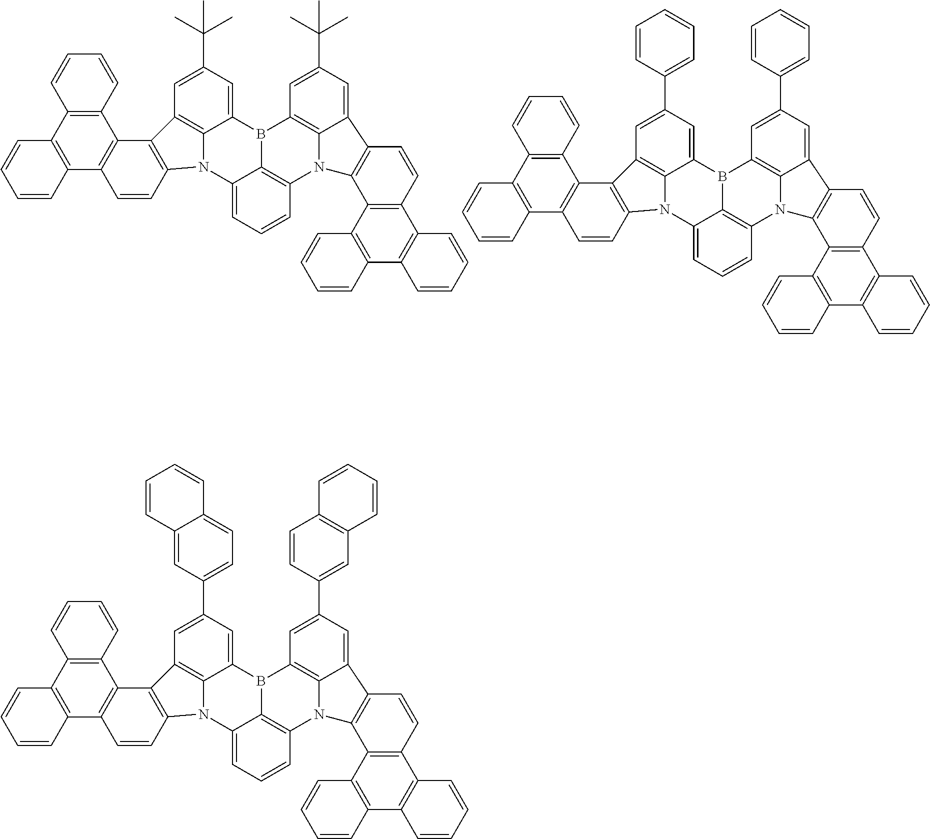

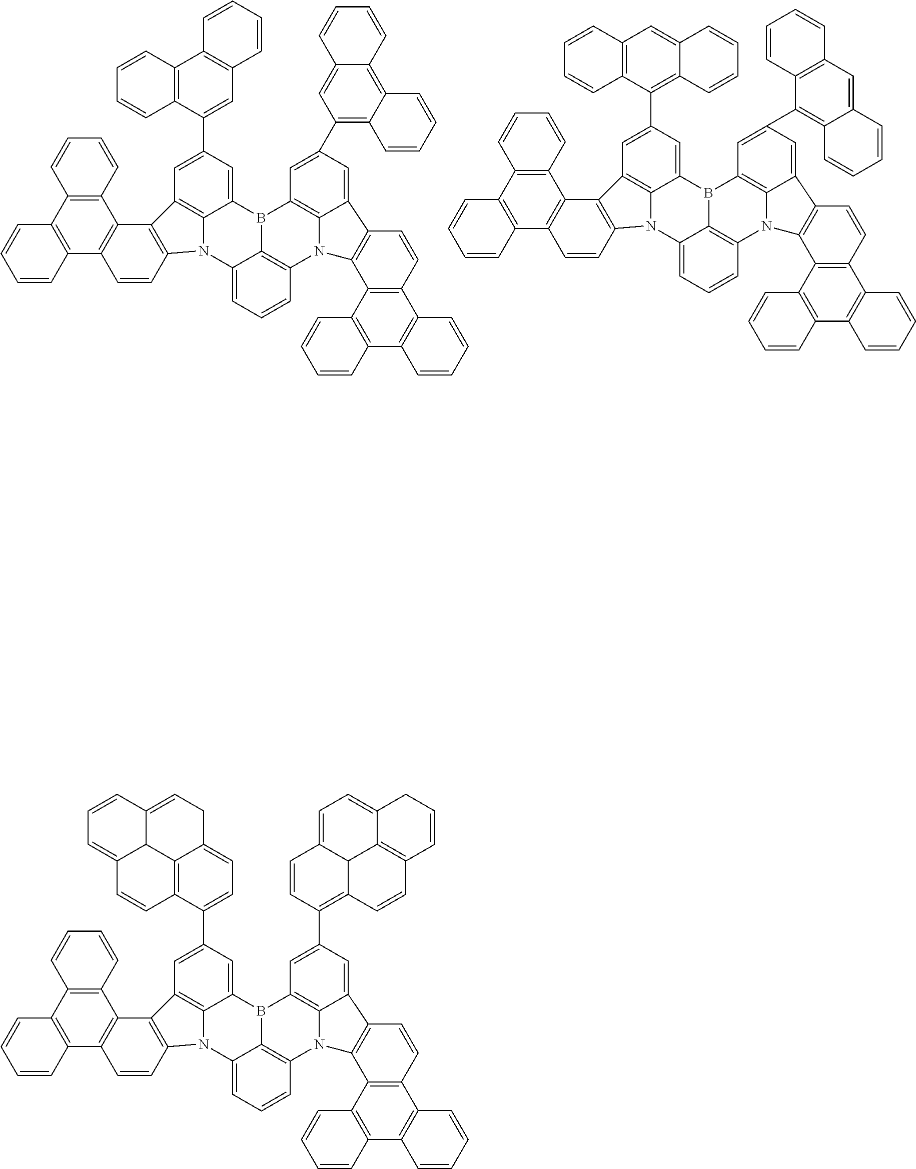

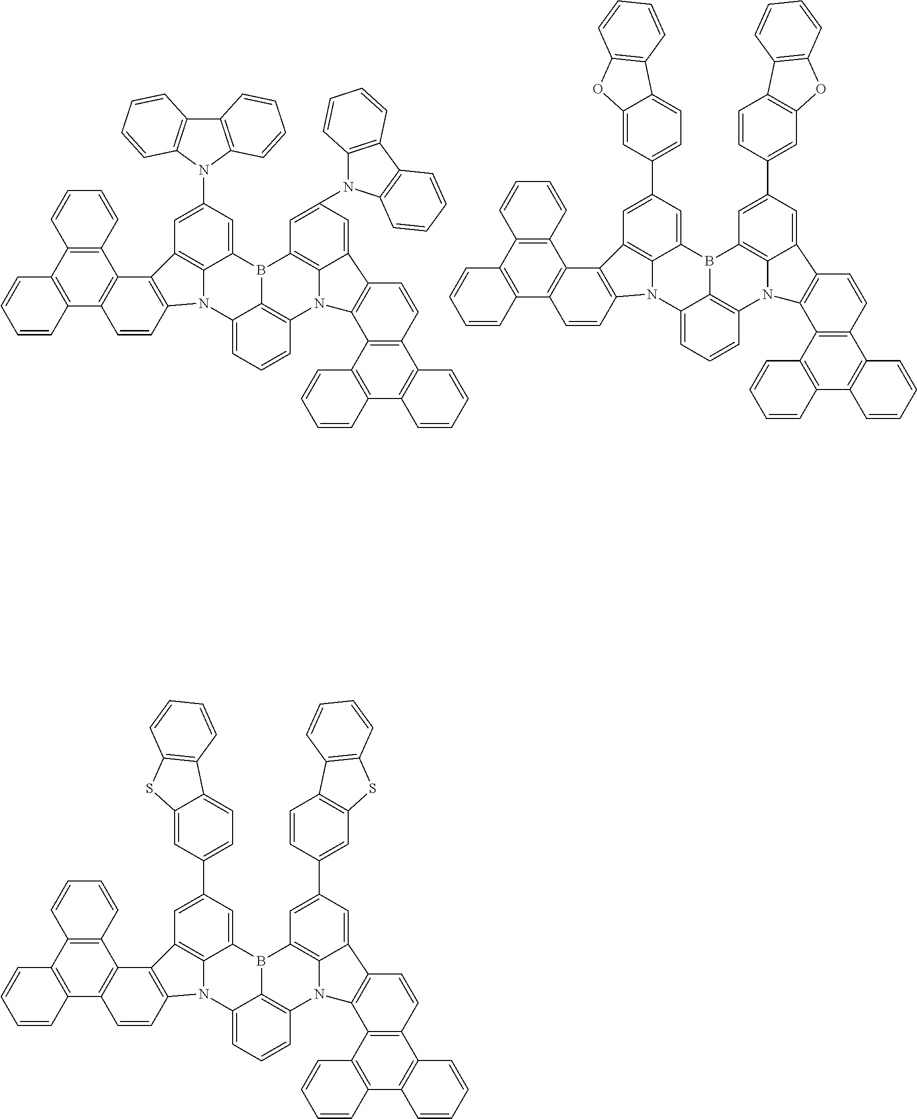

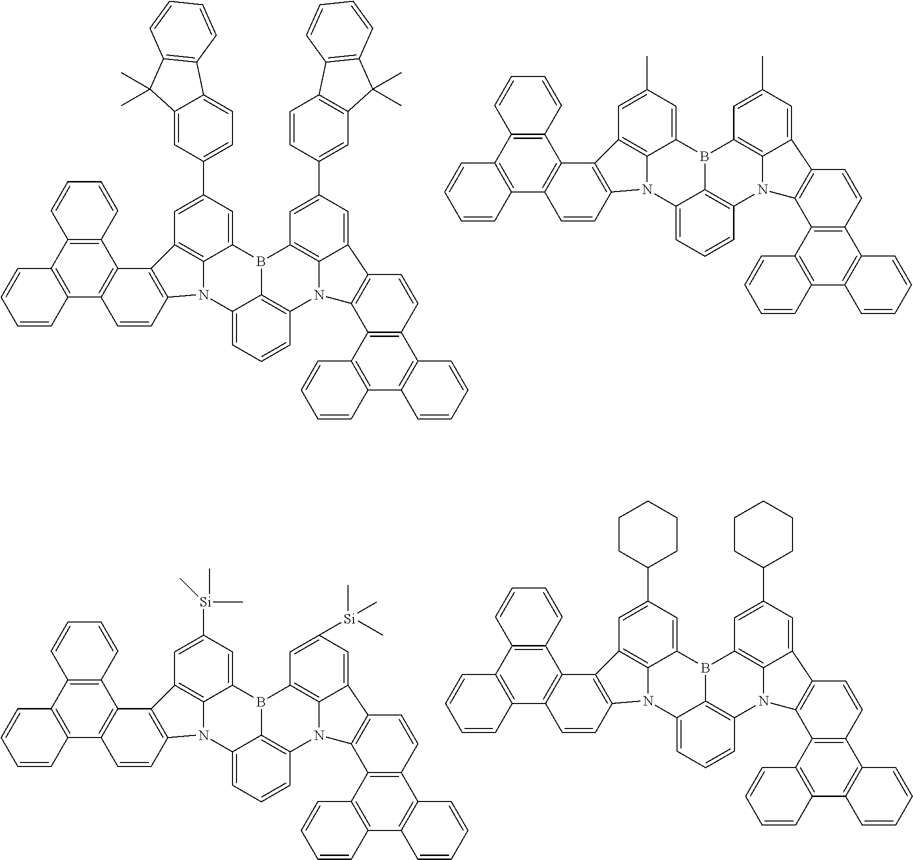

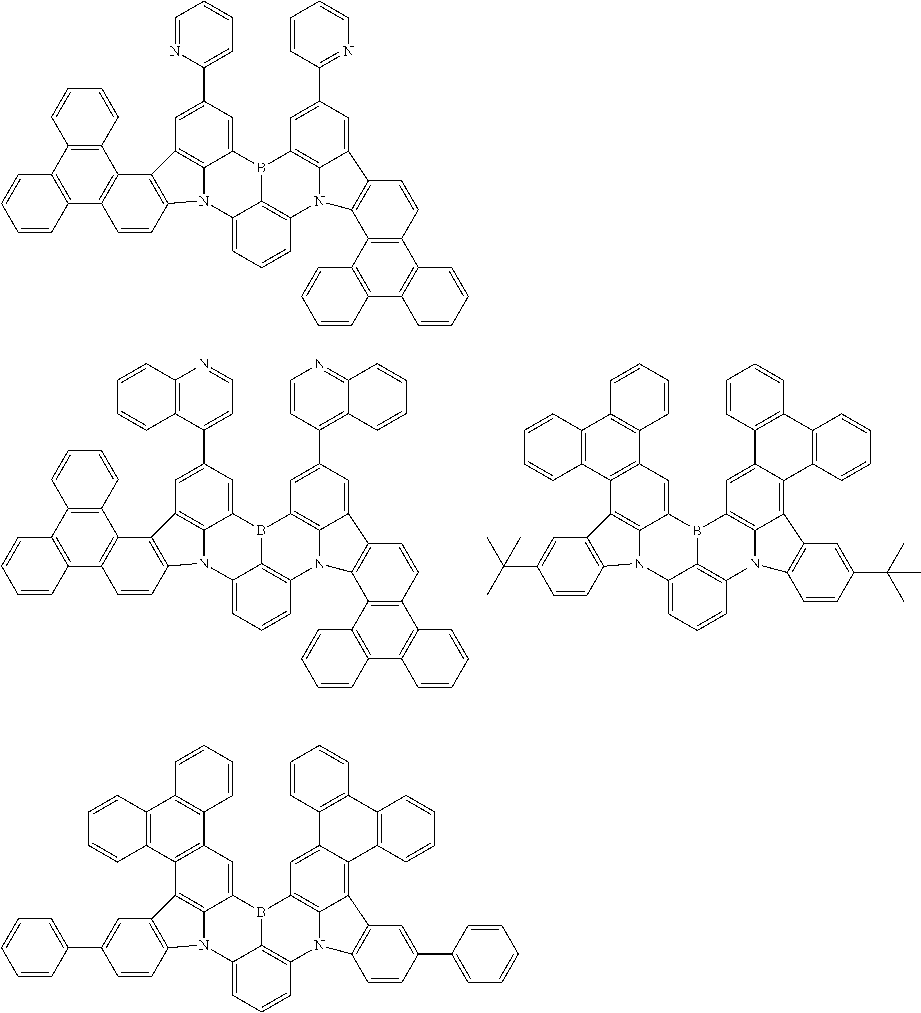

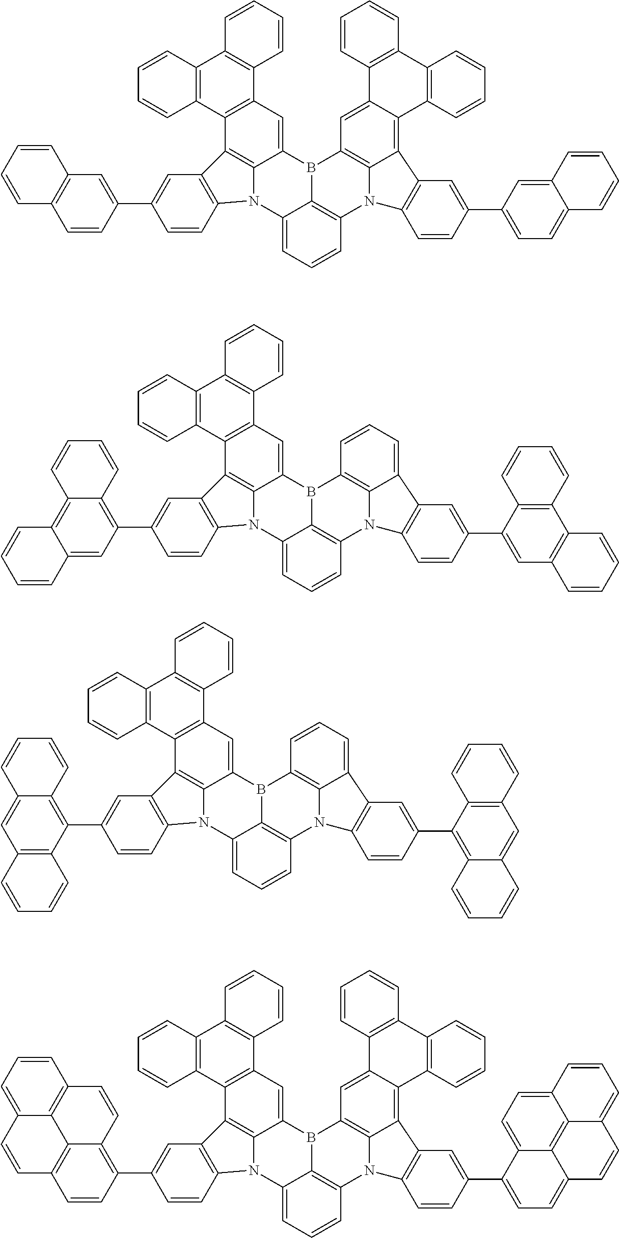

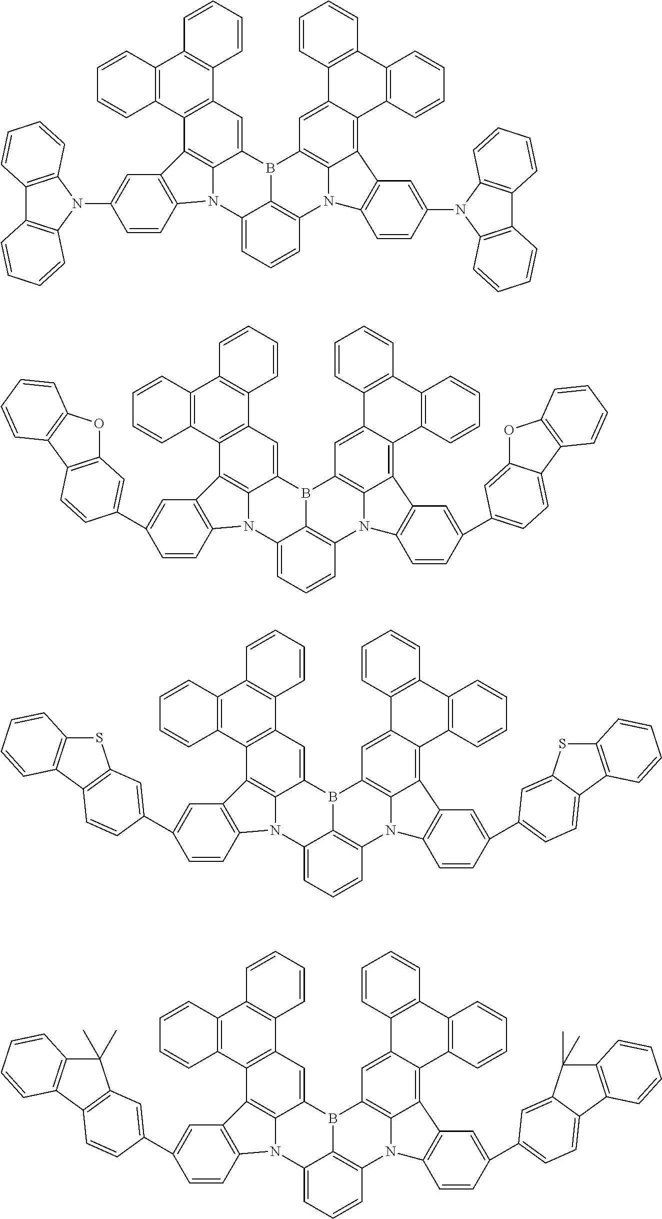

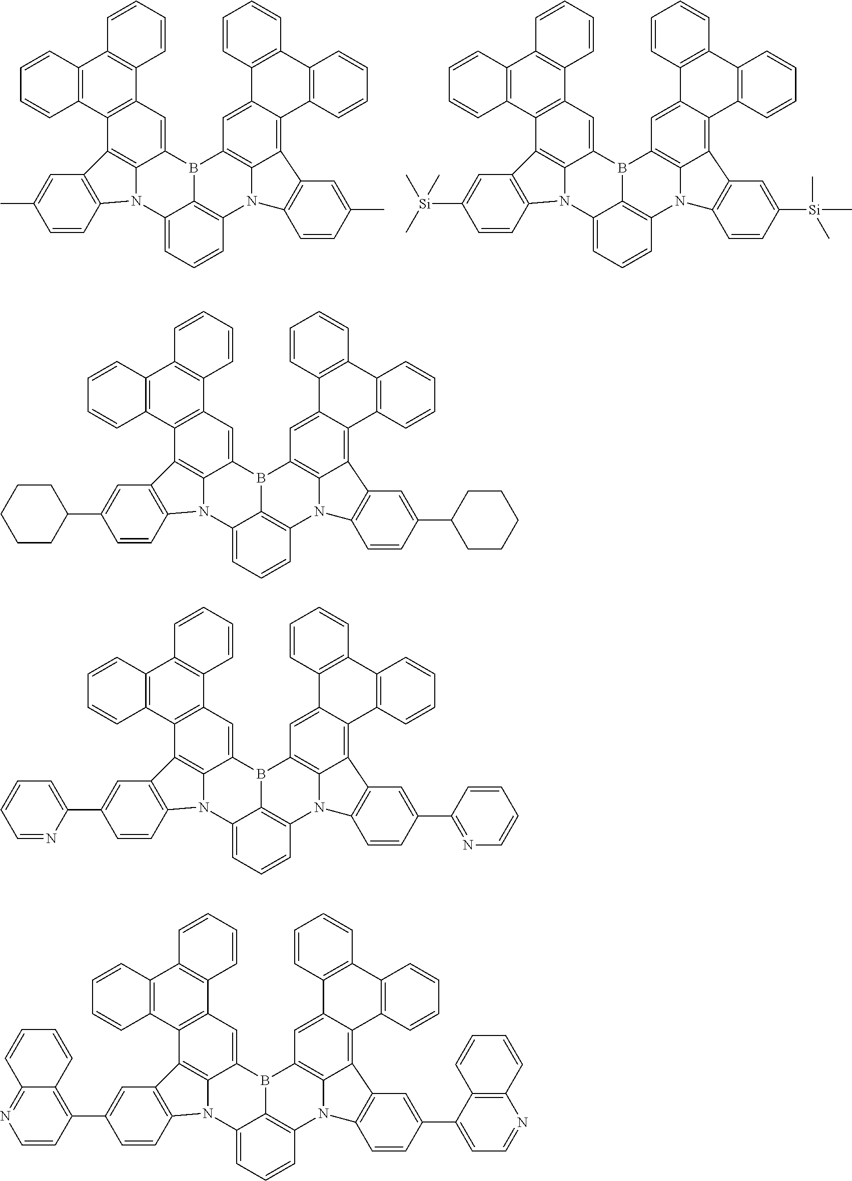

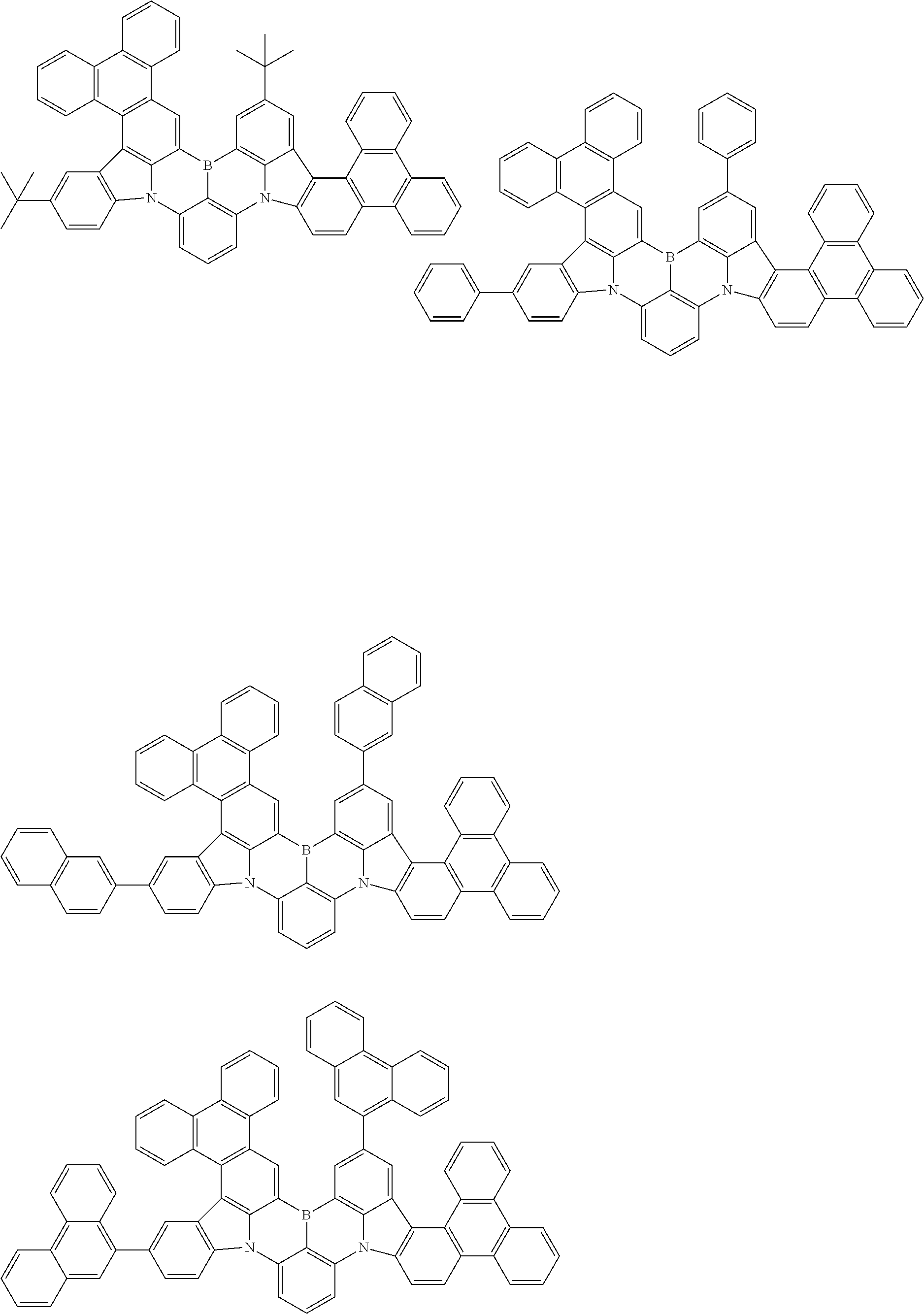

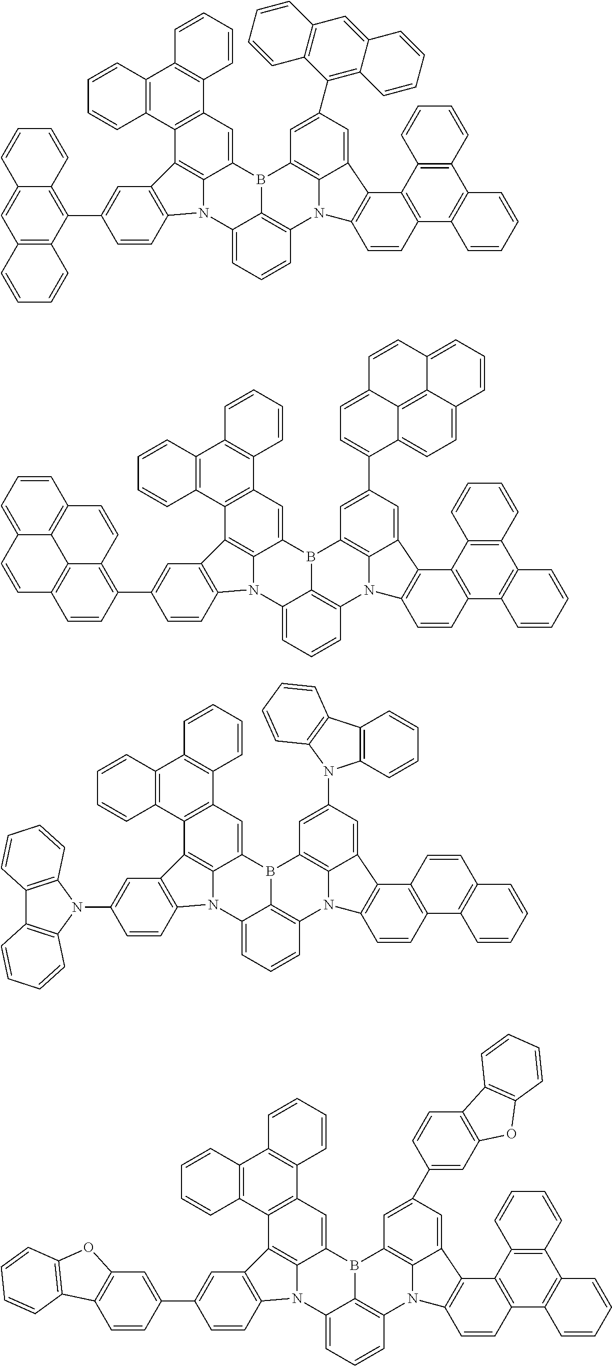

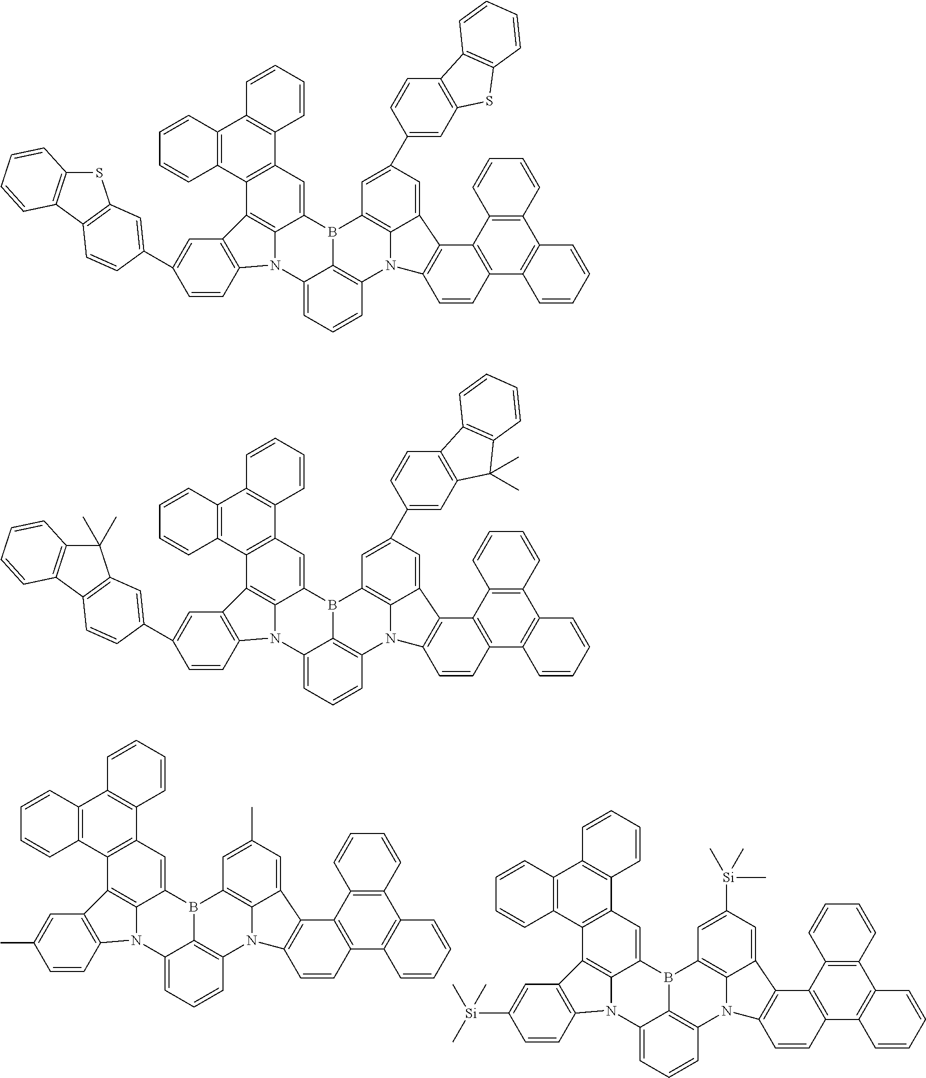

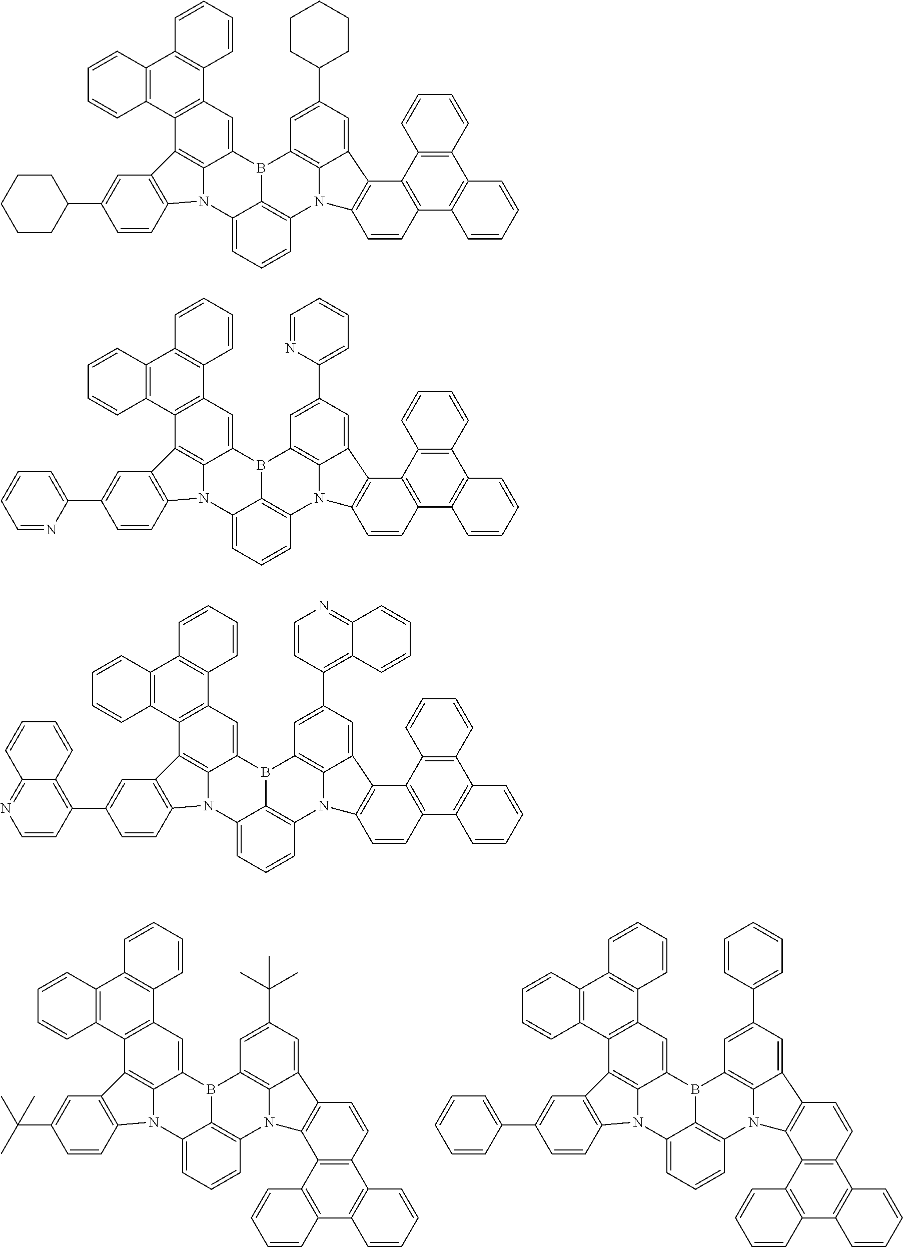

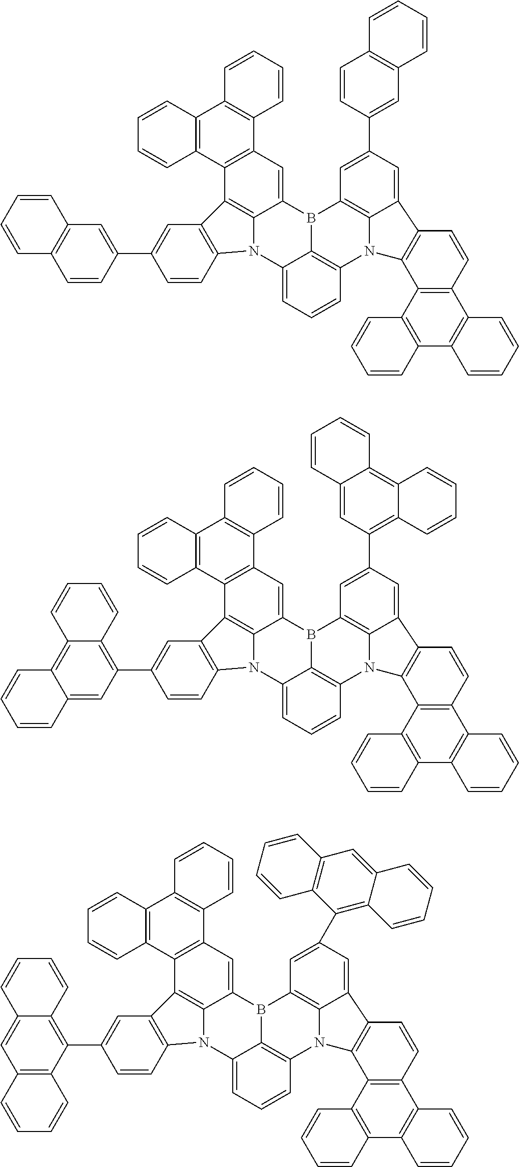 [SMILES: c1cc2c3c(c1)-n1c4c(cc(-c5ccc6ccccc6c5)cc4c4ccc5c6ccccc6c6ccccc6c5c41)B3c1cc3c4ccccc4c4ccccc4c3c3c4cc(-c5ccc6ccccc6c5)ccc4n-2c13 ; c1cc2c3c(c1)-n1c4c(cc(-c5cc6ccccc6c6ccccc56)cc4c4ccc5c6ccccc6c6ccccc6c5c41)B3c1cc3c4ccccc4c4ccccc4c3c3c4cc(-c5cc6ccccc6c6ccccc56)ccc4n-2c13 ; c1cc2c3c(c1)-n1c4c(cc(-c5c6ccccc6cc6ccccc56)cc4c4ccc5c6ccccc6c6ccccc6c5c41)B3c1cc3c4ccccc4c4ccccc4c3c3c4cc(-c5c6ccccc6cc6ccccc56)ccc4n-2c13]

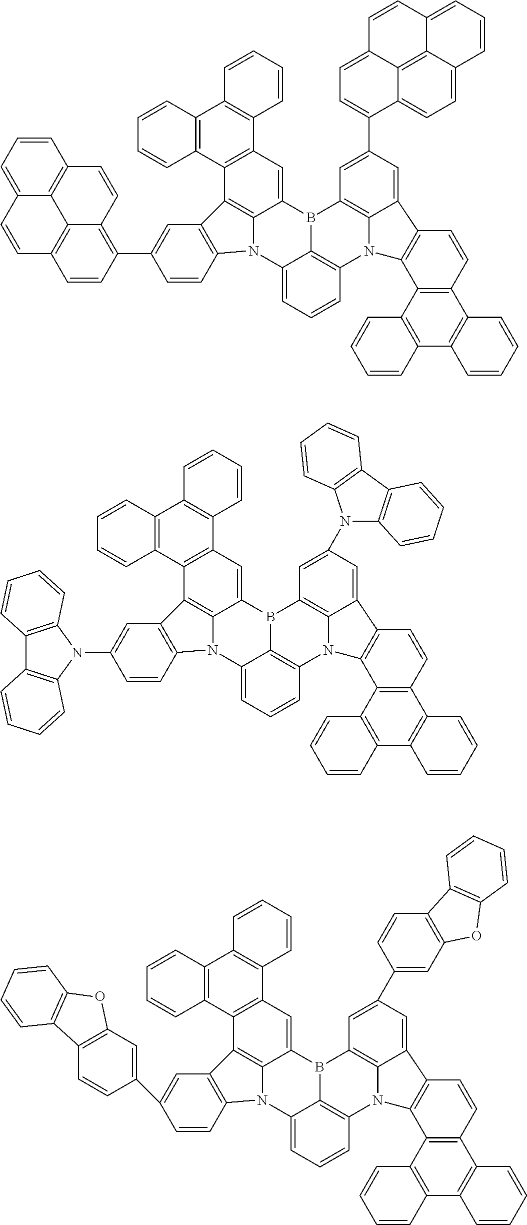 [SMILES: c1cc2c3c(c1)-n1c4c(cc(-c5ccc6ccc7cccc8ccc5c6c78)cc4c4ccc5c6ccccc6c6ccccc6c5c41)B3c1cc3c4ccccc4c4ccccc4c3c3c4cc(-c5ccc6ccc7cccc8ccc5c6c78)ccc4n-2c13 ; c1cc2c3c(c1)-n1c4c(cc(-n5c6ccccc6c6ccccc65)cc4c4ccc5c6ccccc6c6ccccc6c5c41)B3c1cc3c4ccccc4c4ccccc4c3c3c4cc(-n5c6ccccc6c6ccccc65)ccc4n-2c13 ; c1cc2c3c(c1)-n1c4c(cc(-c5ccc6c(c5)oc5ccccc56)cc4c4ccc5c6ccccc6c6ccccc6c5c41)B3c1cc3c4ccccc4c4ccccc4c3c3c4cc(-c5ccc6c(c5)oc5ccccc56)ccc4n-2c13]

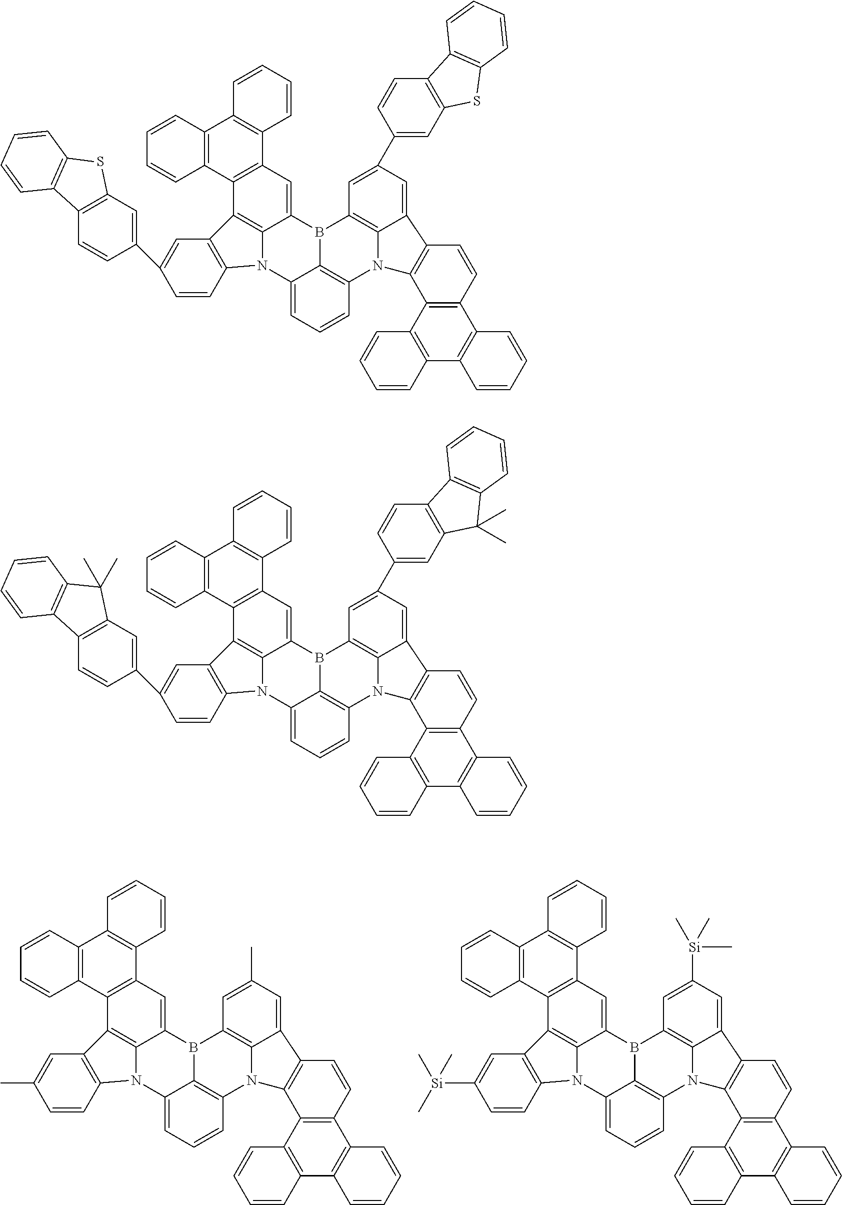

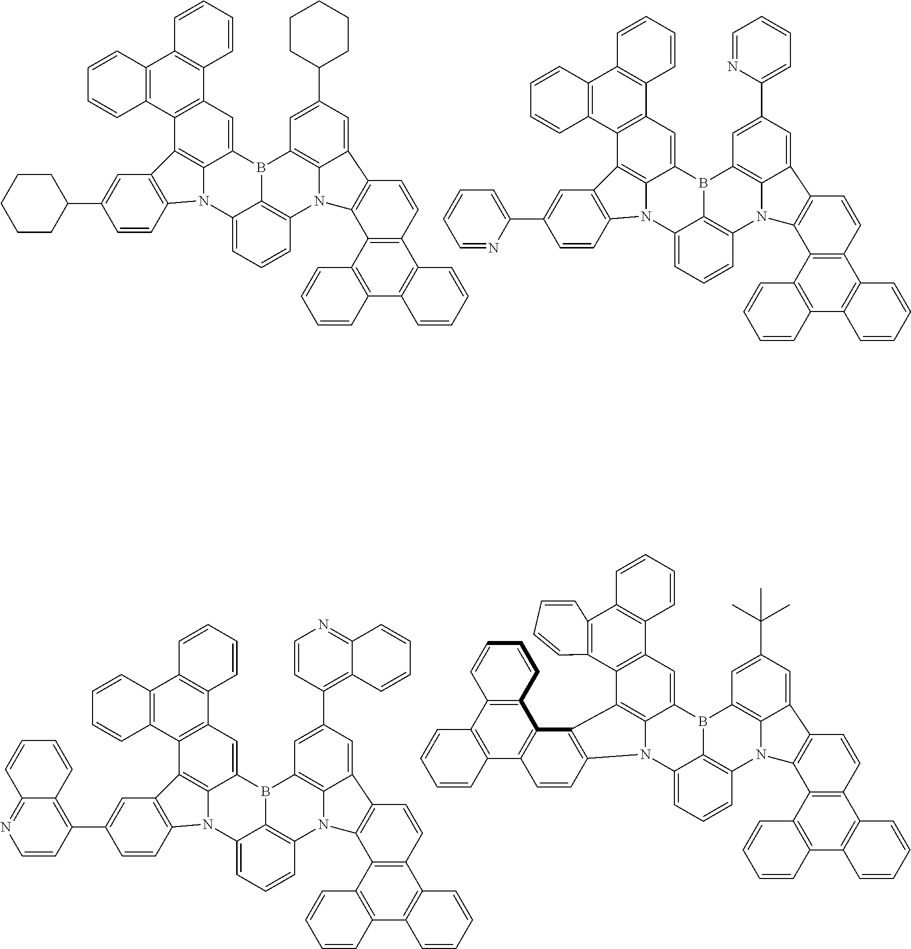

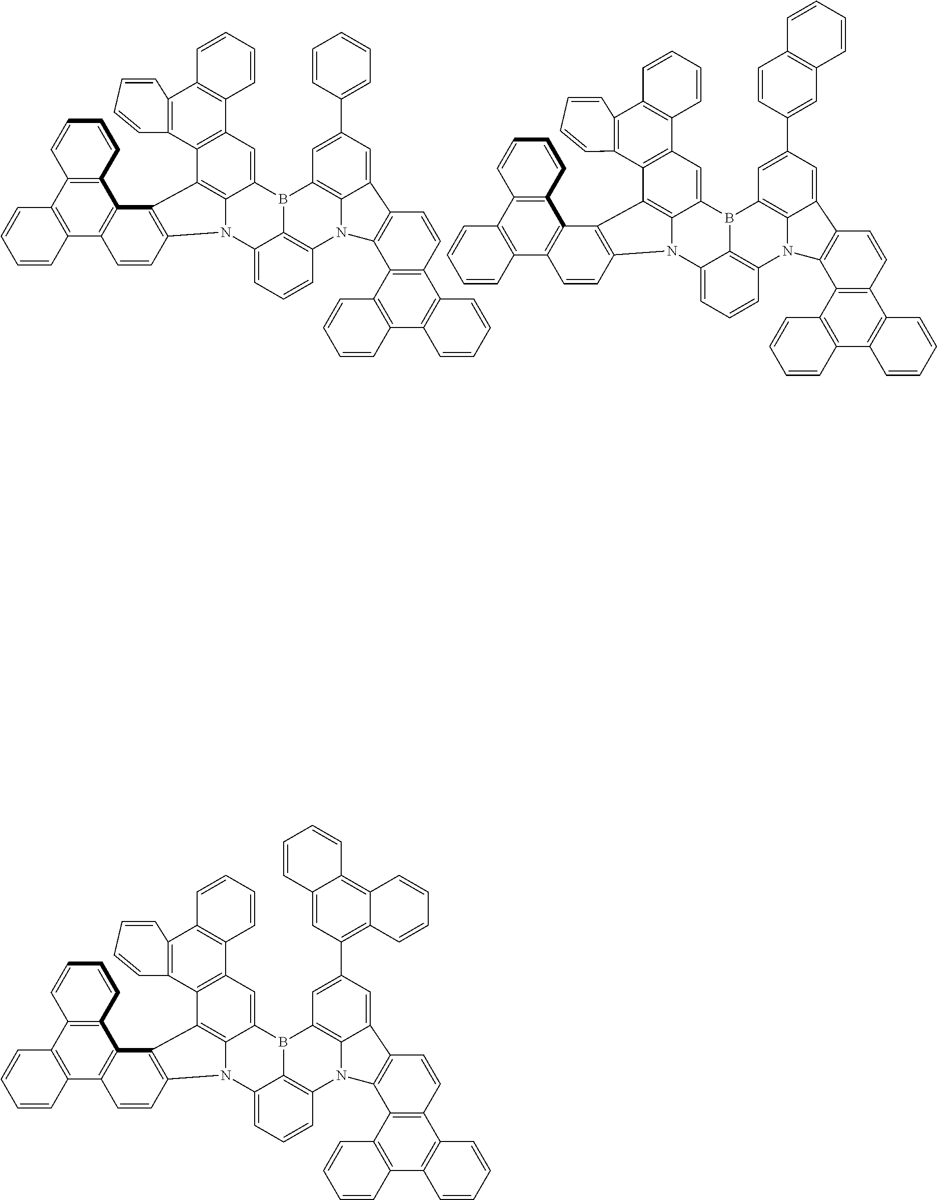

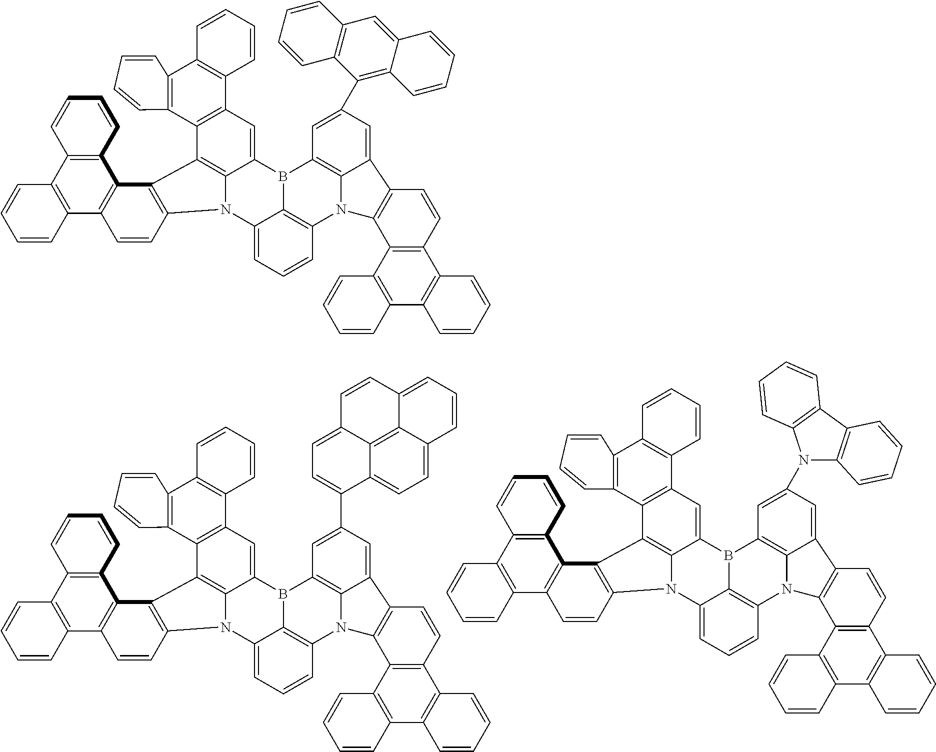

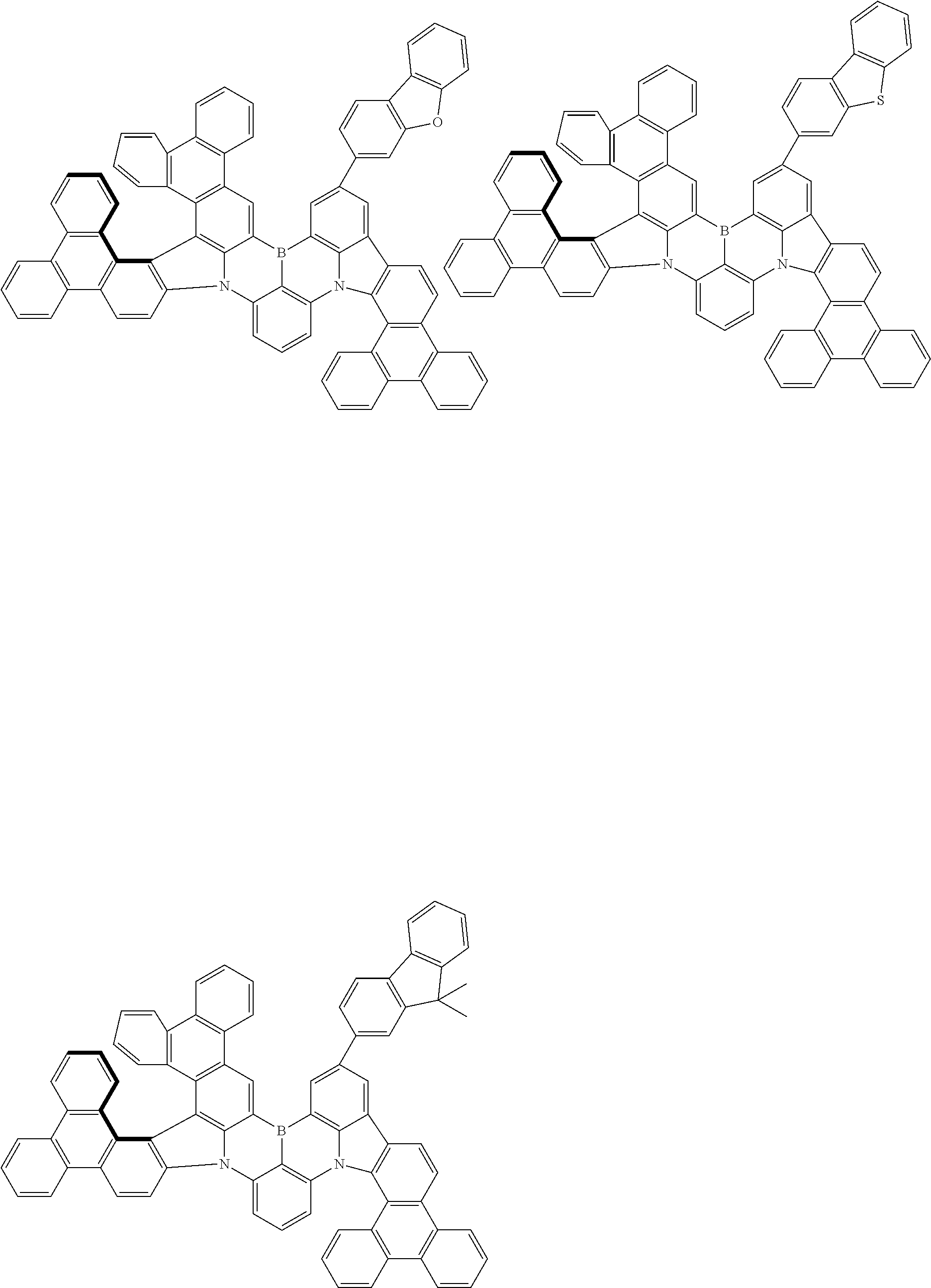

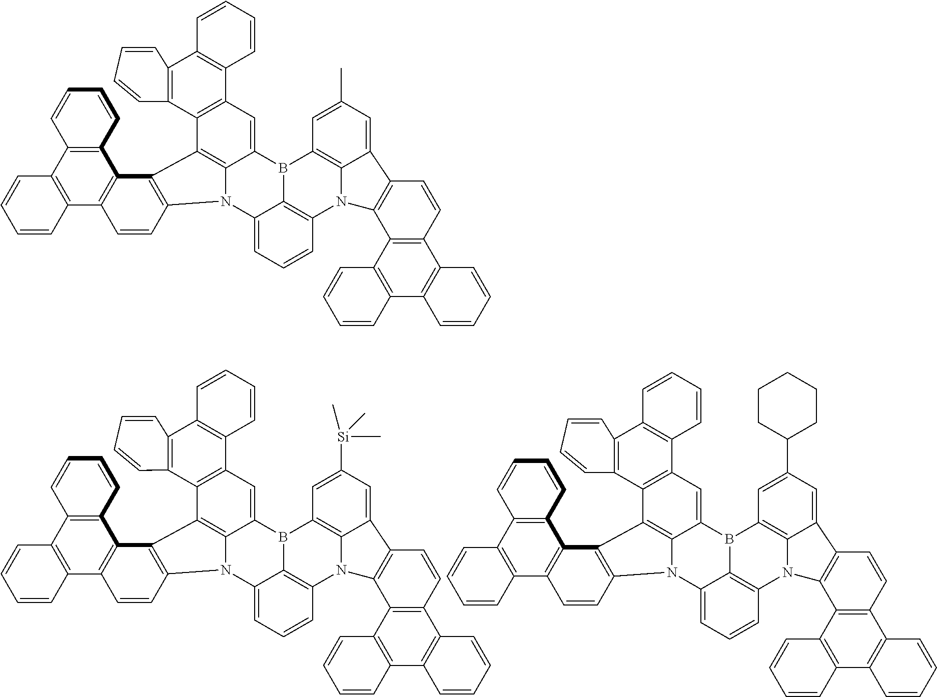

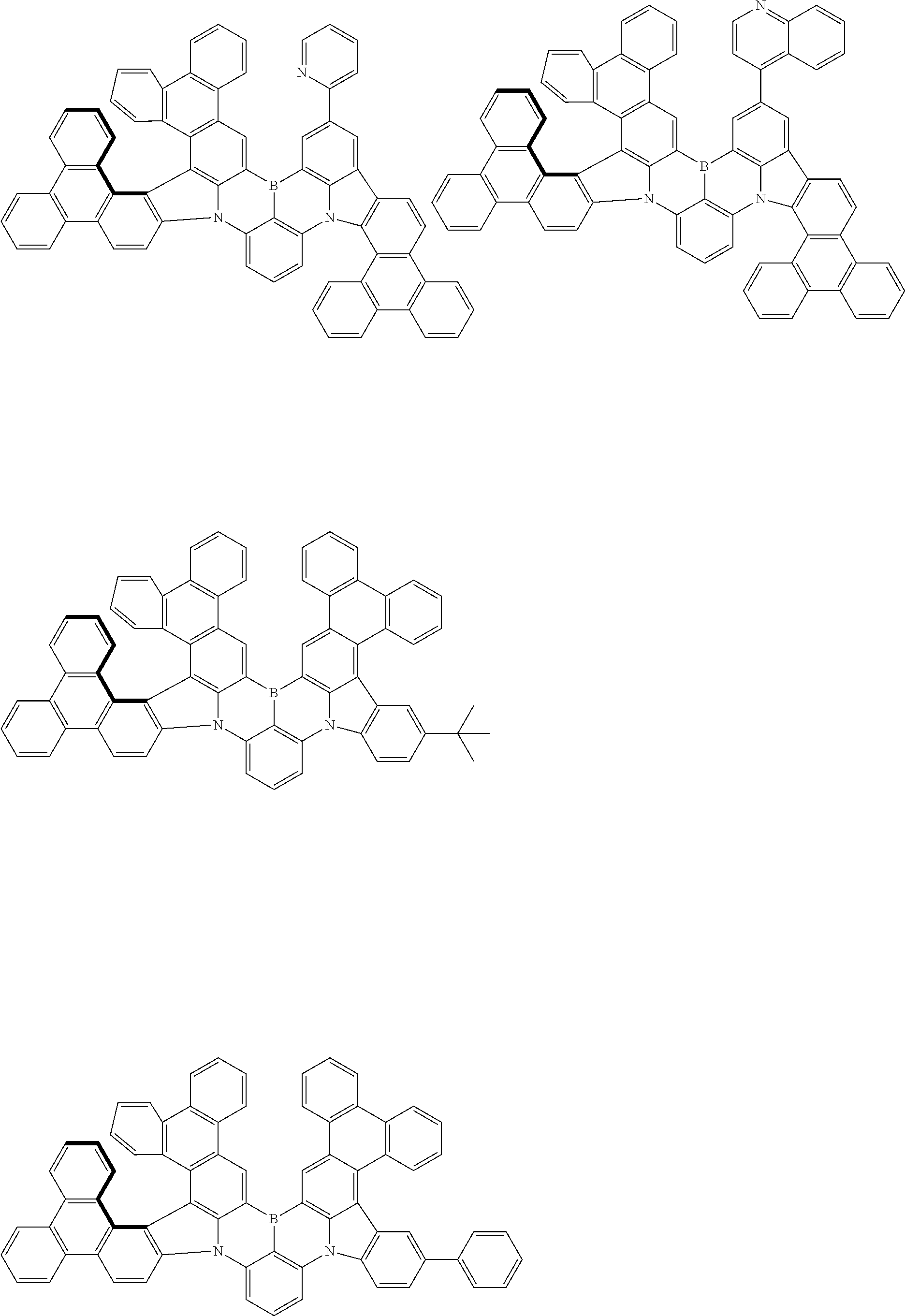

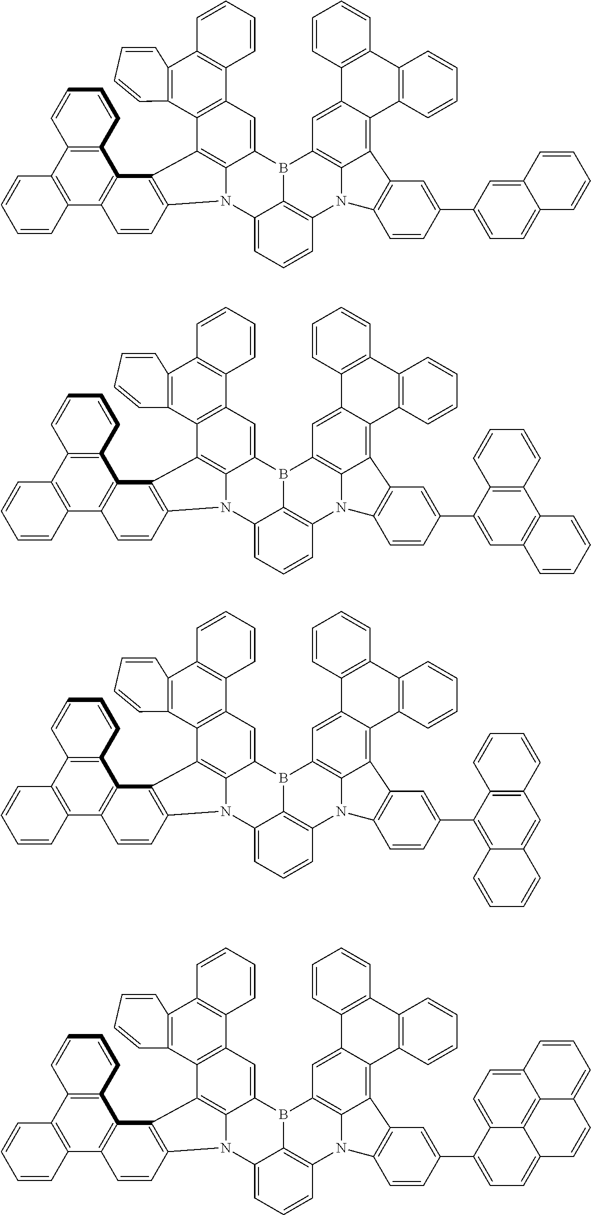

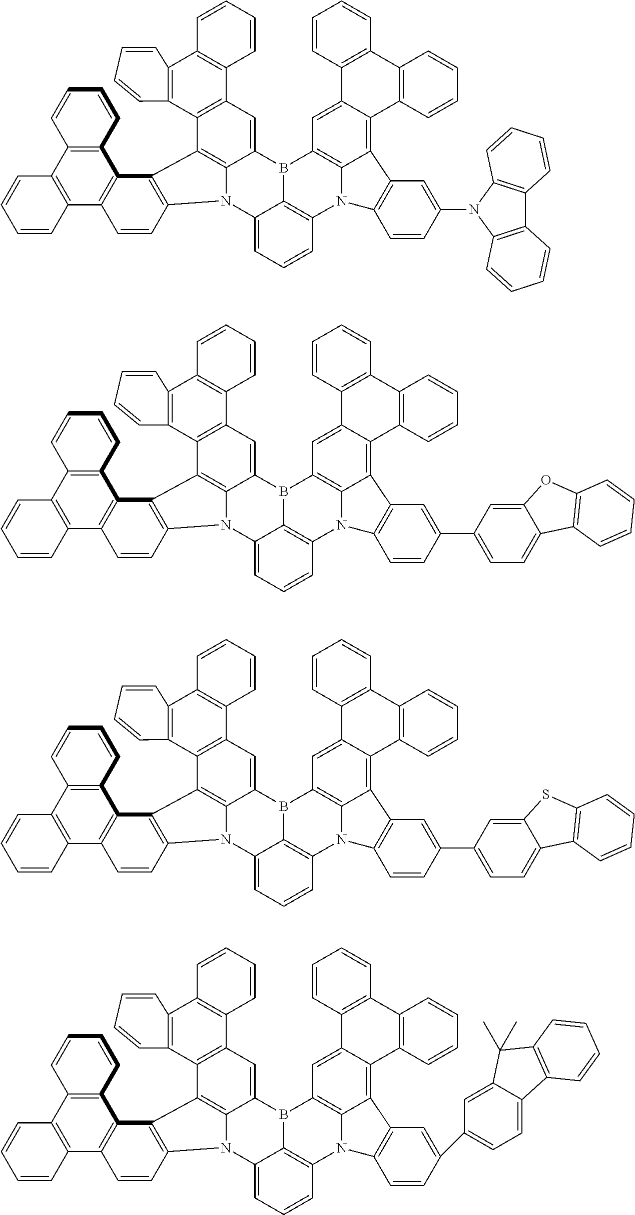

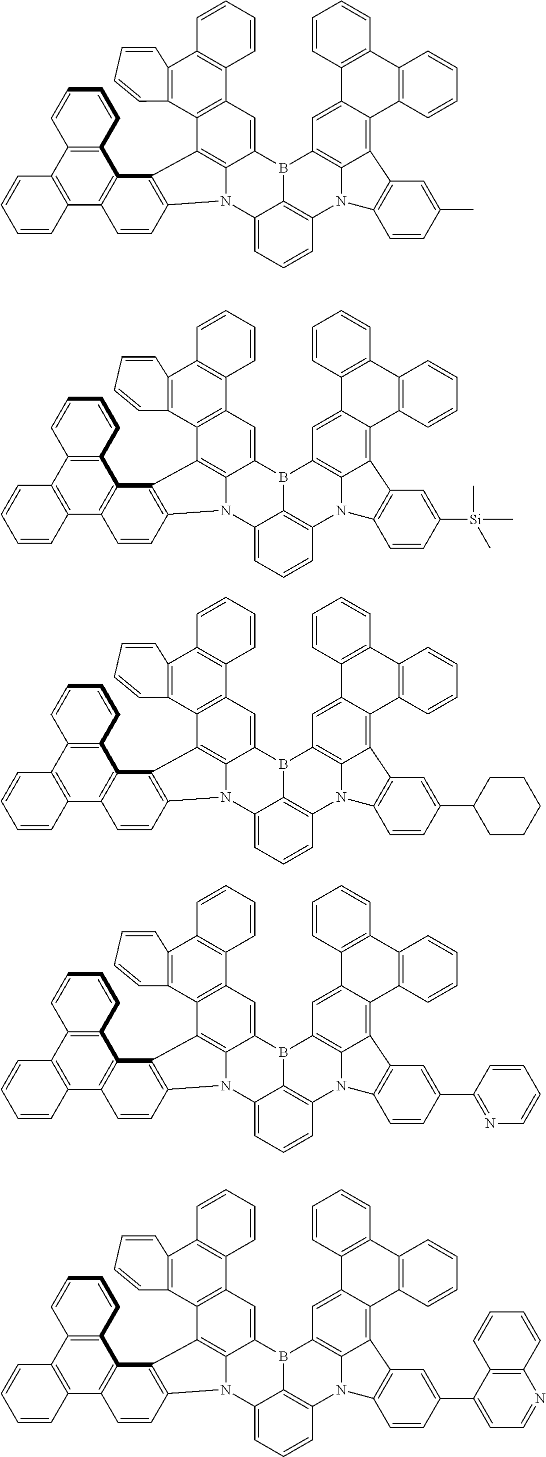

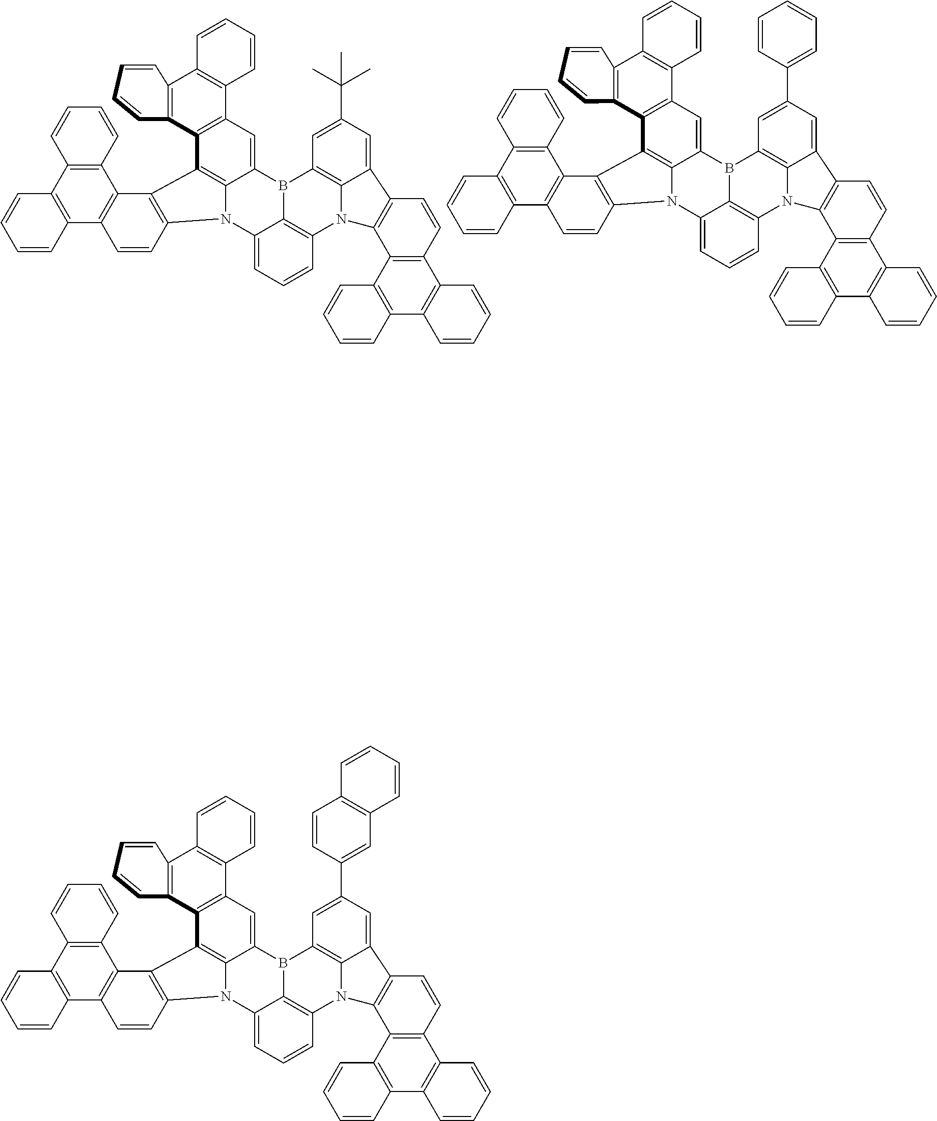

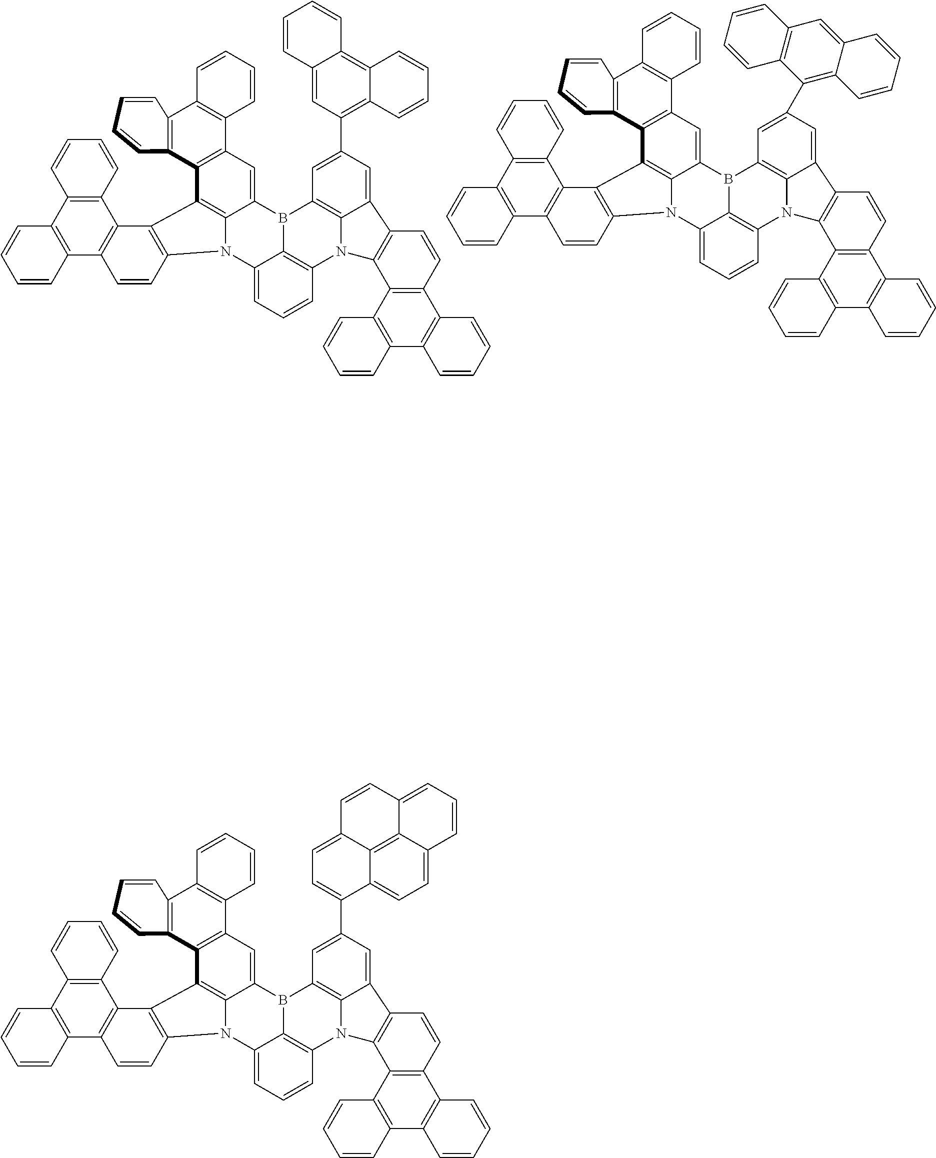

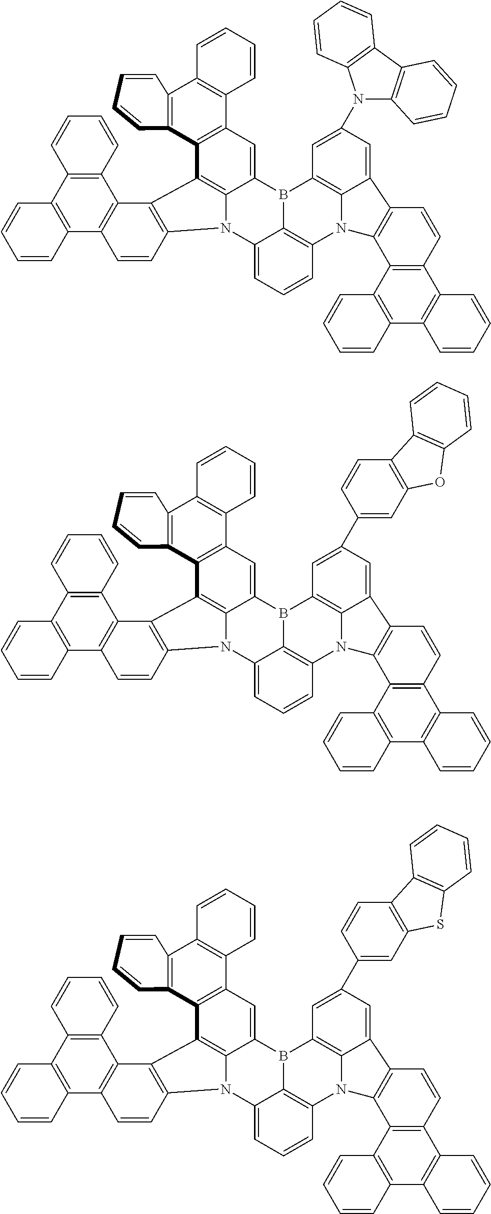

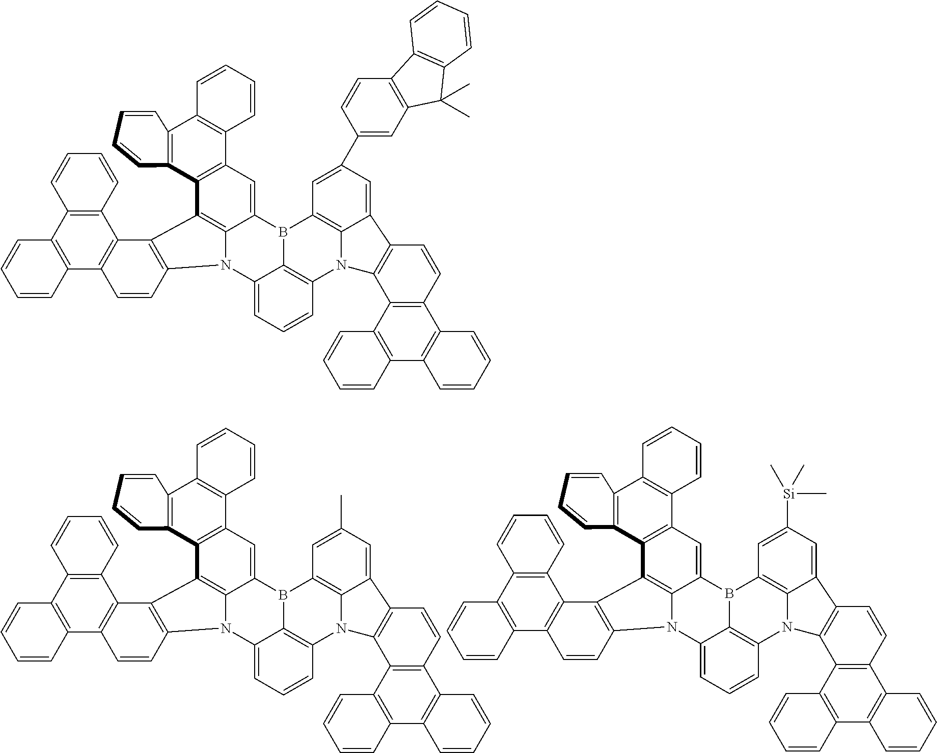

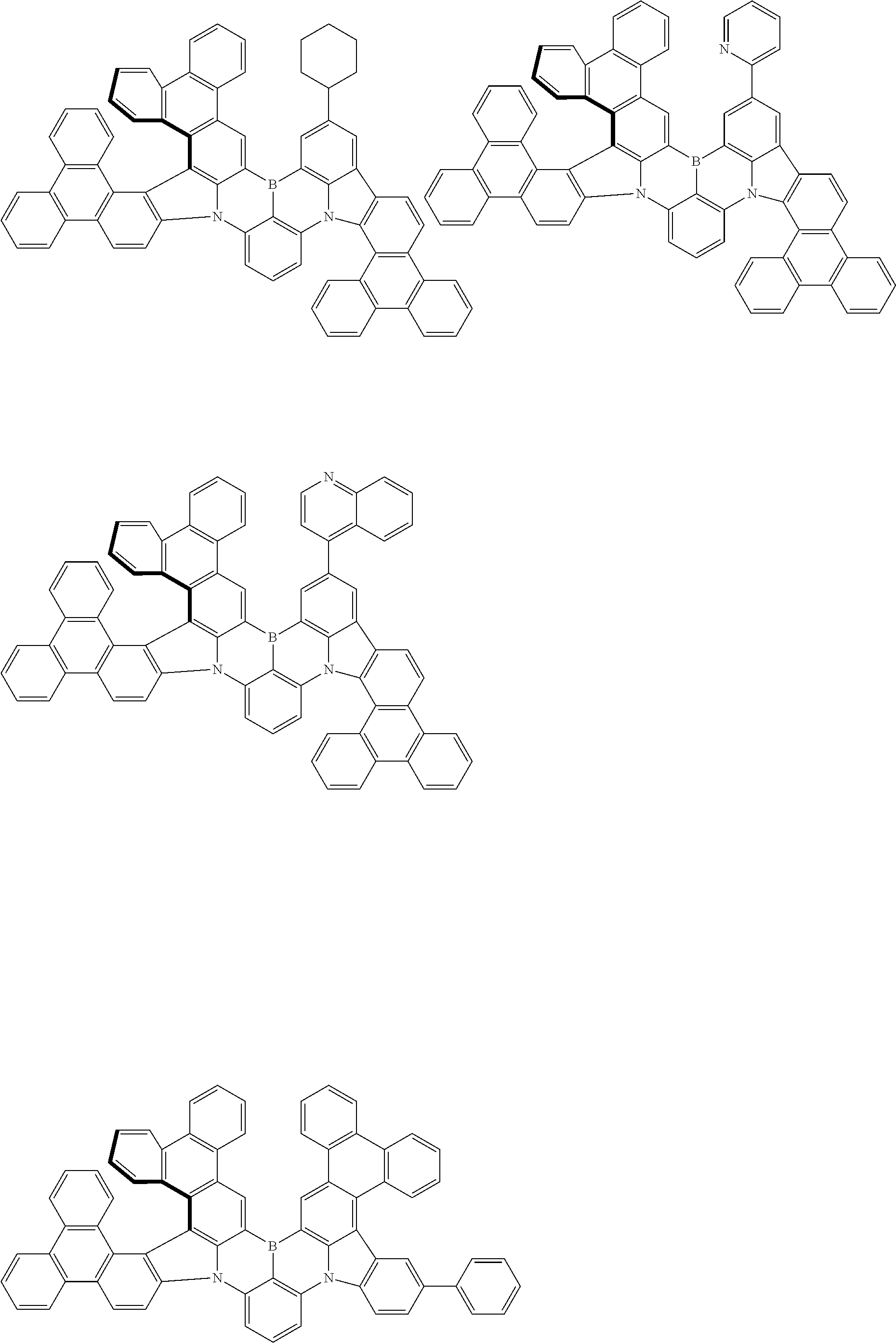

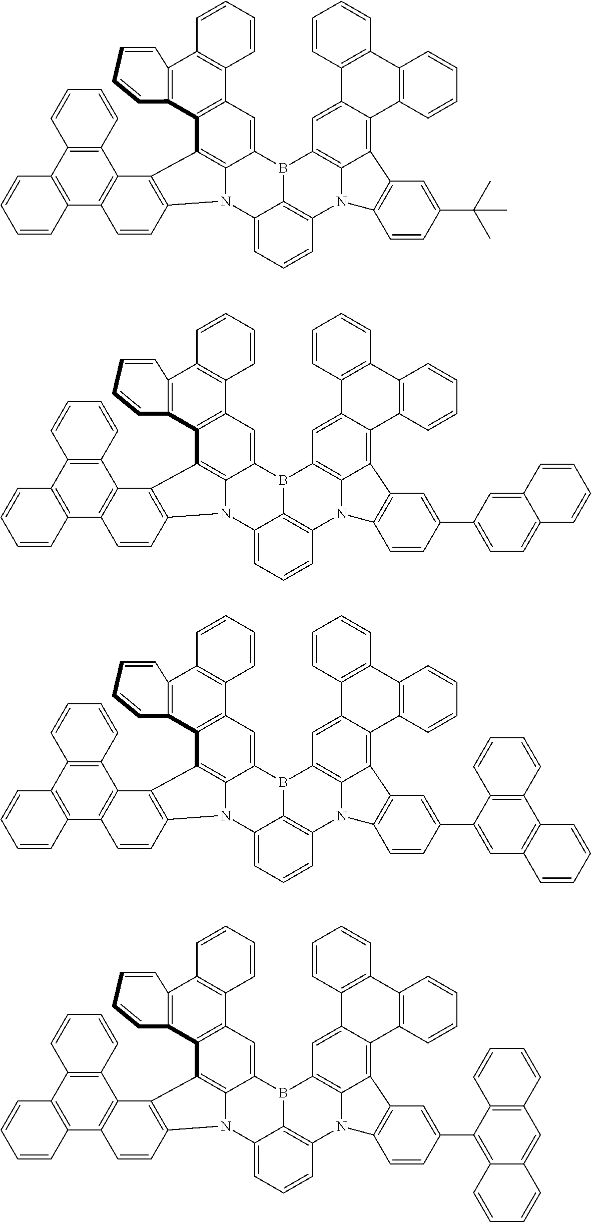

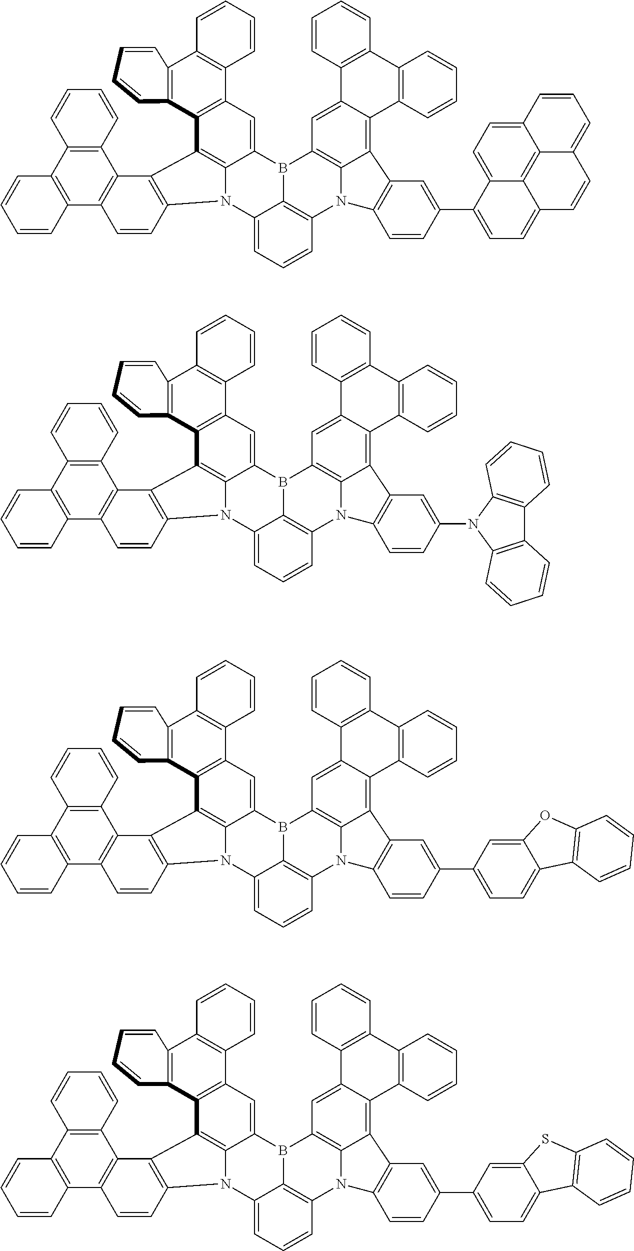

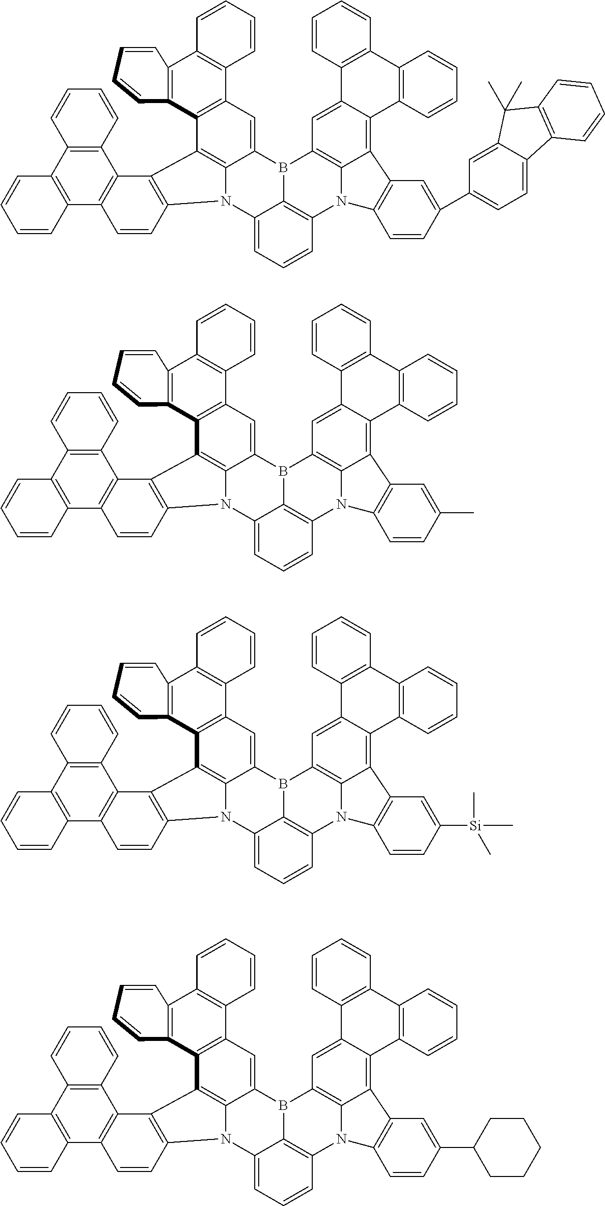

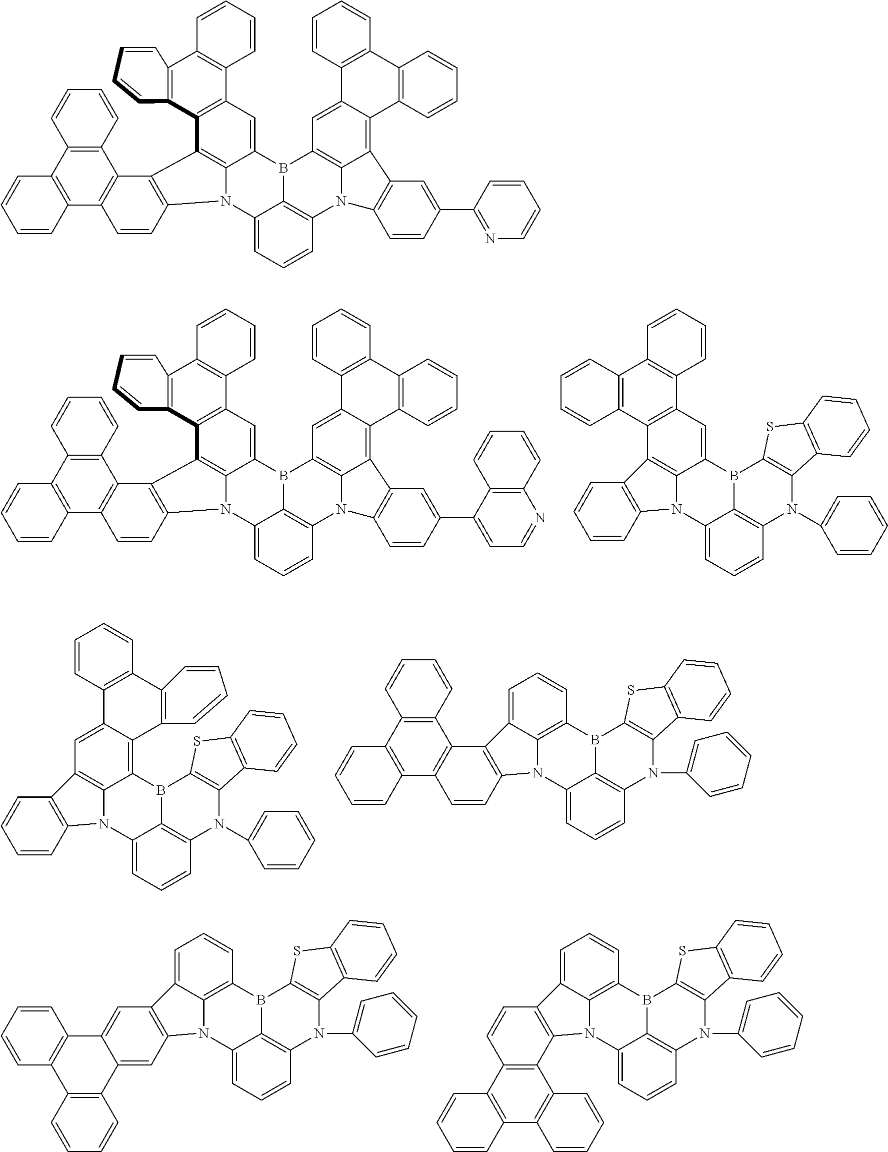

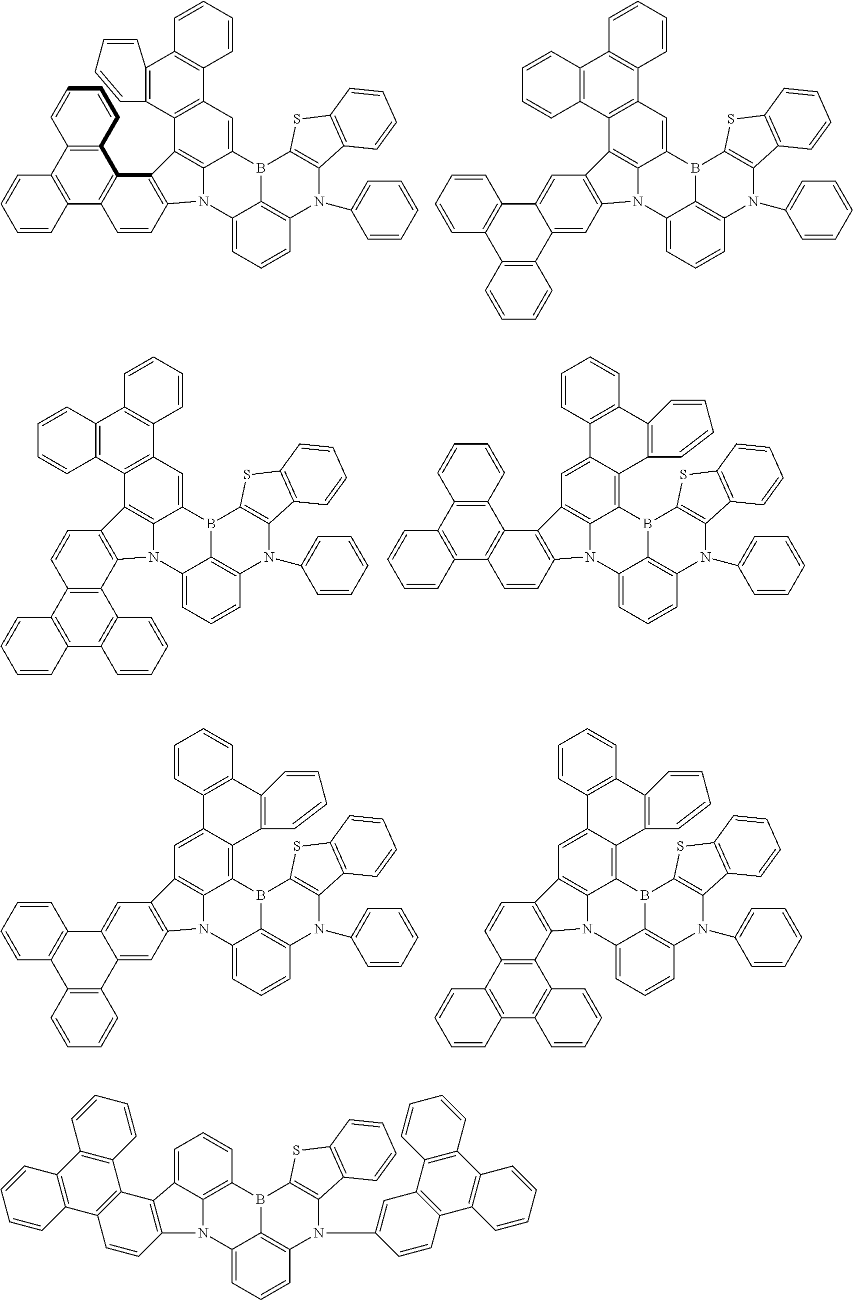

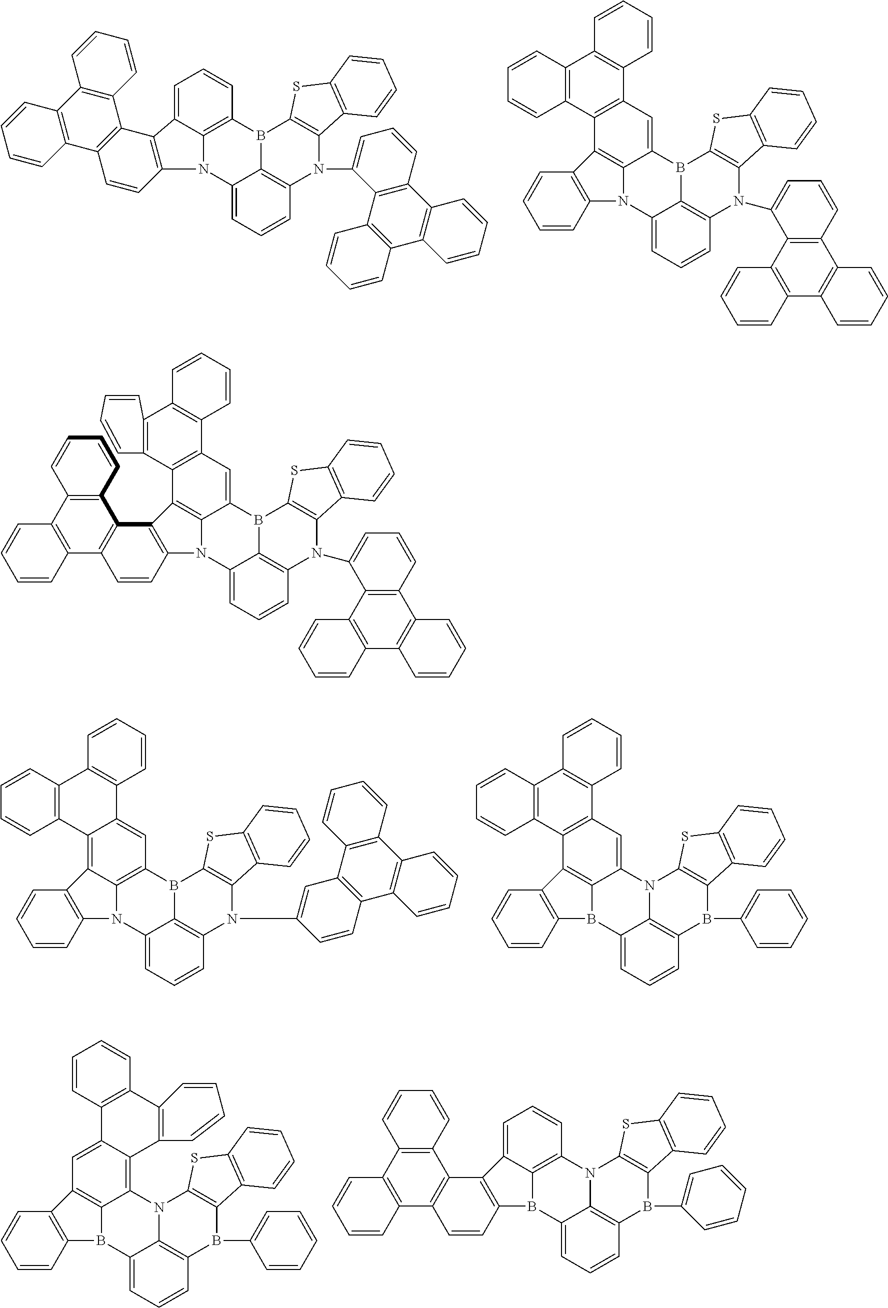

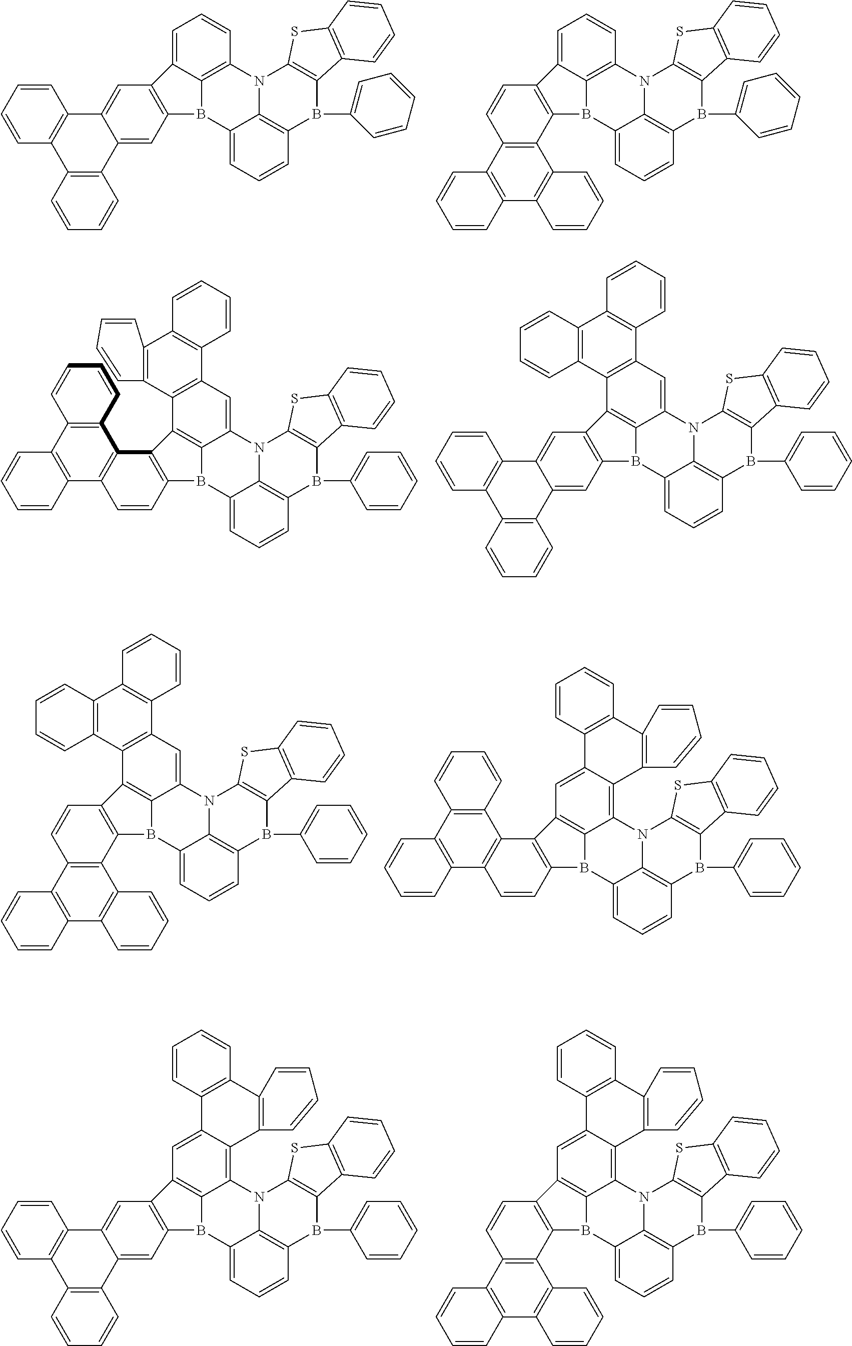

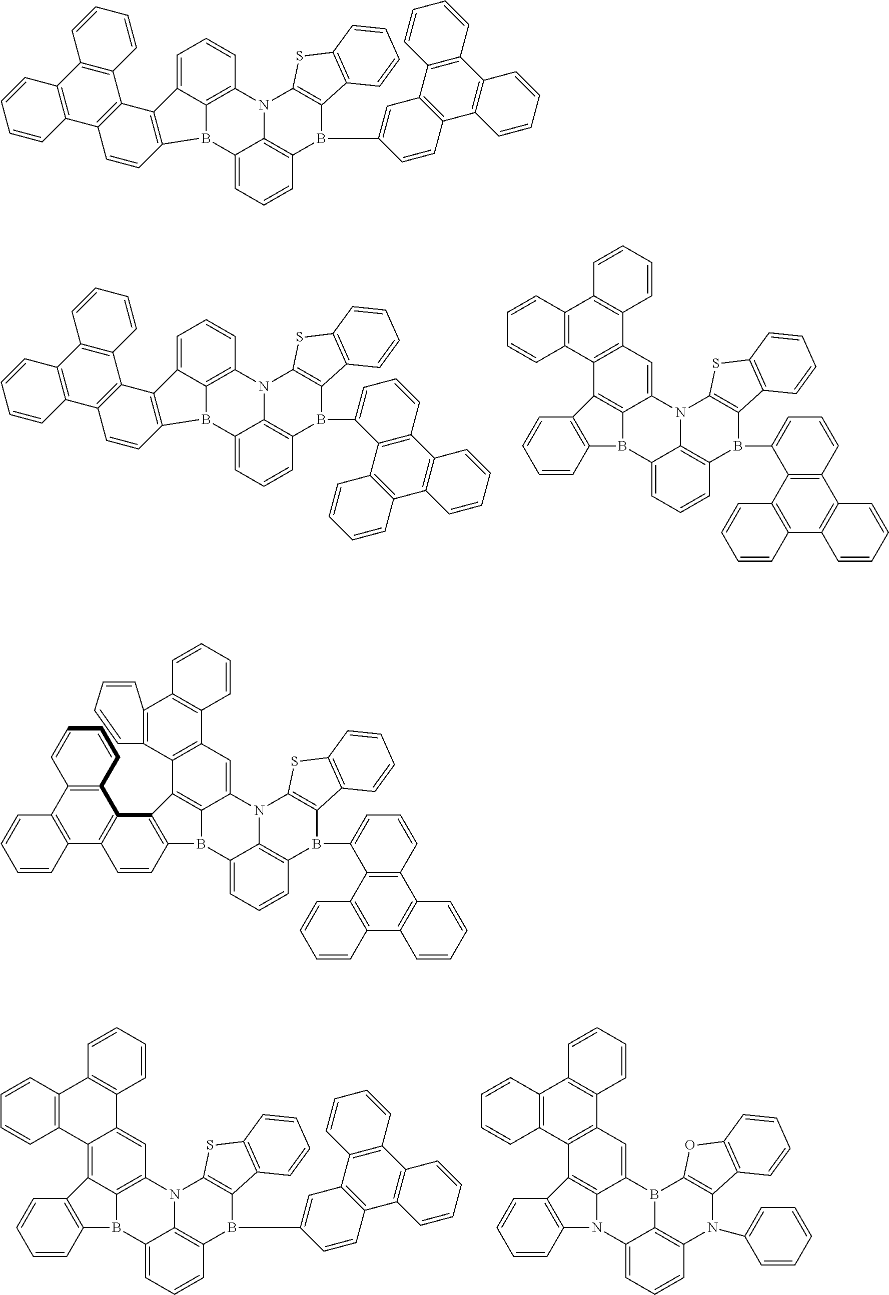

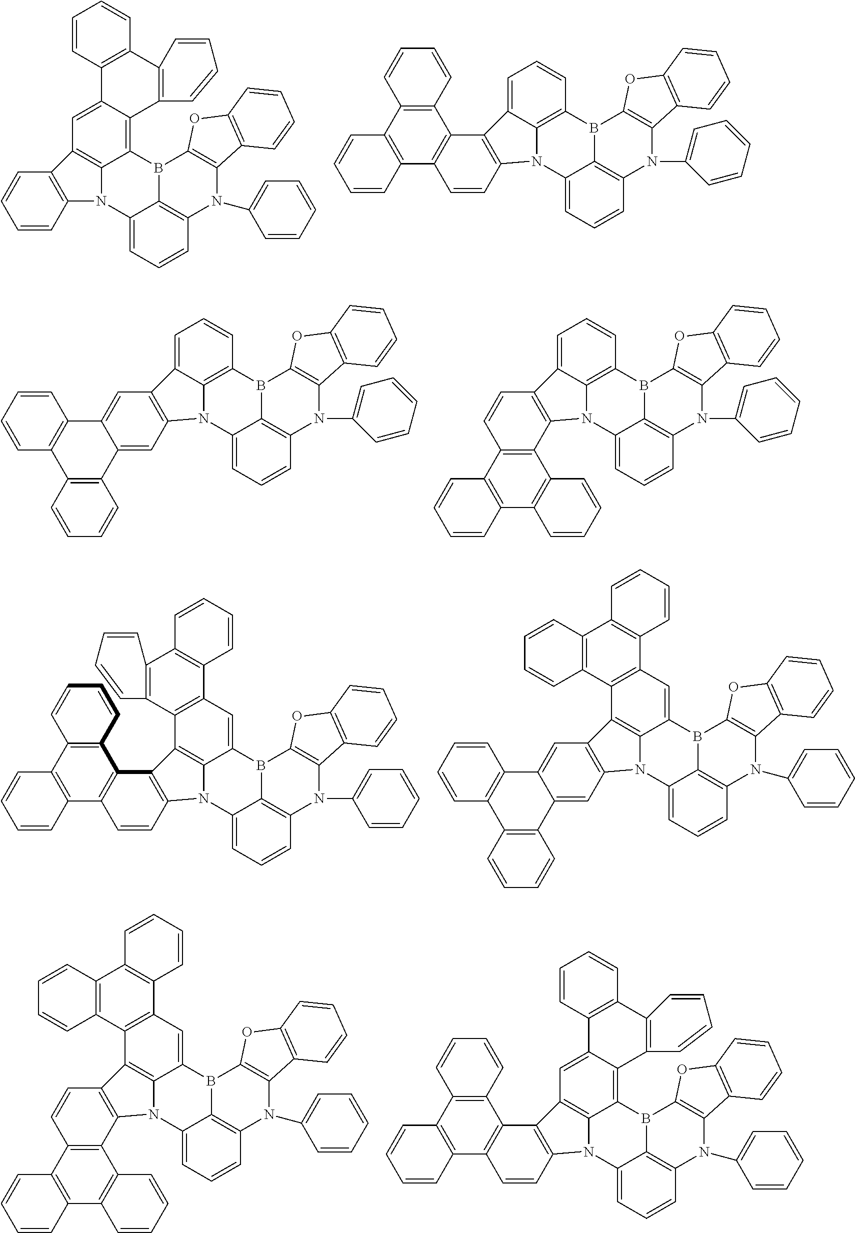

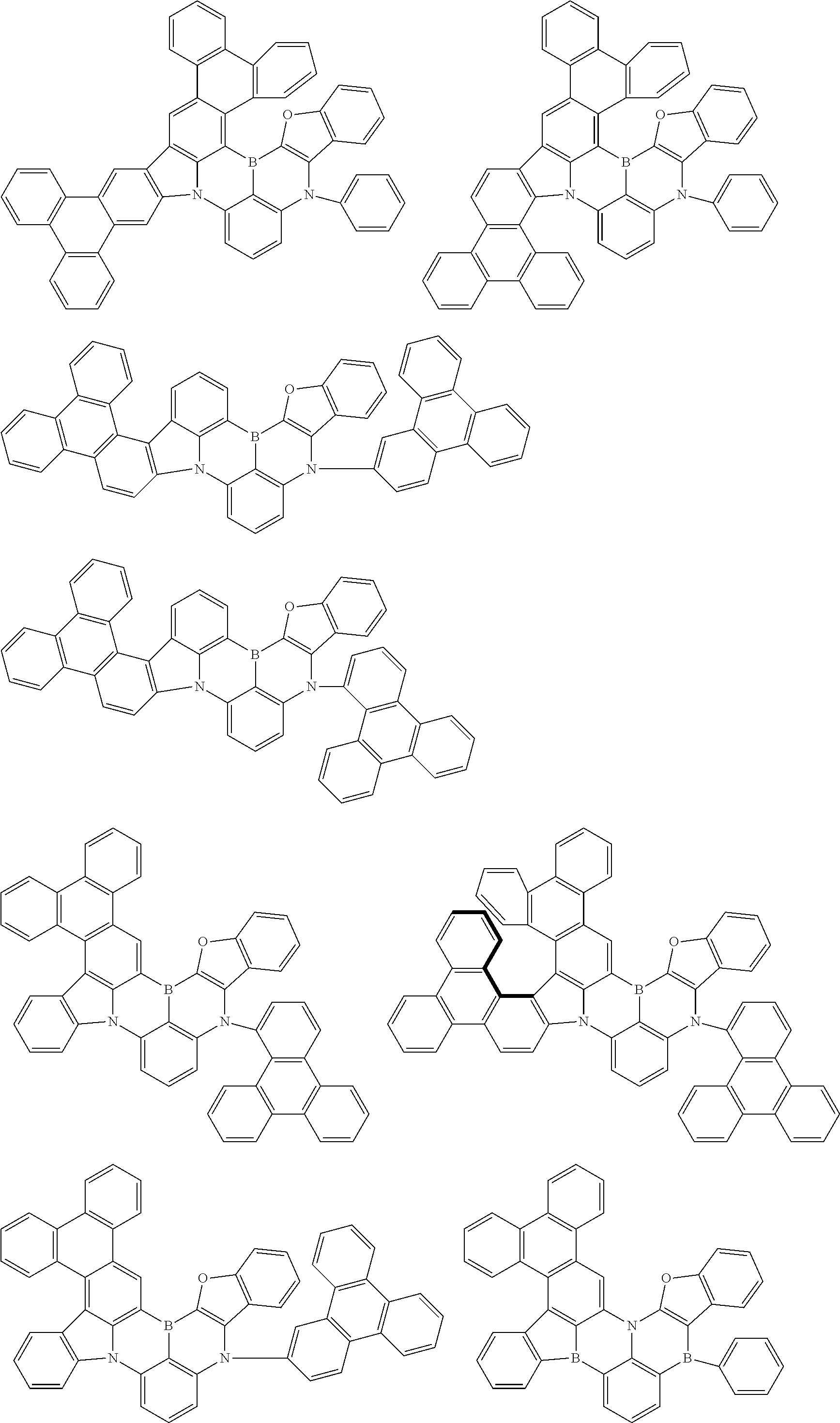

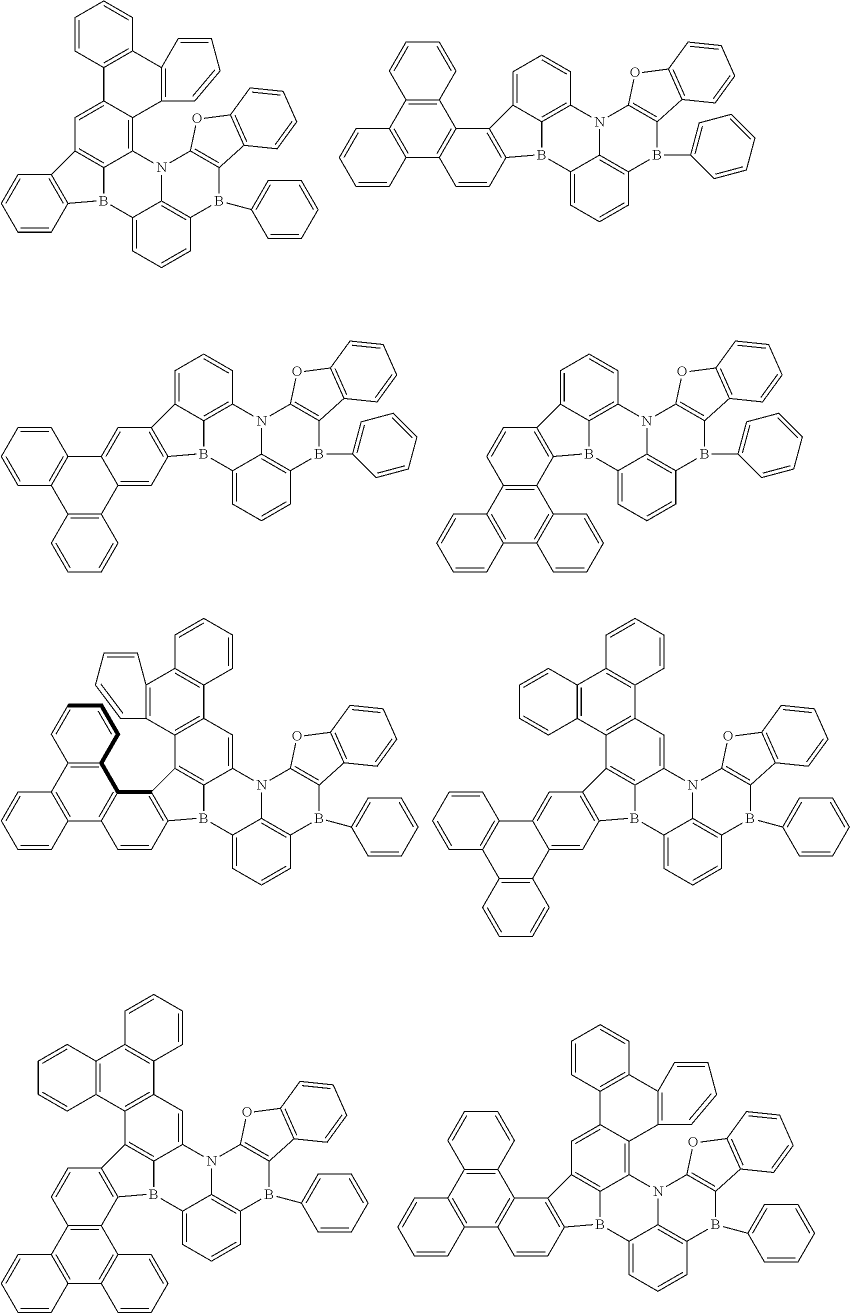

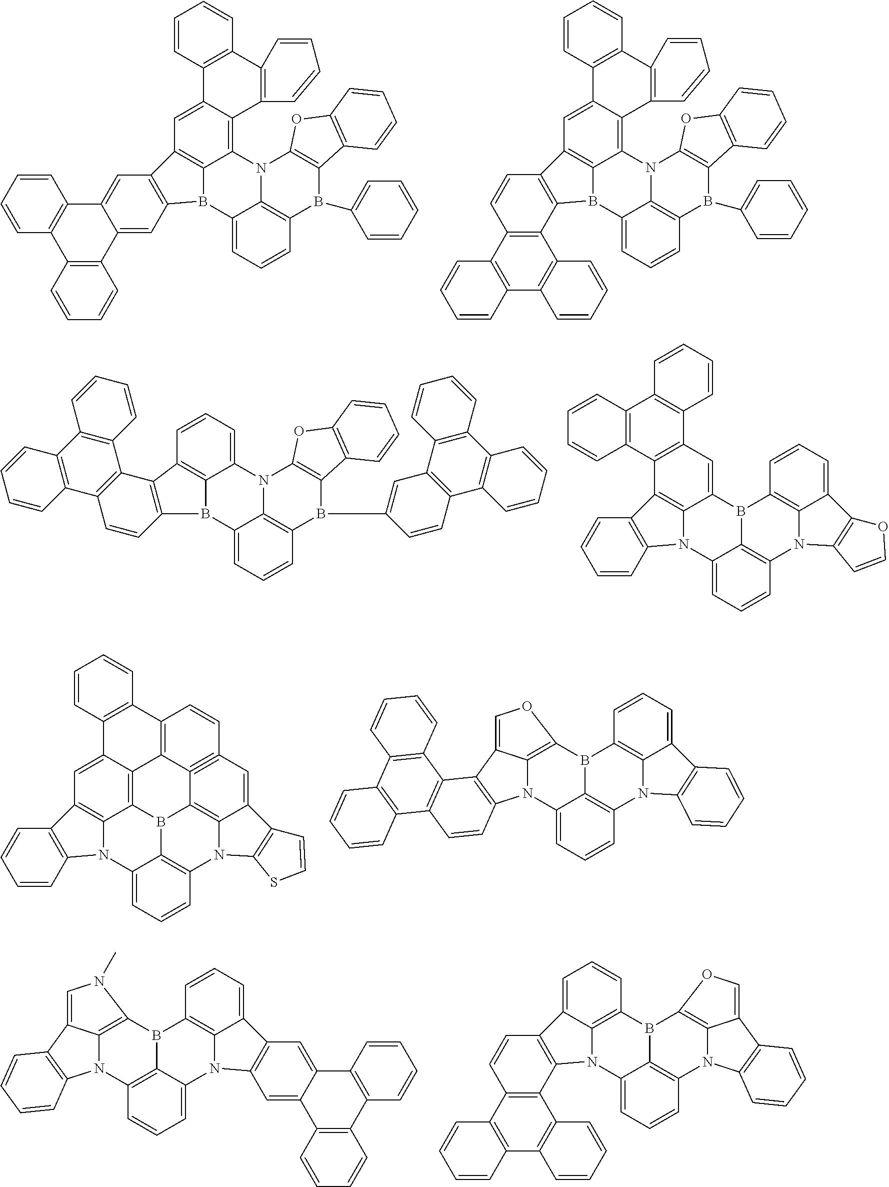

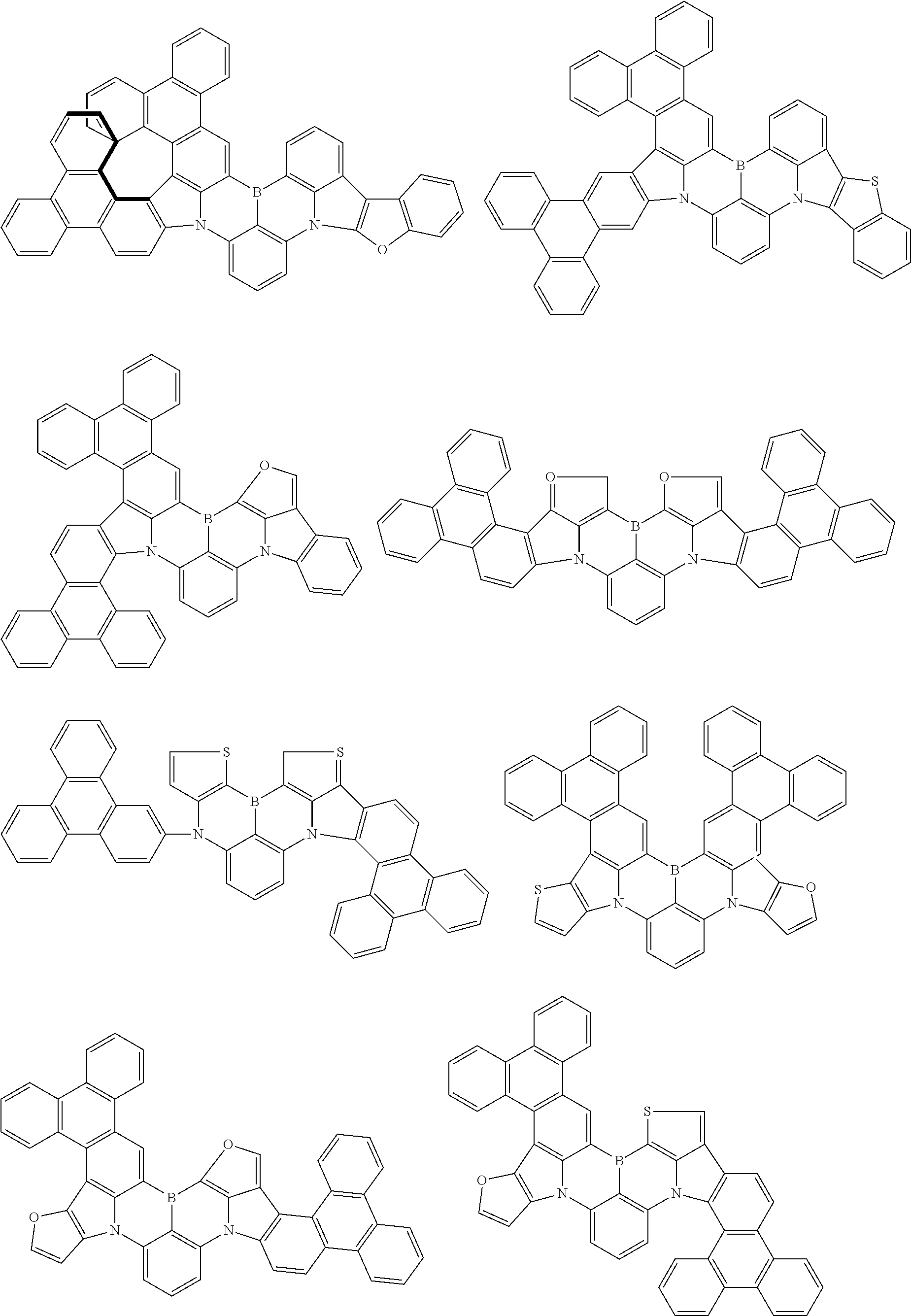

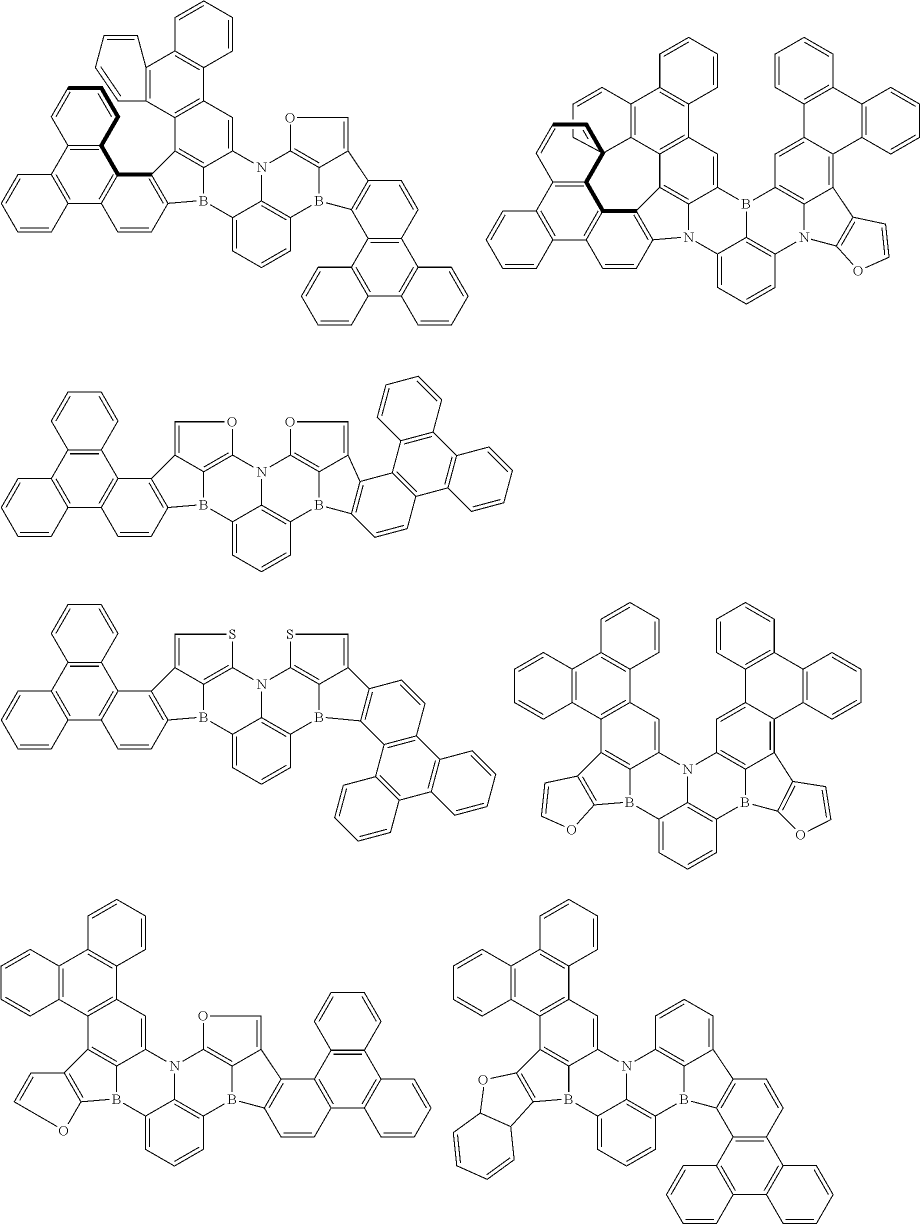

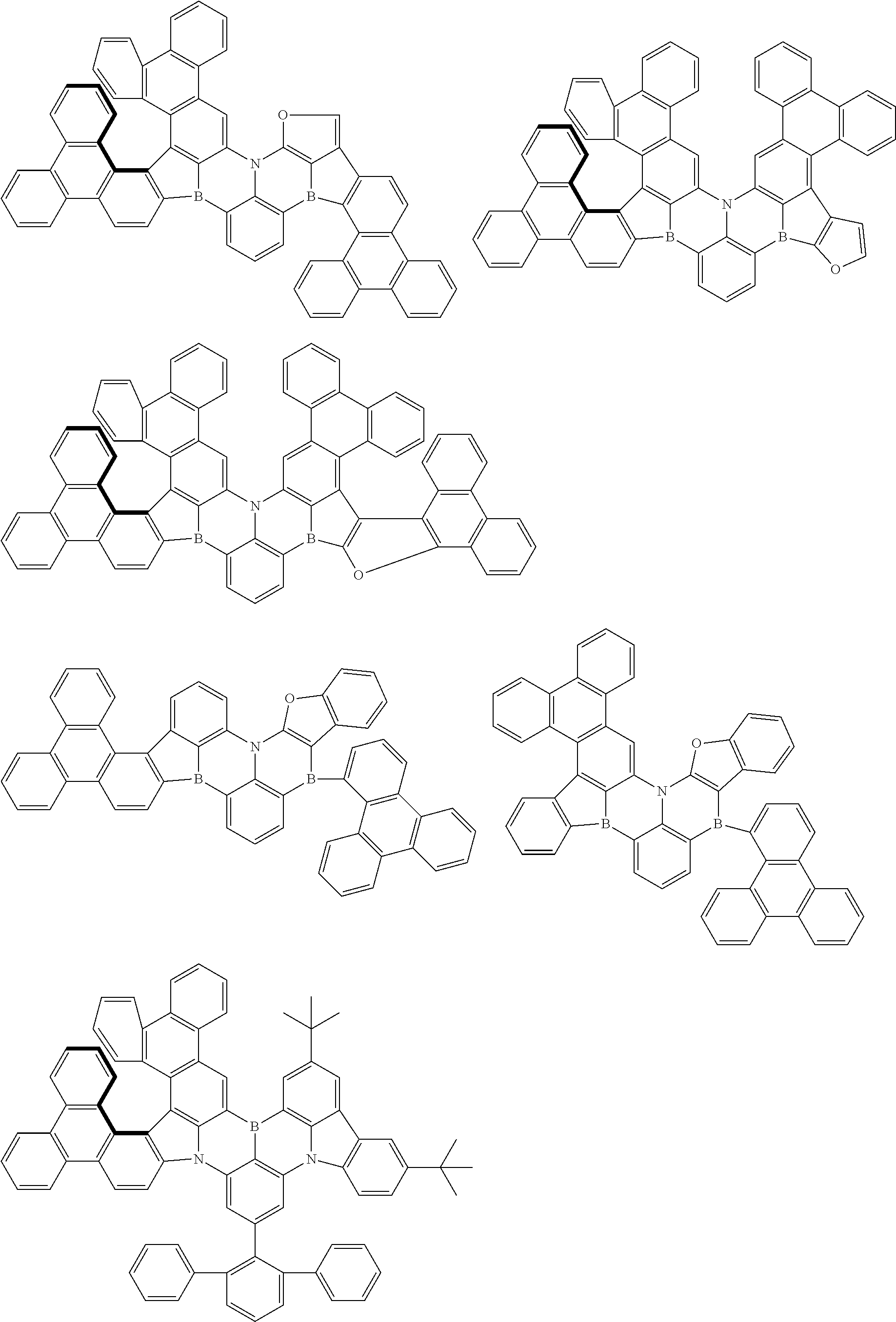

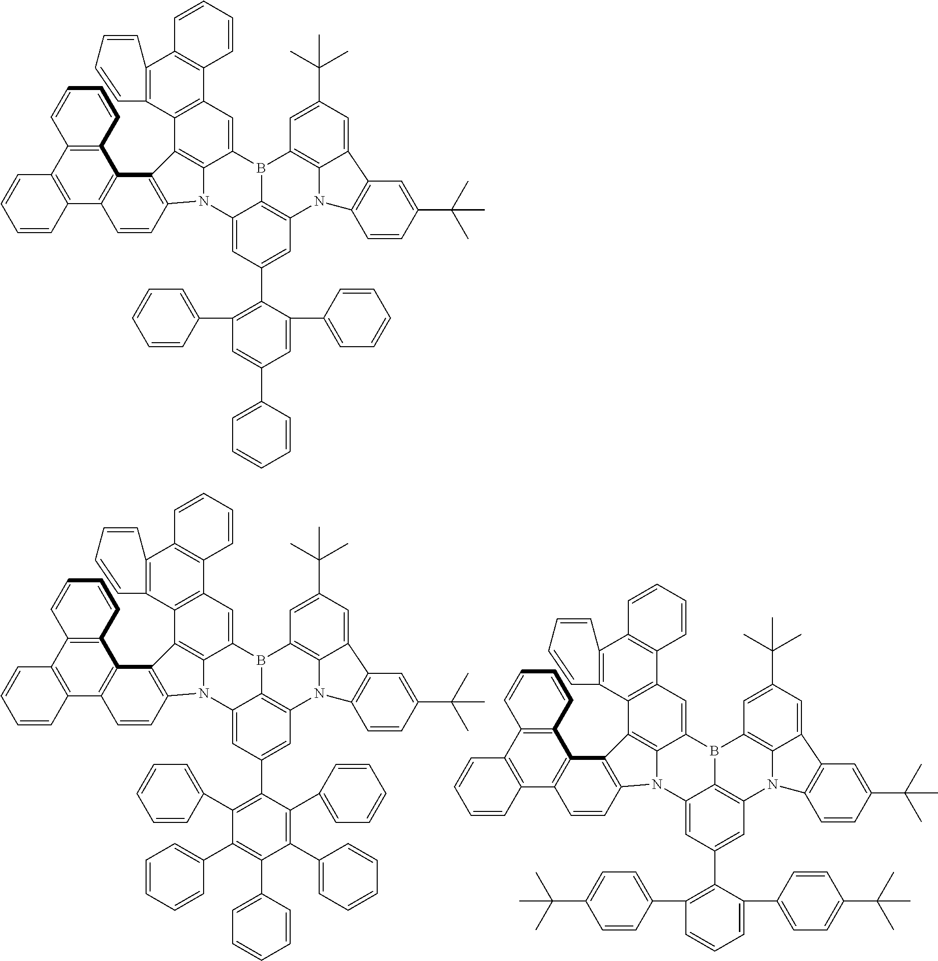

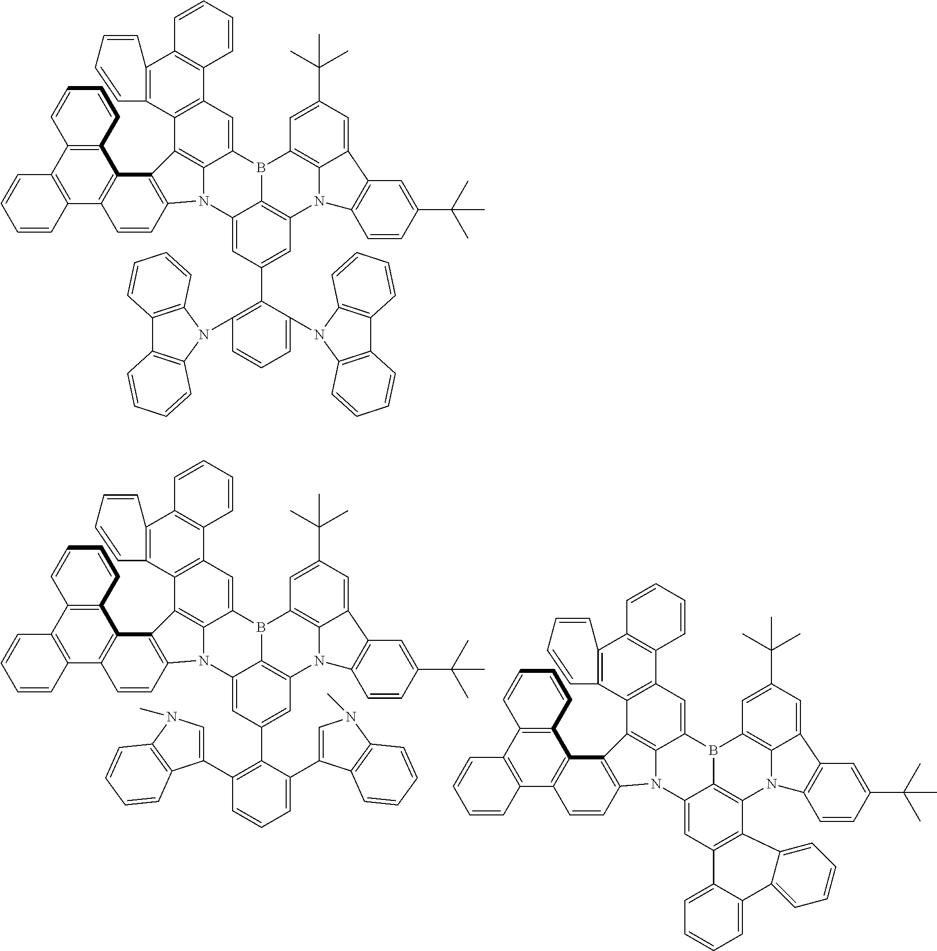

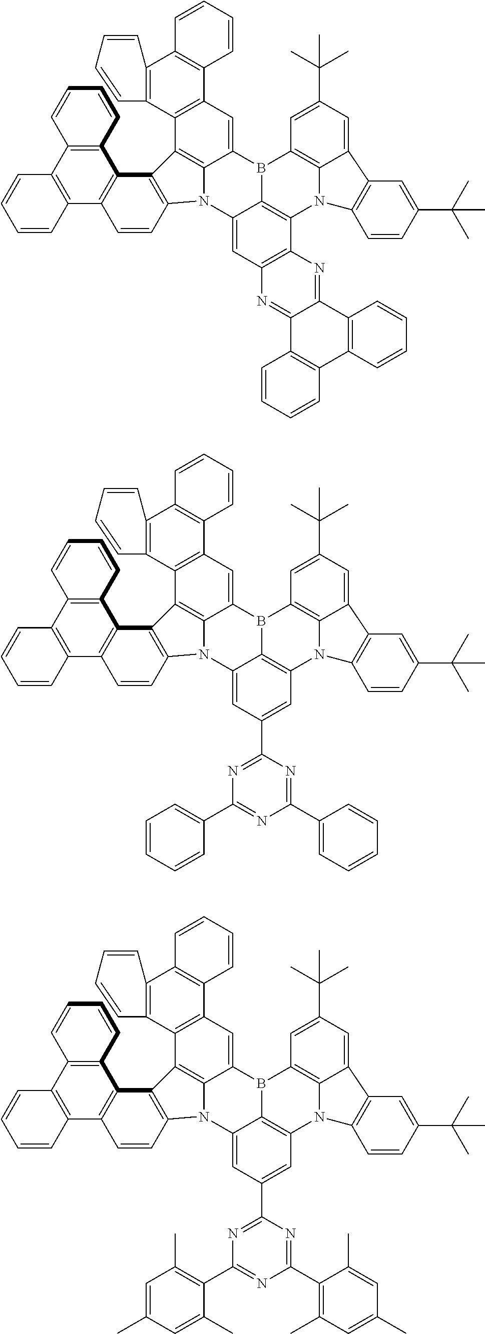

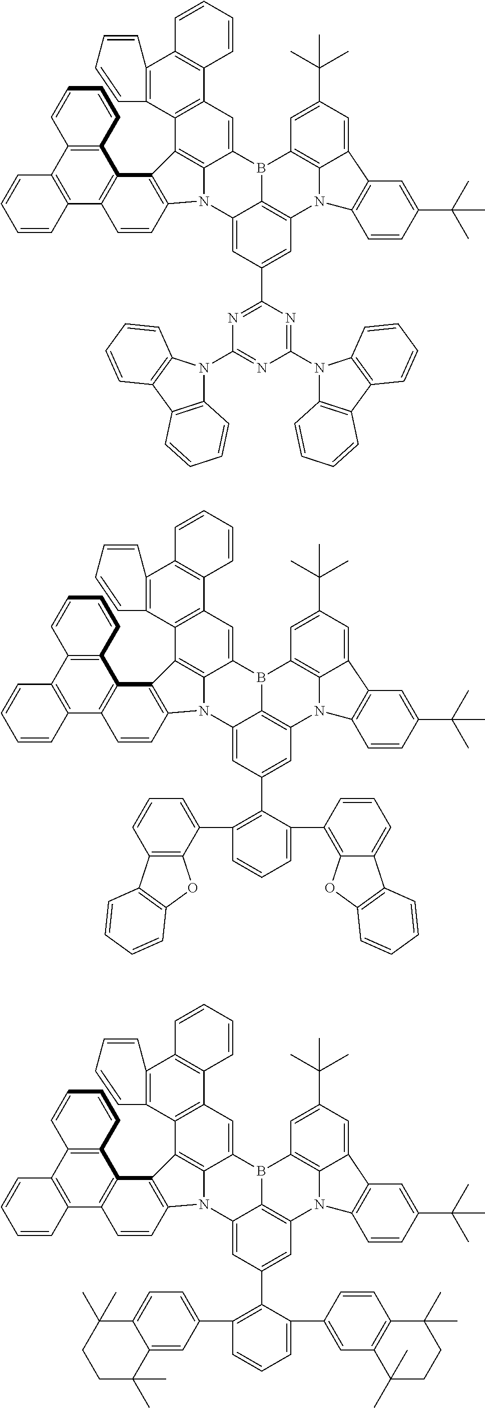

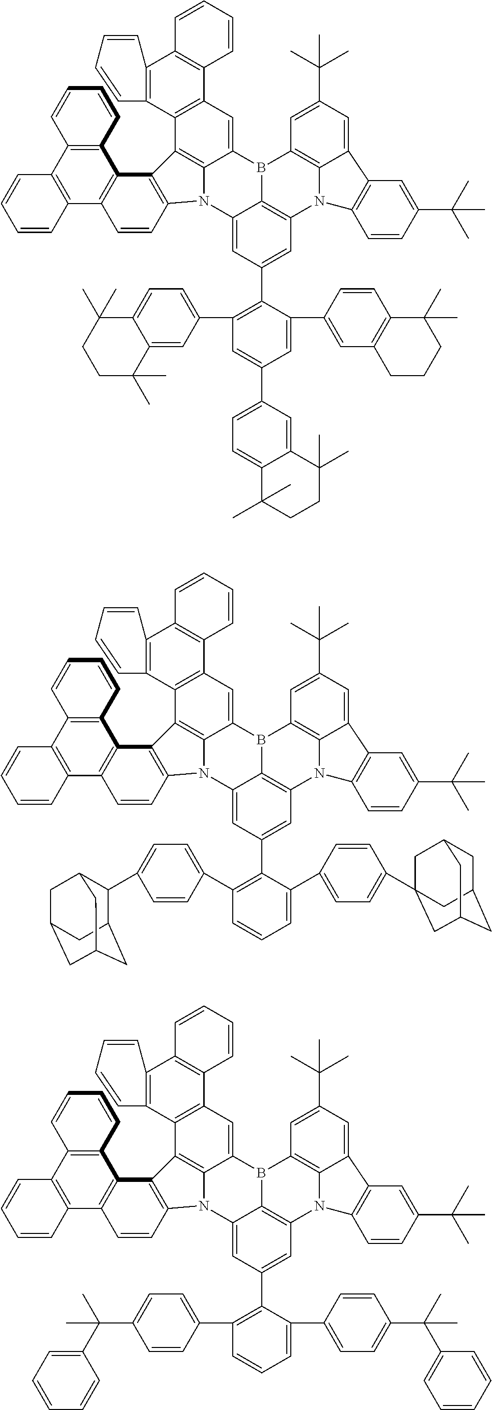

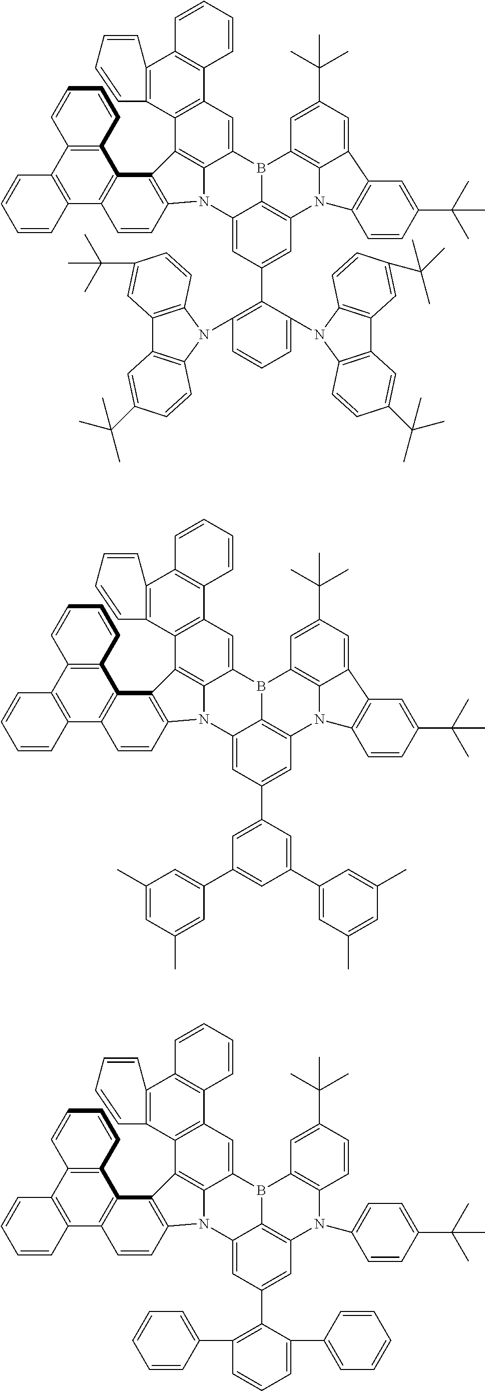

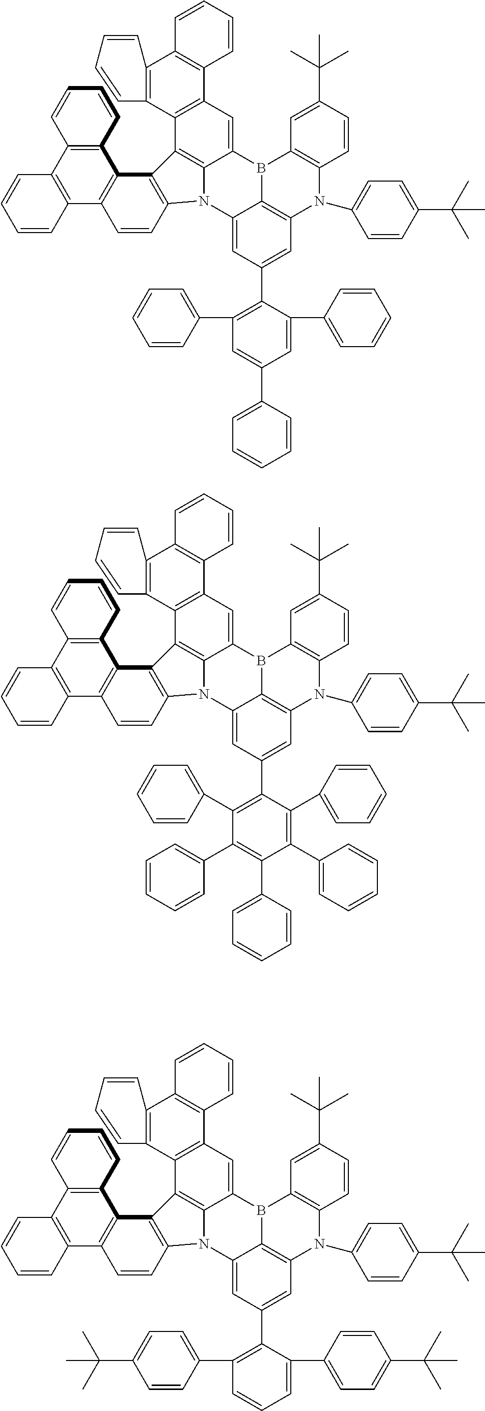

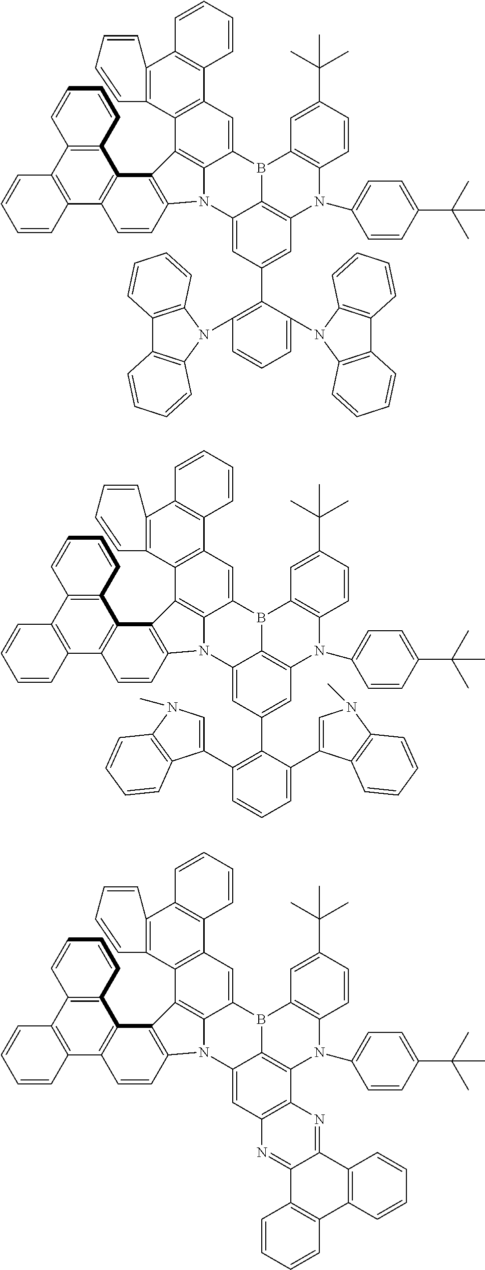

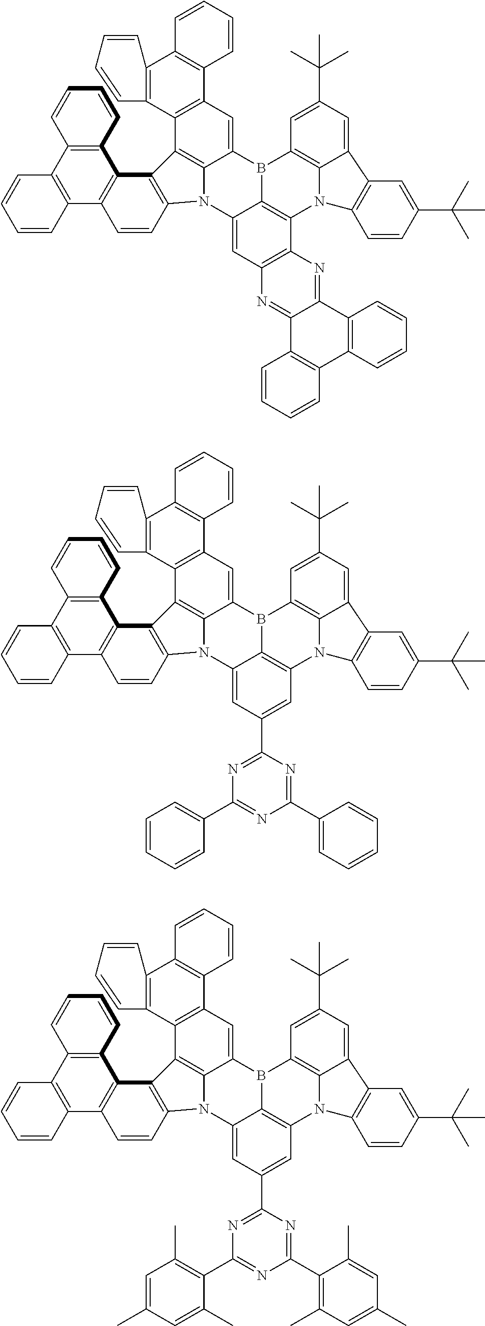

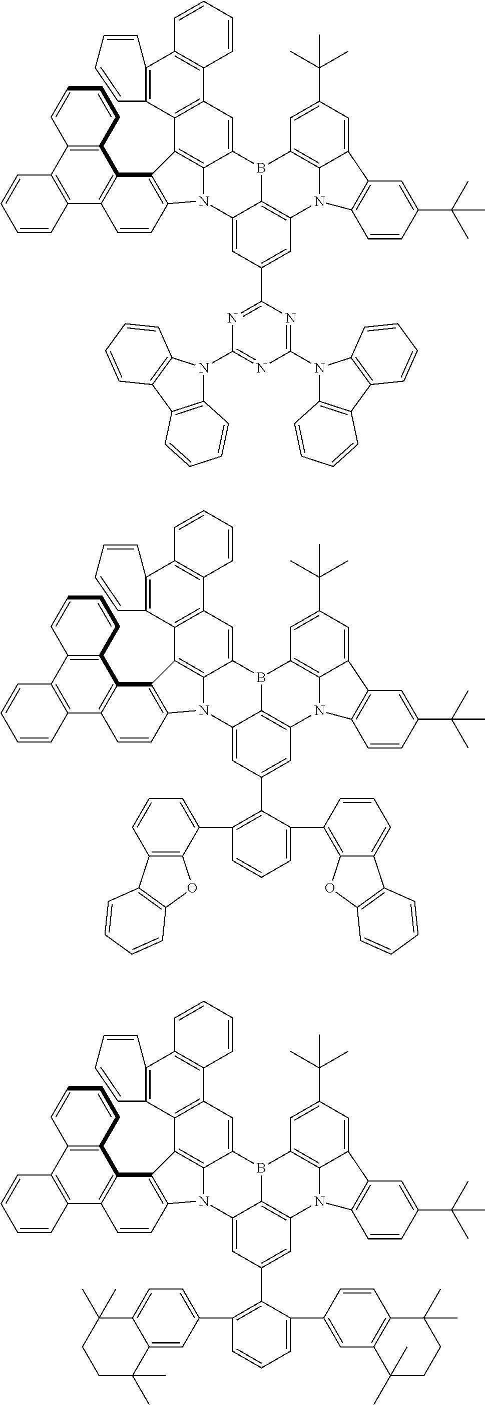

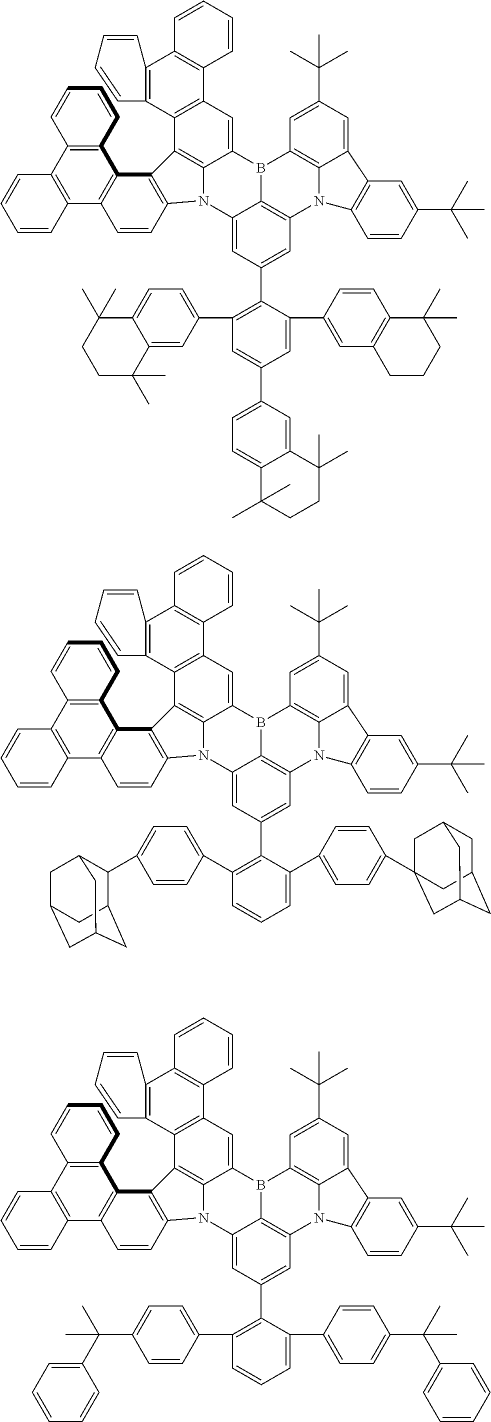

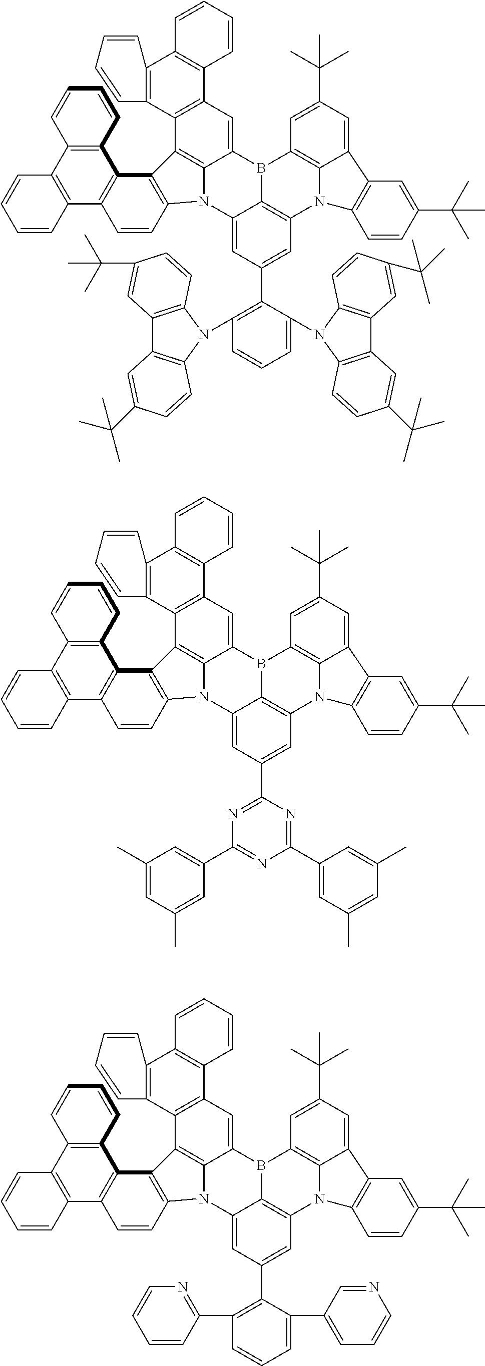

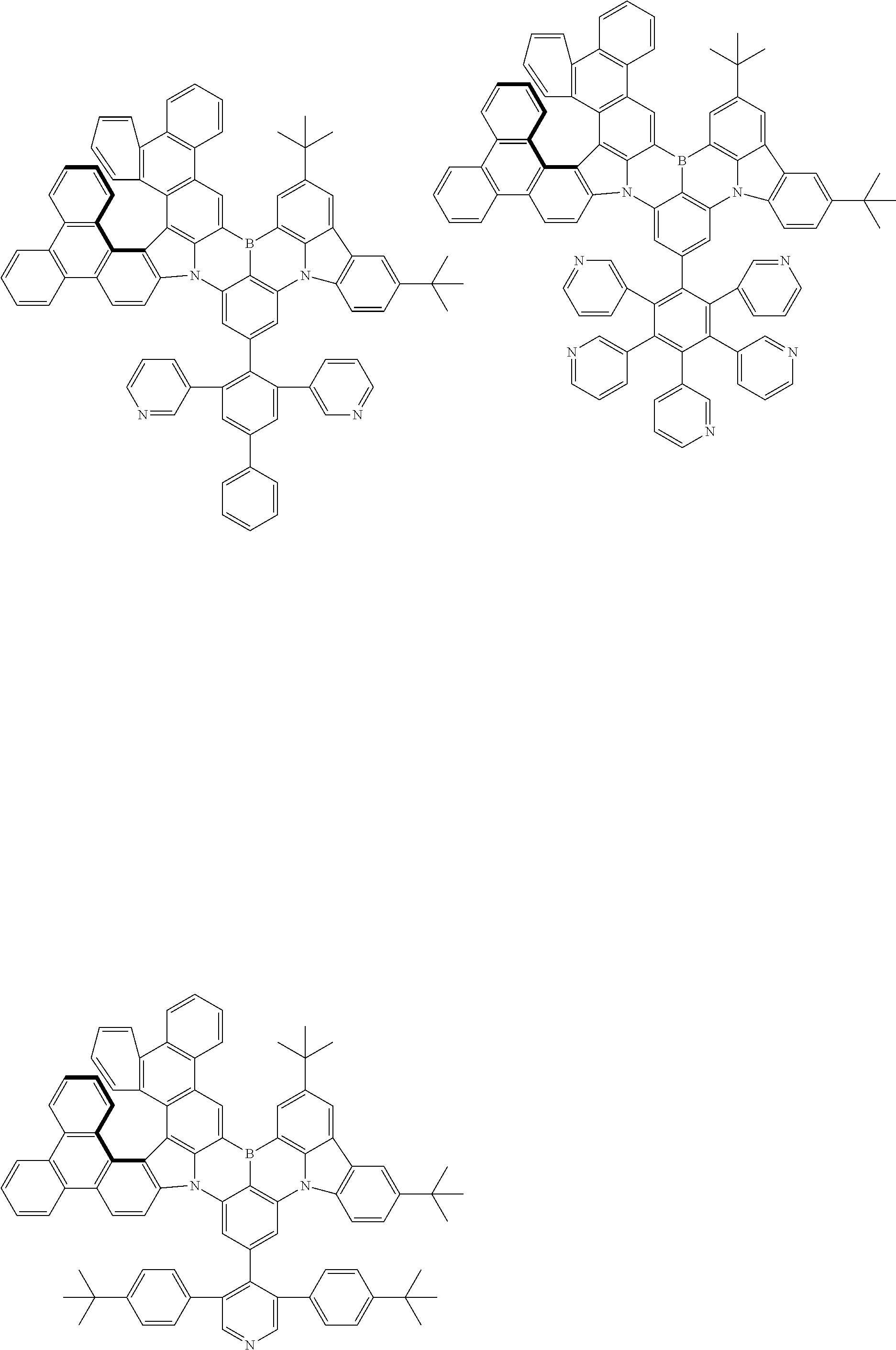

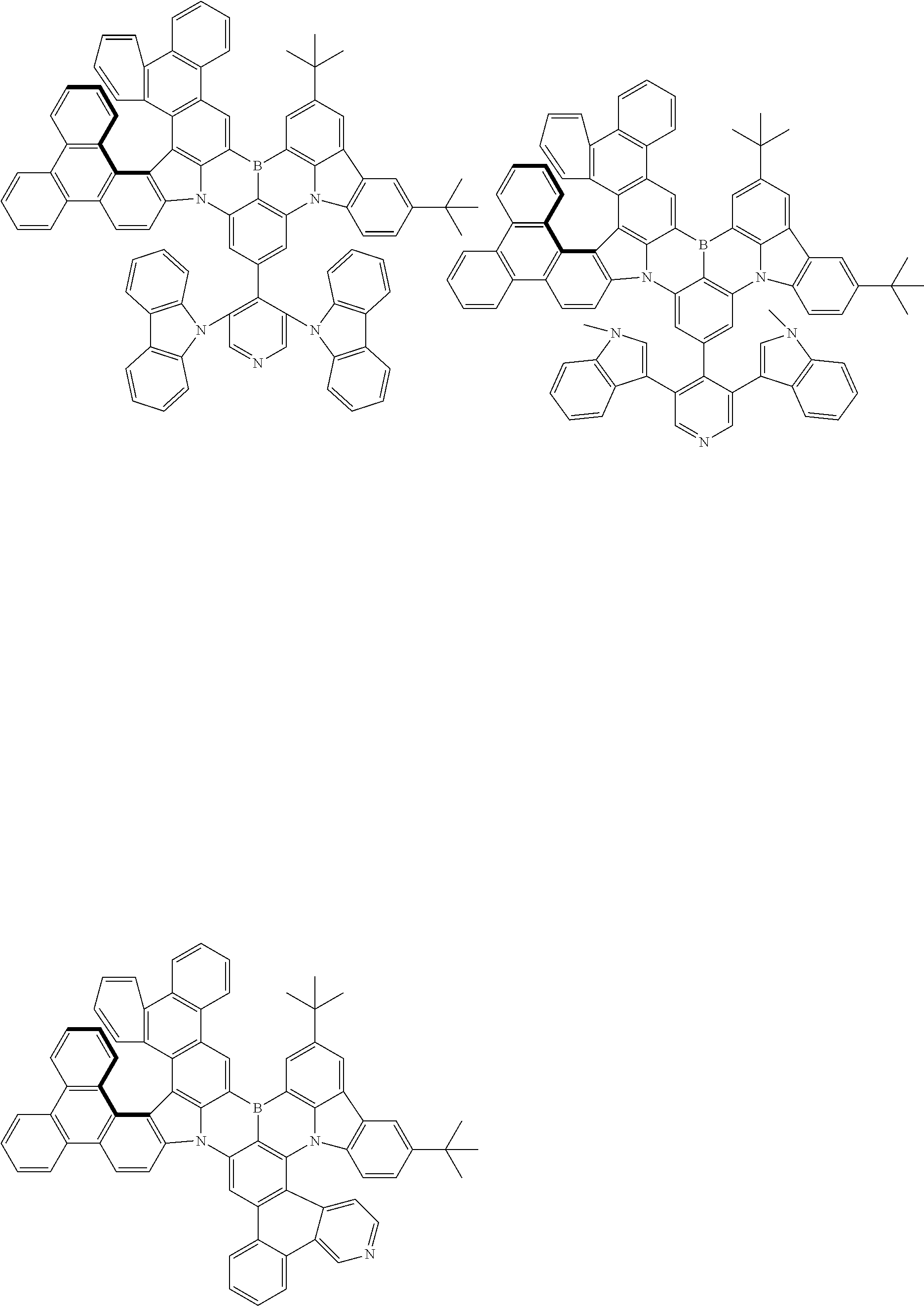

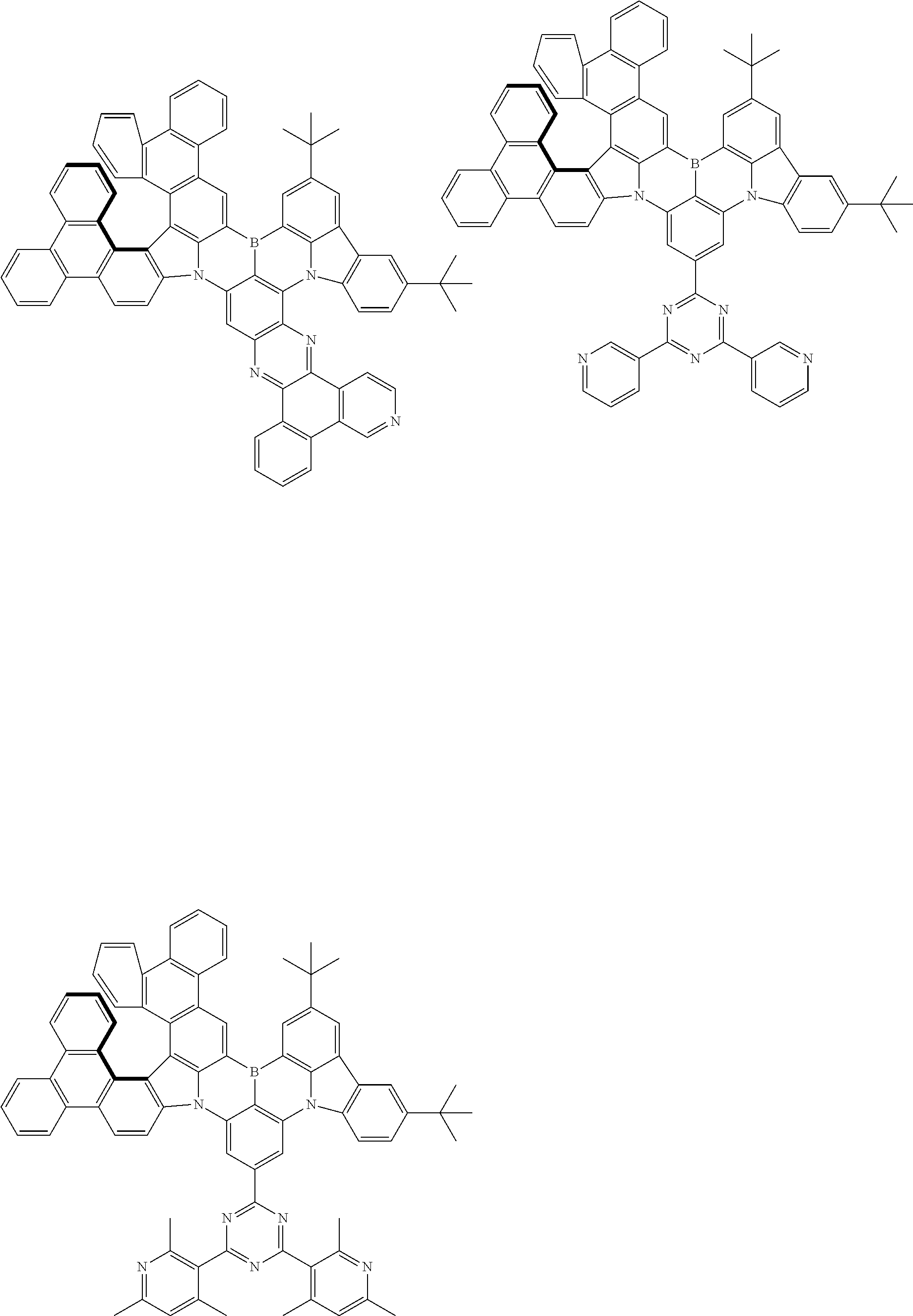

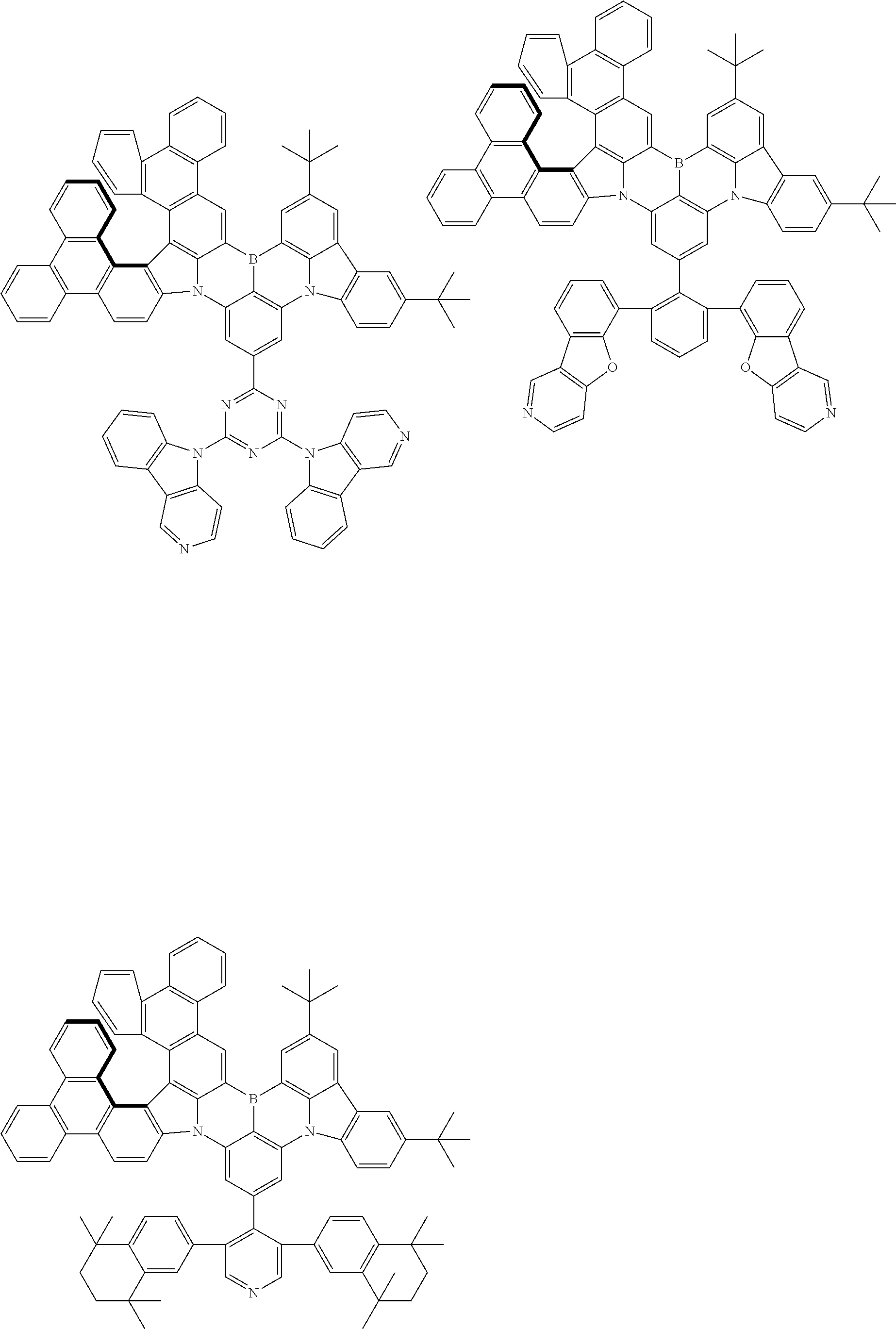

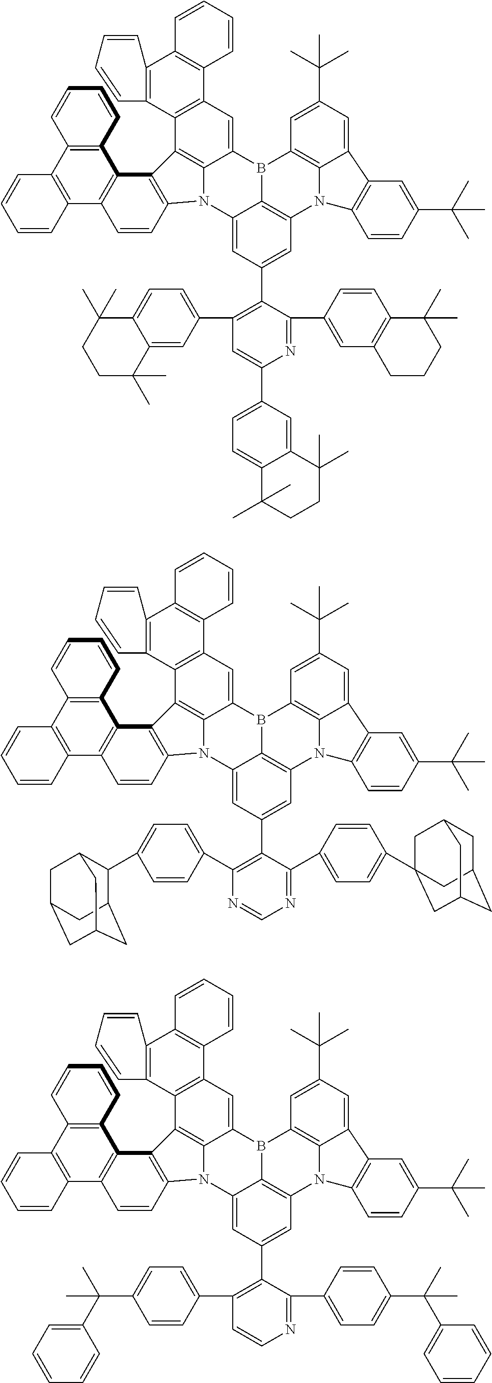

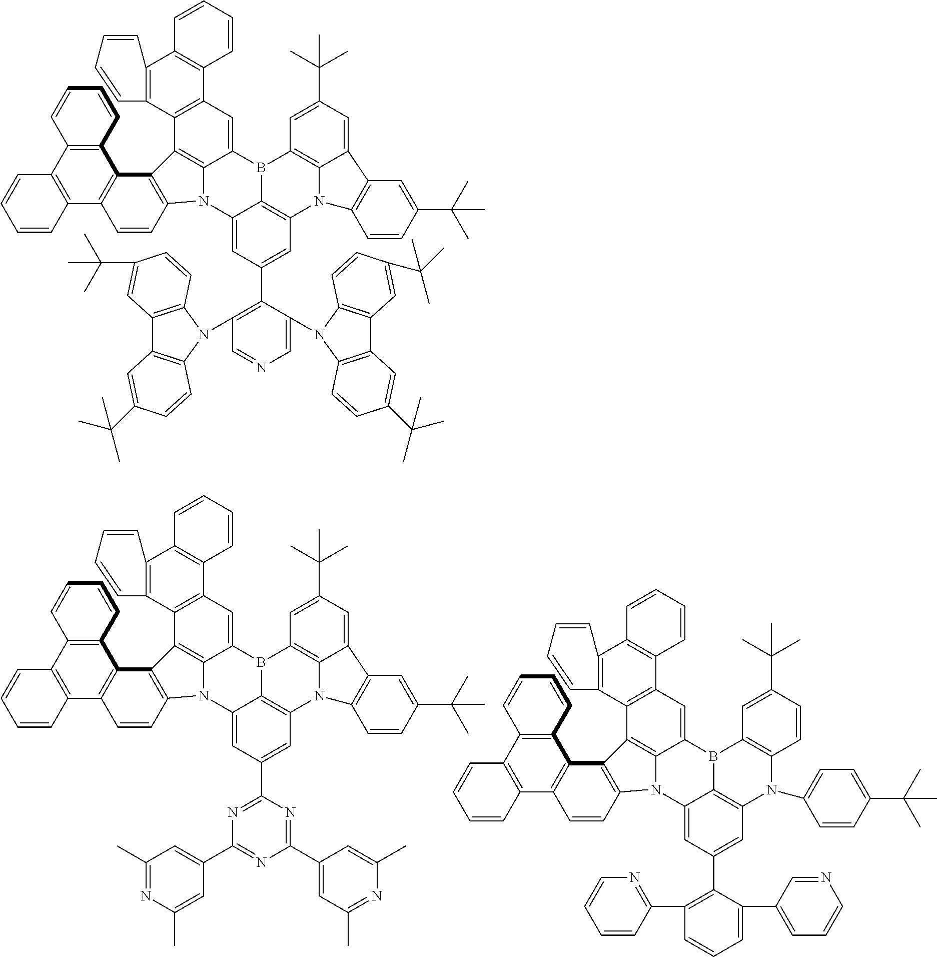

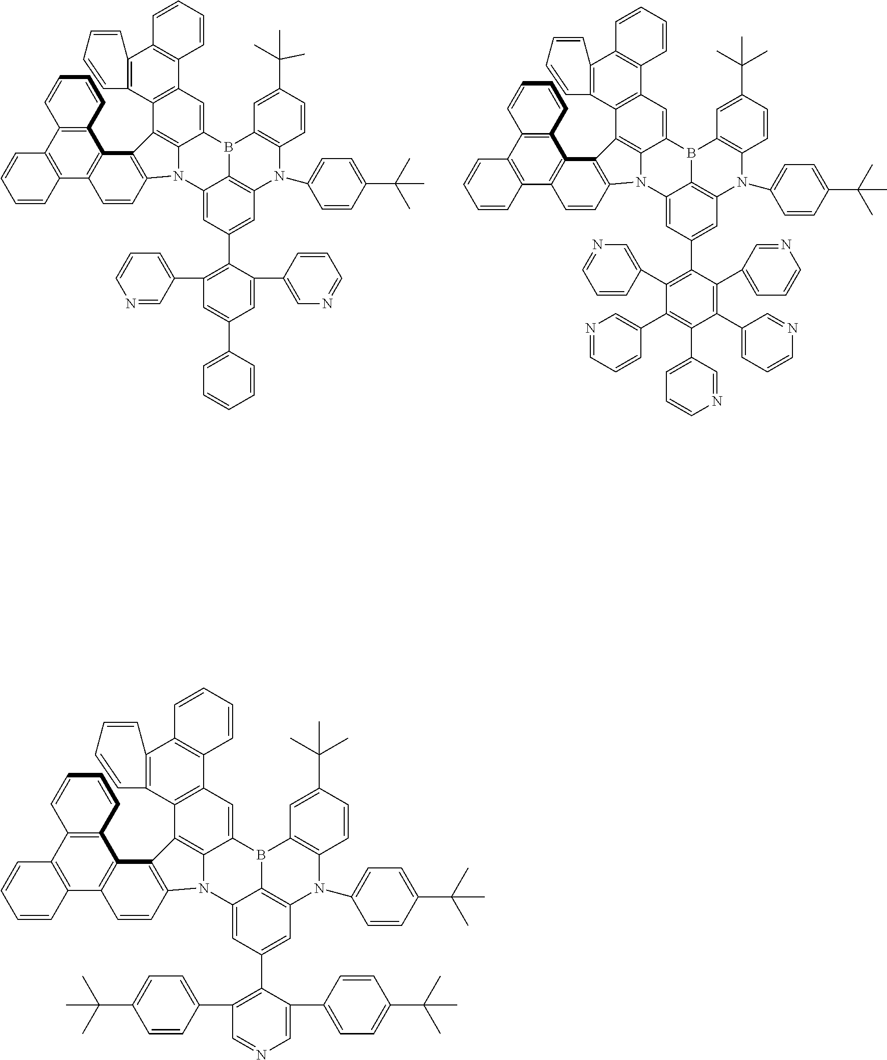

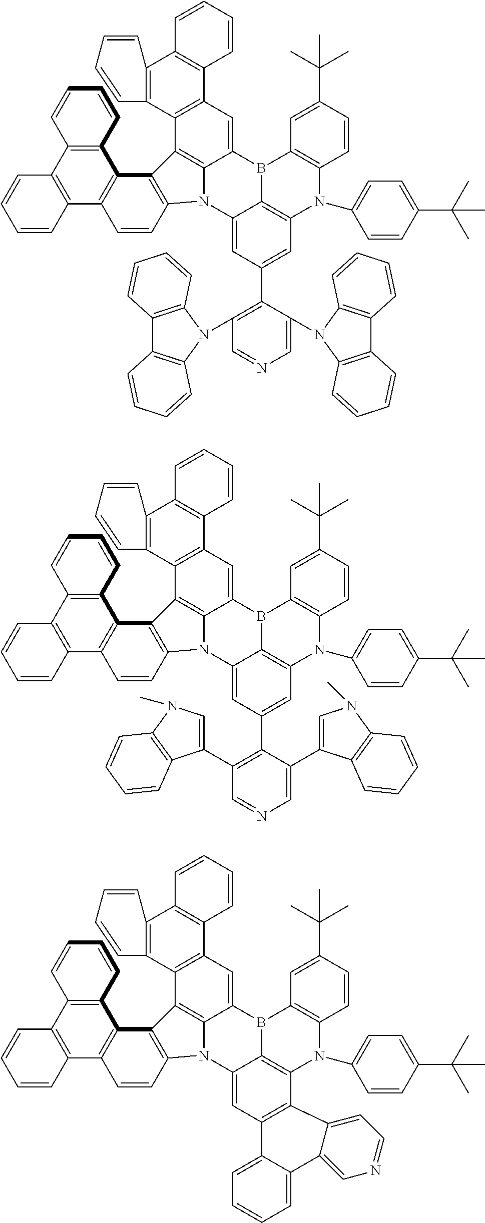

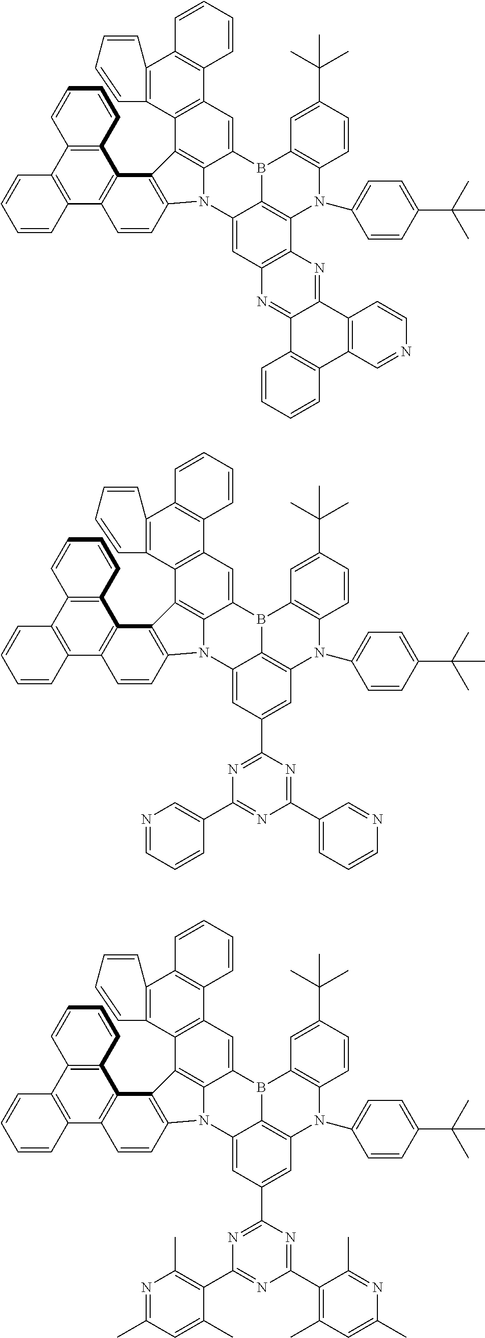

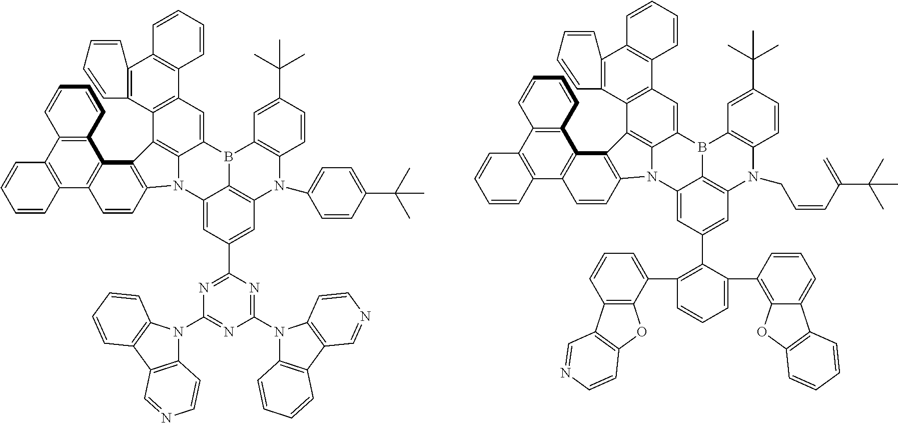

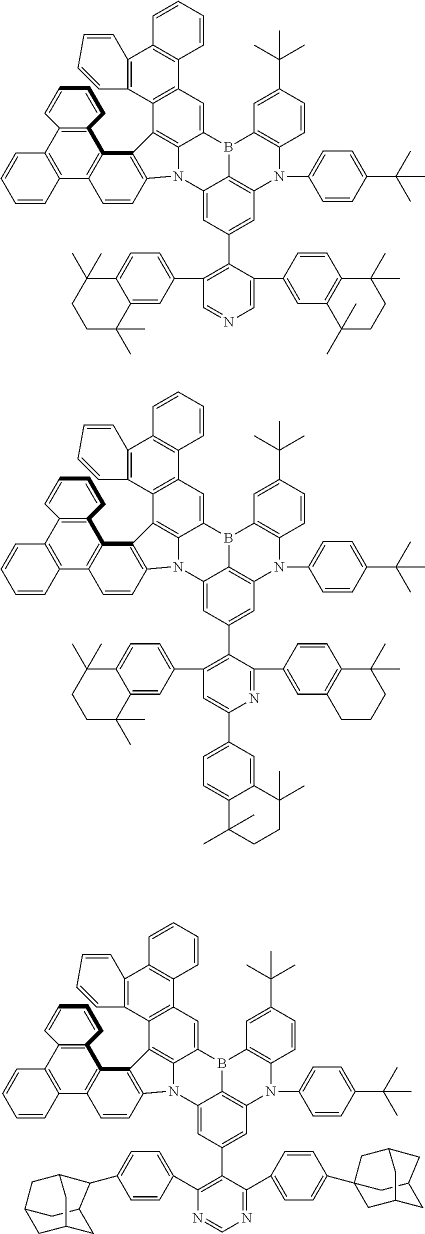

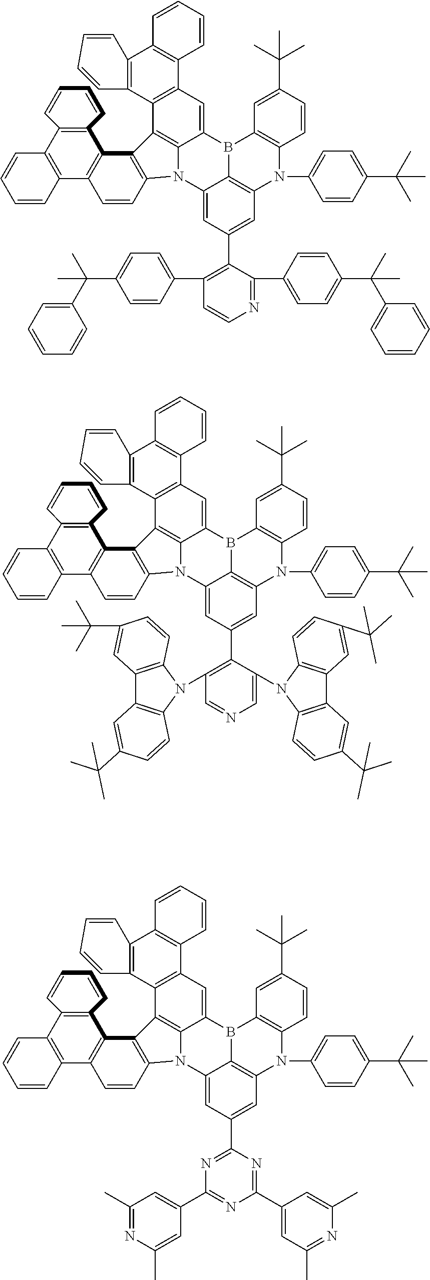

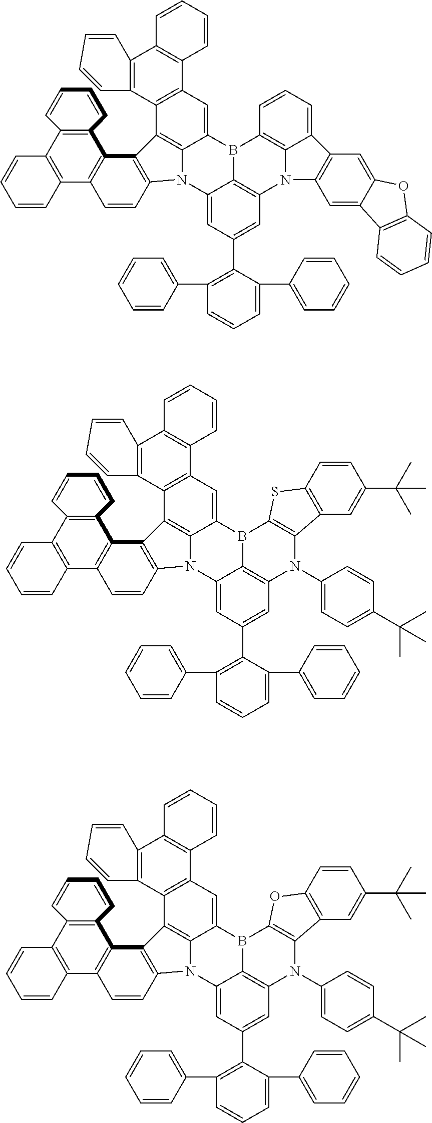

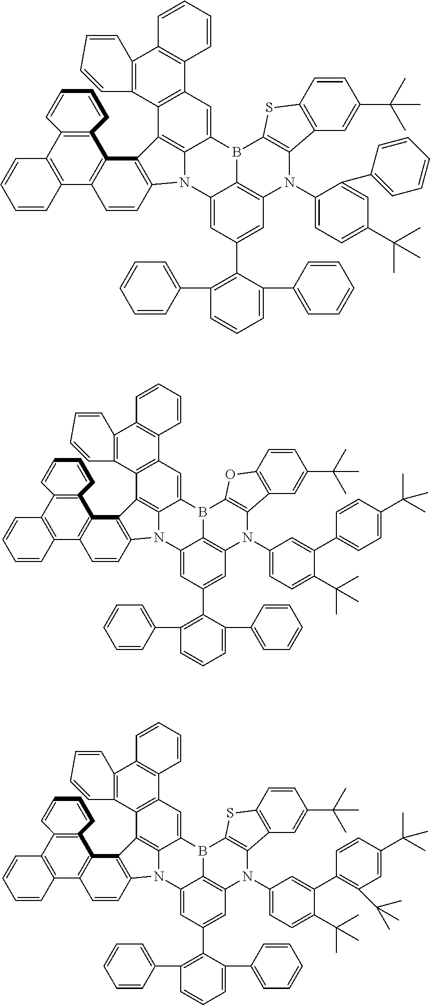

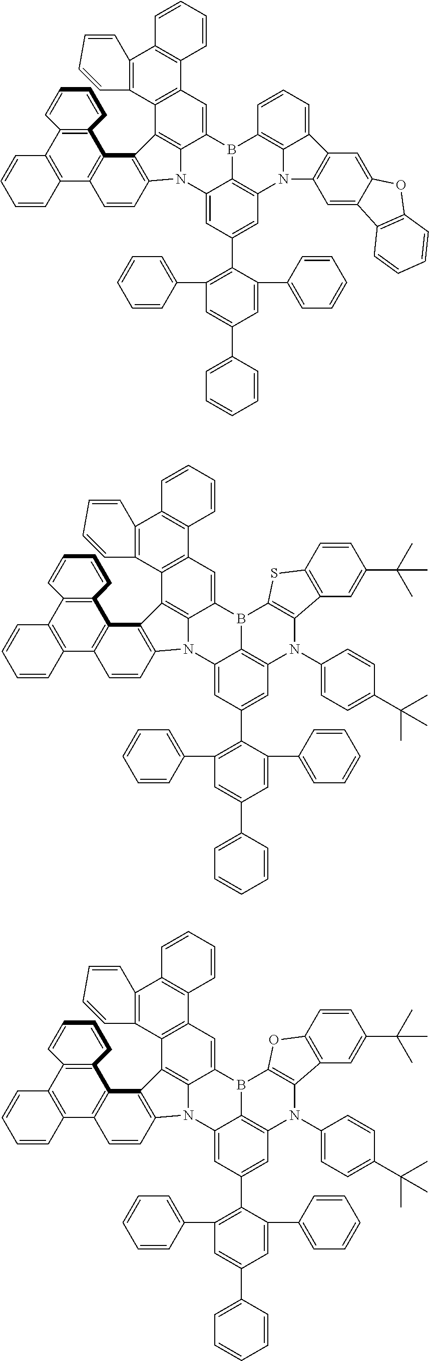

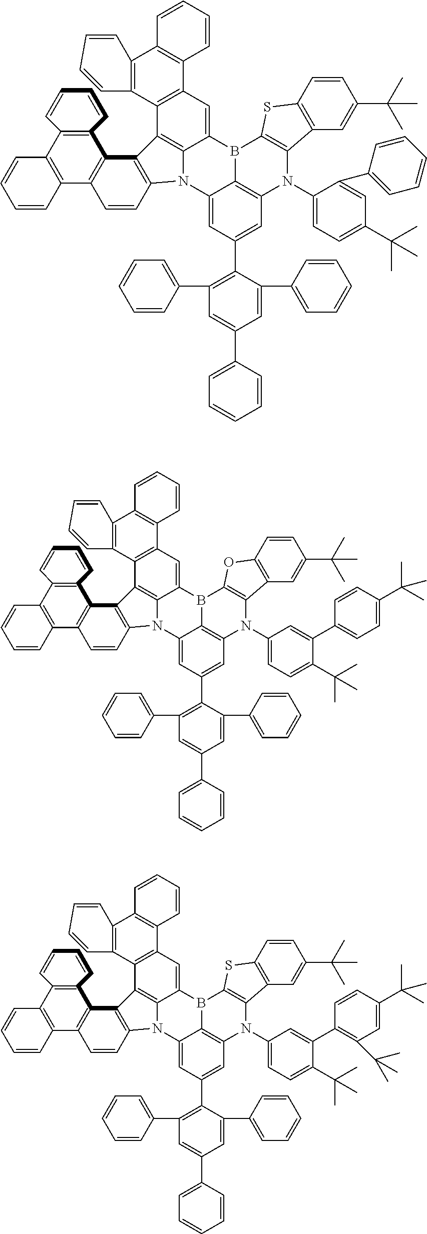

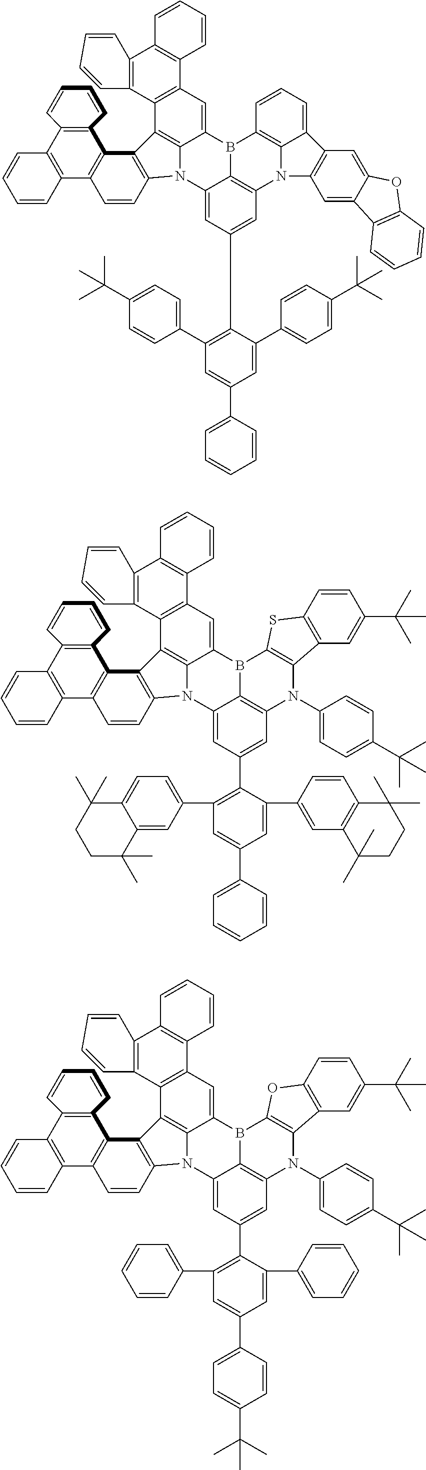

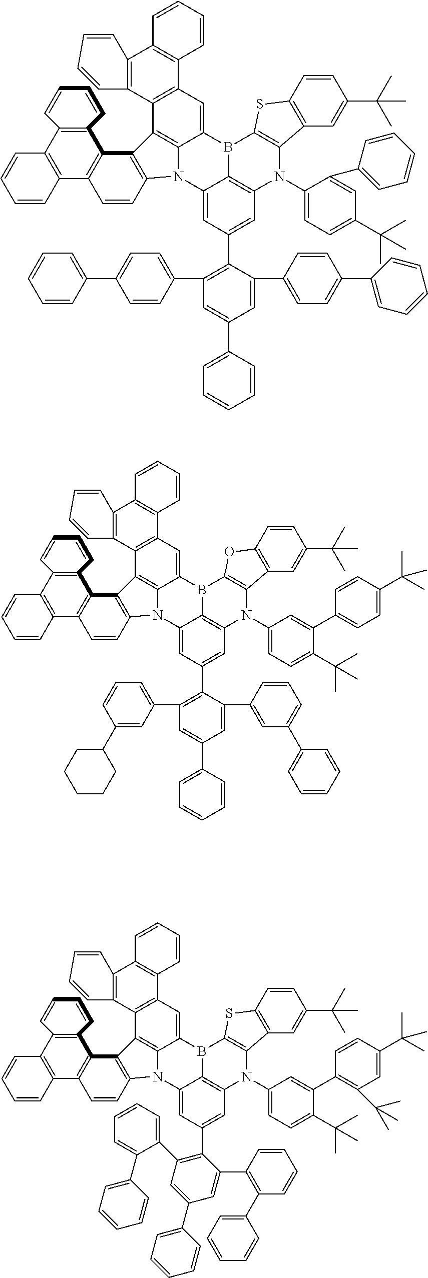

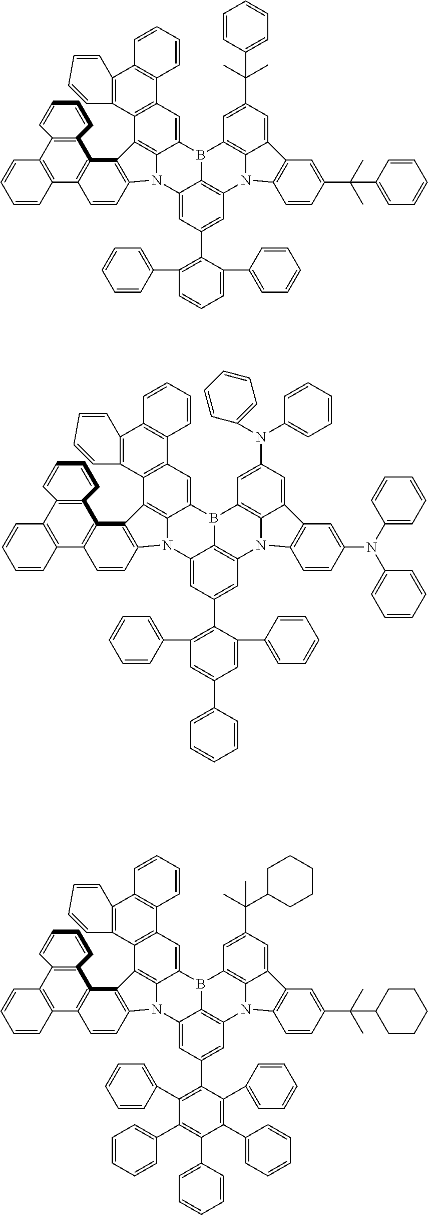

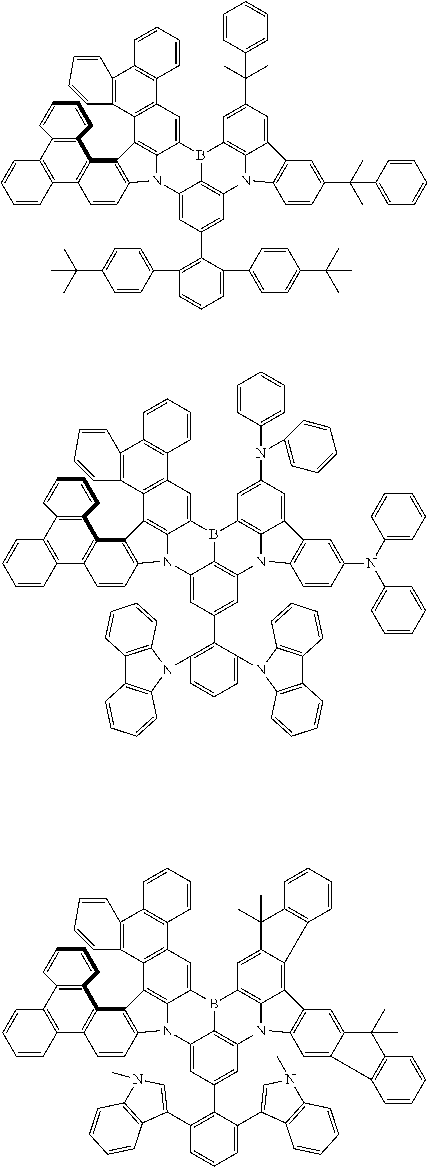

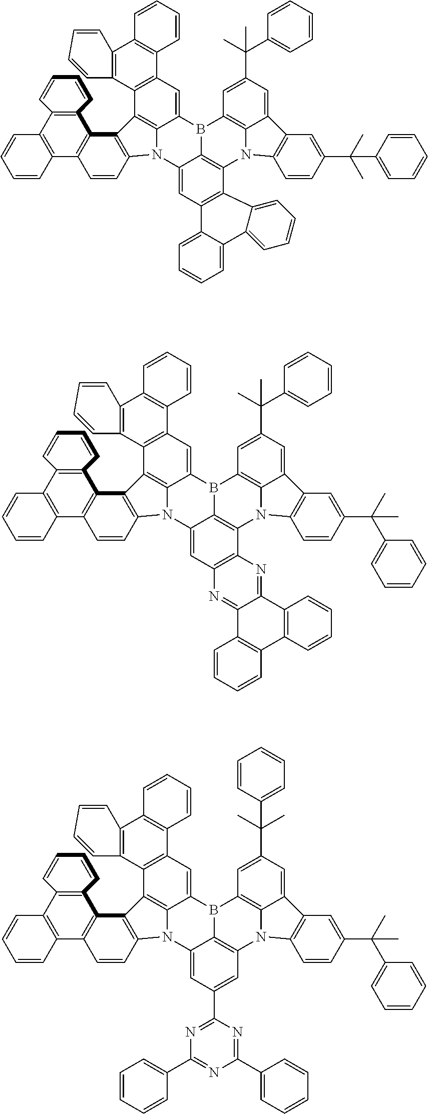

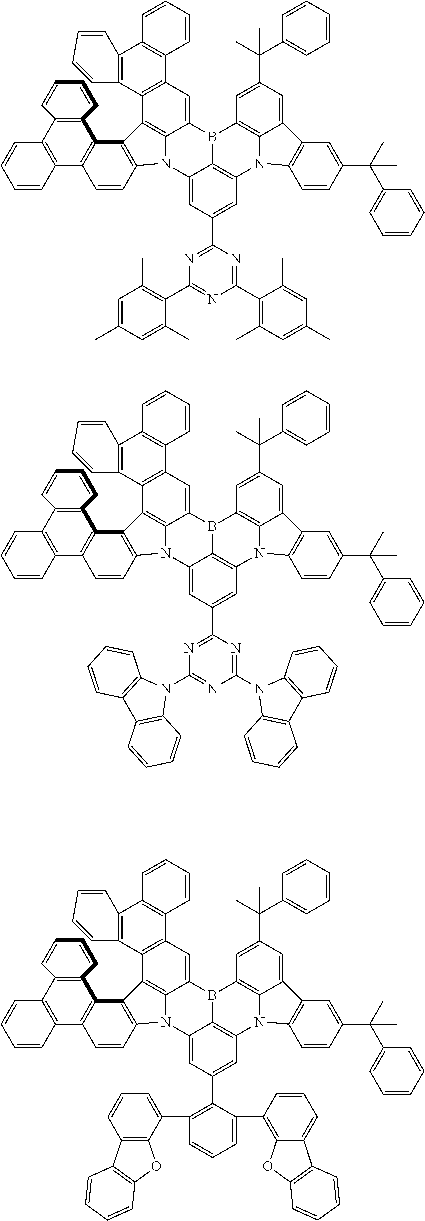

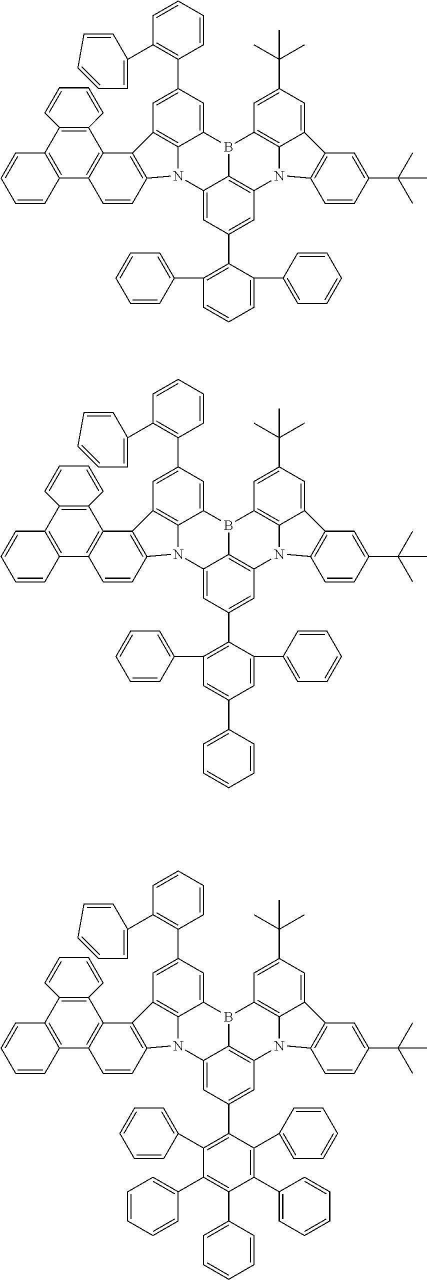

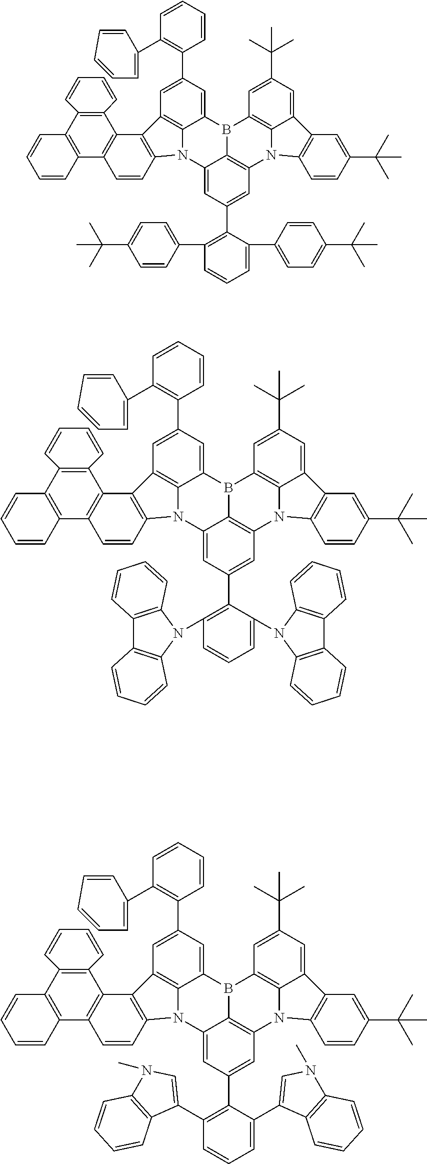 [SMILES: CC(C)(C)c1ccc(-c2cccc(-c3ccc(C(C)(C)C)cc3)c2-c2cc3c4c(c2)-n2c5ccc6c7ccccc7c7ccccc7c6c5c5cc(-c6ccccc6-c6ccccc6)cc(c52)B4c2cc(C(C)(C)C)cc4c5cc(C(C)(C)C)ccc5n-3c24)cc1 ; CC(C)(C)c1ccc2c(c1)c1cc(C(C)(C)C)cc3c1n2-c1cc(-c2c(-n4c5ccccc5c5ccccc54)cccc2-n2c4ccccc4c4ccccc42)cc2c1B3c1cc(-c3ccccc3-c3ccccc3)cc3c4c5c6ccccc6c6ccccc6c5ccc4n-2c13 ; Cn1cc(-c2cccc(-c3cn(C)c4ccccc34)c2-c2cc3c4c(c2)-n2c5ccc6c7ccccc7c7ccccc7c6c5c5cc(-c6ccccc6-c6ccccc6)cc(c52)B4c2cc(C(C)(C)C)cc4c5cc(C(C)(C)C)ccc5n-3c24)c2ccccc21]

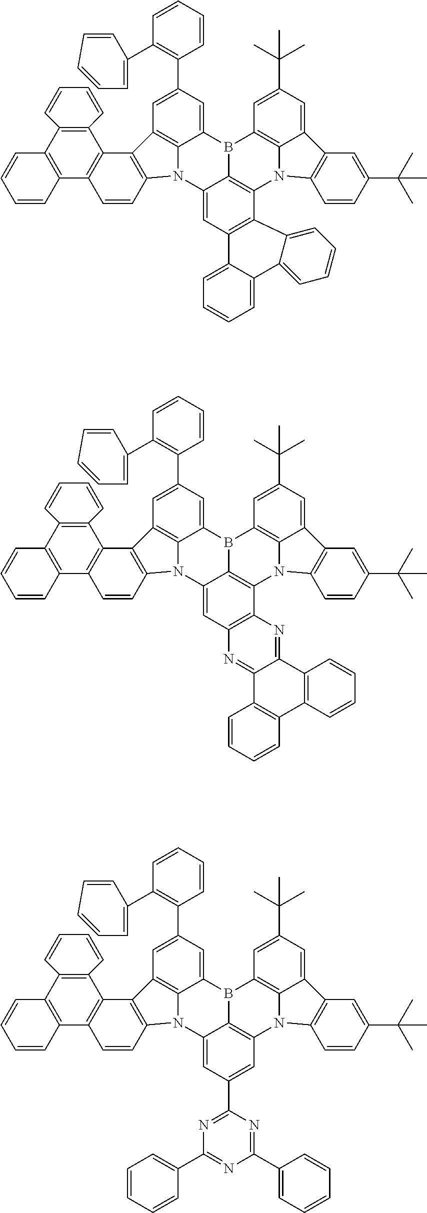 [SMILES: CC(C)(C)c1ccc2c(c1)c1cc(C(C)(C)C)cc3c1n2-c1c2c(cc4c5ccccc5c5ccccc5c14)-n1c4ccc5c6ccccc6c6ccccc6c5c4c4cc(-c5ccccc5-c5ccccc5)cc(c41)B23 ; CC(C)(C)c1ccc2c(c1)c1cc(C(C)(C)C)cc3c1n2-c1c2c(cc4nc5c6ccccc6c6ccccc6c5nc14)-n1c4ccc5c6ccccc6c6ccccc6c5c4c4cc(-c5ccccc5-c5ccccc5)cc(c41)B23 ; CC(C)(C)c1ccc2c(c1)c1cc(C(C)(C)C)cc3c1n2-c1cc(-c2nc(-c4ccccc4)nc(-c4ccccc4)n2)cc2c1B3c1cc(-c3ccccc3-c3ccccc3)cc3c4c5c6ccccc6c6ccccc6c5ccc4n-2c13]

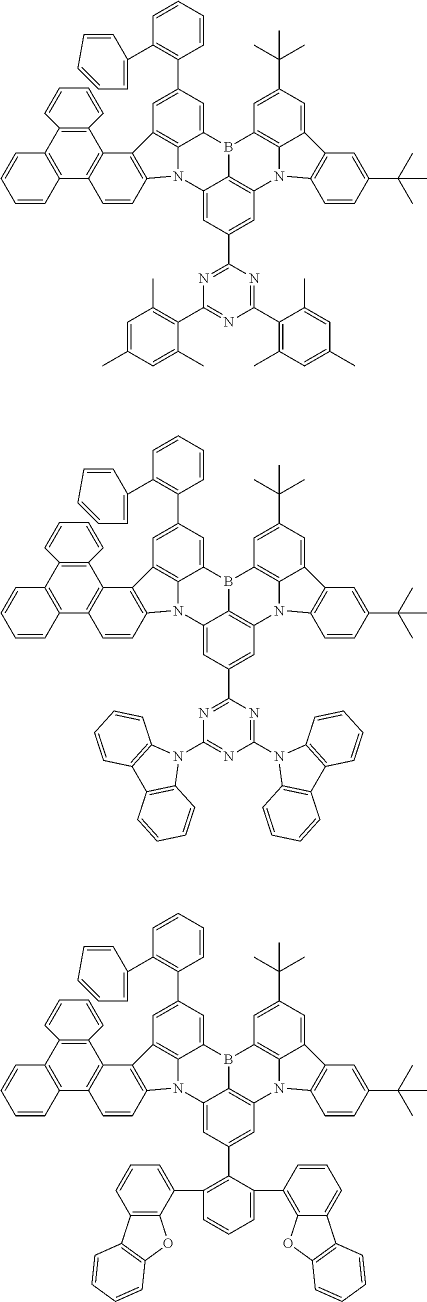 [SMILES: Cc1cc(C)c(-c2nc(-c3cc4c5c(c3)-n3c6ccc7c8ccccc8c8ccccc8c7c6c6cc(-c7ccccc7-c7ccccc7)cc(c63)B5c3cc(C(C)(C)C)cc5c6cc(C(C)(C)C)ccc6n-4c35)nc(-c3c(C)cc(C)cc3C)n2)c(C)c1 ; CC(C)(C)c1ccc2c(c1)c1cc(C(C)(C)C)cc3c1n2-c1cc(-c2nc(-n4c5ccccc5c5ccccc54)nc(-n4c5ccccc5c5ccccc54)n2)cc2c1B3c1cc(-c3ccccc3-c3ccccc3)cc3c4c5c6ccccc6c6ccccc6c5ccc4n-2c13 ; CC(C)(C)c1ccc2c(c1)c1cc(C(C)(C)C)cc3c1n2-c1cc(-c2c(-c4cccc5c4oc4ccccc45)cccc2-c2cccc4c2oc2ccccc24)cc2c1B3c1cc(-c3ccccc3-c3ccccc3)cc3c4c5c6ccccc6c6ccccc6c5ccc4n-2c13]

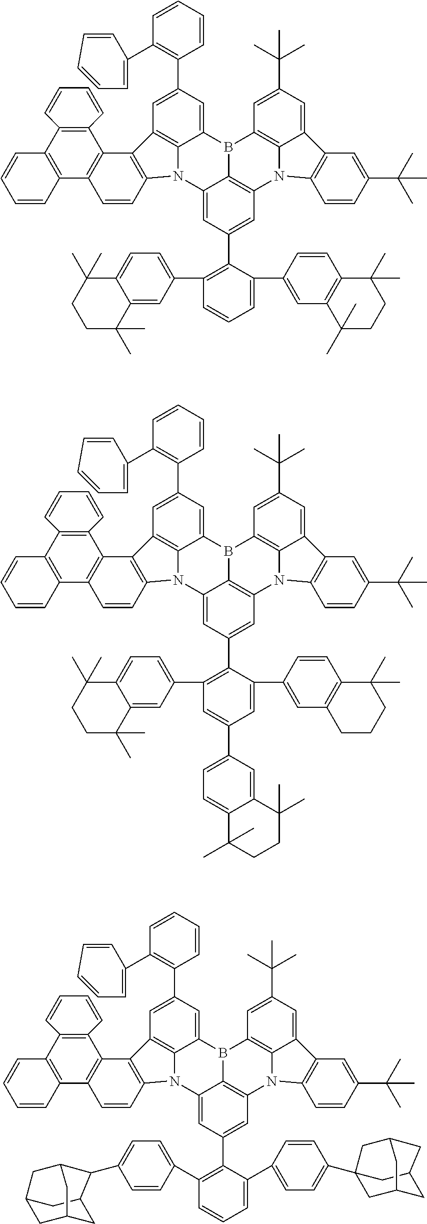

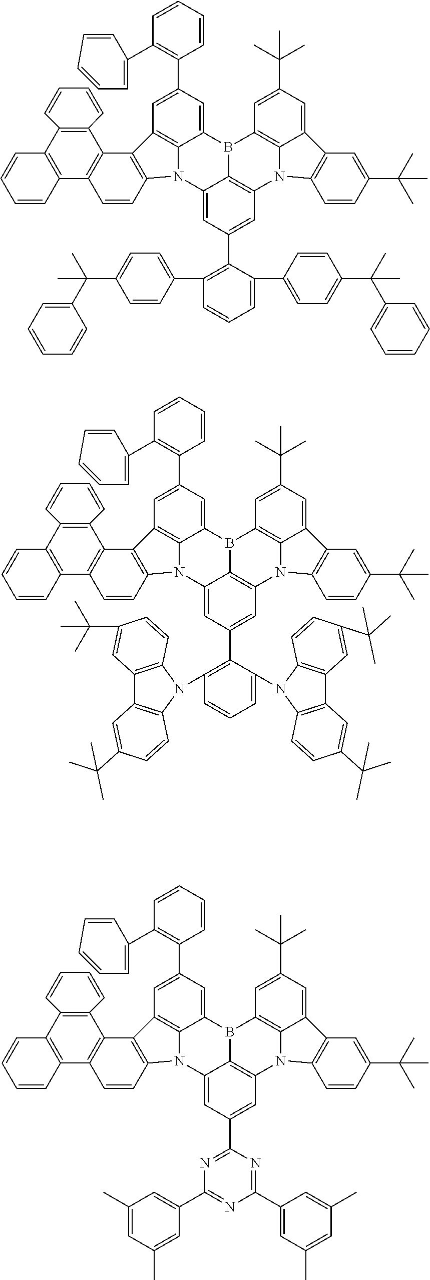

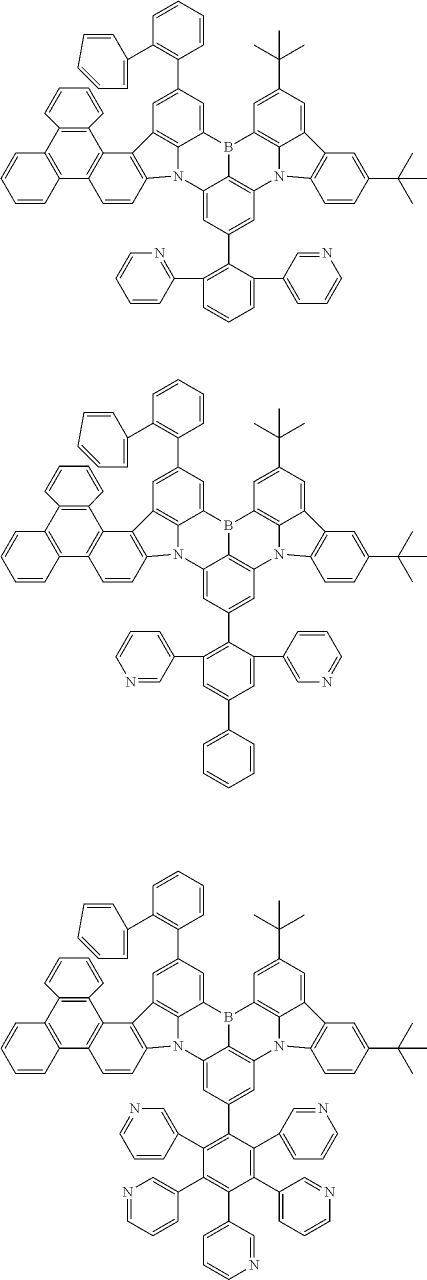

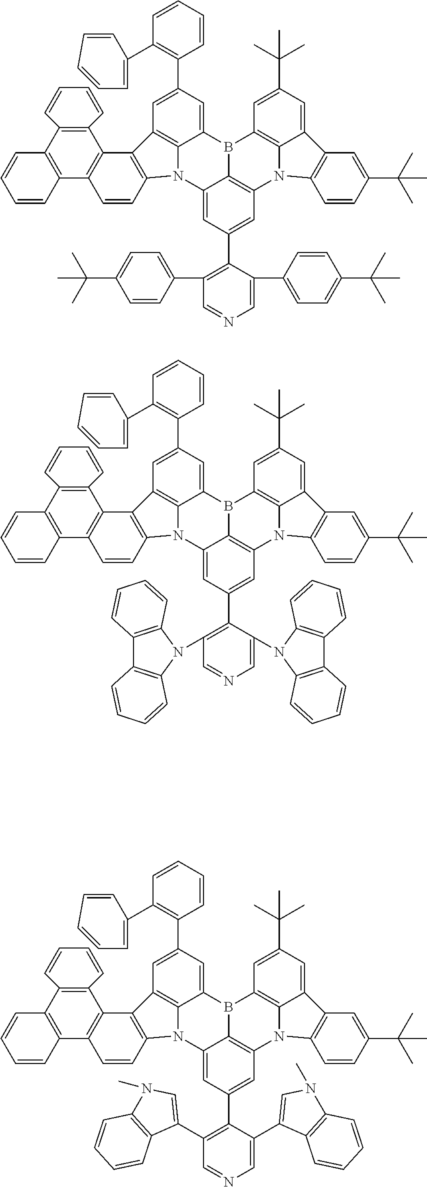 [SMILES: CC(C)(C)c1ccc(-c2cncc(-c3ccc(C(C)(C)C)cc3)c2-c2cc3c4c(c2)-n2c5ccc6c7ccccc7c7ccccc7c6c5c5cc(-c6ccccc6-c6ccccc6)cc(c52)B4c2cc(C(C)(C)C)cc4c5cc(C(C)(C)C)ccc5n-3c24)cc1 ; CC(C)(C)c1ccc2c(c1)c1cc(C(C)(C)C)cc3c1n2-c1cc(-c2c(-n4c5ccccc5c5ccccc54)cncc2-n2c4ccccc4c4ccccc42)cc2c1B3c1cc(-c3ccccc3-c3ccccc3)cc3c4c5c6ccccc6c6ccccc6c5ccc4n-2c13 ; Cn1cc(-c2cncc(-c3cn(C)c4ccccc34)c2-c2cc3c4c(c2)-n2c5ccc6c7ccccc7c7ccccc7c6c5c5cc(-c6ccccc6-c6ccccc6)cc(c52)B4c2cc(C(C)(C)C)cc4c5cc(C(C)(C)C)ccc5n-3c24)c2ccccc21]

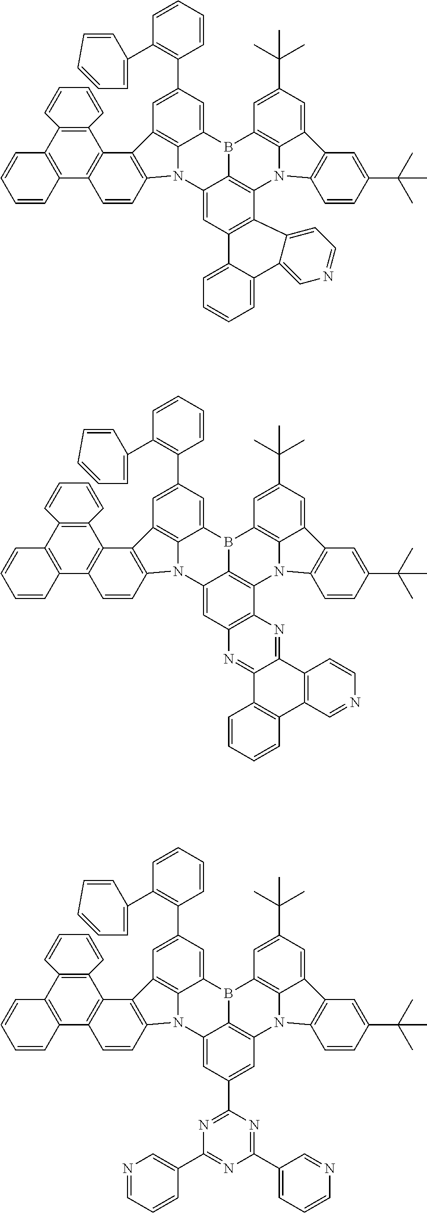 [SMILES: CC(C)(C)c1ccc2c(c1)c1cc(C(C)(C)C)cc3c1n2-c1c2c(cc4c5ccccc5c5cnccc5c14)-n1c4ccc5c6ccccc6c6ccccc6c5c4c4cc(-c5ccccc5-c5ccccc5)cc(c41)B23 ; CC(C)(C)c1ccc2c(c1)c1cc(C(C)(C)C)cc3c1n2-c1c2c(cc4nc5c6ccccc6c6cnccc6c5nc14)-n1c4ccc5c6ccccc6c6ccccc6c5c4c4cc(-c5ccccc5-c5ccccc5)cc(c41)B23 ; CC(C)(C)c1ccc2c(c1)c1cc(C(C)(C)C)cc3c1n2-c1cc(-c2nc(-c4cccnc4)nc(-c4cccnc4)n2)cc2c1B3c1cc(-c3ccccc3-c3ccccc3)cc3c4c5c6ccccc6c6ccccc6c5ccc4n-2c13]

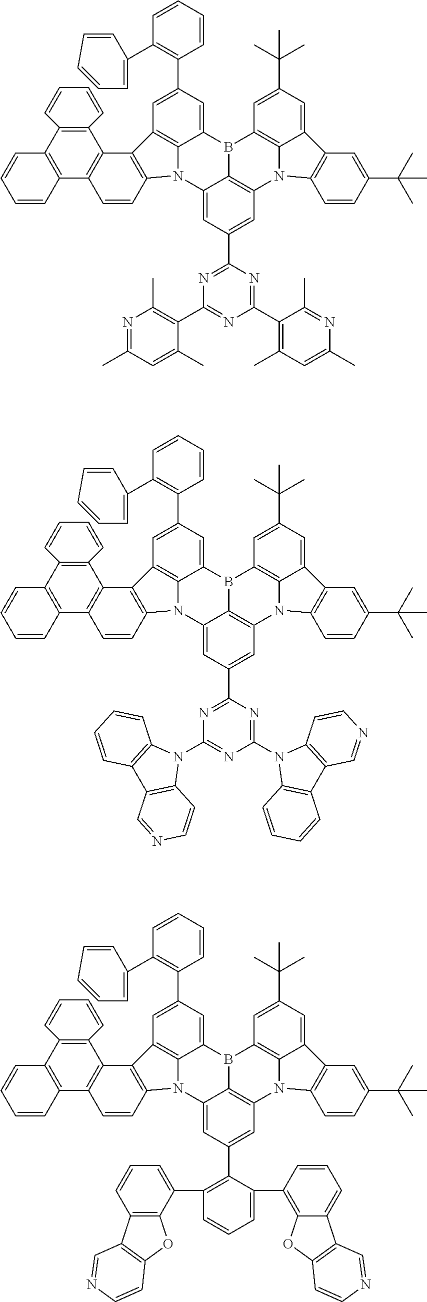 [SMILES: Cc1cc(C)c(-c2nc(-c3cc4c5c(c3)-n3c6ccc7c8ccccc8c8ccccc8c7c6c6cc(-c7ccccc7-c7ccccc7)cc(c63)B5c3cc(C(C)(C)C)cc5c6cc(C(C)(C)C)ccc6n-4c35)nc(-c3c(C)cc(C)nc3C)n2)c(C)n1 ; CC(C)(C)c1ccc2c(c1)c1cc(C(C)(C)C)cc3c1n2-c1cc(-c2nc(-n4c5ccccc5c5cnccc54)nc(-n4c5ccccc5c5cnccc54)n2)cc2c1B3c1cc(-c3ccccc3-c3ccccc3)cc3c4c5c6ccccc6c6ccccc6c5ccc4n-2c13 ; CC(C)(C)c1ccc2c(c1)c1cc(C(C)(C)C)cc3c1n2-c1cc(-c2c(-c4cccc5c4oc4ccncc45)cccc2-c2cccc4c2oc2ccncc24)cc2c1B3c1cc(-c3ccccc3-c3ccccc3)cc3c4c5c6ccccc6c6ccccc6c5ccc4n-2c13]

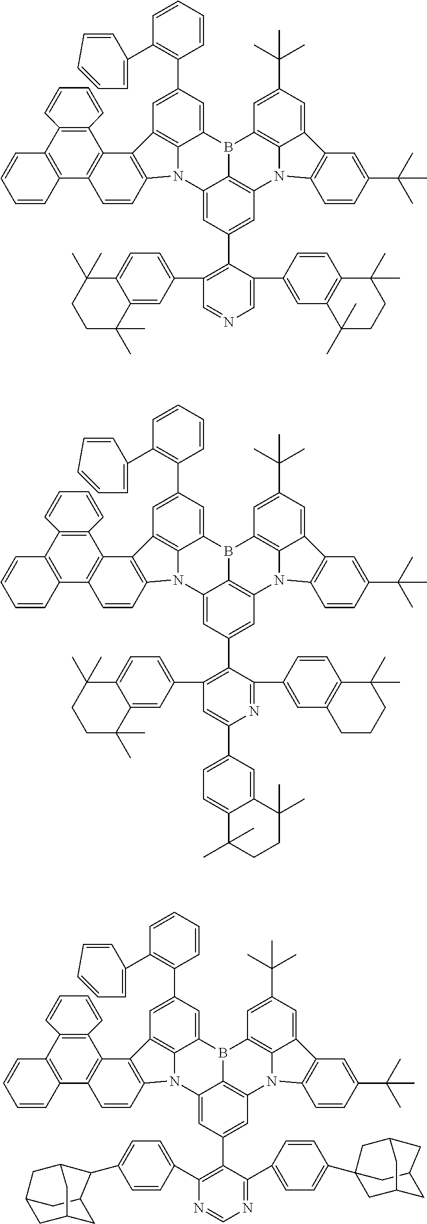

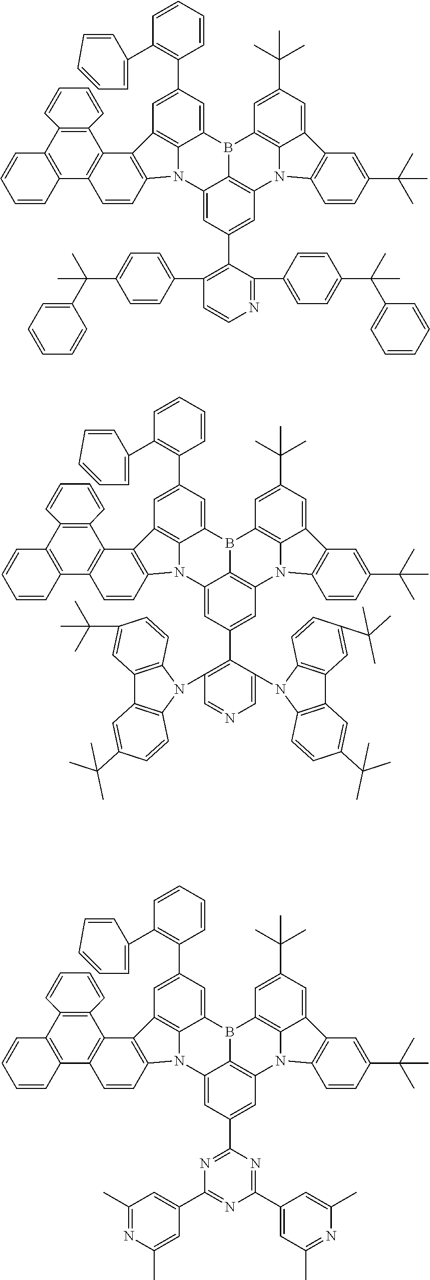

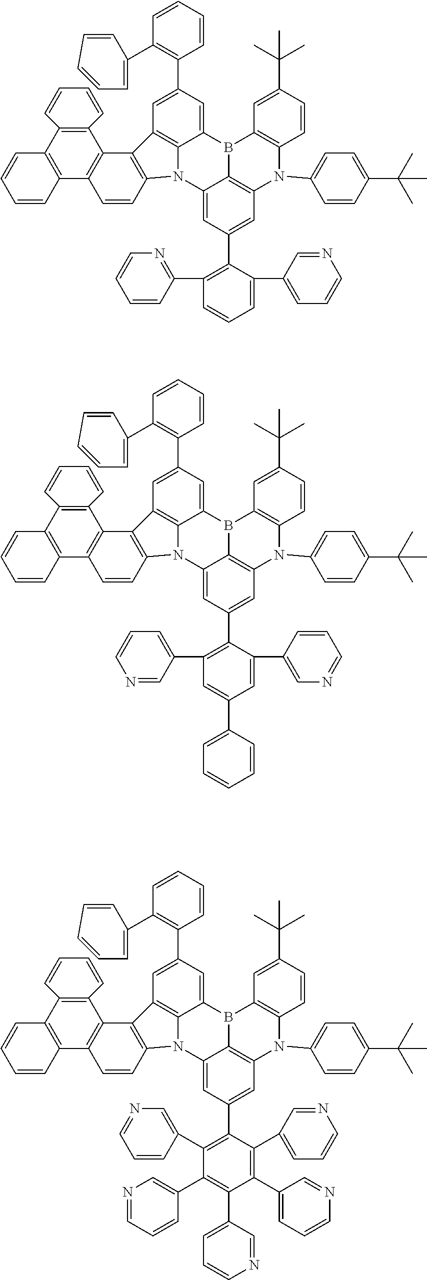

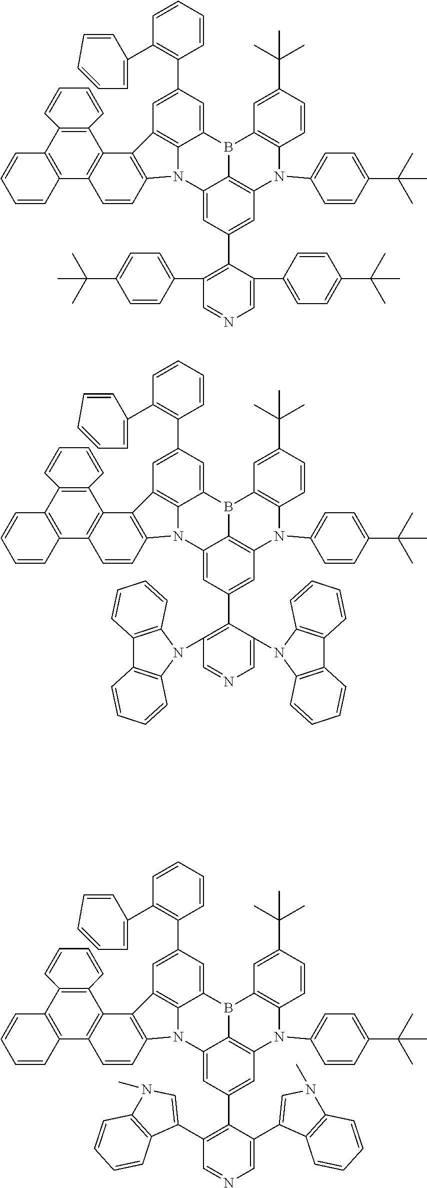 [SMILES: CC(C)(C)c1ccc(-c2cncc(-c3ccc(C(C)(C)C)cc3)c2-c2cc3c4c(c2)-n2c5ccc6c7ccccc7c7ccccc7c6c5c5cc(-c6ccccc6-c6ccccc6)cc(c52)B4c2cc(C(C)(C)C)ccc2N3c2ccc(C(C)(C)C)cc2)cc1 ; CC(C)(C)c1ccc(N2c3ccc(C(C)(C)C)cc3B3c4c2cc(-c2c(-n5c6ccccc6c6ccccc65)cncc2-n2c5ccccc5c5ccccc52)cc4-n2c4ccc5c6ccccc6c6ccccc6c5c4c4cc(-c5ccccc5-c5ccccc5)cc3c42)cc1 ; Cn1cc(-c2cncc(-c3cn(C)c4ccccc34)c2-c2cc3c4c(c2)-n2c5ccc6c7ccccc7c7ccccc7c6c5c5cc(-c6ccccc6-c6ccccc6)cc(c52)B4c2cc(C(C)(C)C)ccc2N3c2ccc(C(C)(C)C)cc2)c2ccccc21]

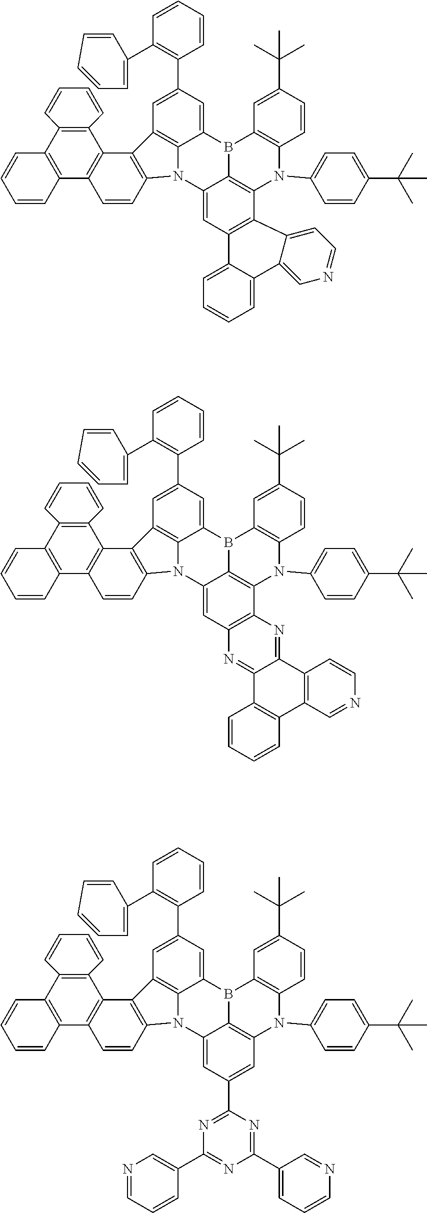 [SMILES: CC(C)(C)c1ccc(N2c3ccc(C(C)(C)C)cc3B3c4c(cc5c6ccccc6c6cnccc6c5c42)-n2c4ccc5c6ccccc6c6ccccc6c5c4c4cc(-c5ccccc5-c5ccccc5)cc3c42)cc1 ; CC(C)(C)c1ccc(N2c3ccc(C(C)(C)C)cc3B3c4c(cc5nc6c7ccccc7c7cnccc7c6nc5c42)-n2c4ccc5c6ccccc6c6ccccc6c5c4c4cc(-c5ccccc5-c5ccccc5)cc3c42)cc1 ; CC(C)(C)c1ccc(N2c3ccc(C(C)(C)C)cc3B3c4c2cc(-c2nc(-c5cccnc5)nc(-c5cccnc5)n2)cc4-n2c4ccc5c6ccccc6c6ccccc6c5c4c4cc(-c5ccccc5-c5ccccc5)cc3c42)cc1]

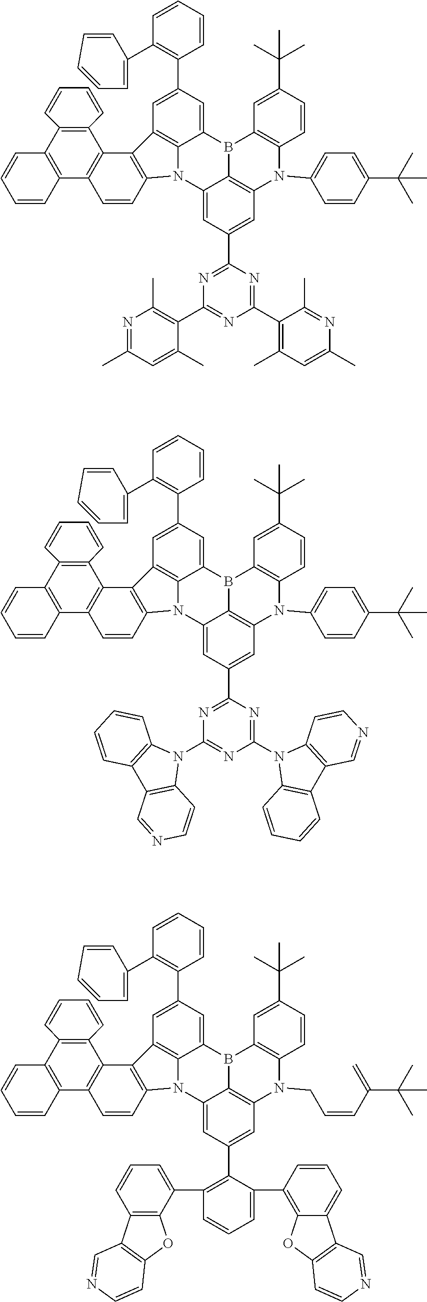 [SMILES: Cc1cc(C)c(-c2nc(-c3cc4c5c(c3)-n3c6ccc7c8ccccc8c8ccccc8c7c6c6cc(-c7ccccc7-c7ccccc7)cc(c63)B5c3cc(C(C)(C)C)ccc3N4c3ccc(C(C)(C)C)cc3)nc(-c3c(C)cc(C)nc3C)n2)c(C)n1 ; CC(C)(C)c1ccc(N2c3ccc(C(C)(C)C)cc3B3c4c2cc(-c2nc(-n5c6ccccc6c6cnccc65)nc(-n5c6ccccc6c6cnccc65)n2)cc4-n2c4ccc5c6ccccc6c6ccccc6c5c4c4cc(-c5ccccc5-c5ccccc5)cc3c42)cc1 ; C=C(/C=C\CN1c2ccc(C(C)(C)C)cc2B2c3c1cc(-c1c(-c4cccc5c4oc4ccncc45)cccc1-c1cccc4c1oc1ccncc14)cc3-n1c3ccc4c5ccccc5c5ccccc5c4c3c3cc(-c4ccccc4-c4ccccc4)cc2c31)C(C)(C)C]

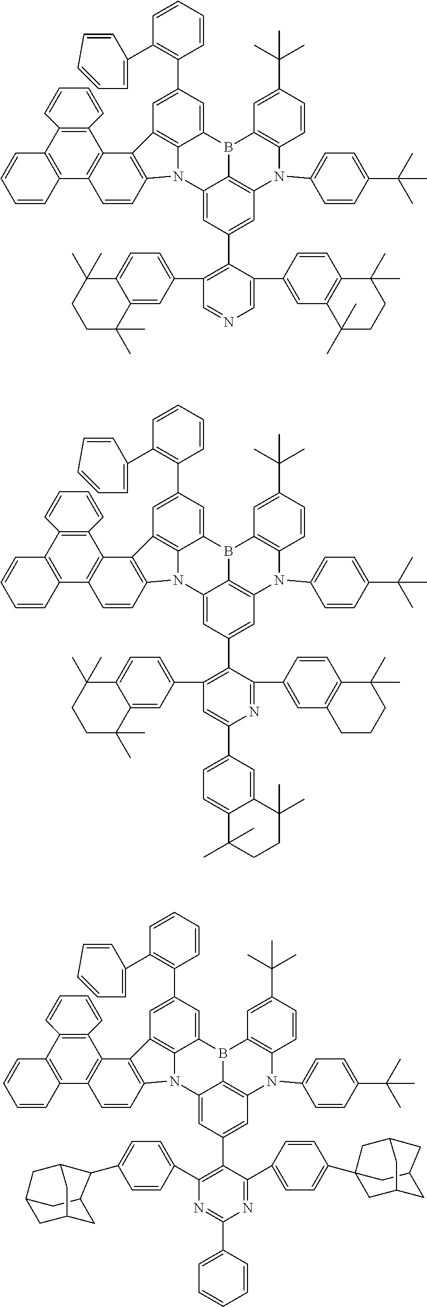

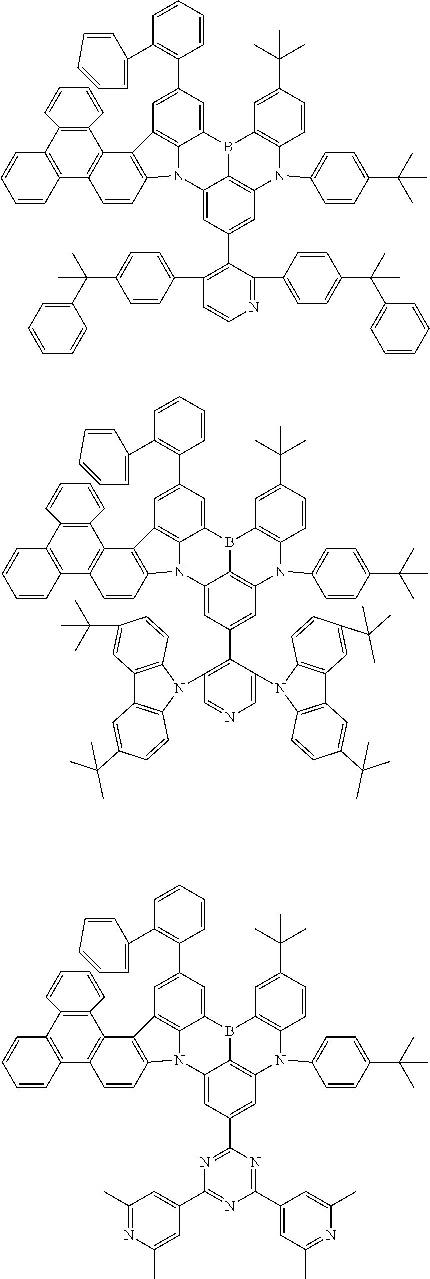

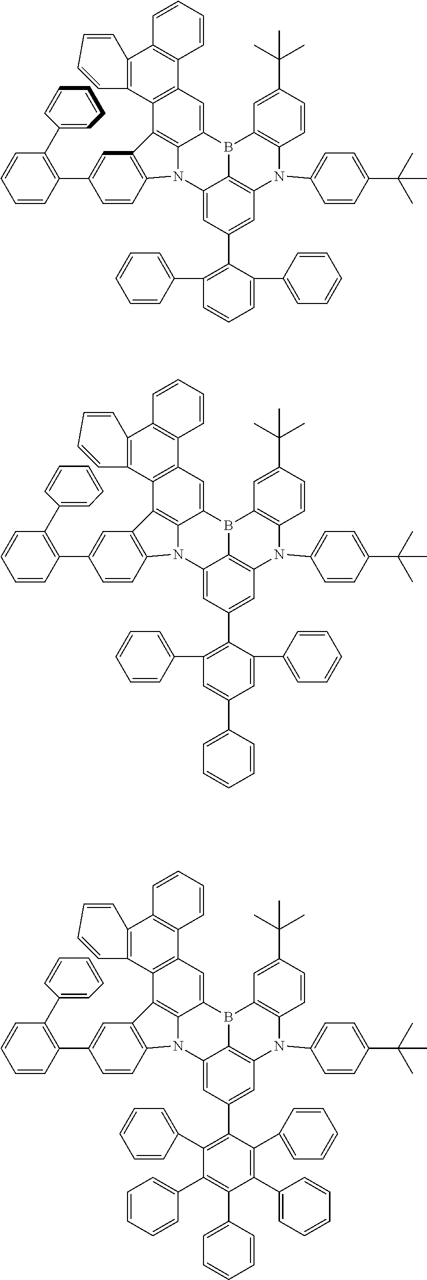

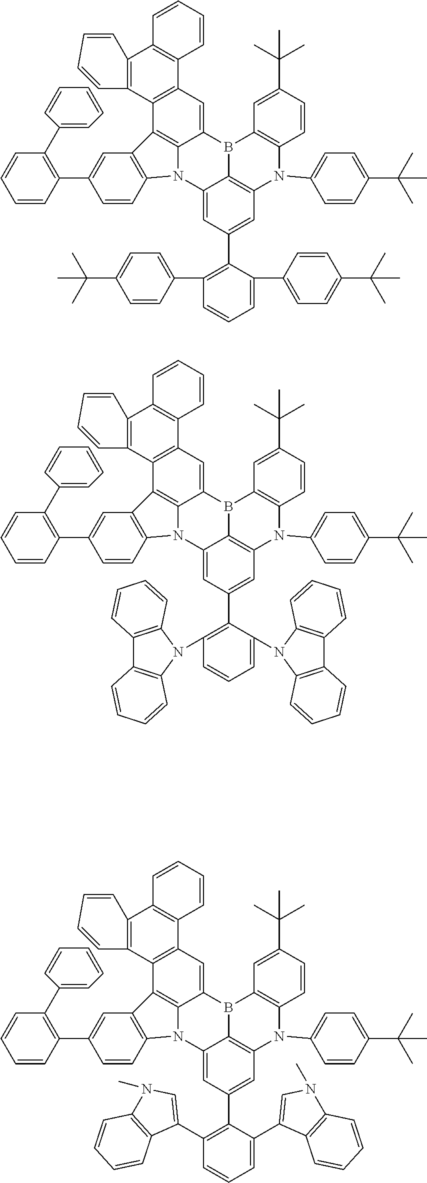 [SMILES: CC(C)(C)c1ccc(-c2cccc(-c3ccc(C(C)(C)C)cc3)c2-c2cc3c4c(c2)-n2c5ccc(-c6ccccc6-c6ccccc6)cc5c5c6c7ccccc7c7ccccc7c6cc(c52)B4c2cc(C(C)(C)C)ccc2N3c2ccc(C(C)(C)C)cc2)cc1 ; CC(C)(C)c1ccc(N2c3ccc(C(C)(C)C)cc3B3c4c2cc(-c2c(-n5c6ccccc6c6ccccc65)cccc2-n2c5ccccc5c5ccccc52)cc4-n2c4ccc(-c5ccccc5-c5ccccc5)cc4c4c5c6ccccc6c6ccccc6c5cc3c42)cc1 ; Cn1cc(-c2cccc(-c3cn(C)c4ccccc34)c2-c2cc3c4c(c2)-n2c5ccc(-c6ccccc6-c6ccccc6)cc5c5c6c7ccccc7c7ccccc7c6cc(c52)B4c2cc(C(C)(C)C)ccc2N3c2ccc(C(C)(C)C)cc2)c2ccccc21]

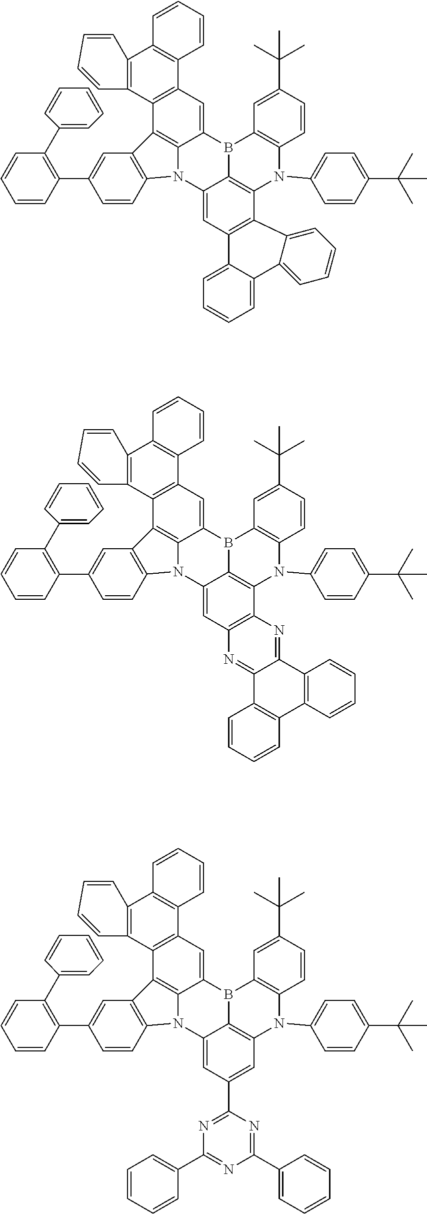 [SMILES: CC(C)(C)c1ccc(N2c3ccc(C(C)(C)C)cc3B3c4c(cc5c6ccccc6c6ccccc6c5c42)-n2c4ccc(-c5ccccc5-c5ccccc5)cc4c4c5c6ccccc6c6ccccc6c5cc3c42)cc1 ; CC(C)(C)c1ccc(N2c3ccc(C(C)(C)C)cc3B3c4c(cc5nc6c7ccccc7c7ccccc7c6nc5c42)-n2c4ccc(-c5ccccc5-c5ccccc5)cc4c4c5c6ccccc6c6ccccc6c5cc3c42)cc1 ; CC(C)(C)c1ccc(N2c3ccc(C(C)(C)C)cc3B3c4c2cc(-c2nc(-c5ccccc5)nc(-c5ccccc5)n2)cc4-n2c4ccc(-c5ccccc5-c5ccccc5)cc4c4c5c6ccccc6c6ccccc6c5cc3c42)cc1]

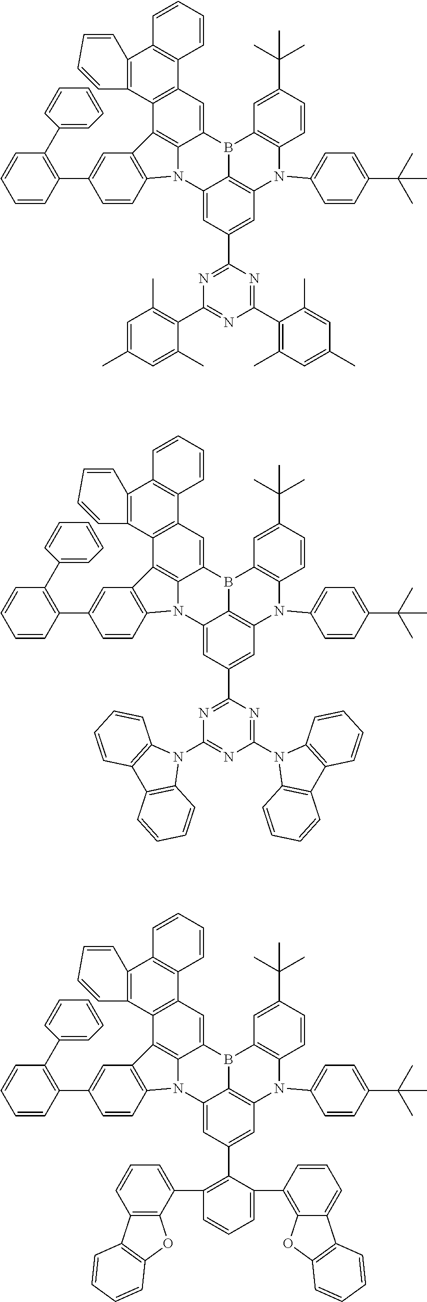 [SMILES: Cc1cc(C)c(-c2nc(-c3cc4c5c(c3)-n3c6ccc(-c7ccccc7-c7ccccc7)cc6c6c7c8ccccc8c8ccccc8c7cc(c63)B5c3cc(C(C)(C)C)ccc3N4c3ccc(C(C)(C)C)cc3)nc(-c3c(C)cc(C)cc3C)n2)c(C)c1 ; CC(C)(C)c1ccc(N2c3ccc(C(C)(C)C)cc3B3c4c2cc(-c2nc(-n5c6ccccc6c6ccccc65)nc(-n5c6ccccc6c6ccccc65)n2)cc4-n2c4ccc(-c5ccccc5-c5ccccc5)cc4c4c5c6ccccc6c6ccccc6c5cc3c42)cc1 ; CC(C)(C)c1ccc(N2c3ccc(C(C)(C)C)cc3B3c4c2cc(-c2c(-c5cccc6c5oc5ccccc56)cccc2-c2cccc5c2oc2ccccc25)cc4-n2c4ccc(-c5ccccc5-c5ccccc5)cc4c4c5c6ccccc6c6ccccc6c5cc3c42)cc1]

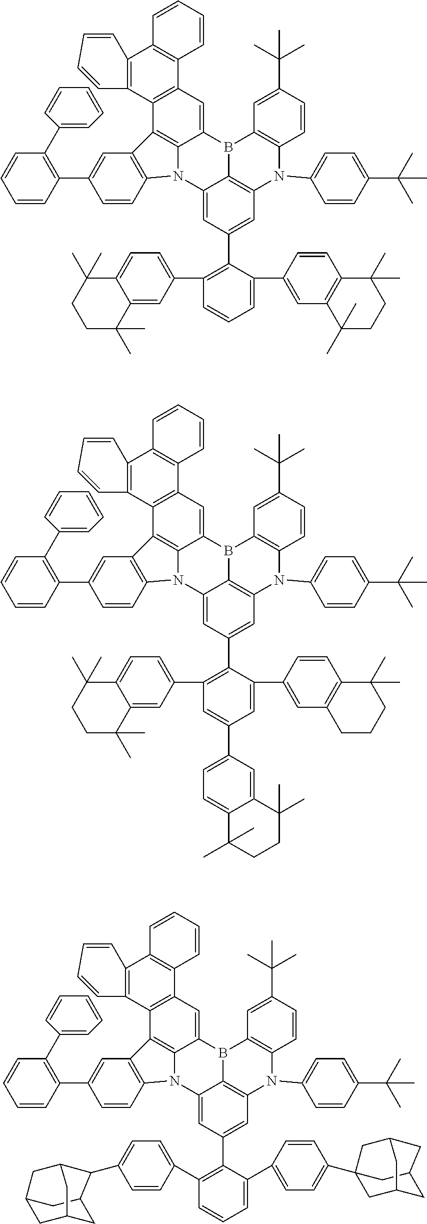

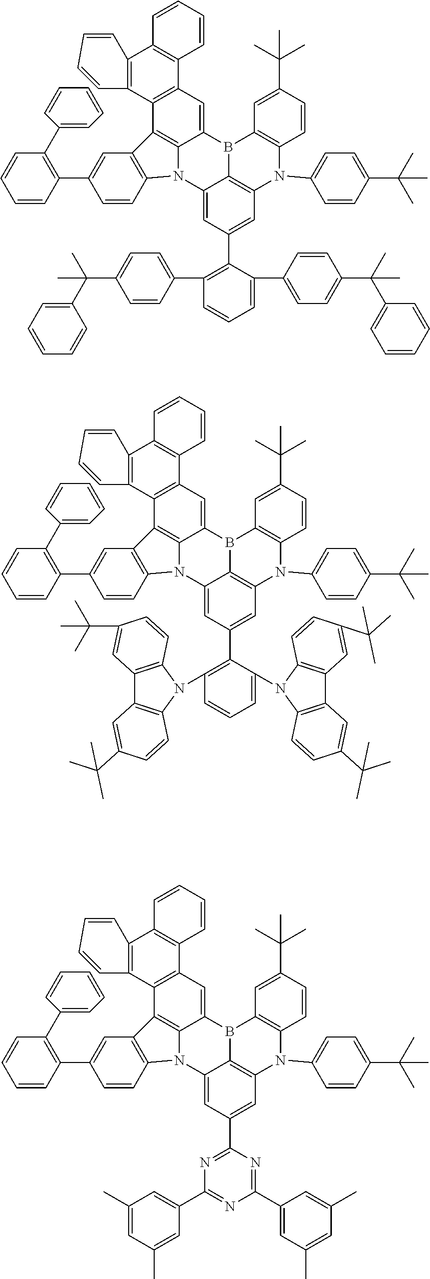

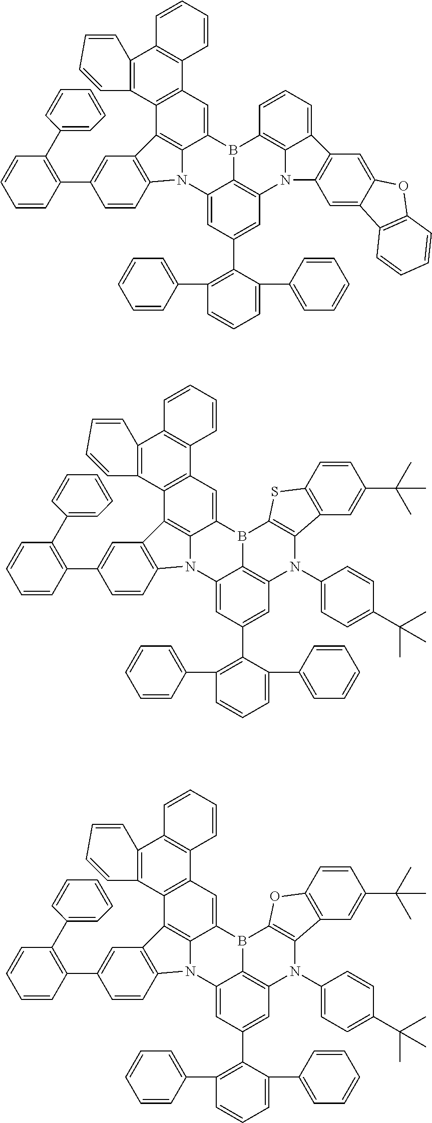 [SMILES: c1ccc(-c2ccccc2-c2ccc3c(c2)c2c4c5ccccc5c5ccccc5c4cc4c2n3-c2cc(-c3c(-c5ccccc5)cccc3-c3ccccc3)cc3c2B4c2cccc4c5cc6oc7ccccc7c6cc5n-3c24)cc1 ; CC(C)(C)c1ccc(N2c3cc(-c4c(-c5ccccc5)cccc4-c4ccccc4)cc4c3B(c3sc5ccc(C(C)(C)C)cc5c32)c2cc3c5ccccc5c5ccccc5c3c3c5cc(-c6ccccc6-c6ccccc6)ccc5n-4c23)cc1 ; CC(C)(C)c1ccc(N2c3cc(-c4c(-c5ccccc5)cccc4-c4ccccc4)cc4c3B(c3oc5ccc(C(C)(C)C)cc5c32)c2cc3c5ccccc5c5ccccc5c3c3c5cc(-c6ccccc6-c6ccccc6)ccc5n-4c23)cc1]

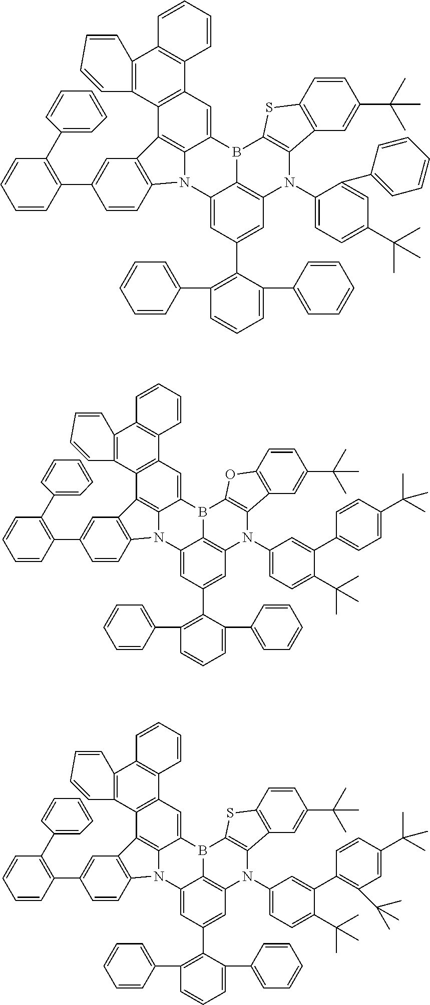

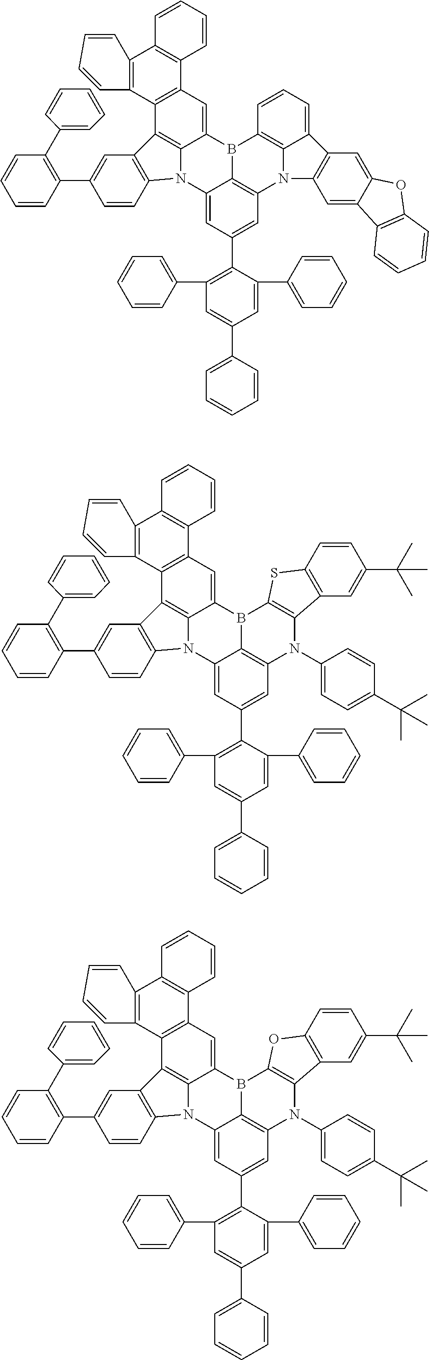 [SMILES: c1ccc(-c2cc(-c3ccccc3)c(-c3cc4c5c(c3)-n3c6ccc(-c7ccccc7-c7ccccc7)cc6c6c7c8ccccc8c8ccccc8c7cc(c63)B5c3cccc5c6cc7oc8ccccc8c7cc6n-4c35)c(-c3ccccc3)c2)cc1 ; CC(C)(C)c1ccc(N2c3cc(-c4c(-c5ccccc5)cc(-c5ccccc5)cc4-c4ccccc4)cc4c3B(c3sc5ccc(C(C)(C)C)cc5c32)c2cc3c5ccccc5c5ccccc5c3c3c5cc(-c6ccccc6-c6ccccc6)ccc5n-4c23)cc1 ; CC(C)(C)c1ccc(N2c3cc(-c4c(-c5ccccc5)cc(-c5ccccc5)cc4-c4ccccc4)cc4c3B(c3oc5ccc(C(C)(C)C)cc5c32)c2cc3c5ccccc5c5ccccc5c3c3c5cc(-c6ccccc6-c6ccccc6)ccc5n-4c23)cc1]

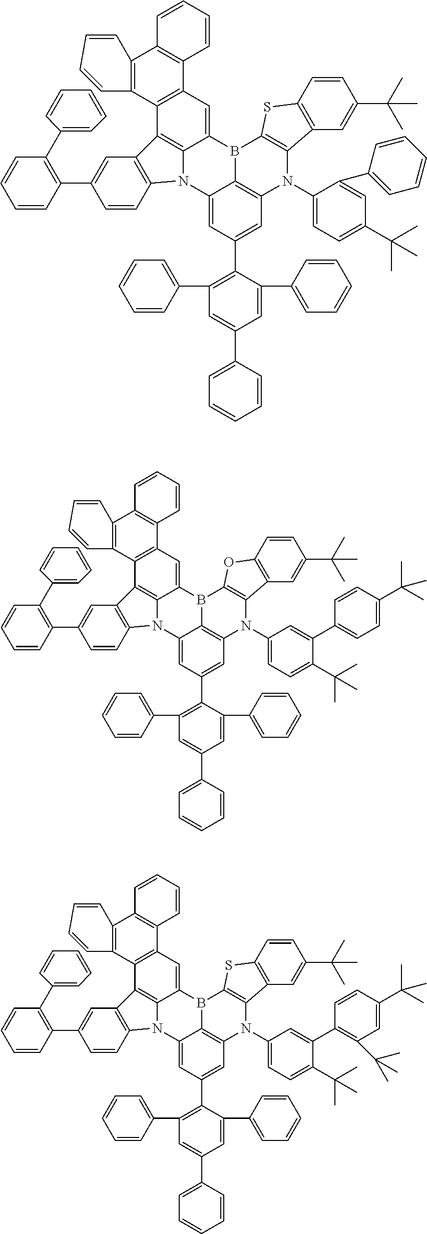

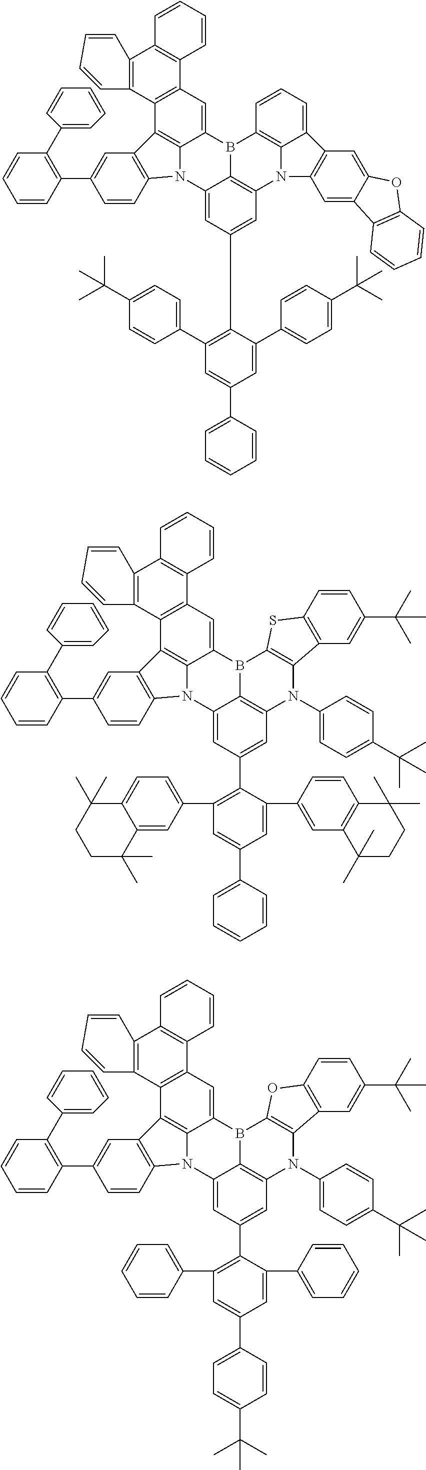

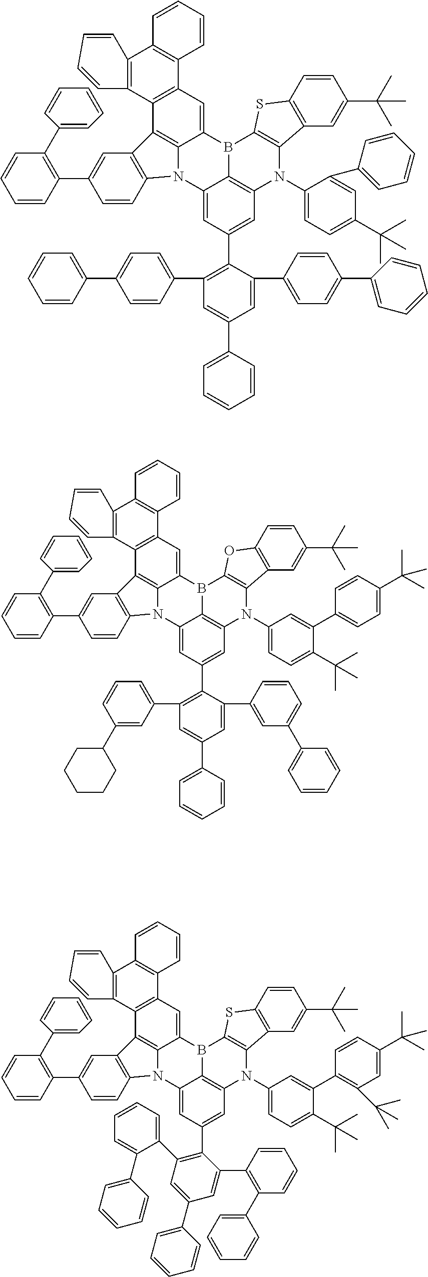

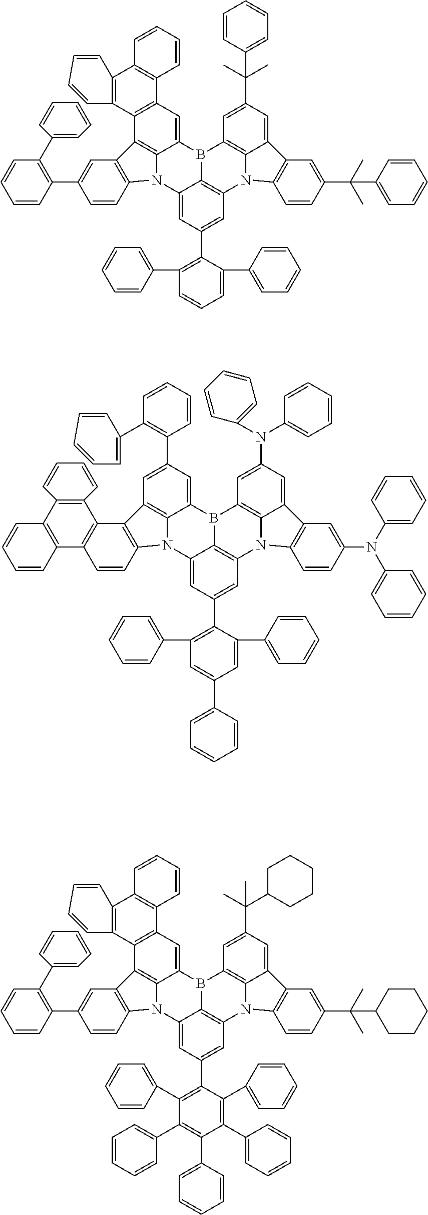

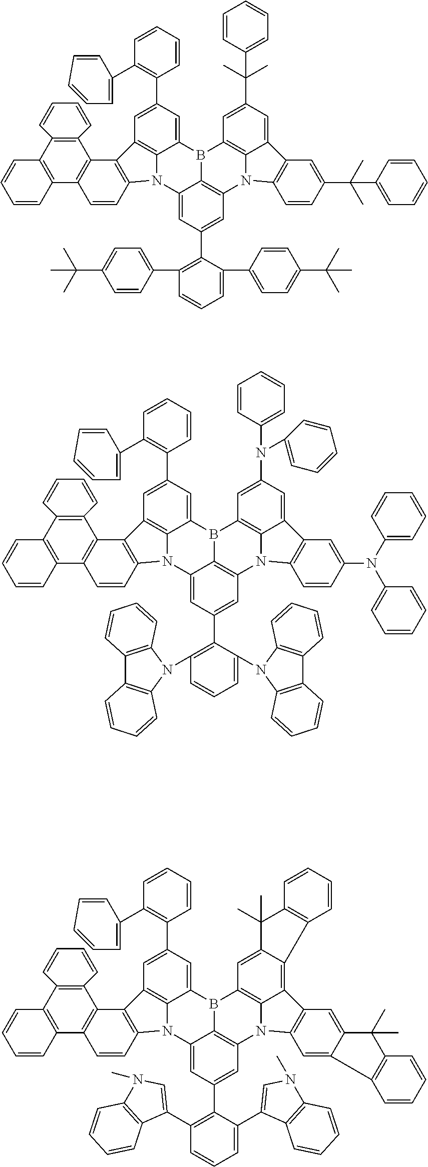

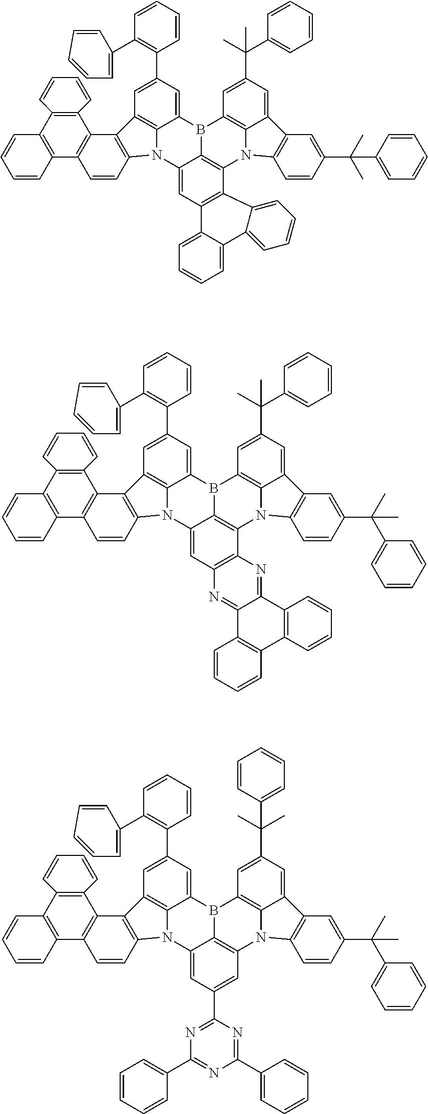 [SMILES: CC(C)(c1ccccc1)c1ccc2c(c1)c1cc(C(C)(C)c3ccccc3)cc3c1n2-c1c2c(cc4c5ccccc5c5ccccc5c14)-n1c4ccc5c6ccccc6c6ccccc6c5c4c4cc(-c5ccccc5-c5ccccc5)cc(c41)B23 ; CC(C)(c1ccccc1)c1ccc2c(c1)c1cc(C(C)(C)c3ccccc3)cc3c1n2-c1c2c(cc4nc5c6ccccc6c6ccccc6c5nc14)-n1c4ccc5c6ccccc6c6ccccc6c5c4c4cc(-c5ccccc5-c5ccccc5)cc(c41)B23 ; CC(C)(c1ccccc1)c1ccc2c(c1)c1cc(C(C)(C)c3ccccc3)cc3c1n2-c1cc(-c2nc(-c4ccccc4)nc(-c4ccccc4)n2)cc2c1B3c1cc(-c3ccccc3-c3ccccc3)cc3c4c5c6ccccc6c6ccccc6c5ccc4n-2c13]

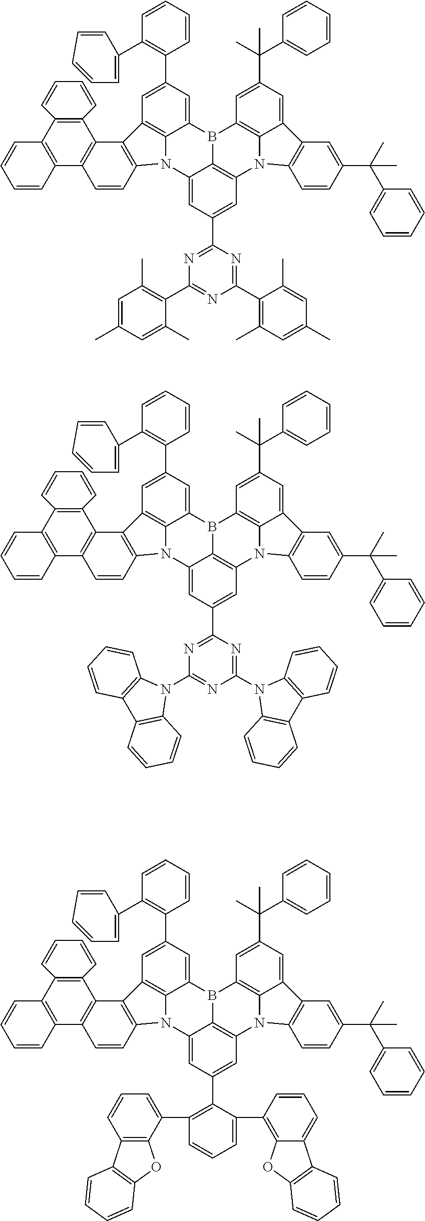

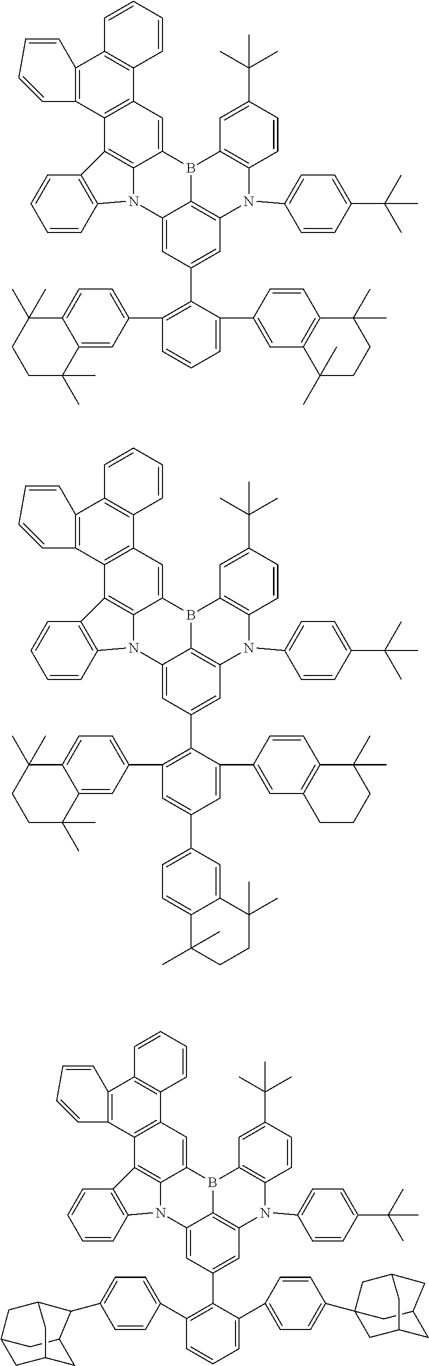

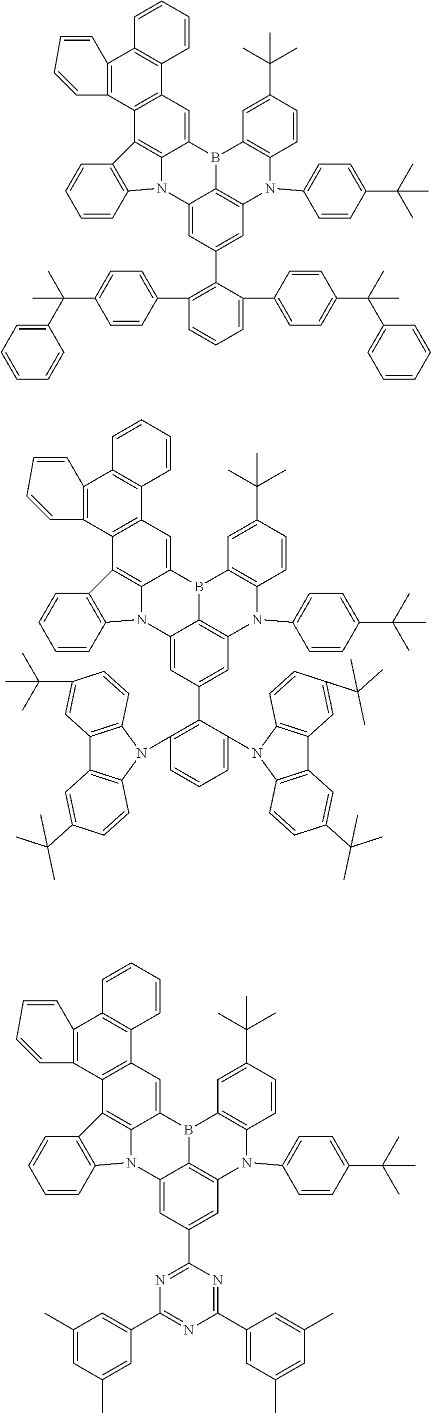 [SMILES: CC(C)(C)c1ccc(N2c3ccc(C(C)(C)C)cc3B3c4c2cc(-c2c(-c5ccc(C(C)(C)c6ccccc6)cc5)cccc2-c2ccc(C(C)(C)c5ccccc5)cc2)cc4-n2c4ccccc4c4c5c6ccccc6c6ccccc6c5cc3c42)cc1 ; CC(C)(C)c1ccc(N2c3ccc(C(C)(C)C)cc3B3c4c2cc(-c2c(-n5c6ccc(C(C)(C)C)cc6c6cc(C(C)(C)C)ccc65)cccc2-n2c5ccc(C(C)(C)C)cc5c5cc(C(C)(C)C)ccc52)cc4-n2c4ccccc4c4c5c6ccccc6c6ccccc6c5cc3c42)cc1 ; Cc1cc(C)cc(-c2nc(-c3cc(C)cc(C)c3)nc(-c3cc4c5c(c3)-n3c6ccccc6c6c7c8ccccc8c8ccccc8c7cc(c63)B5c3cc(C(C)(C)C)ccc3N4c3ccc(C(C)(C)C)cc3)n2)c1]

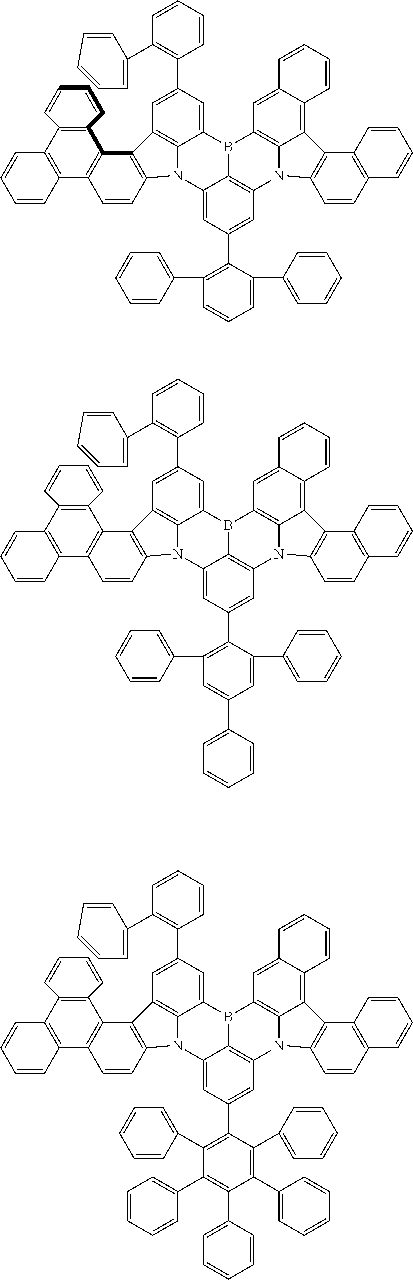

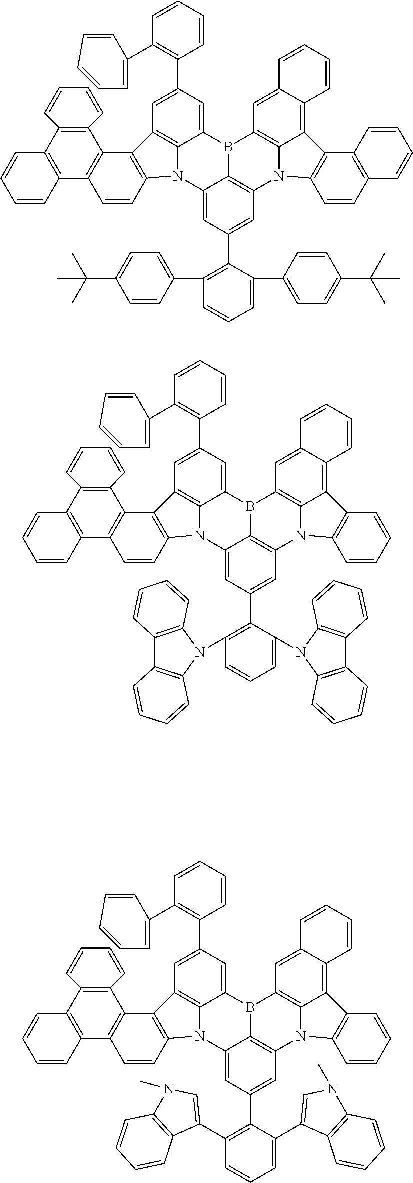 [SMILES: CC(C)(C)c1ccc(-c2cccc(-c3ccc(C(C)(C)C)cc3)c2-c2cc3c4c(c2)-n2c5ccc6ccccc6c5c5c6ccccc6cc(c52)B4c2cc(-c4ccccc4-c4ccccc4)cc4c5c6c7ccccc7c7ccccc7c6ccc5n-3c24)cc1 ; c1ccc(-c2ccccc2-c2cc3c4c(c2)c2c5c6ccccc6c6ccccc6c5ccc2n4-c2cc(-c4c(-n5c6ccccc6c6ccccc65)cccc4-n4c5ccccc5c5ccccc54)cc4c2B3c2cc3ccccc3c3c5ccccc5n-4c23)cc1 ; Cn1cc(-c2cccc(-c3cn(C)c4ccccc34)c2-c2cc3c4c(c2)-n2c5ccccc5c5c6ccccc6cc(c52)B4c2cc(-c4ccccc4-c4ccccc4)cc4c5c6c7ccccc7c7ccccc7c6ccc5n-3c24)c2ccccc21]

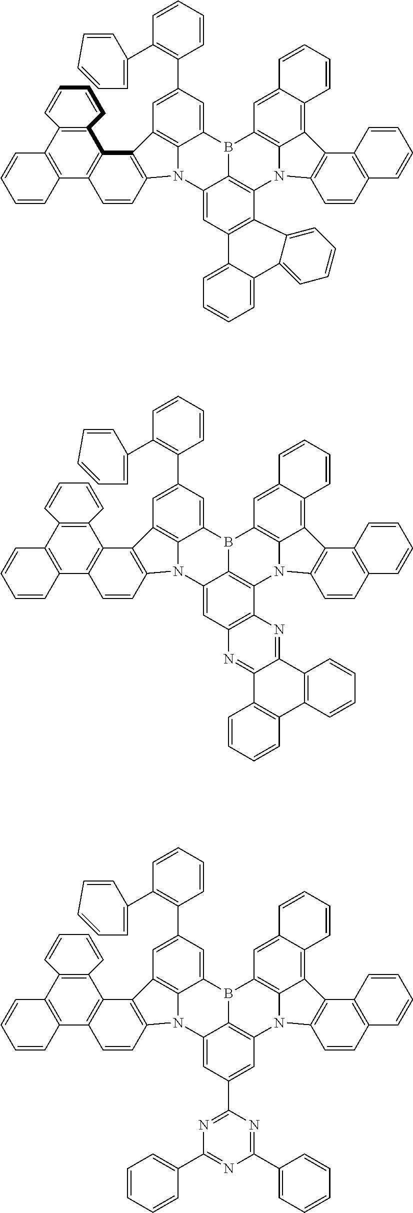

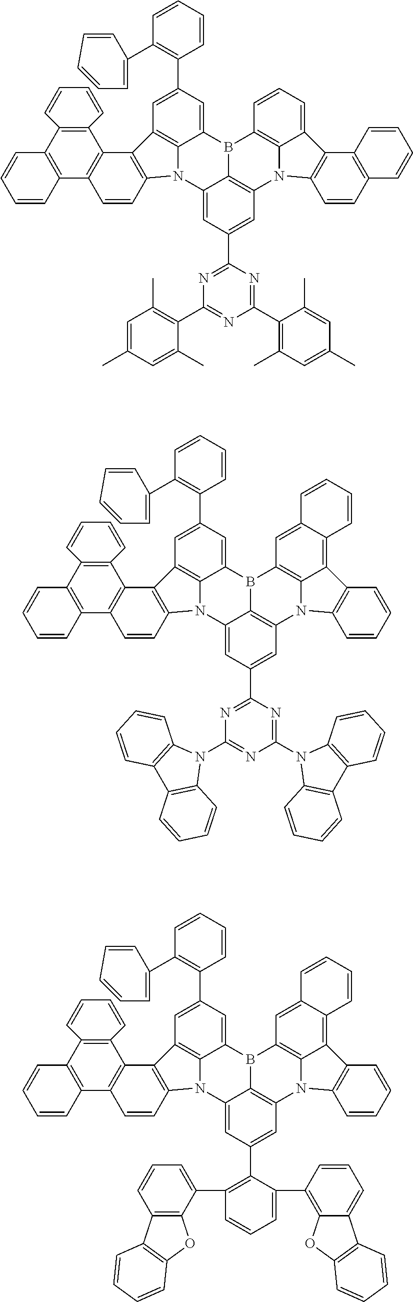 [SMILES: Cc1cc(C)c(-c2nc(-c3cc4c5c(c3)-n3c6ccc7c8ccccc8c8ccccc8c7c6c6cc(-c7ccccc7-c7ccccc7)cc(c63)B5c3cccc5c6c7ccccc7ccc6n-4c35)nc(-c3c(C)cc(C)cc3C)n2)c(C)c1 ; c1ccc(-c2ccccc2-c2cc3c4c(c2)c2c5c6ccccc6c6ccccc6c5ccc2n4-c2cc(-c4nc(-n5c6ccccc6c6ccccc65)nc(-n5c6ccccc6c6ccccc65)n4)cc4c2B3c2cc3ccccc3c3c5ccccc5n-4c23)cc1 ; c1ccc(-c2ccccc2-c2cc3c4c(c2)c2c5c6ccccc6c6ccccc6c5ccc2n4-c2cc(-c4c(-c5cccc6c5oc5ccccc56)cccc4-c4cccc5c4oc4ccccc45)cc4c2B3c2cc3ccccc3c3c5ccccc5n-4c23)cc1]

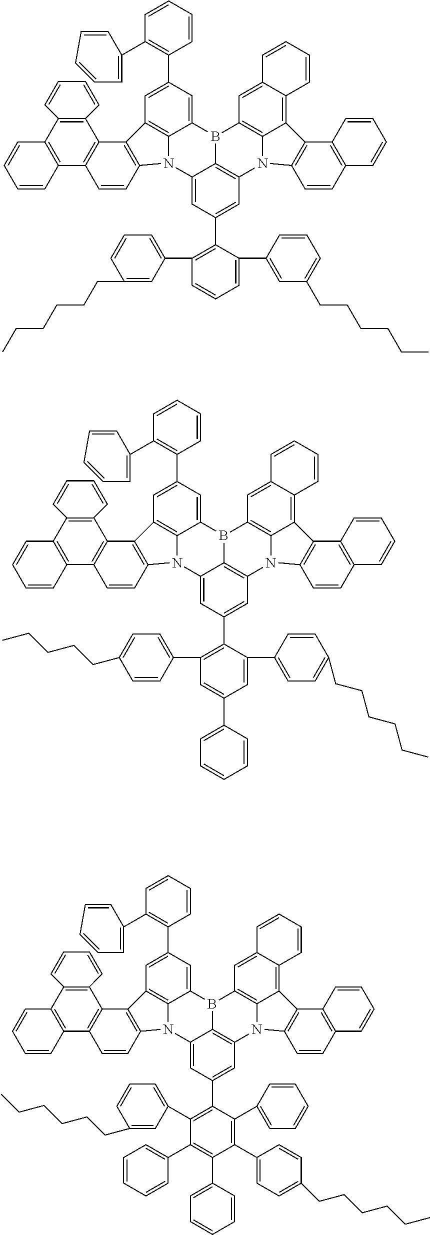

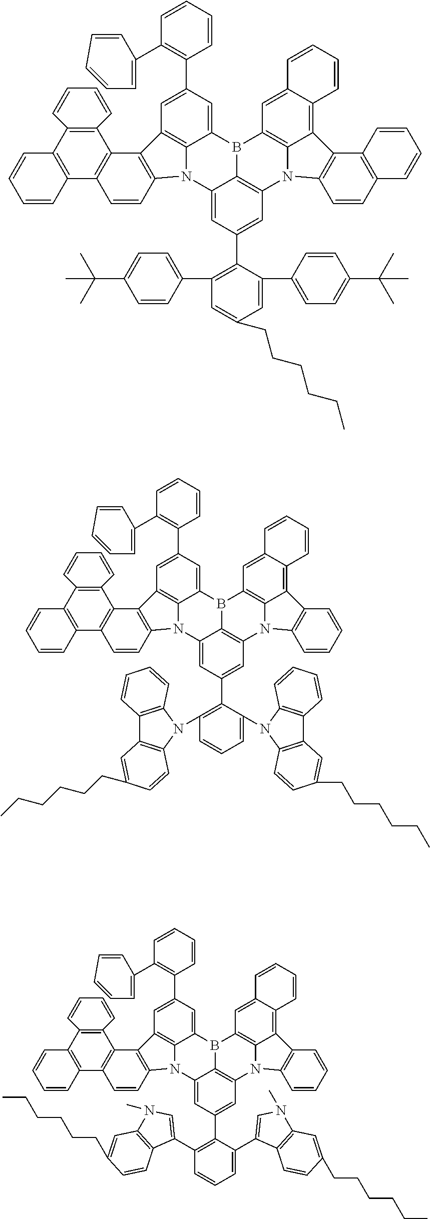

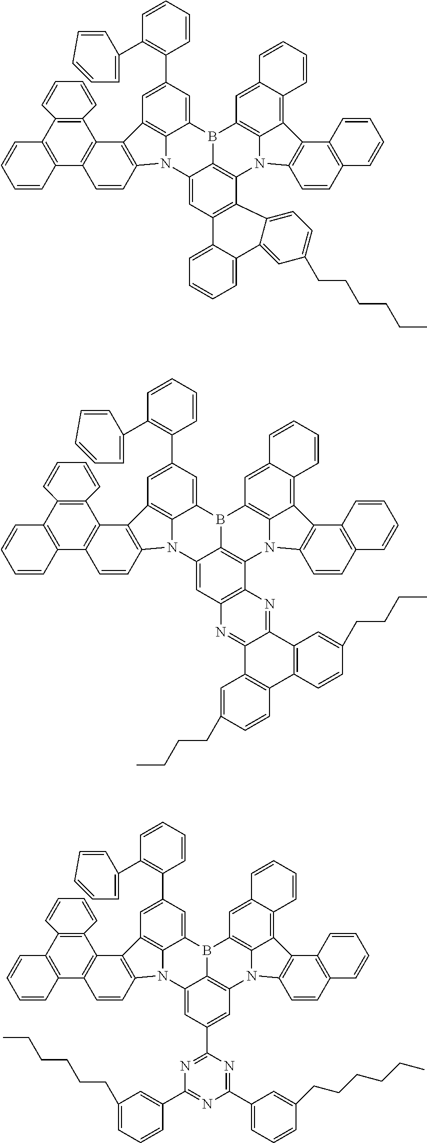

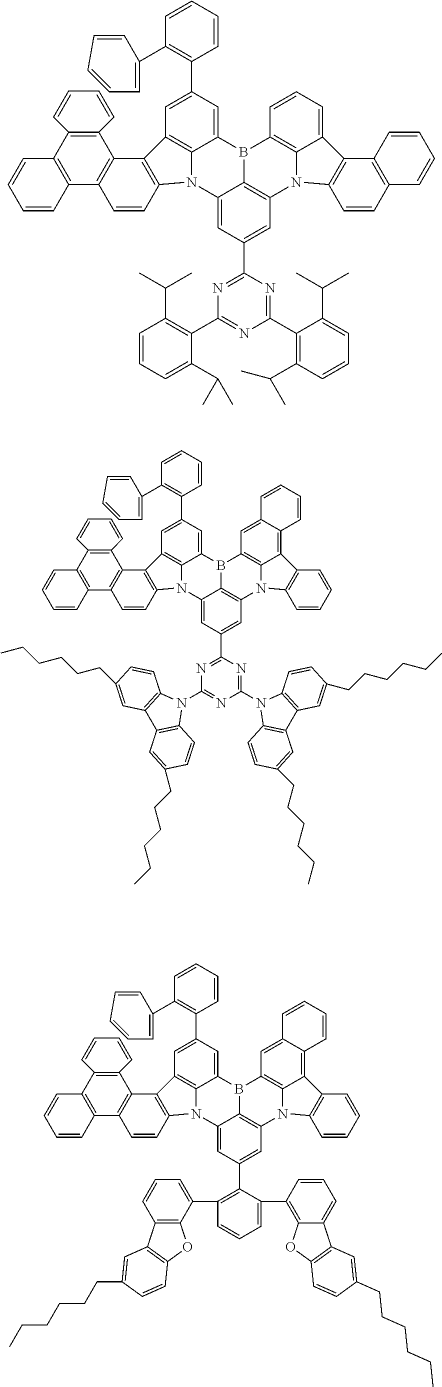

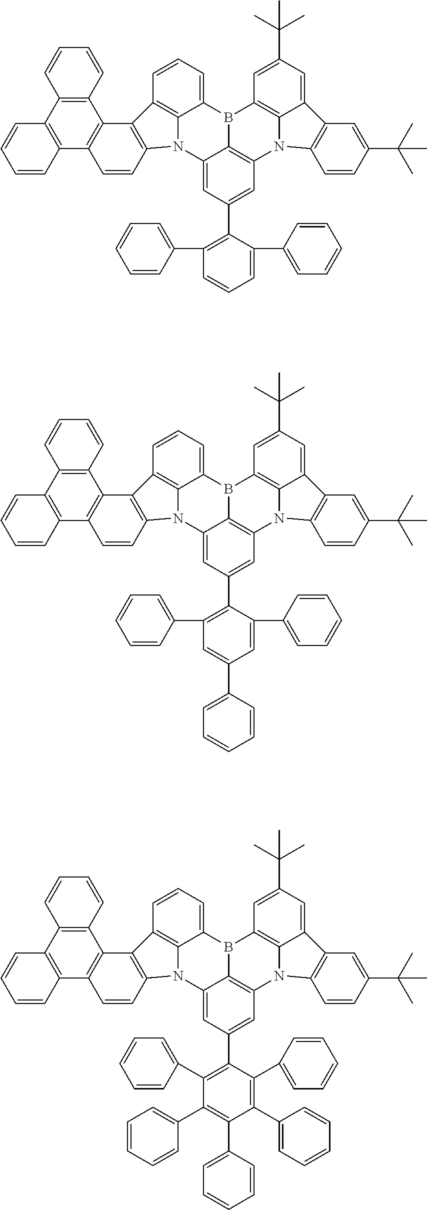

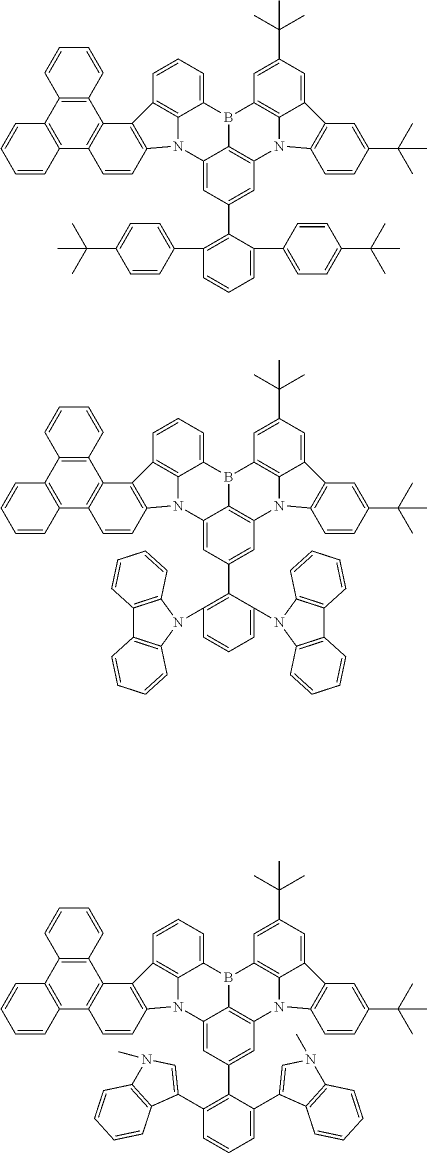 [SMILES: CC(C)(C)c1ccc(-c2cccc(-c3ccc(C(C)(C)C)cc3)c2-c2cc3c4c(c2)-n2c5ccc6c7ccccc7c7ccccc7c6c5c5cccc(c52)B4c2cc(C(C)(C)C)cc4c5cc(C(C)(C)C)ccc5n-3c24)cc1 ; CC(C)(C)c1ccc2c(c1)c1cc(C(C)(C)C)cc3c1n2-c1cc(-c2c(-n4c5ccccc5c5ccccc54)cccc2-n2c4ccccc4c4ccccc42)cc2c1B3c1cccc3c4c5c6ccccc6c6ccccc6c5ccc4n-2c13 ; Cn1cc(-c2cccc(-c3cn(C)c4ccccc34)c2-c2cc3c4c(c2)-n2c5ccc6c7ccccc7c7ccccc7c6c5c5cccc(c52)B4c2cc(C(C)(C)C)cc4c5cc(C(C)(C)C)ccc5n-3c24)c2ccccc21]

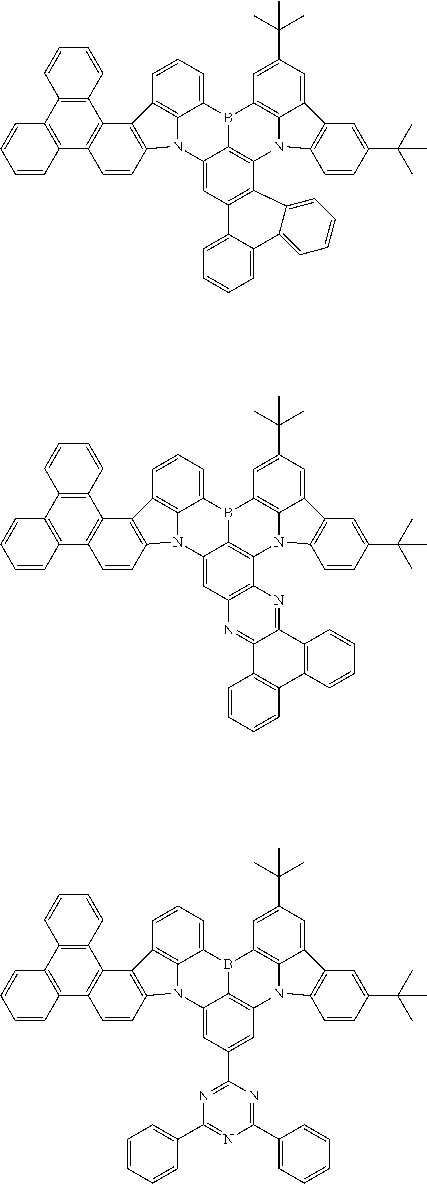 [SMILES: CC(C)(C)c1ccc2c(c1)c1cc(C(C)(C)C)cc3c1n2-c1c2c(cc4c5ccccc5c5ccccc5c14)-n1c4ccc5c6ccccc6c6ccccc6c5c4c4cccc(c41)B23 ; CC(C)(C)c1ccc2c(c1)c1cc(C(C)(C)C)cc3c1n2-c1c2c(cc4nc5c6ccccc6c6ccccc6c5nc14)-n1c4ccc5c6ccccc6c6ccccc6c5c4c4cccc(c41)B23 ; CC(C)(C)c1ccc2c(c1)c1cc(C(C)(C)C)cc3c1n2-c1cc(-c2nc(-c4ccccc4)nc(-c4ccccc4)n2)cc2c1B3c1cccc3c4c5c6ccccc6c6ccccc6c5ccc4n-2c13]

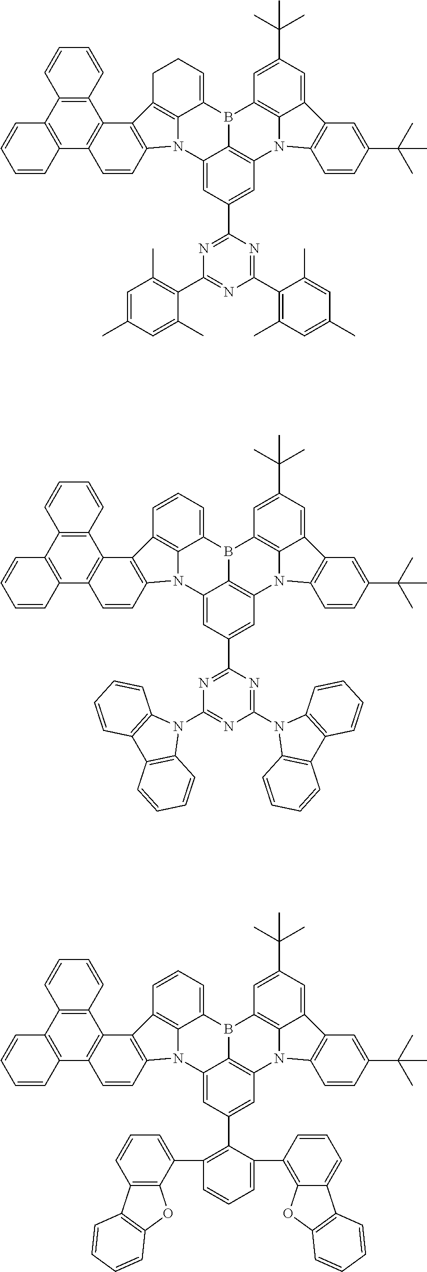 [SMILES: Cc1cc(C)c(-c2nc(-c3cc4c5c(c3)-n3c6ccc(C(C)(C)C)cc6c6cc(C(C)(C)C)cc(c63)B5C3=CCCc5c3n-4c3ccc4c6ccccc6c6ccccc6c4c53)nc(-c3c(C)cc(C)cc3C)n2)c(C)c1 ; CC(C)(C)c1ccc2c(c1)c1cc(C(C)(C)C)cc3c1n2-c1cc(-c2nc(-n4c5ccccc5c5ccccc54)nc(-n4c5ccccc5c5ccccc54)n2)cc2c1B3c1cccc3c4c5c6ccccc6c6ccccc6c5ccc4n-2c13 ; CC(C)(C)c1ccc2c(c1)c1cc(C(C)(C)C)cc3c1n2-c1cc(-c2c(-c4cccc5c4oc4ccccc45)cccc2-c2cccc4c2oc2ccccc24)cc2c1B3c1cccc3c4c5c6ccccc6c6ccccc6c5ccc4n-2c13]

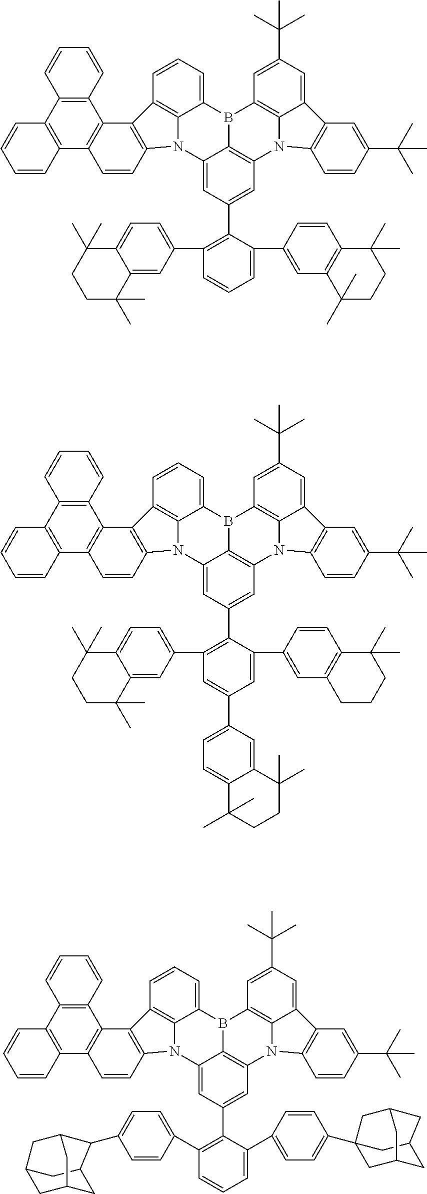

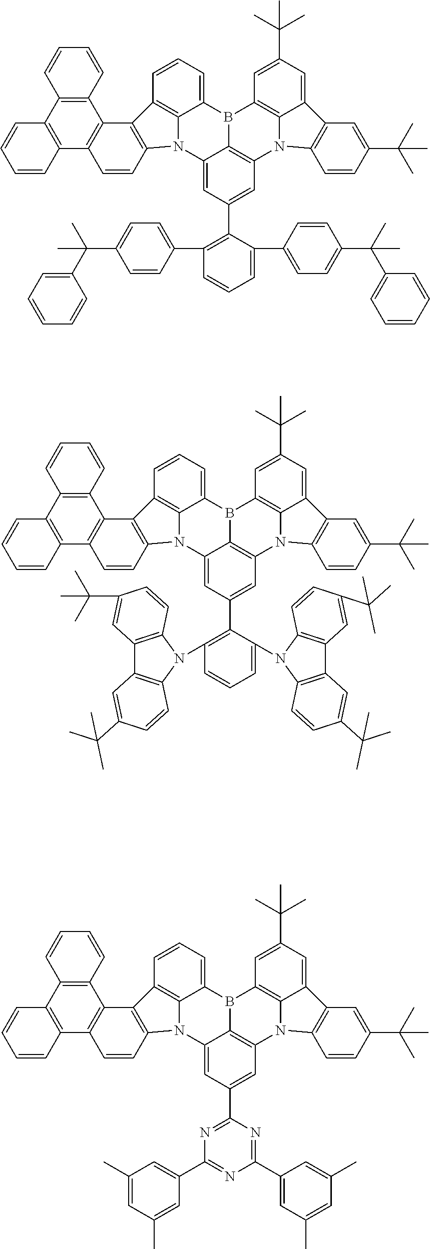 [SMILES: CC(C)(C)c1ccc2c(c1)c1cc(C(C)(C)C)cc3c1n2-c1cc(-c2c(-c4ccc(C(C)(C)c5ccccc5)cc4)cccc2-c2ccc(C(C)(C)c4ccccc4)cc2)cc2c1B3c1cccc3c4c5c6ccccc6c6ccccc6c5ccc4n-2c13 ; CC(C)(C)c1ccc2c(c1)c1cc(C(C)(C)C)ccc1n2-c1cccc(-n2c3ccc(C(C)(C)C)cc3c3cc(C(C)(C)C)ccc32)c1-c1cc2c3c(c1)-n1c4ccc5c6ccccc6c6ccccc6c5c4c4cccc(c41)B3c1cc(C(C)(C)C)cc3c4cc(C(C)(C)C)ccc4n-2c13 ; Cc1cc(C)cc(-c2nc(-c3cc(C)cc(C)c3)nc(-c3cc4c5c(c3)-n3c6ccc7c8ccccc8c8ccccc8c7c6c6cccc(c63)B5c3cc(C(C)(C)C)cc5c6cc(C(C)(C)C)ccc6n-4c35)n2)c1]

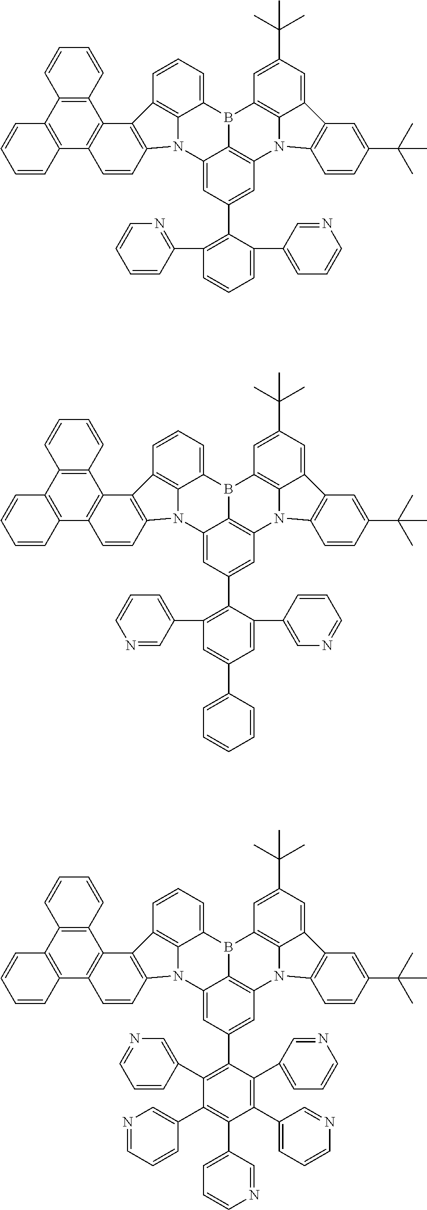

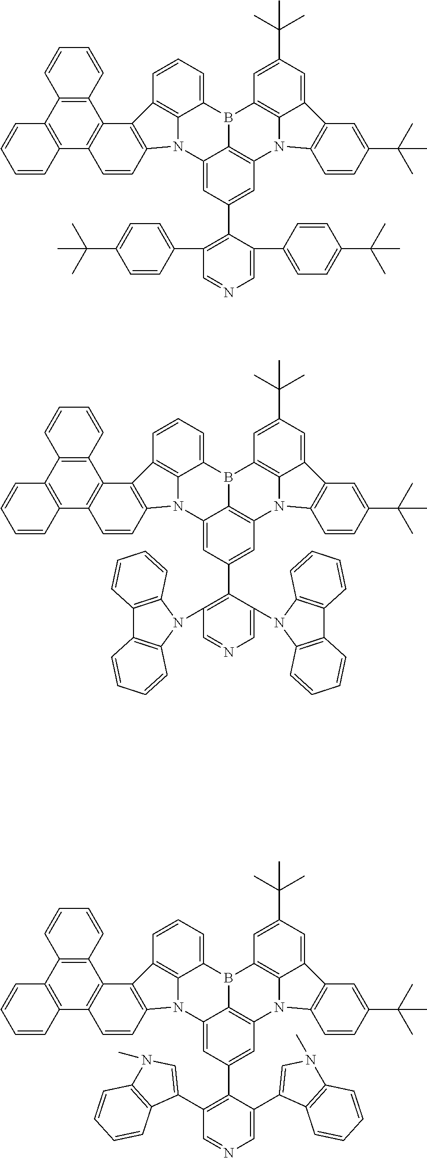 [SMILES: CC(C)(C)c1ccc(-c2cncc(-c3ccc(C(C)(C)C)cc3)c2-c2cc3c4c(c2)-n2c5ccc6c7ccccc7c7ccccc7c6c5c5cccc(c52)B4c2cc(C(C)(C)C)cc4c5cc(C(C)(C)C)ccc5n-3c24)cc1 ; CC(C)(C)c1ccc2c(c1)c1cc(C(C)(C)C)cc3c1n2-c1cc(-c2c(-n4c5ccccc5c5ccccc54)cncc2-n2c4ccccc4c4ccccc42)cc2c1B3c1cccc3c4c5c6ccccc6c6ccccc6c5ccc4n-2c13 ; Cn1cc(-c2cncc(-c3cn(C)c4ccccc34)c2-c2cc3c4c(c2)-n2c5ccc6c7ccccc7c7ccccc7c6c5c5cccc(c52)B4c2cc(C(C)(C)C)cc4c5cc(C(C)(C)C)ccc5n-3c24)c2ccccc21]

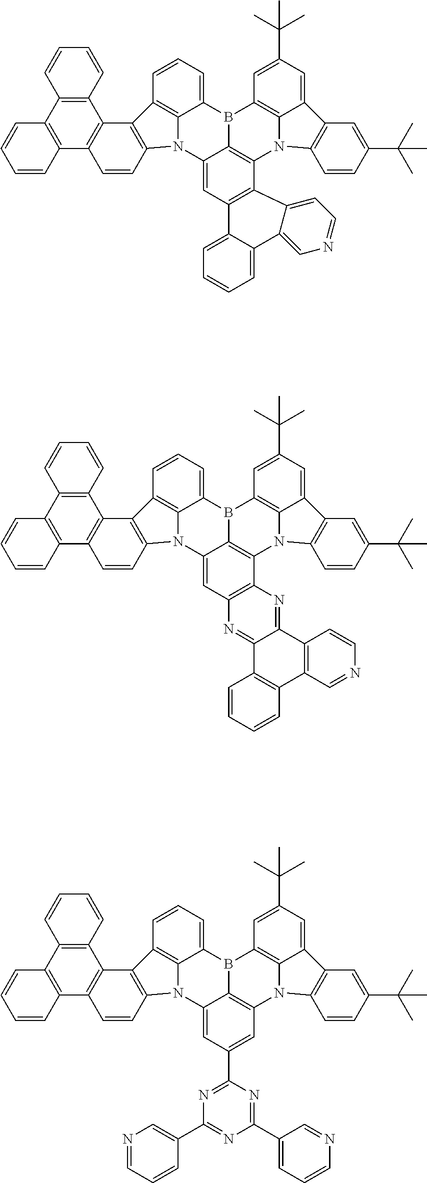 [SMILES: CC(C)(C)c1ccc2c(c1)c1cc(C(C)(C)C)cc3c1n2-c1c2c(cc4c5ccccc5c5cnccc5c14)-n1c4ccc5c6ccccc6c6ccccc6c5c4c4cccc(c41)B23 ; CC(C)(C)c1ccc2c(c1)c1cc(C(C)(C)C)cc3c1n2-c1c2c(cc4nc5c6ccccc6c6cnccc6c5nc14)-n1c4ccc5c6ccccc6c6ccccc6c5c4c4cccc(c41)B23 ; CC(C)(C)c1ccc2c(c1)c1cc(C(C)(C)C)cc3c1n2-c1cc(-c2nc(-c4cccnc4)nc(-c4cccnc4)n2)cc2c1B3c1cccc3c4c5c6ccccc6c6ccccc6c5ccc4n-2c13]

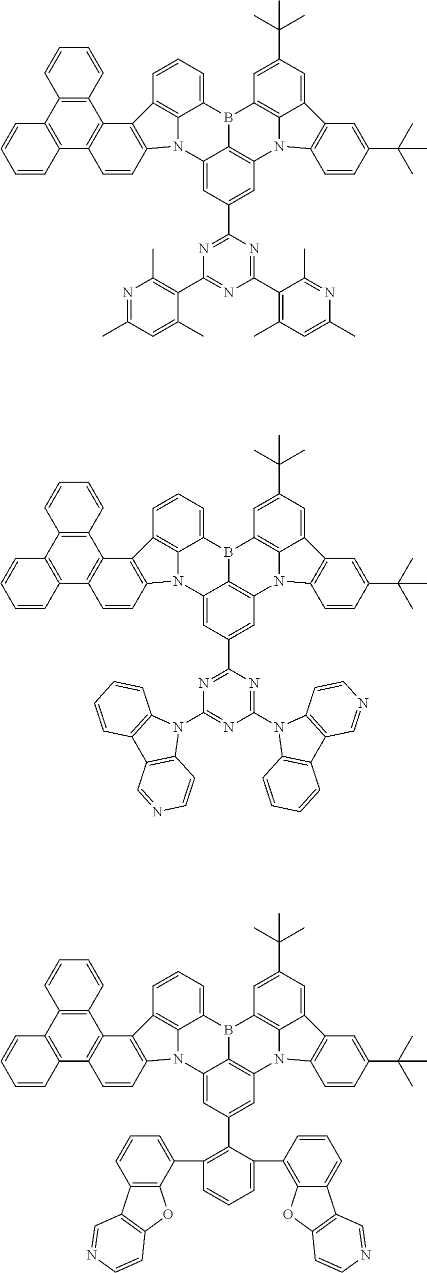 [SMILES: Cc1cc(C)c(-c2nc(-c3cc4c5c(c3)-n3c6ccc7c8ccccc8c8ccccc8c7c6c6cccc(c63)B5c3cc(C(C)(C)C)cc5c6cc(C(C)(C)C)ccc6n-4c35)nc(-c3c(C)cc(C)nc3C)n2)c(C)n1 ; CC(C)(C)c1ccc2c(c1)c1cc(C(C)(C)C)cc3c1n2-c1cc(-c2nc(-n4c5ccccc5c5cnccc54)nc(-n4c5ccccc5c5cnccc54)n2)cc2c1B3c1cccc3c4c5c6ccccc6c6ccccc6c5ccc4n-2c13 ; CC(C)(C)c1ccc2c(c1)c1cc(C(C)(C)C)cc3c1n2-c1cc(-c2c(-c4cccc5c4oc4ccncc45)cccc2-c2cccc4c2oc2ccncc24)cc2c1B3c1cccc3c4c5c6ccccc6c6ccccc6c5ccc4n-2c13]

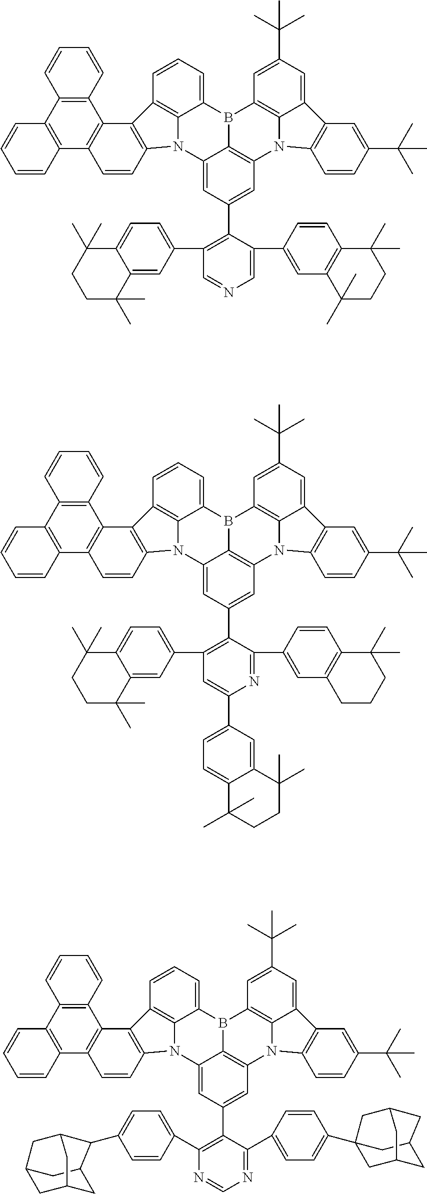

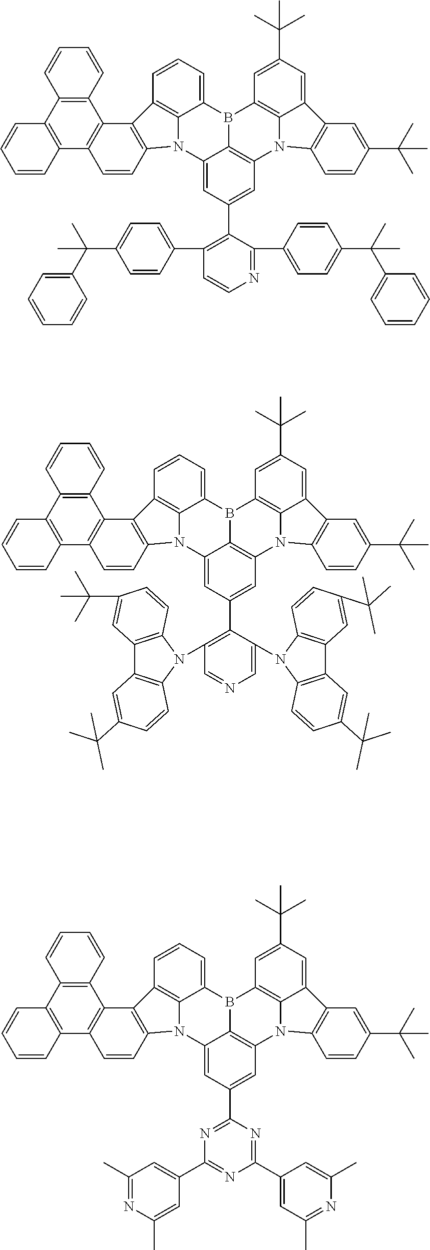 [SMILES: CC(C)(C)c1ccc2c(c1)c1cc(C(C)(C)C)cc3c1n2-c1cc(-c2c(-c4ccc(C(C)(C)c5ccccc5)cc4)ccnc2-c2ccc(C(C)(C)c4ccccc4)cc2)cc2c1B3c1cccc3c4c5c6ccccc6c6ccccc6c5ccc4n-2c13 ; CC(C)(C)c1ccc2c(c1)c1cc(C(C)(C)C)ccc1n2-c1cncc(-n2c3ccc(C(C)(C)C)cc3c3cc(C(C)(C)C)ccc32)c1-c1cc2c3c(c1)-n1c4ccc5c6ccccc6c6ccccc6c5c4c4cccc(c41)B3c1cc(C(C)(C)C)cc3c4cc(C(C)(C)C)ccc4n-2c13 ; Cc1cc(-c2nc(-c3cc(C)nc(C)c3)nc(-c3cc4c5c(c3)-n3c6ccc7c8ccccc8c8ccccc8c7c6c6cccc(c63)B5c3cc(C(C)(C)C)cc5c6cc(C(C)(C)C)ccc6n-4c35)n2)cc(C)n1]

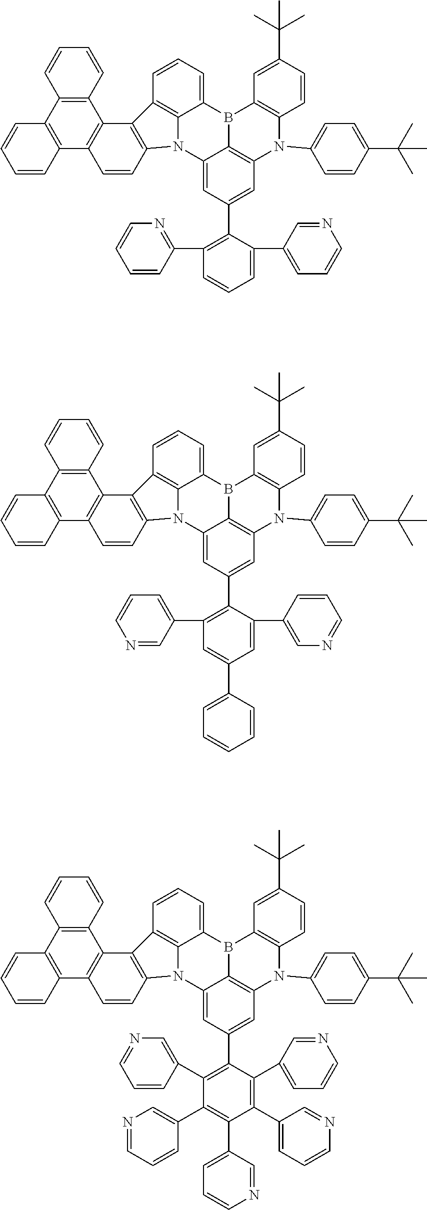

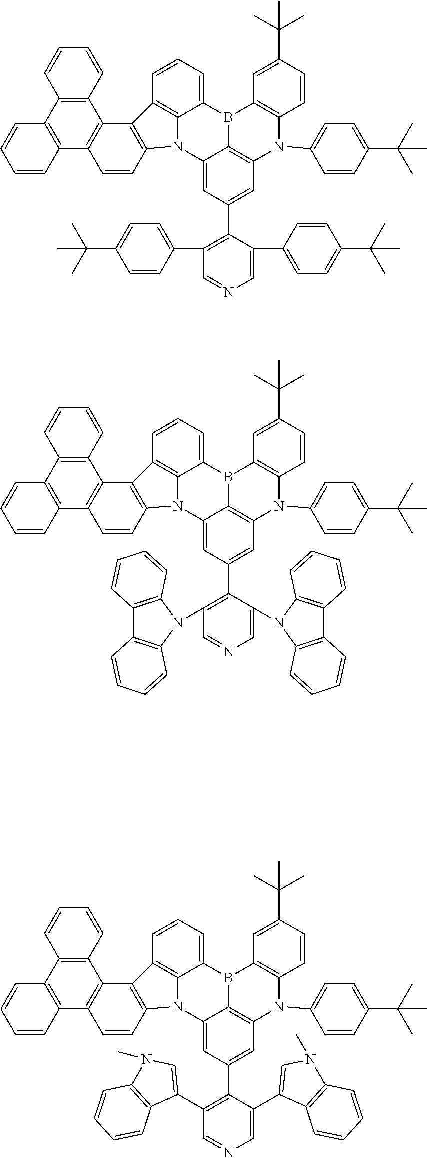 [SMILES: CC(C)(C)c1ccc(-c2cncc(-c3ccc(C(C)(C)C)cc3)c2-c2cc3c4c(c2)-n2c5ccc6c7ccccc7c7ccccc7c6c5c5cccc(c52)B4c2cc(C(C)(C)C)ccc2N3c2ccc(C(C)(C)C)cc2)cc1 ; CC(C)(C)c1ccc(N2c3ccc(C(C)(C)C)cc3B3c4c2cc(-c2c(-n5c6ccccc6c6ccccc65)cncc2-n2c5ccccc5c5ccccc52)cc4-n2c4ccc5c6ccccc6c6ccccc6c5c4c4cccc3c42)cc1 ; Cn1cc(-c2cncc(-c3cn(C)c4ccccc34)c2-c2cc3c4c(c2)-n2c5ccc6c7ccccc7c7ccccc7c6c5c5cccc(c52)B4c2cc(C(C)(C)C)ccc2N3c2ccc(C(C)(C)C)cc2)c2ccccc21]

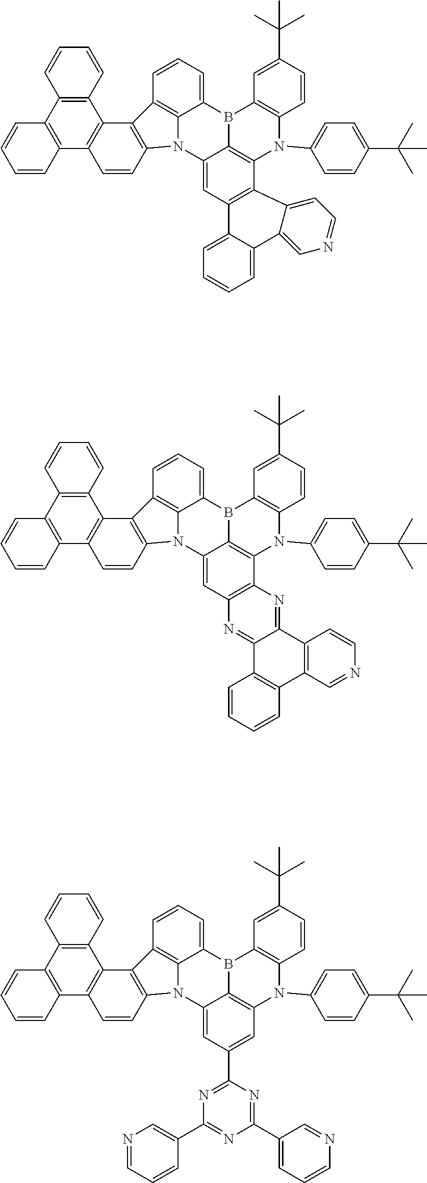 [SMILES: CC(C)(C)c1ccc(N2c3ccc(C(C)(C)C)cc3B3c4c(cc5c6ccccc6c6cnccc6c5c42)-n2c4ccc5c6ccccc6c6ccccc6c5c4c4cccc3c42)cc1 ; CC(C)(C)c1ccc(N2c3ccc(C(C)(C)C)cc3B3c4c(cc5nc6c7ccccc7c7cnccc7c6nc5c42)-n2c4ccc5c6ccccc6c6ccccc6c5c4c4cccc3c42)cc1 ; CC(C)(C)c1ccc(N2c3ccc(C(C)(C)C)cc3B3c4c2cc(-c2nc(-c5cccnc5)nc(-c5cccnc5)n2)cc4-n2c4ccc5c6ccccc6c6ccccc6c5c4c4cccc3c42)cc1]

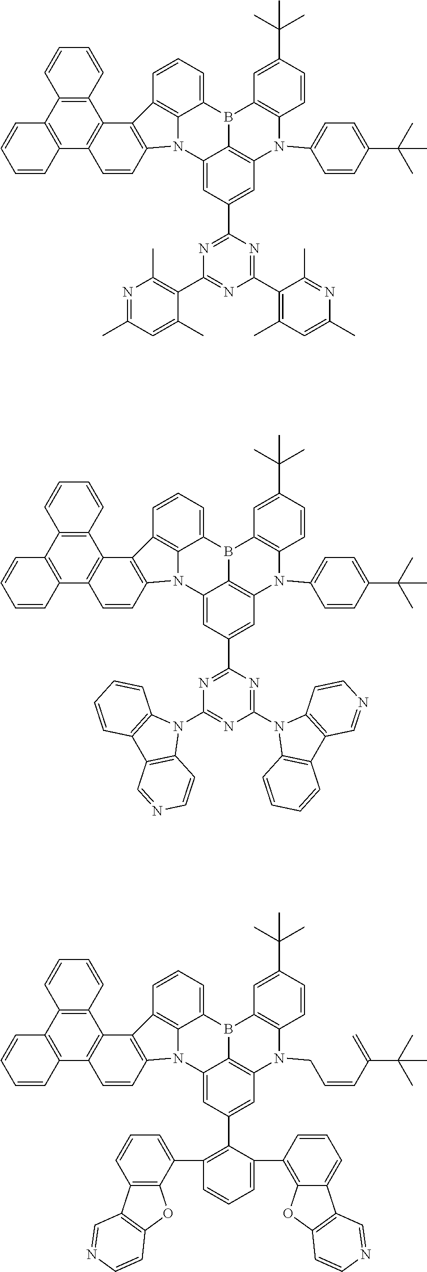 [SMILES: Cc1cc(C)c(-c2nc(-c3cc4c5c(c3)-n3c6ccc7c8ccccc8c8ccccc8c7c6c6cccc(c63)B5c3cc(C(C)(C)C)ccc3N4c3ccc(C(C)(C)C)cc3)nc(-c3c(C)cc(C)nc3C)n2)c(C)n1 ; CC(C)(C)c1ccc(N2c3ccc(C(C)(C)C)cc3B3c4c2cc(-c2nc(-n5c6ccccc6c6cnccc65)nc(-n5c6ccccc6c6cnccc65)n2)cc4-n2c4ccc5c6ccccc6c6ccccc6c5c4c4cccc3c42)cc1 ; C=C(/C=C\CN1c2ccc(C(C)(C)C)cc2B2c3c1cc(-c1c(-c4cccc5c4oc4ccncc45)cccc1-c1cccc4c1oc1ccncc14)cc3-n1c3ccc4c5ccccc5c5ccccc5c4c3c3cccc2c31)C(C)(C)C]

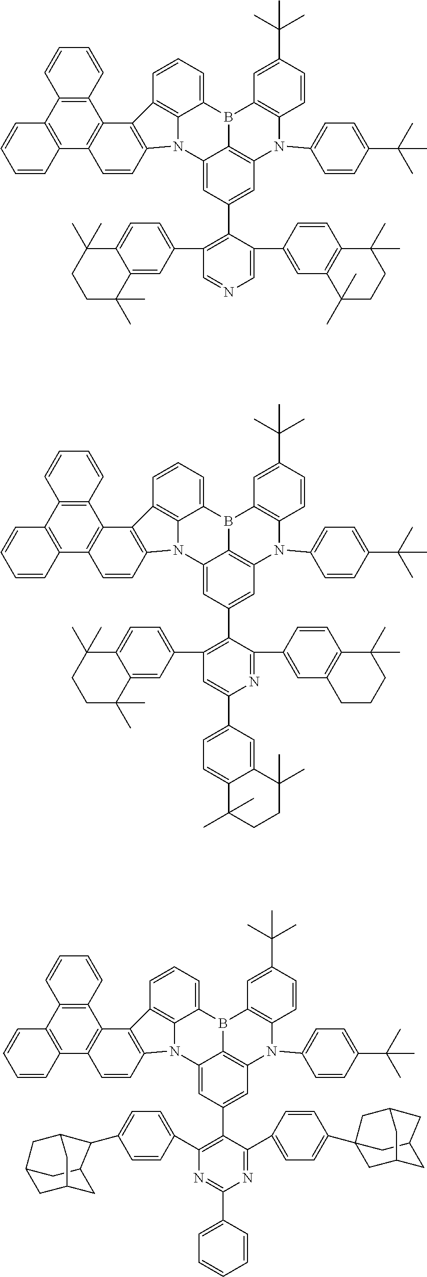

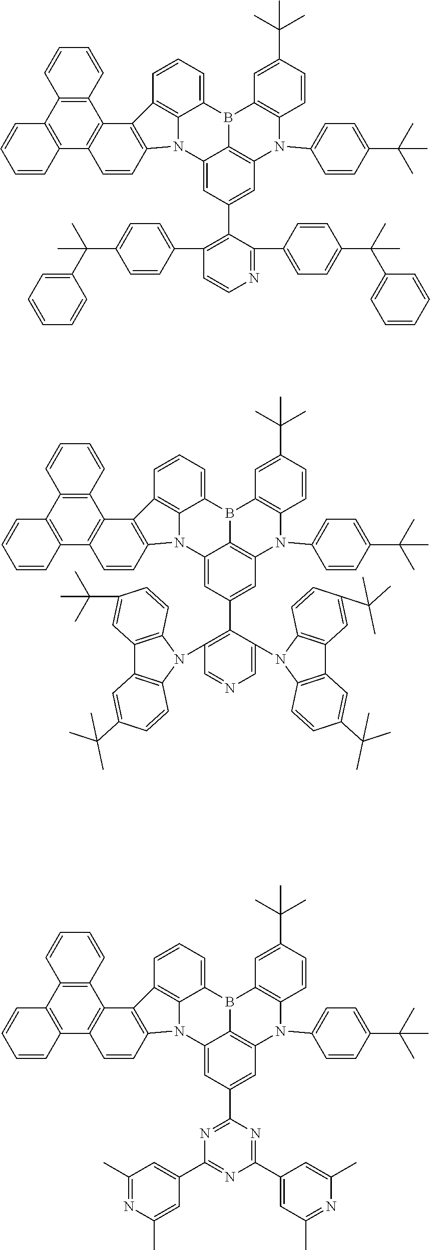 [SMILES: CC(C)(C)c1ccc(N2c3ccc(C(C)(C)C)cc3B3c4c2cc(-c2c(-c5ccc(C(C)(C)c6ccccc6)cc5)ccnc2-c2ccc(C(C)(C)c5ccccc5)cc2)cc4-n2c4ccc5c6ccccc6c6ccccc6c5c4c4cccc3c42)cc1 ; CC(C)(C)c1ccc(N2c3ccc(C(C)(C)C)cc3B3c4c2cc(-c2c(-n5c6ccc(C(C)(C)C)cc6c6cc(C(C)(C)C)ccc65)cncc2-n2c5ccc(C(C)(C)C)cc5c5cc(C(C)(C)C)ccc52)cc4-n2c4ccc5c6ccccc6c6ccccc6c5c4c4cccc3c42)cc1 ; Cc1cc(-c2nc(-c3cc(C)nc(C)c3)nc(-c3cc4c5c(c3)-n3c6ccc7c8ccccc8c8ccccc8c7c6c6cccc(c63)B5c3cc(C(C)(C)C)ccc3N4c3ccc(C(C)(C)C)cc3)n2)cc(C)n1]

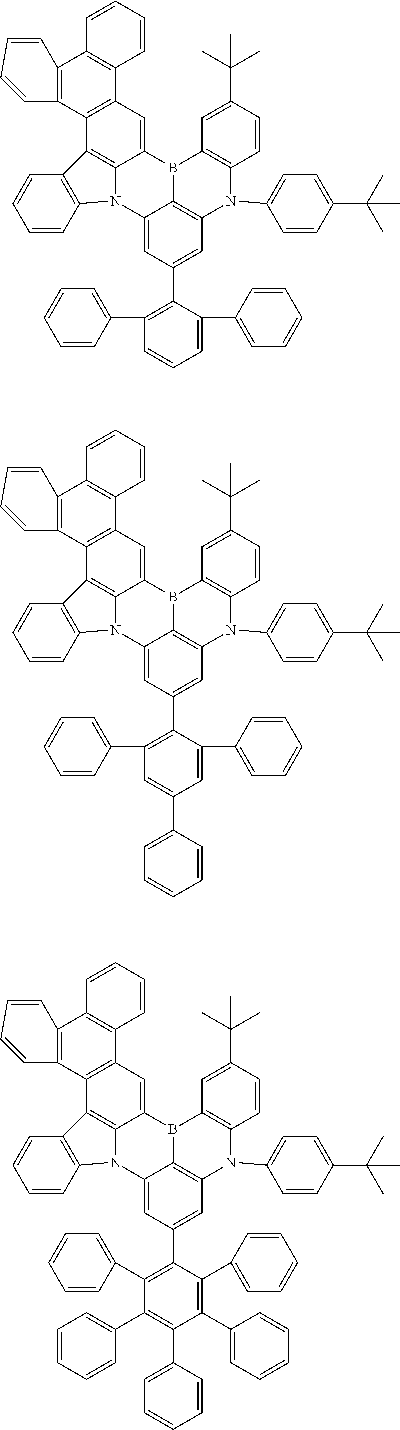 [SMILES: CC(C)(C)c1ccc(N2c3ccc(C(C)(C)C)cc3B3c4c2cc(-c2c(-c5ccccc5)cccc2-c2ccccc2)cc4-n2c4ccccc4c4c5c6ccccc6c6ccccc6c5cc3c42)cc1 ; CC(C)(C)c1ccc(N2c3ccc(C(C)(C)C)cc3B3c4c2cc(-c2c(-c5ccccc5)cc(-c5ccccc5)cc2-c2ccccc2)cc4-n2c4ccccc4c4c5c6ccccc6c6ccccc6c5cc3c42)cc1 ; CC(C)(C)c1ccc(N2c3ccc(C(C)(C)C)cc3B3c4c2cc(-c2c(-c5ccccc5)c(-c5ccccc5)c(-c5ccccc5)c(-c5ccccc5)c2-c2ccccc2)cc4-n2c4ccccc4c4c5c6ccccc6c6ccccc6c5cc3c42)cc1]

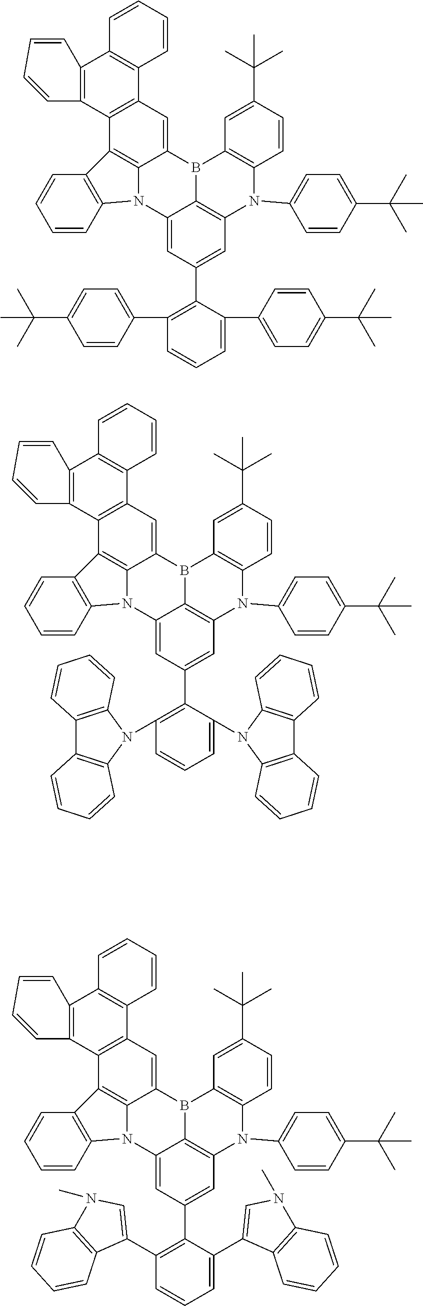 [SMILES: CC(C)(C)c1ccc(-c2cccc(-c3ccc(C(C)(C)C)cc3)c2-c2cc3c4c(c2)-n2c5ccccc5c5c6c7ccccc7c7ccccc7c6cc(c52)B4c2cc(C(C)(C)C)ccc2N3c2ccc(C(C)(C)C)cc2)cc1 ; CC(C)(C)c1ccc(N2c3ccc(C(C)(C)C)cc3B3c4c2cc(-c2c(-n5c6ccccc6c6ccccc65)cccc2-n2c5ccccc5c5ccccc52)cc4-n2c4ccccc4c4c5c6ccccc6c6ccccc6c5cc3c42)cc1 ; Cn1cc(-c2cccc(-c3cn(C)c4ccccc34)c2-c2cc3c4c(c2)-n2c5ccccc5c5c6c7ccccc7c7ccccc7c6cc(c52)B4c2cc(C(C)(C)C)ccc2N3c2ccc(C(C)(C)C)cc2)c2ccccc21]

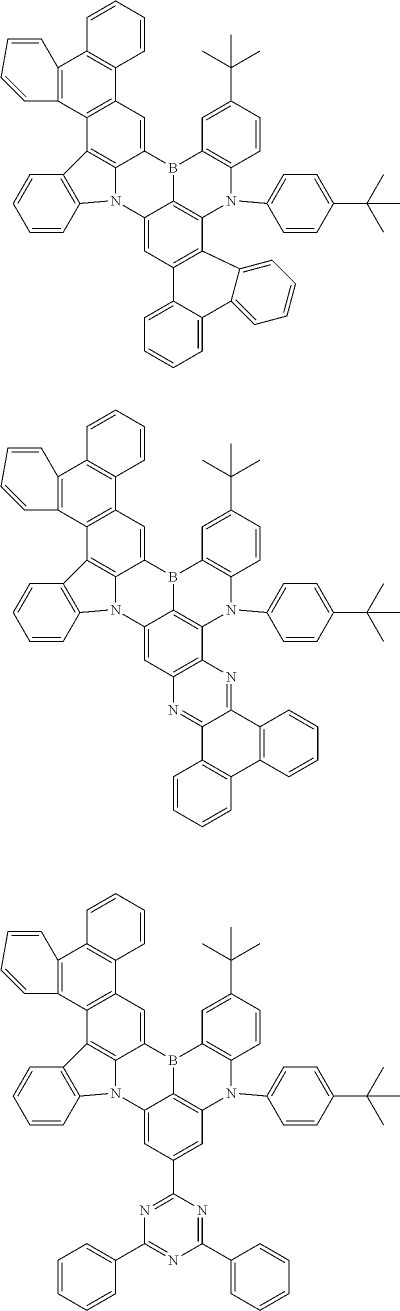 [SMILES: CC(C)(C)c1ccc(N2c3ccc(C(C)(C)C)cc3B3c4c(cc5c6ccccc6c6ccccc6c5c42)-n2c4ccccc4c4c5c6ccccc6c6ccccc6c5cc3c42)cc1 ; CC(C)(C)c1ccc(N2c3ccc(C(C)(C)C)cc3B3c4c(cc5nc6c7ccccc7c7ccccc7c6nc5c42)-n2c4ccccc4c4c5c6ccccc6c6ccccc6c5cc3c42)cc1 ; CC(C)(C)c1ccc(N2c3ccc(C(C)(C)C)cc3B3c4c2cc(-c2nc(-c5ccccc5)nc(-c5ccccc5)n2)cc4-n2c4ccccc4c4c5c6ccccc6c6ccccc6c5cc3c42)cc1]

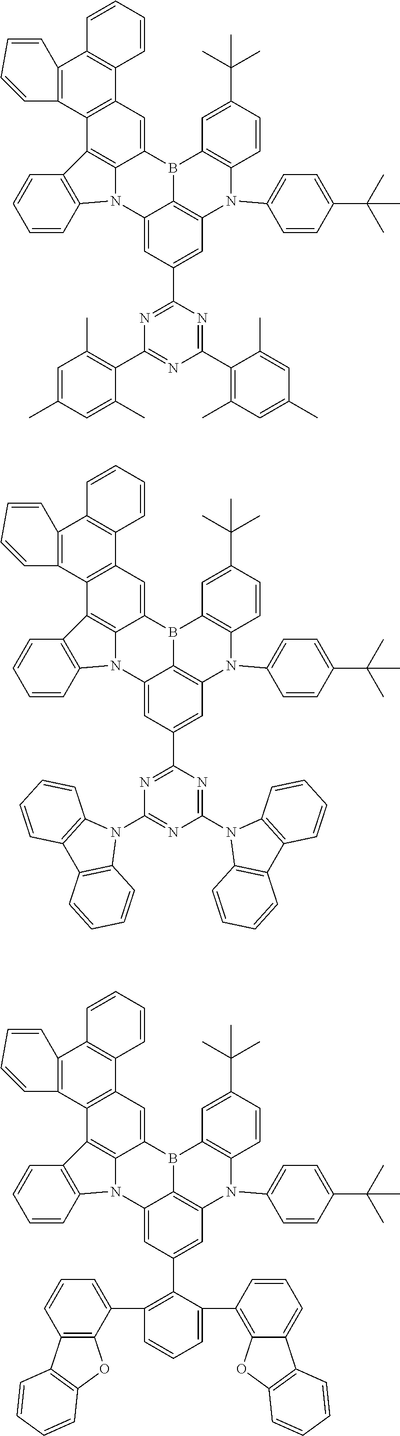 [SMILES: Cc1cc(C)c(-c2nc(-c3cc4c5c(c3)-n3c6ccccc6c6c7c8ccccc8c8ccccc8c7cc(c63)B5c3cc(C(C)(C)C)ccc3N4c3ccc(C(C)(C)C)cc3)nc(-c3c(C)cc(C)cc3C)n2)c(C)c1 ; CC(C)(C)c1ccc(N2c3ccc(C(C)(C)C)cc3B3c4c2cc(-c2nc(-n5c6ccccc6c6ccccc65)nc(-n5c6ccccc6c6ccccc65)n2)cc4-n2c4ccccc4c4c5c6ccccc6c6ccccc6c5cc3c42)cc1 ; CC(C)(C)c1ccc(N2c3ccc(C(C)(C)C)cc3B3c4c2cc(-c2c(-c5cccc6c5oc5ccccc56)cccc2-c2cccc5c2oc2ccccc25)cc4-n2c4ccccc4c4c5c6ccccc6c6ccccc6c5cc3c42)cc1]

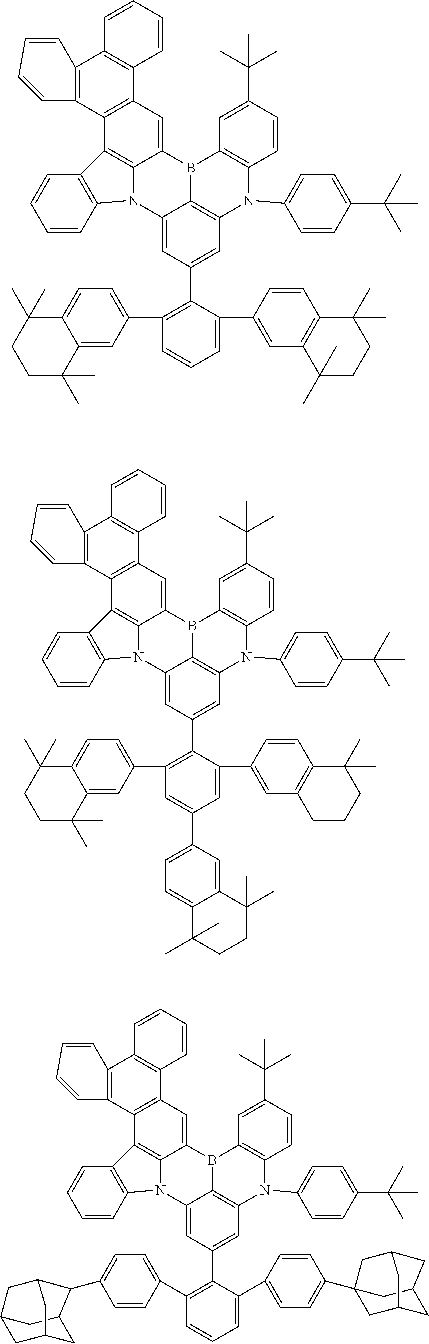

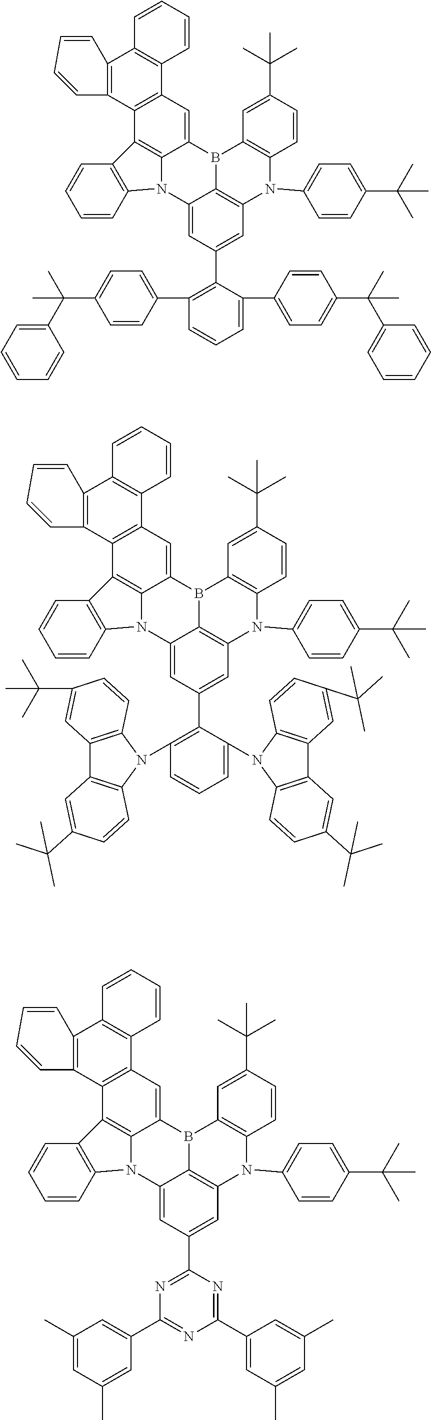 [SMILES: CC(C)(C)c1ccc(N2c3ccc(C(C)(C)C)cc3B3c4c2cc(-c2c(-c5ccc(C(C)(C)c6ccccc6)cc5)cccc2-c2ccc(C(C)(C)c5ccccc5)cc2)cc4-n2c4ccccc4c4c5c6ccccc6c6ccccc6c5cc3c42)cc1 ; CC(C)(C)c1ccc(N2c3ccc(C(C)(C)C)cc3B3c4c2cc(-c2c(-n5c6ccc(C(C)(C)C)cc6c6cc(C(C)(C)C)ccc65)cccc2-n2c5ccc(C(C)(C)C)cc5c5cc(C(C)(C)C)ccc52)cc4-n2c4ccccc4c4c5c6ccccc6c6ccccc6c5cc3c42)cc1 ; Cc1cc(C)cc(-c2nc(-c3cc(C)cc(C)c3)nc(-c3cc4c5c(c3)-n3c6ccccc6c6c7c8ccccc8c8ccccc8c7cc(c63)B5c3cc(C(C)(C)C)ccc3N4c3ccc(C(C)(C)C)cc3)n2)c1]

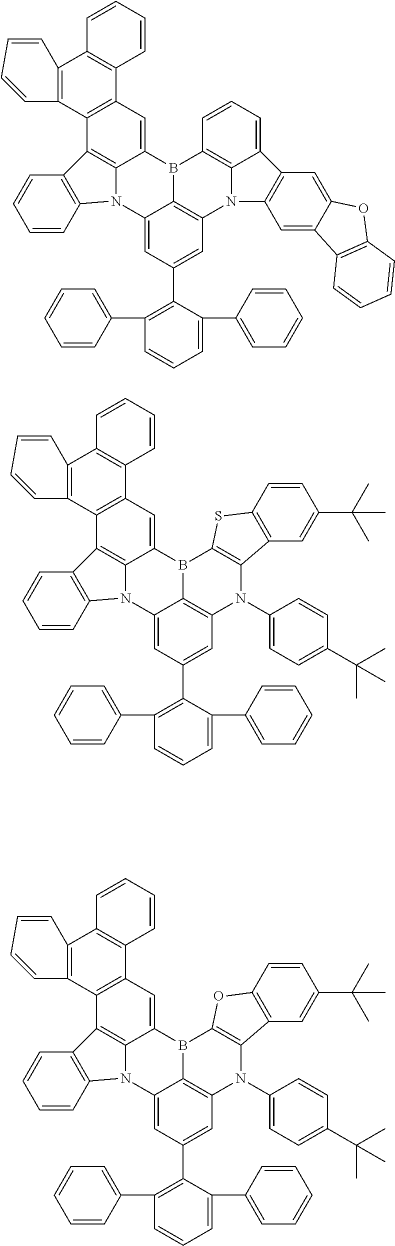 [SMILES: c1ccc(-c2cccc(-c3ccccc3)c2-c2cc3c4c(c2)-n2c5ccccc5c5c6c7ccccc7c7ccccc7c6cc(c52)B4c2cccc4c5cc6oc7ccccc7c6cc5n-3c24)cc1 ; CC(C)(C)c1ccc(N2c3cc(-c4c(-c5ccccc5)cccc4-c4ccccc4)cc4c3B(c3sc5ccc(C(C)(C)C)cc5c32)c2cc3c5ccccc5c5ccccc5c3c3c5ccccc5n-4c23)cc1 ; CC(C)(C)c1ccc(N2c3cc(-c4c(-c5ccccc5)cccc4-c4ccccc4)cc4c3B(c3oc5ccc(C(C)(C)C)cc5c32)c2cc3c5ccccc5c5ccccc5c3c3c5ccccc5n-4c23)cc1]

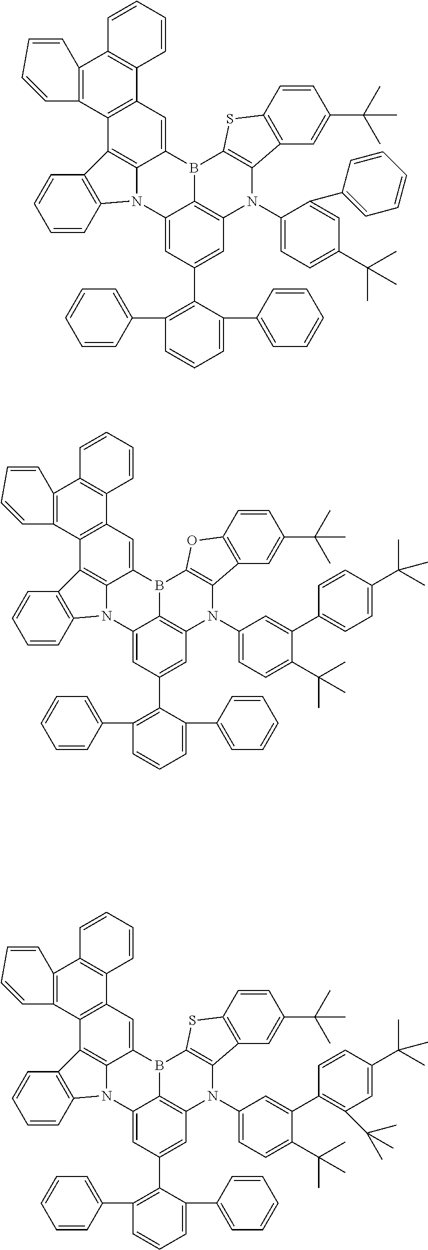 [SMILES: CC(C)(C)c1ccc(N2c3cc(-c4c(-c5ccccc5)cccc4-c4ccccc4)cc4c3B(c3sc5ccc(C(C)(C)C)cc5c32)c2cc3c5ccccc5c5ccccc5c3c3c5ccccc5n-4c23)c(-c2ccccc2)c1 ; CC(C)(C)c1ccc(-c2cc(N3c4cc(-c5c(-c6ccccc6)cccc5-c5ccccc5)cc5c4B(c4oc6ccc(C(C)(C)C)cc6c43)c3cc4c6ccccc6c6ccccc6c4c4c6ccccc6n-5c34)ccc2C(C)(C)C)cc1 ; CC(C)(C)c1ccc(-c2cc(N3c4cc(-c5c(-c6ccccc6)cccc5-c5ccccc5)cc5c4B(c4sc6ccc(C(C)(C)C)cc6c43)c3cc4c6ccccc6c6ccccc6c4c4c6ccccc6n-5c34)ccc2C(C)(C)C)c(C(C)(C)C)c1]

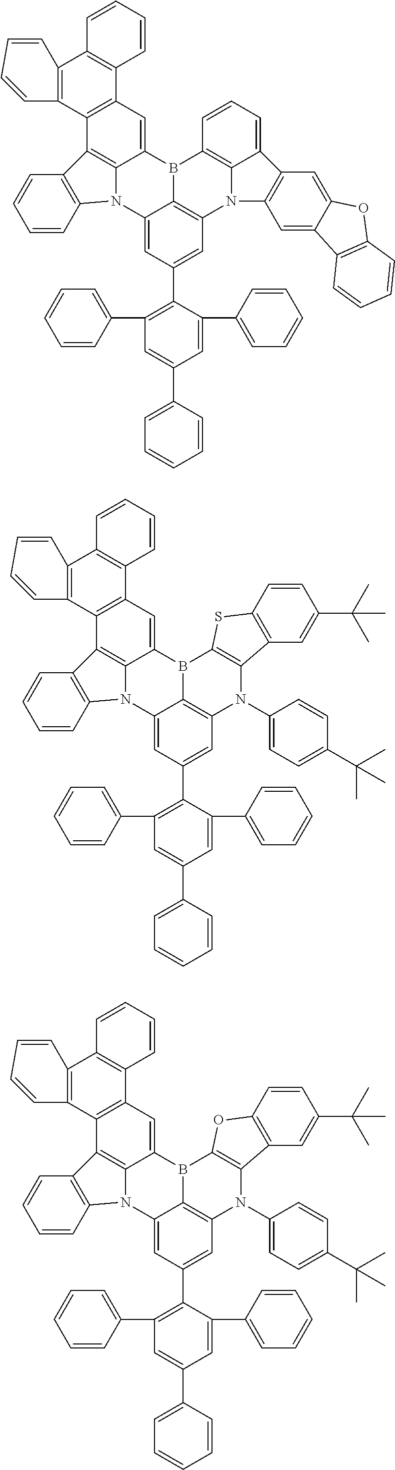 [SMILES: c1ccc(-c2cc(-c3ccccc3)c(-c3cc4c5c(c3)-n3c6ccccc6c6c7c8ccccc8c8ccccc8c7cc(c63)B5c3cccc5c6cc7oc8ccccc8c7cc6n-4c35)c(-c3ccccc3)c2)cc1 ; CC(C)(C)c1ccc(N2c3cc(-c4c(-c5ccccc5)cc(-c5ccccc5)cc4-c4ccccc4)cc4c3B(c3sc5ccc(C(C)(C)C)cc5c32)c2cc3c5ccccc5c5ccccc5c3c3c5ccccc5n-4c23)cc1 ; CC(C)(C)c1ccc(N2c3cc(-c4c(-c5ccccc5)cc(-c5ccccc5)cc4-c4ccccc4)cc4c3B(c3oc5ccc(C(C)(C)C)cc5c32)c2cc3c5ccccc5c5ccccc5c3c3c5ccccc5n-4c23)cc1]

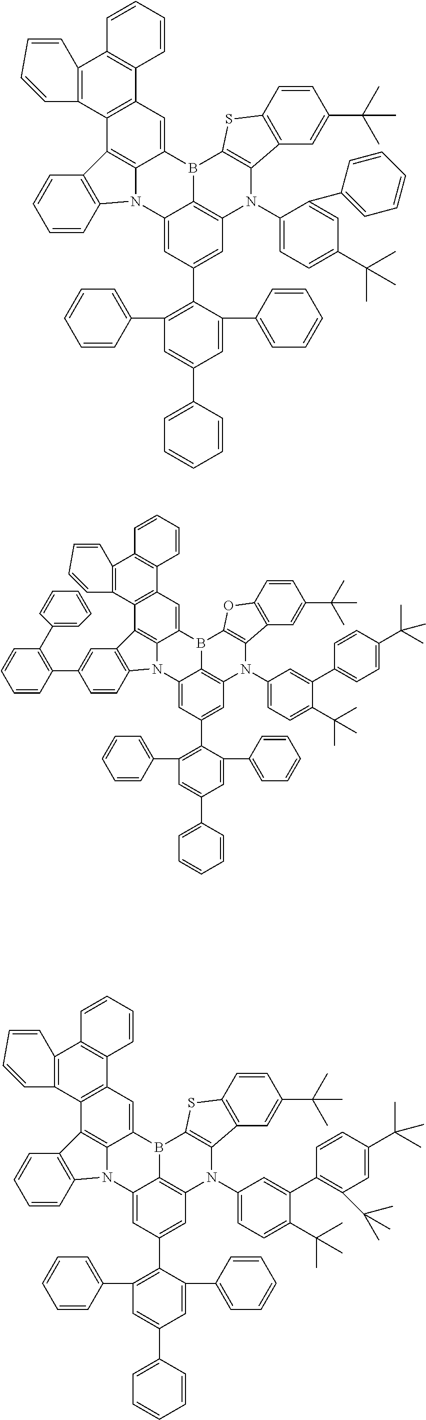 [SMILES: CC(C)(C)c1ccc(N2c3cc(-c4c(-c5ccccc5)cc(-c5ccccc5)cc4-c4ccccc4)cc4c3B(c3sc5ccc(C(C)(C)C)cc5c32)c2cc3c5ccccc5c5ccccc5c3c3c5ccccc5n-4c23)c(-c2ccccc2)c1 ; CC(C)(C)c1ccc(-c2cc(N3c4cc(-c5c(-c6ccccc6)cc(-c6ccccc6)cc5-c5ccccc5)cc5c4B(c4oc6ccc(C(C)(C)C)cc6c43)c3cc4c6ccccc6c6ccccc6c4c4c6cc(-c7ccccc7-c7ccccc7)ccc6n-5c34)ccc2C(C)(C)C)cc1 ; CC(C)(C)c1ccc(-c2cc(N3c4cc(-c5c(-c6ccccc6)cc(-c6ccccc6)cc5-c5ccccc5)cc5c4B(c4sc6ccc(C(C)(C)C)cc6c43)c3cc4c6ccccc6c6ccccc6c4c4c6ccccc6n-5c34)ccc2C(C)(C)C)c(C(C)(C)C)c1]

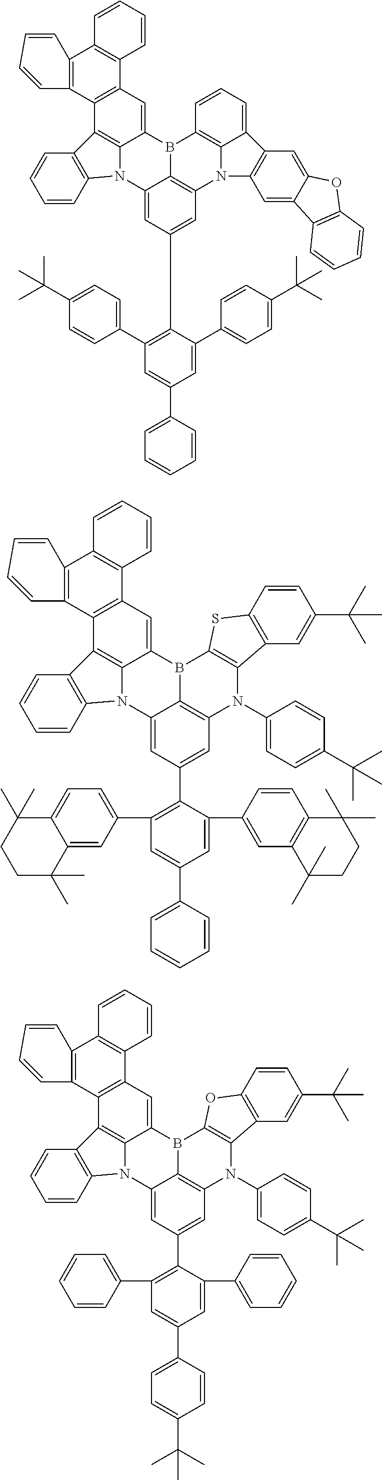

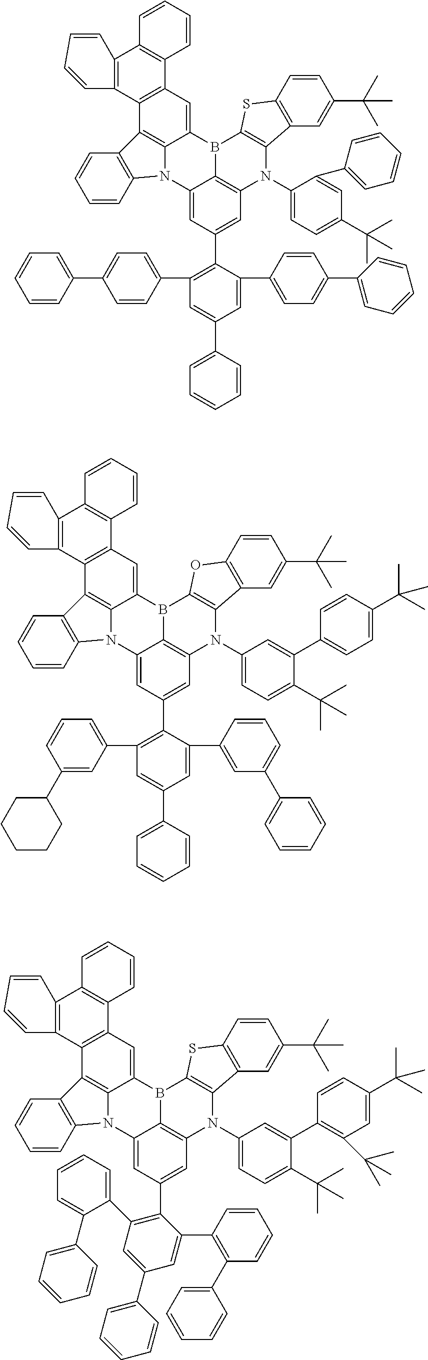

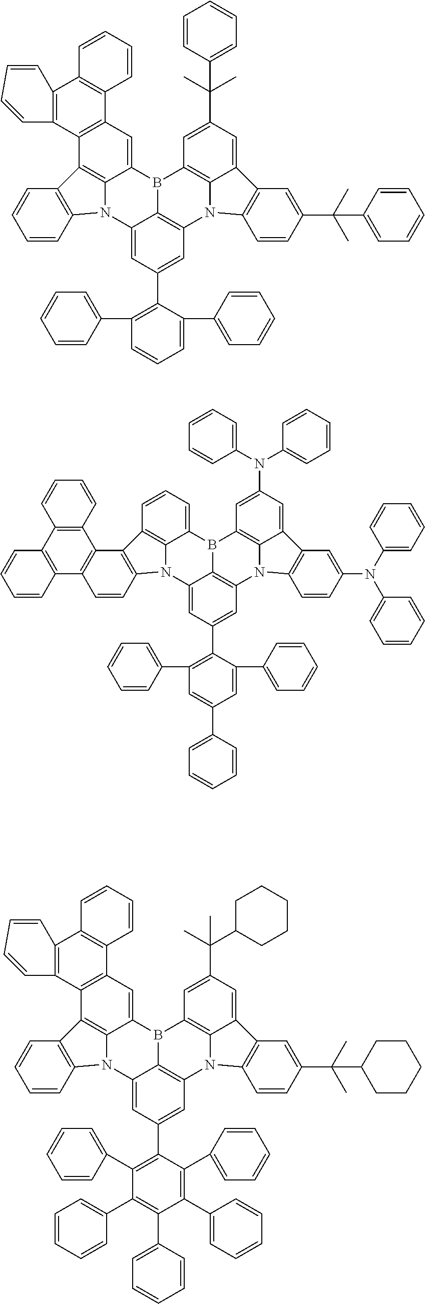 [SMILES: CC(C)(c1ccccc1)c1ccc2c(c1)c1cc(C(C)(C)c3ccccc3)cc3c1n2-c1cc(-c2c(-c4ccccc4)cccc2-c2ccccc2)cc2c1B3c1cc3c4ccccc4c4ccccc4c3c3c4ccccc4n-2c13 ; c1ccc(-c2cc(-c3ccccc3)c(-c3cc4c5c(c3)-n3c6ccc7c8ccccc8c8ccccc8c7c6c6cccc(c63)B5c3cc(N(c5ccccc5)c5ccccc5)cc5c6cc(N(c7ccccc7)c7ccccc7)ccc6n-4c35)c(-c3ccccc3)c2)cc1 ; CC(C)(c1ccc2c(c1)c1cc(C(C)(C)C3CCCCC3)cc3c1n2-c1cc(-c2c(-c4ccccc4)c(-c4ccccc4)c(-c4ccccc4)c(-c4ccccc4)c2-c2ccccc2)cc2c1B3c1cc3c4ccccc4c4ccccc4c3c3c4ccccc4n-2c13)C1CCCCC1]

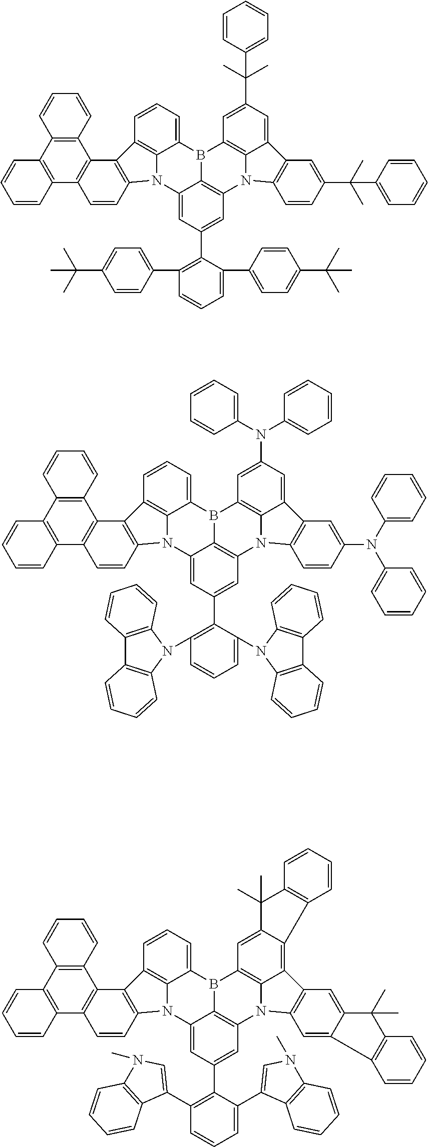 [SMILES: CC(C)(C)c1ccc(-c2cccc(-c3ccc(C(C)(C)C)cc3)c2-c2cc3c4c(c2)-n2c5ccc6c7ccccc7c7ccccc7c6c5c5cccc(c52)B4c2cc(C(C)(C)c4ccccc4)cc4c5cc(C(C)(C)c6ccccc6)ccc5n-3c24)cc1 ; c1ccc(N(c2ccccc2)c2ccc3c(c2)c2cc(N(c4ccccc4)c4ccccc4)cc4c2n3-c2cc(-c3c(-n5c6ccccc6c6ccccc65)cccc3-n3c5ccccc5c5ccccc53)cc3c2B4c2cccc4c5c6c7ccccc7c7ccccc7c6ccc5n-3c24)cc1 ; Cn1cc(-c2cccc(-c3cn(C)c4ccccc34)c2-c2cc3c4c(c2)-n2c5cc6c(cc5c5c7c(cc(c52)B4c2cccc4c5c8c9ccccc9c9ccccc9c8ccc5n-3c24)C(C)(C)c2ccccc2-7)C(C)(C)c2ccccc2-6)c2ccccc21]

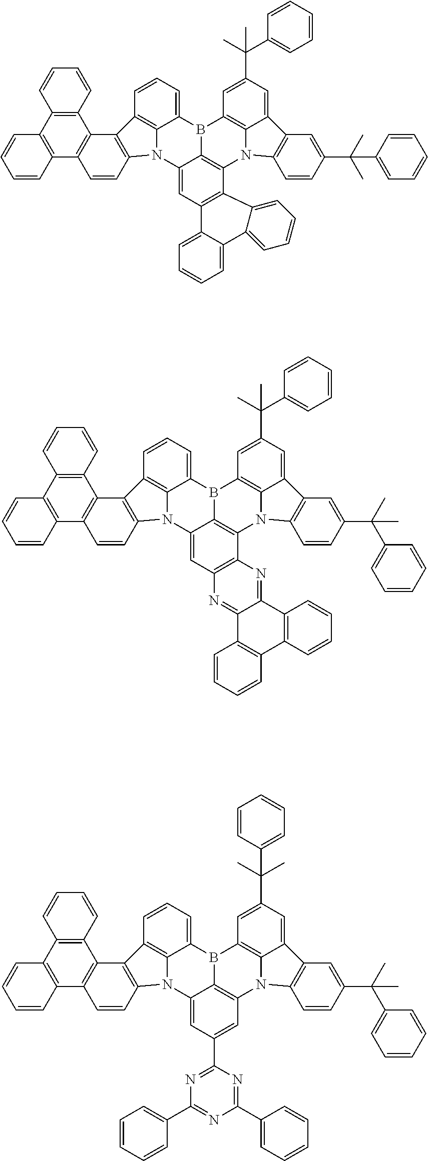 [SMILES: CC(C)(c1ccccc1)c1ccc2c(c1)c1cc(C(C)(C)c3ccccc3)cc3c1n2-c1c2c(cc4c5ccccc5c5ccccc5c14)-n1c4ccc5c6ccccc6c6ccccc6c5c4c4cccc(c41)B23 ; CC(C)(c1ccccc1)c1ccc2c(c1)c1cc(C(C)(C)c3ccccc3)cc3c1n2-c1c2c(cc4nc5c6ccccc6c6ccccc6c5nc14)-n1c4ccc5c6ccccc6c6ccccc6c5c4c4cccc(c41)B23 ; CC(C)(c1ccccc1)c1ccc2c(c1)c1cc(C(C)(C)c3ccccc3)cc3c1n2-c1cc(-c2nc(-c4ccccc4)nc(-c4ccccc4)n2)cc2c1B3c1cccc3c4c5c6ccccc6c6ccccc6c5ccc4n-2c13]

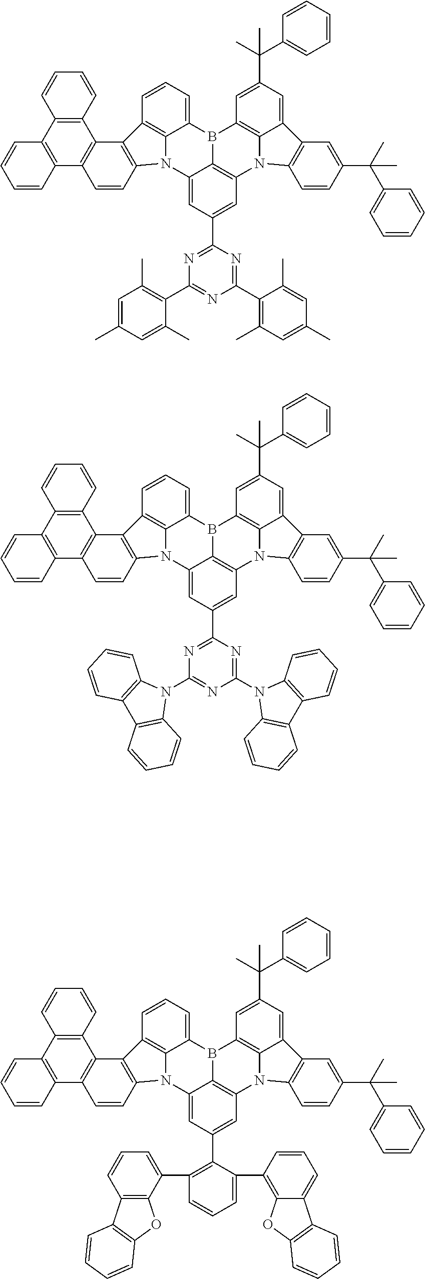 [SMILES: Cc1cc(C)c(-c2nc(-c3cc4c5c(c3)-n3c6ccc7c8ccccc8c8ccccc8c7c6c6cccc(c63)B5c3cc(C(C)(C)c5ccccc5)cc5c6cc(C(C)(C)c7ccccc7)ccc6n-4c35)nc(-c3c(C)cc(C)cc3C)n2)c(C)c1 ; CC(C)(c1ccccc1)c1ccc2c(c1)c1cc(C(C)(C)c3ccccc3)cc3c1n2-c1cc(-c2nc(-n4c5ccccc5c5ccccc54)nc(-n4c5ccccc5c5ccccc54)n2)cc2c1B3c1cccc3c4c5c6ccccc6c6ccccc6c5ccc4n-2c13 ; CC(C)(c1ccccc1)c1ccc2c(c1)c1cc(C(C)(C)c3ccccc3)cc3c1n2-c1cc(-c2c(-c4cccc5c4oc4ccccc45)cccc2-c2cccc4c2oc2ccccc24)cc2c1B3c1cccc3c4c5c6ccccc6c6ccccc6c5ccc4n-2c13]

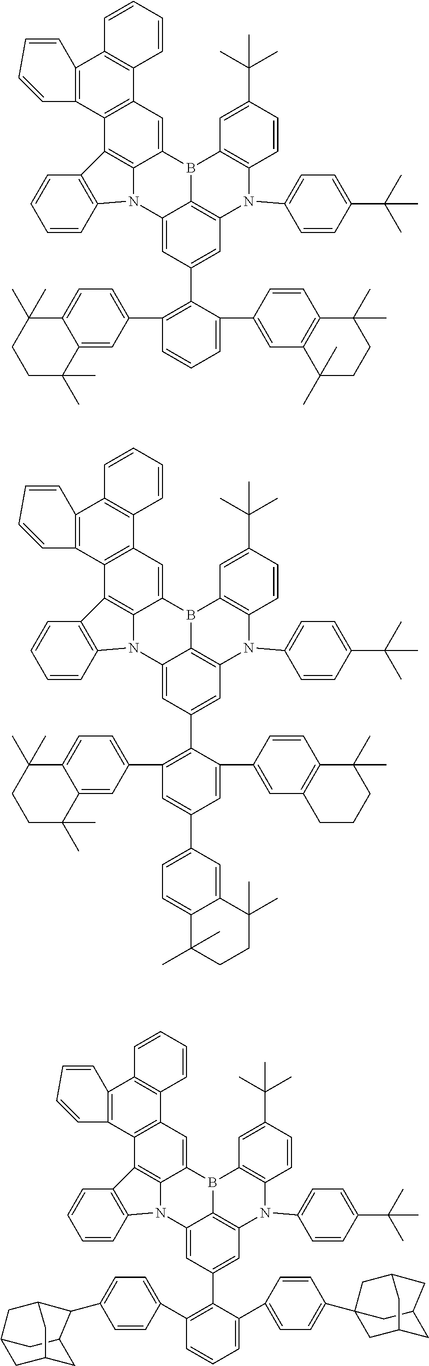

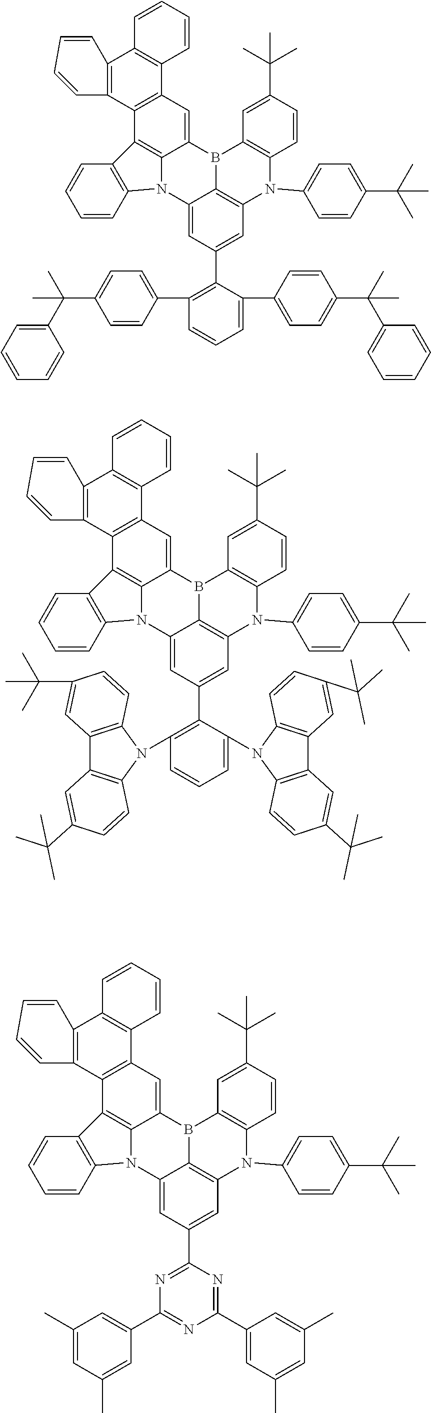 [SMILES: CC(C)(C)c1ccc(N2c3ccc(C(C)(C)C)cc3B3c4c2cc(-c2c(-c5ccc(C(C)(C)c6ccccc6)cc5)cccc2-c2ccc(C(C)(C)c5ccccc5)cc2)cc4-n2c4ccccc4c4c5c6ccccc6c6ccccc6c5cc3c42)cc1 ; CC(C)(C)c1ccc(N2c3ccc(C(C)(C)C)cc3B3c4c2cc(-c2c(-n5c6ccc(C(C)(C)C)cc6c6cc(C(C)(C)C)ccc65)cccc2-n2c5ccc(C(C)(C)C)cc5c5cc(C(C)(C)C)ccc52)cc4-n2c4ccccc4c4c5c6ccccc6c6ccccc6c5cc3c42)cc1 ; Cc1cc(C)cc(-c2nc(-c3cc(C)cc(C)c3)nc(-c3cc4c5c(c3)-n3c6ccccc6c6c7c8ccccc8c8ccccc8c7cc(c63)B5c3cc(C(C)(C)C)ccc3N4c3ccc(C(C)(C)C)cc3)n2)c1]

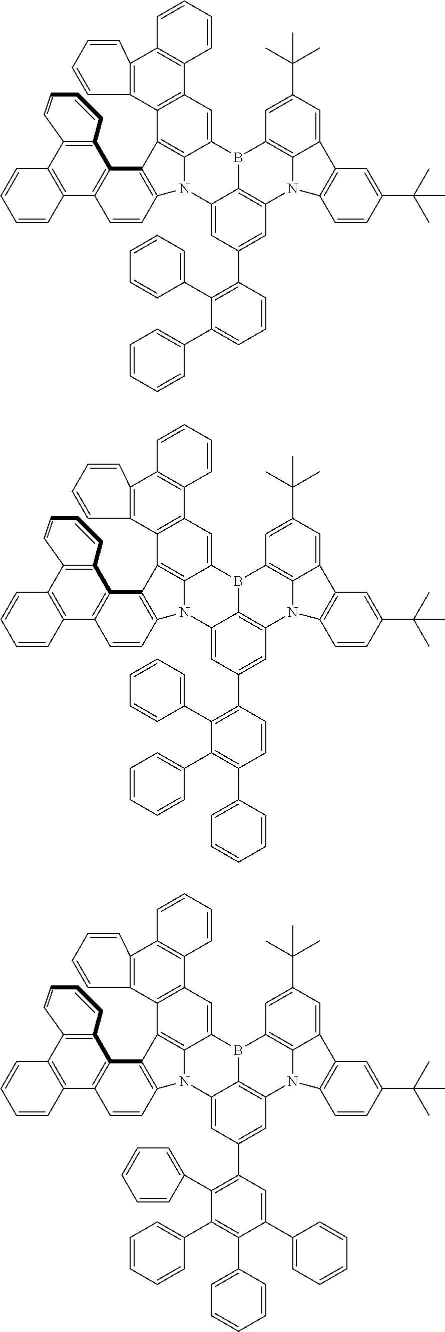

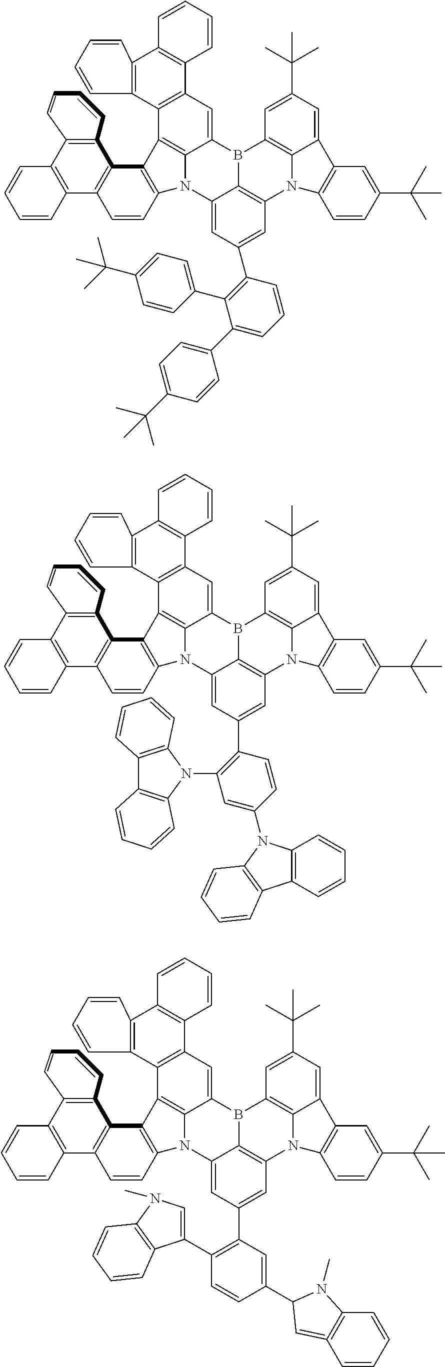

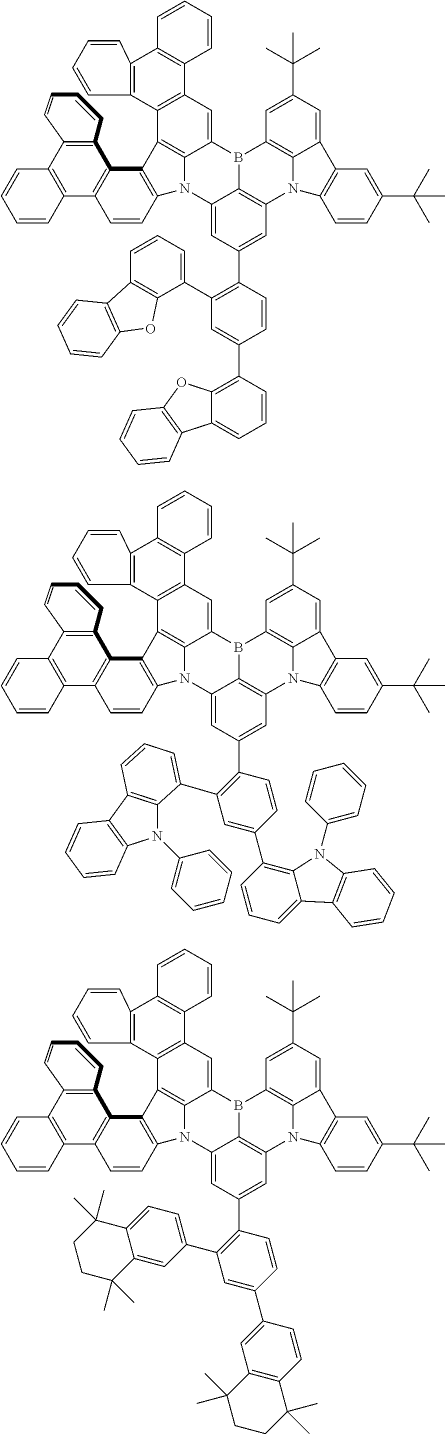

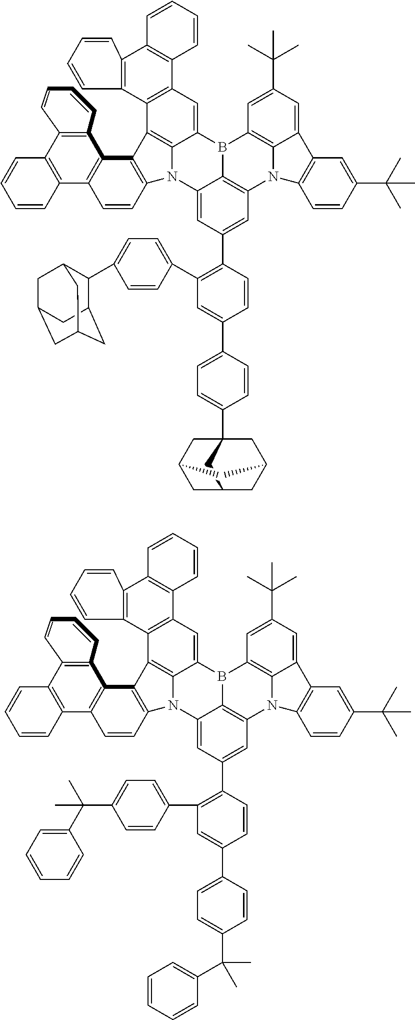

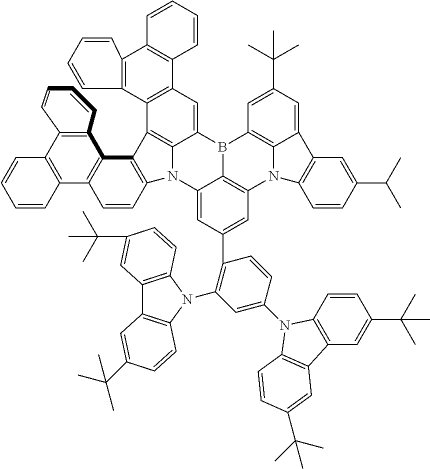

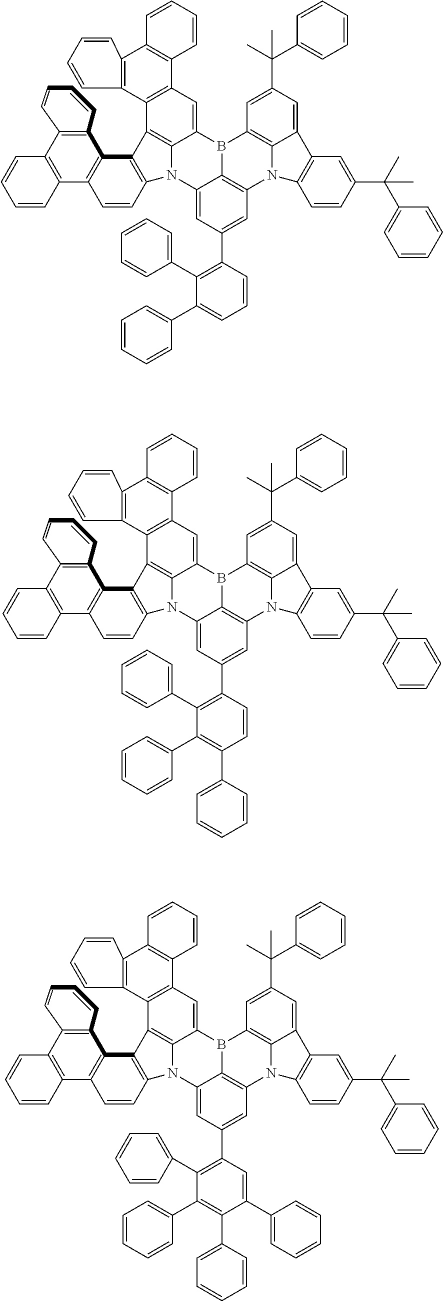

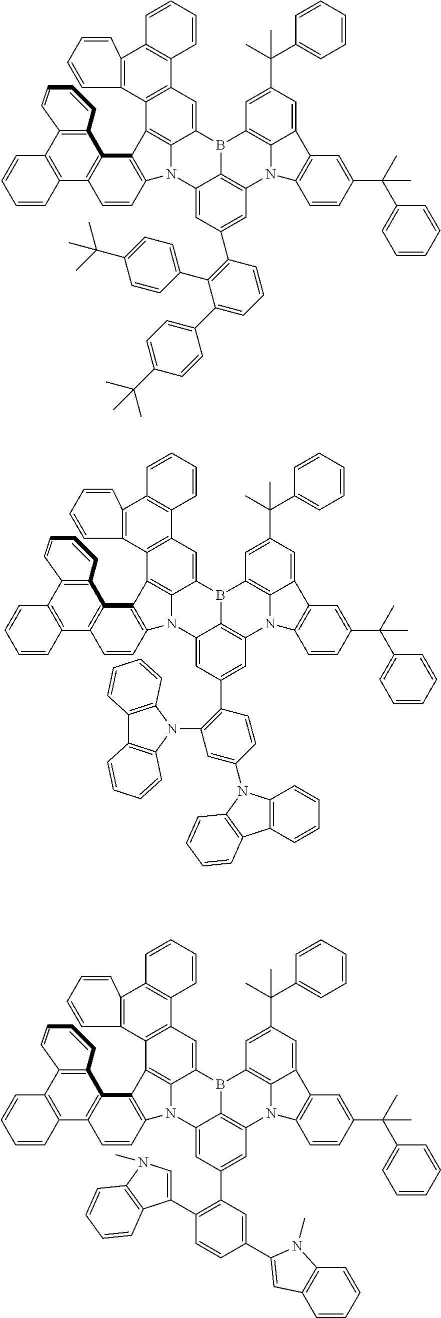

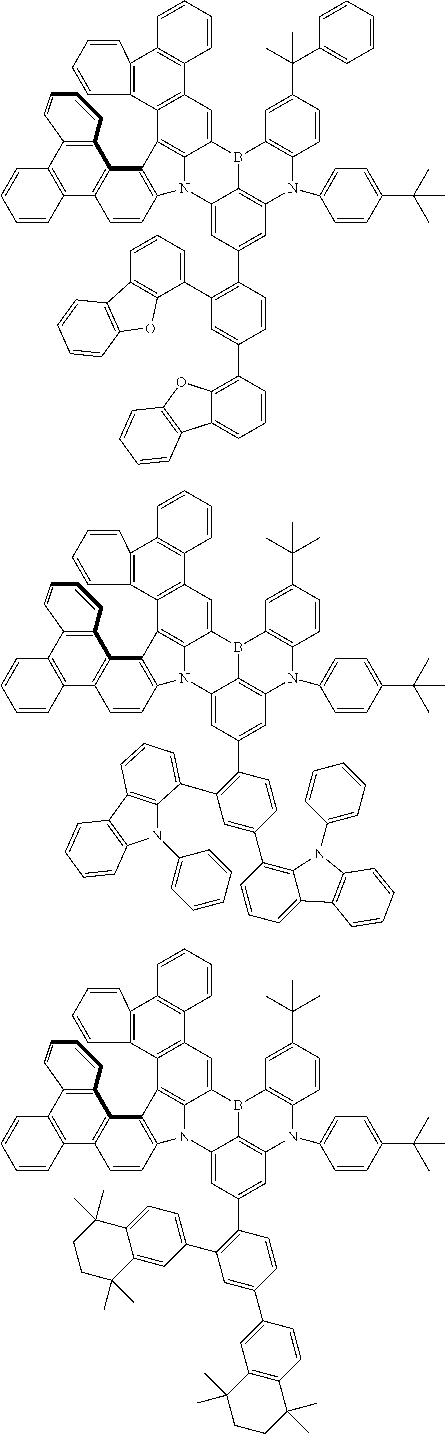

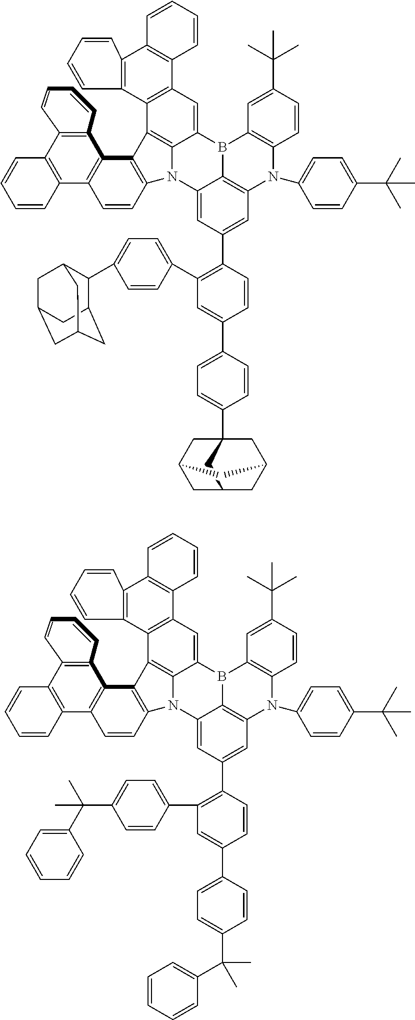

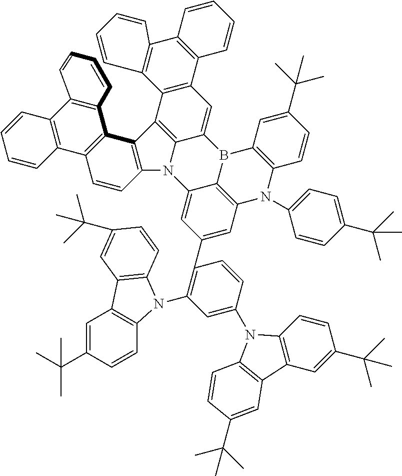

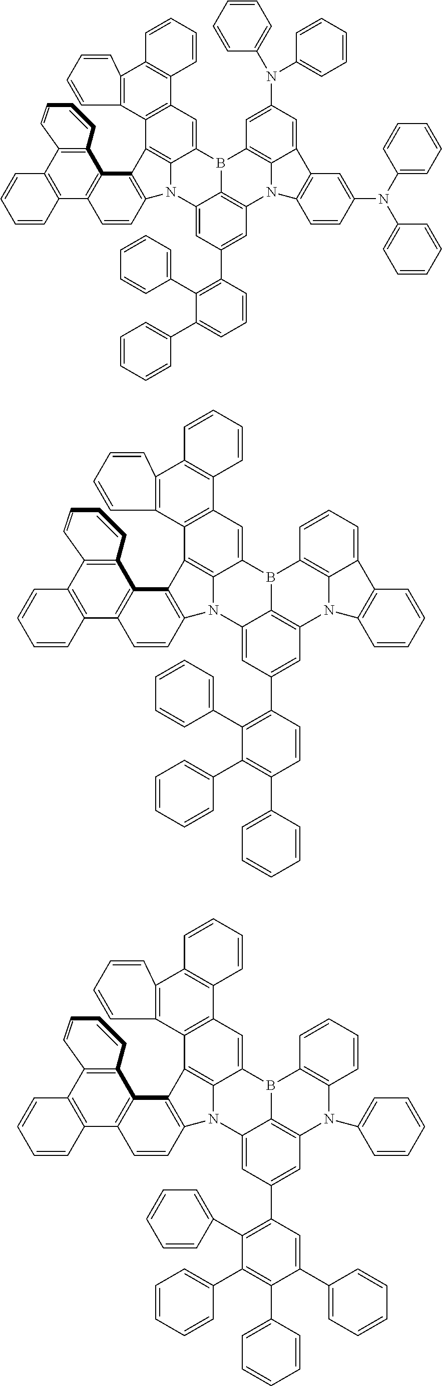

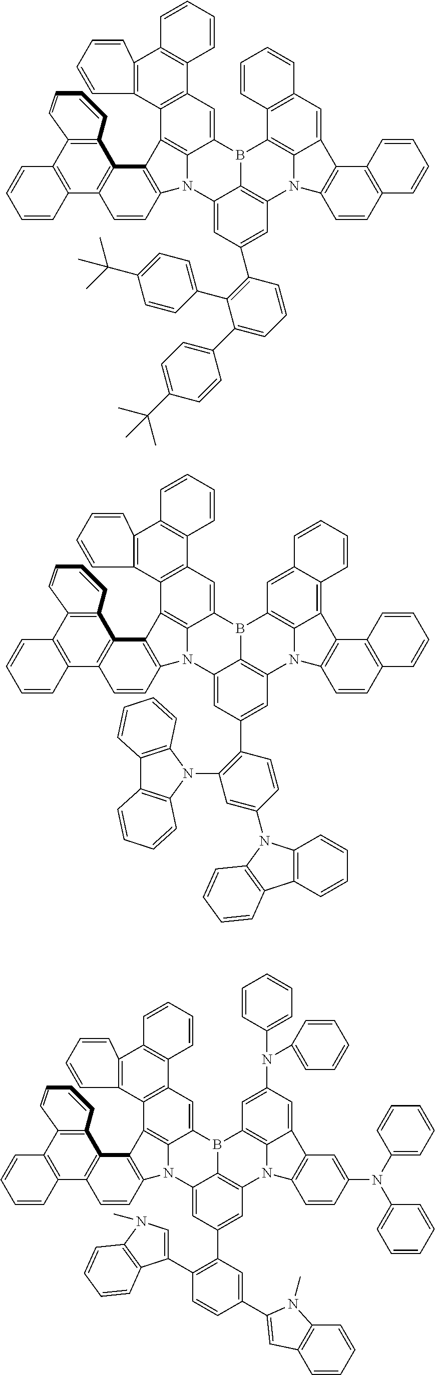

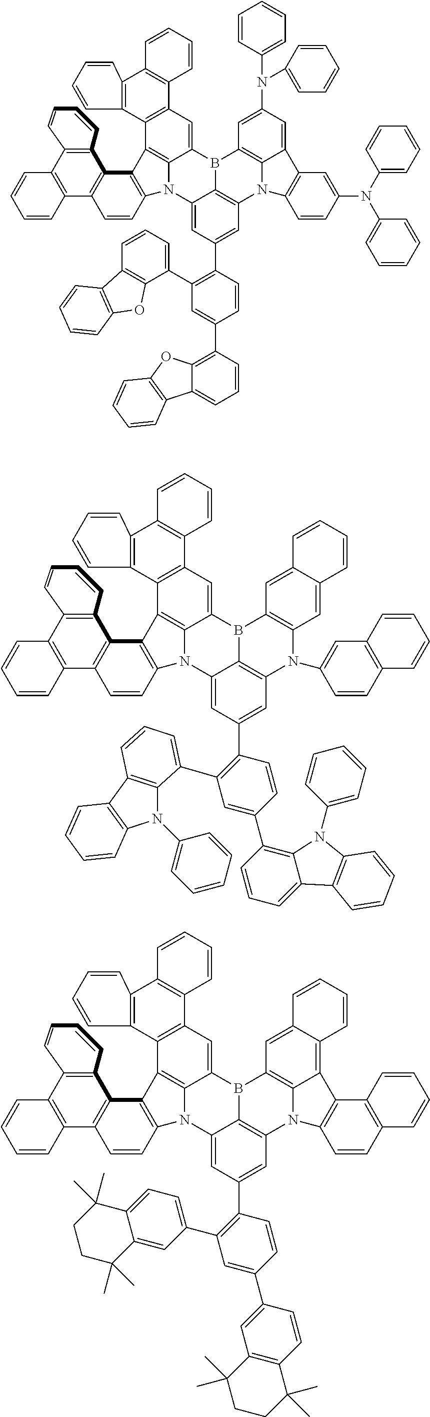

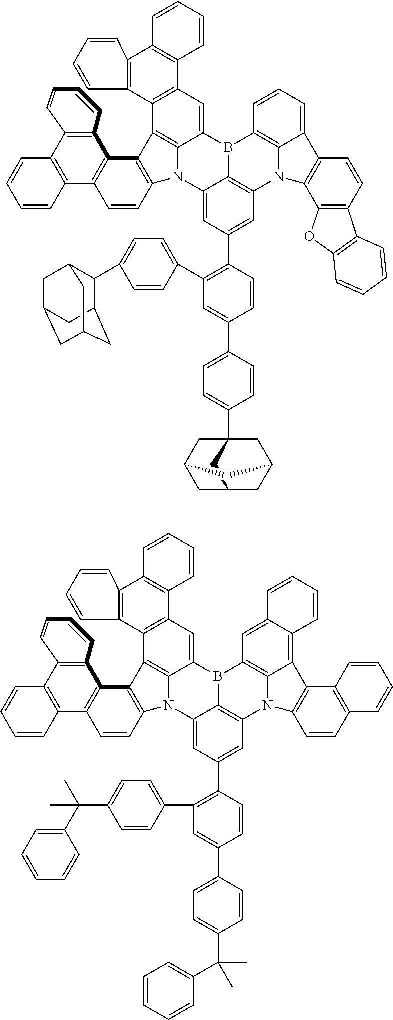

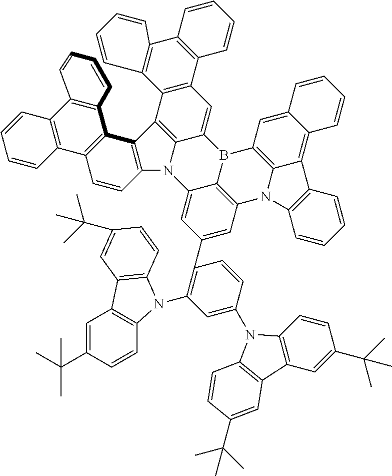

The benzophenanthrene-containing organic compound as described herein can be used as an organic functional material in optical devices (such as color converters or electronic devices), particularly in electroluminescent devices. The electroluminescent device may be selected from an OLED, an OLEEC, or an organic light emitting field effect transistor, particularly preferably selected from an OLED. The organic functional material is selected from a hole-injection material (HIM), a hole-transport material (HTM), an electron-transport material (ETM), an electron-injection material (EIM), an electron-blocking material (EBM), a hole-blocking material (HBM), an emitting material (Emitter), a host material (Host), or an organic dye. In some embodiments, the benzophenanthrene-containing organic compound as described herein may be used as a host material, an electron-transport material, or a hole-transport material.

In some embodiments, the emitting wavelength of the electroluminescent device is between 300 nm and 1500 nm, preferably between 400 nm and 1000 nm, more preferably between 400 nm and 800 nm.

In some embodiments, the benzophenanthrene-containing organic compound has a luminescent function with an emitting wavelength between 300 nm and 1000 nm, preferably between 350 nm and 900 nm, more preferably between 400 nm and 800 nm. Herein the emission refers to photoluminescence or electroluminescence.

In some embodiments, the benzophenanthrene-containing organic compound as described herein may be used as a fluorescent dopant material.

As the fluorescent dopant material, the benzophenanthrene-containing organic compound should have an appropriate singlet energy level, namely S₁. In some embodiments, the S₁ of the benzophenanthrene-containing organic compound as described herein ≥2.3 eV, preferably ≥2.4 eV, more preferably ≥2.5 eV, and most preferably ≥2.6 eV.

As the fluorescent dopant material, the benzophenanthrene-containing organic compound should have a high photoluminescence quantum yield, namely PLQY In some embodiments, the PLQY of the benzophenanthrene-containing organic compound as described herein ≥40%, preferably ≥50%, more preferably ≥60%, and most preferably ≥70%.

The PLQY of the compound is generally positively correlated with its oscillator strength f₁ (which is calculated as follows). In some embodiments, the f₁ of the benzophenanthrene-containing organic compound as described herein ≥0.3, preferably ≥0.4, more preferably ≥0.5, and most preferably ≥0.6.

In some embodiments, the benzophenanthrene-containing organic compound is a green emitting material; in some embodiments, the benzophenanthrene-containing organic compound is an orange or red emitting material.

In some embodiments, the full width at half maximum (FWHM) of the emission spectrum of the benzophenanthrene-containing organic compound≤40 nm, preferably ≤35 nm, more preferably ≤30 nm, and most preferably ≤25 nm.

In some embodiments, the benzophenanthrene-containing organic compound as described herein is a thermally activated delayed fluorescence material (TADF material). Generally, the ΔE_{ST} of the benzophenanthrene-containing organic compound as described herein ≤0.3 eV, preferably ≤0.25 eV, more preferably ≤0.2 eV, and most preferably ≤0.15 eV.

As an organic functional material, it is desirable to have good thermal stability. Generally, the glass transition temperature (Tg) of the benzophenanthrene-containing organic compound≥100° C., preferably ≥140° C., more preferably ≥180° C.

In some embodiments, the (HOMO−(HOMO−1)) of the benzophenanthrene-containing organic compound≥0.2 eV, preferably ≥0.3 eV, more preferably ≥0.4 eV, and most preferably ≥0.45 eV.

In some embodiments, the ((LUMO+1)−LUMO) of the benzophenanthrene-containing organic compound≥0.15 eV, preferably 0.25 eV, more preferably ≥0.30 eV, and most preferably ≥0.35 eV.

In another aspect, the present disclosure also provides a polymer comprising at least one repeating unit, the at least one repeating unit comprises a structure corresponding to a benzophenanthrene-containing organic compound as described herein.

In some embodiments, the polymer is a non-conjugated polymer in which the structure of formula (I) is on a side chain. In some embodiments, the polymer is a conjugated polymer.

In some embodiments, the synthetic method of the polymer is selected from the group consisting of SUZUKI-, YAMAMOTO-, STILLE-, NIGESHI-, KUMADA-, HECK-, SONOGASHIRA-, HIYAMA-, FUKUYAMA-, HARTWIG-BUCHWALD-, and ULLMAN-.

In some embodiments, the glass transition temperature (Tg) of the polymer≥100° C., preferably ≥120° C., more preferably ≥140° C., further preferably ≥160° C., and most preferably ≥180° C.

In some embodiments, the polydispersity index (PDI) of the polymer is preferably from 1 to 5, more preferably 1 to 4, even more preferably 1 to 3, further preferably 1 to 2, and most preferably 1 to 1.5.

In some embodiments, the weight-average molecular weight (M_{w}) of the polymer is preferably from 10 k to 1 million, more preferably 50 k to 500 k, even more preferably 100 k to 400 k, further preferably 150 k to 300 k, and most preferably 200 k to 250 k.

In some embodiments, the (HOMO−(HOMO−1)) of the polymer≥0.2 eV, preferably ≥0.3 eV, more preferably ≥0.4 eV, and most preferably ≥0.45 eV.

In yet another aspect, the present disclosure further provides a mixture comprising at least one benzophenanthrene-containing organic compound or polymer as described herein, and at least one organic functional material. The at least one organic functional material is selected from a hole-injection material (HIM), a hole-transport material (HTM), an electron-transport material (ETM), an electron-injection material (EIM), an electron-blocking material (EBM), a hole-blocking material (HBM), a light-emitting material, or a host material. The light-emitting material is selected from a singlet emitting material (fluorescent emitting material), a triplet emitting material (phosphorescent emitting material), or a thermally activated delayed fluorescence material (TADF material). These organic functional materials are described in detail, for example, in WO2010135519A1, US20090134784A1, and WO2011110277A1. The entire contents of these three documents are hereby incorporated into this document for reference. The at least one organic functional material can be a small molecule and a polymer.

In some embodiments, the mixture comprises at least one benzophenanthrene-containing organic compound as described herein and a fluorescent host. Herein, the benzophenanthrene-containing organic compound as described herein can be used as a fluorescent dopant material, and the weight percentage thereof ≤10 wt %, preferably ≤9 wt %, more preferably ≤8 wt %, further preferably ≤7 wt %, and most preferably ≤5 wt %.

In some embodiments, the mixture comprises at least one benzophenanthrene-containing organic compound as described herein, a blue emitting material, and a fluorescent host material. Herein, the benzophenanthrene-containing organic compound as described herein and the blue emitting material are fluorescent co-dopant materials, where the weight ratio of the benzophenanthrene-containing organic compound and the blue emitting material ranges from 2:8 to 8:2, preferably from 3:7 to 7:3, and most preferably from 4:6 to 6:4. In some embodiments, the emission spectrum of the blue emitting material is at least partially overlapping with the absorption spectrum of the benzophenanthrene-containing organic compound, so that the blue emitting material energy can be efficiently transferred to the benzophenanthrene-containing organic compound.

The detailed description of the host material, the fluorescent luminescent material, the TADF material, and other organic functional materials is described in detail in WO2018095395, which is incorporated herein by reference in their entirety.

It is an object of the present disclosure to provide a material for the evaporation-based OLEDs.

In some embodiments, the molecular weight of the benzophenanthrene-containing organic compound≤1100 g/mol, preferably ≤1000 g/mol, more preferably ≤950 g/mol, further preferably ≤900 g/mol, and most preferably ≤800 g/mol.

Another object of the present disclosure is to provide a material for the printed OLEDs.

In some embodiments, the molecular weight of the benzophenanthrene-containing organic compound≥700 g/mol, preferably ≥900 g/mol, more preferably ≥1000 g/mol, and most preferably ≥1100 g/mol.

In some embodiments, the benzophenanthrene-containing organic compound as described herein has a solubility of ≥10 mg/mL in toluene at 25° C., preferably ≥15 mg/mL, and most preferably ≥20 mg/mL.

In yet another aspect, the present disclosure further provides a formulation or a ink comprising a benzophenanthrene-containing organic compound or a polymer or a mixture as described herein, and at least one organic solvent.

The viscosity and surface tension of the ink are important parameters in printing processes. A suitable ink surface tension is required for the specific substrates and the specific printing methods.

In some embodiments, the surface tension of the ink at 25° C. is in the range of 19 dyne/cm to 50 dyne/cm; more preferably in the range of 22 dyne/cm to 35 dyne/cm; and most preferably in the range of 25 dyne/cm to 33 dyne/cm.

In some embodiments, the viscosity of the ink at 25° C. is in the range of 1 cps to 100 cps; preferably in the range of 1 cps to 50 cps; more preferably in the range of 1.5 cps to 20 cps; and most preferably in the range of 4 cps to 20 cps. The resulting formulation will be particularly suitable for ink-jet printing.

The viscosity can be adjusted by different methods, such as by the selection of appropriate organic solvent and the concentration of the functional materials in the ink. In the ink comprising the above-mentioned metal-organic complexes or polymers as described herein facilitate the adjustment of the printing ink in the appropriate range according to the printing method used. Generally, in the formulation comprising the functional material as described herein, the weight ratio of the functional material ranges from 0.3 wt % to 30 wt %, preferably in the range of 0.5 wt % to 20 wt %, more preferably in the range of 0.5 wt % to 15 wt %, further preferably in the range of 0.5 wt % to 10 wt %, and most preferably in the range of 1 wt % to 5 wt %.

In some embodiments, the at least one organic solvent of the ink as described herein is selected from aromatic-based or heteroaromatic-based solvents, particular in aliphatic chain/ring substituted aromatic solvents, aromatic ketone solvents, or aromatic ether solvents.

Examples of organic solvents suitable for the present disclosure include, but not limited to aromatic-based or heteroaromatic-based solvents, such as diisopropylbenzene, phenylpentane, tetralin, cyclohexylbenzene, 1-chloronaphthalene, 1,4-dimethylnaphthalene, 3-isopropylbiphenyl, p-methyl cumene, dipentylbenzene, tripentylbenzene, pentyltoluene, o-xylene, m-xylene, p-xylene, 1,2-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, 1-methylnaphthalene, 1,2,4-trichlorobenzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl)pyridine, benzyl benzoate, phenyl xylyl ethane, 2-isopropylnaphthalene, benzyl ether, etc; ketone-based solvents, such as 1-tetralone, 2-tetralone, 2-(phenylepoxy)tetralone, 6-(methoxy)tetralone, acetophenone, propiophenone, benzophenone, and derivatives thereof such as 4-methylacetophenone, 3-methylacetophenone, 2-methylacetophenone, 4-methylphenylacetone, 3-methylpropiophenone, 2-methylpropiophenone, isophorone, 2,6,8-trimethyl-4-nonanone, fenchone, 2-nonanone, 3-nonanone, 5-nonanone, 2-decanone, 2,5-hexanedione, phorone, 6-undecanone; aromatic ether solvents, such as 3-phenoxytoluene, butoxybenzene, benzylbutylbenzene, p-anisaldehyde dimethyl acetal, tetrahydro-2-phenoxy-2H-pyran, 1,2-dimethoxy-4-(1-propenyl)benzene, 1,4-benzodioxan, 1,3-diisopropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-anethole, 1,2-dimethoxybenzene, 1-methoxynaphthalene, diphenyl ether, 2-phenoxymethyl ether, 2-phenoxytetrahydrofuran, ethyl-2-naphthyl ether, dipentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, etc; ester solvent, such as alkyl octanoate, alkyl sebacate, alkyl stearate, alkyl benzoate, alkyl phenylacetate, alkyl cinnamate, alkyl oxalate, alkyl maleate, alkyl lactone, alkyl oleate, etc.

Further, the at least one organic solvent of the ink as described herein can be selected from aliphatic ketones, such as 2-nonanone, 3-nonanone, 5-nonanone, 2-decanone, 2,5-hexanedione, 2,6,8-trimethyl-4-nonanone, phorone, 6-undecanone, etc; and the at least one organic solvent as described herein can be selected from aliphatic ether, such as, dipentyl ether, hexyl ether, n-octyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, etc.

In some embodiments, the printing ink further comprises another organic solvent. Examples of the another organic solvents include, but not limited to: methanol, ethanol, 2-methoxyethanol, dichloromethane, trichloromethane, chlorobenzene, 1,2-dichlorobenzene, tetrahydrofuran, anisole, morpholine, toluene, o-xylene, m-xylene, p-xylene, 1,4-dioxane, acetone, 2-butanone, 1,2-dichloroethane, 3-phenoxytoluene, 1,1,1-trichloroethane, 1,1,2,2-tetrachloroethane, ethyl acetate, butyl acetate, N,N-dimethylformamide, N,N-dimethylacetamide, dimethyl sulfoxide, tetraline, decahydronaphthalene, indene, and/or any combination thereof.

In some embodiments, the formulation as described herein is a solution.

In some embodiments, the formulation as described herein is a dispersion.

The formulations in the embodiments of the present disclosure may comprise the benzophenanthrene-containing organic compound or the polymer or the mixture of 0.01 wt % to 20 wt %, preferably 0.1 wt % to 15 wt %, more preferably 0.2 wt % to 10 wt %, and most preferably 0.25 wt % to 5 wt %.

The present disclosure further provides the use of the formulation as a coating or printing ink in the preparation of organic optoelectronic devices, particularly preferably by printing or coating processing methods.

Where suitable printing or coating techniques include, but not limited to ink-jet printing, nozzle printing, gravure printing, typographic printing, screen printing, dip coating, spin coating, blade coating, roller printing, torsion roll printing, planographic printing, flexographic printing, rotary printing, spray coating, brush coating, pad printing, slit die coating, etc. Preferred techniques are ink-jet printing, nozzle printing, and gravure printing. The solution or dispersion may additionally comprise one or more components, such as surface active compounds, lubricants, wetting agents, dispersing agents, hydrophobic agents, binders, etc., which are used to adjust the viscosity and film forming properties, or to improve adhesion, etc. For more information on printing technologies and their requirements for solutions, such as solvent, concentration, viscosity, etc, please refer to Handbook of Print Media: Technologies and Production Methods, edited by Helmut Kipphan, ISBN 3-540-67326-1.

Based on the above-mentioned benzophenanthrene-containing organic compound, the present disclosure further provides the application of the benzophenanthrene-containing organic compound or the polymer as described herein, i.e., the benzophenanthrene-containing organic compound or the polymer is applied to an organic optoelectronic device, and the organic optoelectronic device may be selected from, but not limited to, a color converter, an organic light-emitting diode (OLED), an organic photovoltaic cell (OPV), an organic light emitting electrochemical cell (OLEEC), an organic field effect transistor (OFET), an organic light emitting field effect transistor, an organic laser, an organic spintronic electronic device, an organic sensor, or an organic plasmon emitting diode (OPED) etc, particularly preferably an organic electroluminescent device, such as an OLED, an OLEEC, an organic light emitting field effect transistor. In the embodiments of the present disclosure, it is preferred to use the benzophenanthrene-containing organic compound for the light-emitting layer of the electroluminescent device.

In yet another aspect, the present disclosure further provides an organic optoelectronic device comprising at least one benzophenanthrene-containing organic compound or polymer or mixture as described herein. Generally, such organic optoelectronic device comprises a cathode, an anode, and a functional layer disposed between the cathode and the anode, where the functional layer comprises at least one benzophenanthrene-containing organic compound or polymer or mixture as described herein. The organic optoelectronic device may be selected from, but not limited to, a color converter, an organic light-emitting diode (OLED), an organic photovoltaic cell (OPV), an organic light emitting electrochemical cell (OLEEC), an organic field effect transistor (OFET), an organic light emitting field effect transistor, an organic laser, an organic spintronic device, an organic sensor, or an organic plasmon emitting diode (OPED), etc., particularly preferably is an organic electroluminescent device, such as an OLED, an OLEEC, an organic light emitting field effect transistor.

In some embodiments, the organic optoelectronic device comprises a light-emitting layer, the light-emitting layer comprises a benzophenanthrene-containing organic compound, or a polymer, or a mixture as described herein; or comprises a benzophenanthrene-containing organic compound as described herein and a phosphorescent emitter; or comprises a benzophenanthrene-containing organic compound as described herein and a host material; or comprises a benzophenanthrene-containing organic compound as described herein, a phosphorescent emitter, and a host material.

In the organic optoelectronic device as described herein, in particular an OLED, which comprises a substrate, an anode, at least one light-emitting layer, and a cathode.

The substrate should be opaque or transparent. A transparent substrate could be used to produce a transparent light-emitting device (for example: Bulovic et al., Nature, 1996, 380, p 29, and Gu et al., Appl. Phys. Lett., 1996, 68, p 2606). The substrate can be rigid or flexible, e.g. it can be plastic, metal, semiconductor wafer, or glass. Preferably, the substrate has a smooth surface. Particularly ideal are substrates without surface defects. In some embodiments, the substrate is flexible and can be selected from a polymer film or plastic with a glass transition temperature (Tg)>150° C., preferably >200° C., more preferably >250° C., and most preferably >300° C. Examples of the suitable flexible substrates include poly ethylene terephthalate (PET) and polyethylene glycol (2,6-naphthalene) (PEN).

The anode may be a conductive metal, or a metal oxide, or a conductive polymer. The anode should be able to easily inject holes into a hole-injection layer (HIL), a hole-transport layer (HTL), or a light-emitting layer. In some embodiments, the absolute value of the difference between the work function of the anode and the HOMO energy level/valence band energy level of the emitter of the light-emitting layer or the p-type semiconductor materials of the hole-injection layer (HIL)/hole-transport layer (HTL)/electron-blocking layer (EBL)<0.5 eV, preferably <0.3 eV, and most preferably <0.2 eV. Examples of anode materials may include, but not limited to: Al, Cu, Au, Ag, Mg, Fe, Co, Ni, Mn, Pd, Pt, ITO, aluminum-doped zinc oxide (AZO), etc. Other suitable anode materials are known and can be readily selected for use by the general technicians in this field. The anode materials can be deposited using any suitable technique, such as a suitable physical vapor deposition method including RF magnetron sputtering, vacuum thermal evaporation, e-beam, etc. In some embodiments, the anode is patterned. Patterned conductive ITO substrates are commercially available and can be used to produce the devices as described herein.

The cathode may be a conductive metal or a metal oxide. The cathode should be able to easily inject electrons into the electron-injection layer (EIL), the electron-transport layer (ETL), or the directly into the light-emitting layer. In some embodiments, the absolute value of the difference between the work function of the cathode and the LUMO energy level/conduction band energy level of the emitter of the light-emitting layer, or the n-type semiconductor materials of the electron-injection layer (EIL)/electron-transport layer (ETL)/hole-blocking layer (HBL)<0.5 eV, preferably <0.3 eV, and most preferably <0.2 eV In principle, all materials those can be used as cathodes for OLEDs may be applied as cathode materials for the devices as described herein. Examples of cathode materials include, but not limited to: Al, Au, Ag, Ca, Ba, Mg, LiF/Al, MgAg alloy, BaF₂/Al, Cu, Fe, Co, Ni, Mn, Pd, Pt, ITO, etc. The cathode materials can be deposited using any suitable technique, such as the suitable physical vapor deposition method including RF magnetron sputtering, vacuum thermal evaporation, e-beam, etc.

The OLED may also comprise other functional layers, such as a hole-injection layer (HIL), a hole-transport layer (HTL), an electron-blocking layer (EBL), an electron-injection layer (EIL), an electron-transport layer (ETL), and a hole-blocking layer (HBL). Materials suitable for use in these functional layers are described in details above and in WO2010135519A1, US20090134784A1 and WO2011110277A1. The entire contents of these three documents are hereby incorporated herein for reference.

In some embodiments, the light-emitting layer of the organic optoelectronic device is formed by using the formulation as described herein.

In the organic optoelectronic device as described herein, particularly in OLED, the emitting wavelength is between 300 nm and 1500 nm, preferably between 350 nm and 1200 nm, more preferably between 400 nm and 800 nm.

For the purposes of the present disclosure, the terms “color converter”, “color conversion layer”, and “CCL” have the same meaning.

The present disclosure further relates to a color conversion layer comprising an emitter, the emitter is a chiral molecule.

In some embodiments, the emitter comprises a benzophenanthrene-containing organic compound or a polymer having chirality as described herein.

In some embodiments, the color conversion layer comprises a host material and a benzophenanthrene-containing organic compound or a polymer as described herein as a dopant material. As described in prior application No. WO2022213993A1, the entire contents of which are hereby incorporated herein by reference.

In some embodiments, the chiral emitter of the color conversion layer is a benzophenanthrene-containing organic compound with chirality as described herein.

Preferably, in the color conversion layer as described herein, the benzophenanthrene-containing organic compound with chirality is selected from one of formulas (I-4)-(I-7), (I-11)-(I-14).

More preferably, in the color conversion layer as described herein, the benzophenanthrene-containing organic compound with chirality is selected from one of formulas (Ia-6), (Ia-7), (Ib-6), (Ib-7), (Ib-13), (Ib-14), (Ib-15), (Ib-17), (Ib-23)-(Ib-31).

In some embodiments, the color conversion layer further comprises an organic resin and/or a solvent. For the purposes of the present invention, the organic resin refers to a resin prepolymer or a resin formed after the prepolymer is crosslinked or cured.

In some embodiments, the color conversion layer further comprises two and more organic resins.

The organic resins suitable for the present disclosure include, but not limited to: polystyrene, polyacrylate, polymethacrylate, polycarbonate, polyurethane, polyvinylpyrrolidone, polyvinyl acetate, polybutylene, polyethylene glycol, silicone oil, epoxy resin, polyvinyl alcohol, polyacrylonitrile, polyvinylidene chloride (PVDC), polystyrene-acrylonitrile (SAN), polybutylene terephthalate (PBT), polyethylene terephthalate (PET), polyvinyl butyrate (PVB), polyvinyl chloride (PVC), polyamide, polyoxymethylene, polyimide, polyetherimide, and mixtures thereof.

Further, the organic resin suitable for the present invention includes, but not limited to, those prepared by the homopolymerization or copolymerization of the following monomers (resin prepolymers): styrene derivatives, acrylate derivatives, acrylonitrile derivatives, acrylamide derivatives, vinyl ester derivatives, vinyl ether derivatives, maleimide derivatives, conjugated diene derivatives.

Examples of styrene derivatives include, but not limited to, alkylstyrenes, such as α-methylstyrene, o-, m-, p-methylstyrene, p-butylstyrene; especially p-tert-butylstyrene, alkoxystyrene, such as p-methoxystyrene, p-butoxystyrene, p-tert-butoxystyrene.

Examples of acrylate derivatives include, but not limited to, methyl acrylate, methyl methacrylate, ethyl acrylate, ethyl methacrylate, n-propyl acrylate, n-propyl methacrylate, iso-propylacrylate, isopropyl methacrylate, n-butyl acrylate, n-butyl methacrylate, isobutyl acrylate, isobutyl methacrylate, sec-butyl acrylate, sec-butyl methacrylate, tert-butyl acrylate, tert-butyl methacrylate, 2-hydroxyethyl acrylate, 2-hydroxyethyl methacrylate, 2-hydroxypropyl acrylate, 2-hydroxypropyl methacrylate, 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate, 4-hydroxybutyl methacrylate, allyl acrylate, allyl methacrylate, benzyl acrylate, benzyl methacrylate, cyclohexyl acrylate, cyclohexyl methacrylate, phenyl acrylate, phenyl methacrylate, 2-methoxyethyl acrylate, 2-methoxyethyl methacrylate, 2-phenoxyethyl acrylate, 2-phenoxyethyl methacrylate, methoxydiethylene glycol acrylate, methoxydiethylene glycol methacrylate, methoxytriethylene glycol acrylate, methoxytriethylene glycol methacrylate, methoxypropylene glycol acrylate, methoxypropylene glycol methacrylate, methoxy dipropylene glycol acrylate, methoxydipropylene glycol methacrylate, isobornyl acrylate, isobornyl methacrylate, dihydrodicyclopentadienyl acrylate, dicyclopentadiene methacrylate, adamantane (meth) acrylate, norbornene (meth) acrylate, 2-hydroxy-3-phenoxypropyl acrylate, 2-hydroxy-3-phenoxypropyl methacrylate, glycerol monoacrylate, glycerol monomethacrylate, 2-aminoethyl acrylate, 2-aminoethyl methacrylate, 2-dimethylaminoethyl acrylate, 2-dimethylaminoethyl methacrylate, N,N-dimethylaminoethyl (meth) acrylic acid, N,N-diethylaminoethyl (meth) acrylate, 2-aminopropyl acrylate, 2-aminopropyl methacrylate, 2-dimethylaminopropyl acrylate, 2-dimethylaminopropyl methacrylate, 3-aminopropyl acrylate, 3-aminopropyl methacrylate, benzyl N,N-dimethyl-1,3-propanediamine(meth)acrylate, 3-dimethylaminopropyl acrylate, 3-dimethylaminopropyl methacrylate, glycidyl acrylate, and glycidyl methacrylate.

Examples of acrylonitrile derivatives include, but not limited to, acrylonitrile, methacrylonitrile, 2-chloroacrylonitrile, and vinylidene cyanide.

Examples of acrylamide derivatives include, but not limited to, acrylamide, methacrylamide, α-chloroacrylamide, N-2-hydroxyethyl acrylamide, and N-2-hydroxyethyl methacrylamide.

Examples of vinyl ester derivatives include, but not limited to vinyl acetate, vinyl propionate, vinyl butyrate and vinyl benzoate.

Examples of vinyl ether derivatives include, but not limited to vinyl methyl ether, vinyl ethyl ether and allyl glycidyl ether.

Examples of maleimide derivatives include, but not limited to maleimide, benzylmaleimide, N-phenylmaleimide and N-cyclohexylmaleimide.

Examples of conjugated diene derivatives include, but not limited to 1,3-butadiene, isoprene and chloroprene.

The homopolymers or copolymers can be prepared by free radical polymerization, cationic polymerization, anionic polymerization, or organometallic catalytic polymerization (for example Ziegler-Natta catalysis). The process of polymerization can be suspension polymerization, emulsion polymerization, solution polymerization, or bulk polymerization.

The number average molecular weight Mn (as determined by GPC) of the organic resins is generally in the range of 10 000 g/mol to 1 000 000 g/mol, preferably in the range of 20 000 g/mol to 750 000 g/mol, more preferably in the range of 30 000 g/mol to 500 000 g/mol.

In some embodiments, the organic resin is a thermosetting resin or an UV curable resin. In some embodiments, the organic resin is cured by a method that will enable roll-to-roll processing.

Thermosetting resins require curing in which they undergo an irreversible process of molecular cross-linking, which makes the resin non-fusible. In some embodiments, the thermosetting resin is an epoxy resin, a phenolic resin, a vinyl ester resin, a melamine co-polycondensation resin, an urea-formaldehyde resin, an unsaturated polyester resin, a polyurethane resin, an allyl resin, an acrylic resin, a polyamide resin, a polyamide-imide resin, a phenol-amide polycondensation resin, an urea-melamine polycondensation resin, or any combination thereof.

In some embodiments, the thermosetting resin is an epoxy resin. The epoxy resins are easy to cure and do not give off volatiles or generate by-products from a wide range of chemicals. The epoxy resins can also be compatible with most substrates and tend to readily wet surfaces. See also Boyle, M. A. et al., “Epoxy Resins”, Composites, Vol. 21, ASM Handbook, pages 78-89 (2001).

In some embodiments, the organic resin is a silicone thermosetting resin. In some embodiments, the silicone thermosetting resin is OE6630A or OE6630B (Dow Corning Corporation (Auburn, Michigan)).

In some embodiments, a thermal initiator is used. In some embodiments, the thermal initiator is AIBN[2,2′-azobis(2-methylpropionitrile)] or benzoyl peroxide.

The UV curable resin is a polymer that will cure and rapidly harden upon exposure to light of a specific wavelength. In some embodiments, the UV curable resin is a resin having a free radical polymerization group, and a cationic polymerizable group as functional groups; the radical polymerizable group is such as (meth)acryloyloxy group, vinyloxy group, styryl group, or vinyl group. The cationically polymerizable group is, for example, epoxy group, thioepoxy group, vinyloxy group, or oxetanyl group. In some embodiments, the UV curable resin is a polyester resin, a polyether resin, a (meth)acrylic resin, an epoxy resin, a polyurethane resin, an alkyd resin, a spiroacetal resin, a polybutadiene resin, or a thiolene resin.

In some embodiments, the UV curable resin is selected from polyurethane acrylate, allyloxy diacrylate, bis(acryloyloxyethyl) hydroxyisocyanurate, bis(acryloyloxyneopentyl glycol) adipate, bisphenol A diacrylate, bisphenol A dimethacrylate, 1,4-butanediol diacrylate, 1,4-butanediol dimethacrylate, 1,3-butanediol diacrylate, 1,3-butanediol dimethacrylate, dicyclopentyl diacrylate, diethylene glycol diacrylate, diethylene glycol dimethacrylate, dipentaerythritol hexaacrylate, dipentaerythritol monohydroxy pentacrylate, bis(trimethylolpropane) tetraacrylate, triethylene glycol dimethacrylate, glyceryl methacrylate, 1,6-hexanediol diacrylate, neopentyl glycol dimethacrylate, neopentyl glycol hydroxypivalonate, pentaerythritol triacrylate, pentaerythritol tetraacrylate, dimethacrylate, polyethylene glycol diacrylate, polypropylene glycol diacrylate, tetraethylene glycol diacrylate, tetrabromobisphenol A diacrylate, triethylene glycol divinyl ether, glycerol diacrylate, trimethylolpropane triacrylate, tripropylene glycol diacrylate, tris(acryloyloxyethyl) isocyanurate, triacrylate, diacrylate, propyl acrylate, vinyl-terminated polydimethylsiloxane, vinyl-terminated diphenyl siloxane-dimethyl siloxane copolymer, vinyl-terminated polyphenyl methyl siloxane, vinyl-terminated difluoromethyl siloxane-dimethyl siloxane copolymer, vinyl-terminated diethyl siloxane-dimethyl siloxane copolymer, vinyl methyl siloxane, monomethacryloxypropyl-terminated polydimethylsiloxane, monovinyl-terminated polydimethylsiloxane, monoallyl-mono-trimethylsilyloxy-terminated polyethylene oxide, or any combination thereof.

In some embodiments, the UV curable resin is a mercapto functional compound that can be cross-linked under UV curing conditions with an isocyanate, an epoxy resin, or an unsaturated compound. In some embodiments, the mercapto functional compound is a polythiol. In some embodiments, the polythiol is selected from: pentaerythritol tetrakis(3-mercaptopropionate) (PETMP), trimethylolpropane tris(3-mercaptopropionate) (TMPMP), ethylene glycol bis(3-mercaptopropionate) (GDMP); tris[25-(3-mercapto-propionyloxy)ethyl]isocyanurate (TEMPIC), dipentaerythritol hexa(3-mercaptopropionate) (Di-PETMP), ethoxylated trimethylolpropane tri(3-mercaptopropionate) (ETMP1300 and ETTMP700), polycaprolactone tetra(3-mercaptopropionate) (PCL4MP1350), pentaerythritol tetramercaptoacetate (PETMA), trimethylolpropane trimercaptoacetate (TMPMA), or ethylene glycol dimercaptoacetate (GDMA). These compounds are sold under the trade name TIOCURE® by Bruno Bock (Malsacht, Germany).

In some embodiments, the UV curable resin further comprises photoinitiator. The photoinitiator will initiate crosslinking and/or curing reactions of the photosensitive material during exposure to light. In some embodiments, the photoinitiator is a compound such as acetophenone-based, benzoin-based, or thidrone-based that initiate the polymerization, crosslinking and curing of monomers.

In some embodiments, the UV curable resin comprises mercapto-functional compound, methacrylate, acrylate, isocyanate, or combinations thereof. In some embodiments, the UV curable resin comprises polythiols, methacrylates, acrylates, isocyanates, or any combination thereof.

In some embodiments, the photoinitiator is MINS-311RM (Minuta Technology Co., Ltd (Korea)).

In some embodiments, the photoinitiator is Irgacure® 127, Irgacure® 184, Irgacure® 184D, Irgacure® 2022, Irgacure® 2100, Irgacure® 250, Irgacure® 270, Irgacure® 2959, Irgacure® 369, Irgacure® 369EG, Irgacure® 379, Irgacure® 500, Irgacure® 651, Irgacure® 754, Irgacure® 784, Irgacure® 819, Irgacure® 819DW, Irgacure® 907, Irgacure® 907FF, Irgacure® OxeOl, Irgacure® TPO-L, Irgacure® 1173, Irgacure® 1173D, Irgacure® 4265, Irgacure® BP, or Irgacure® MBF (BASF Corporation (Wyandotte, Michigan)). In some embodiments, the photoinitiator is TPO (2,4,6-trimethylbenzoyl-diphenyl-oxide) or MBF (methyl benzoyl formate).

In some embodiments, the weight percentage of organic resin in the formulation is about 20% to about 99%, about 20% to about 95%, about 20% to about 90%, about 20% to about 85%, about 20% to about 80%, about 20% to about 70%, about 20% to about 60%, about 40% to about 99%, about 40% to about 95%, about 40% to about 90%, about 40% to about 85%, about 40% to about 80%, about 40% to about 70%, about 70% to about 99%, about 70% to about 95%, about 70% to about 90%, about 70% to about 85%, about 70% to about 80%, about 80% to about 99%, about 80% to about 95%, about 80% to about 90%, about 80% to about 85%, about 85% to about 99%, about 85% to about 95%, about 85% to about 90%, about 90% to about 99%, about 90% to about 95%, or about 95% to about 99%.

The present disclosure further provides the applications of organic optoelectronic devices in various electronic equipment, including, but not limited to, display devices, lighting equipments, light sources, sensors, etc.

The present disclosure further provides organic optoelectronic devices comprising organic electronic devices of the present disclosure, including, but not limited to, display devices, lighting equipments, light sources, sensors, etc.

The present disclosure will be described below in conjunction with the preferred embodiments, but the present disclosure is not limited to the following embodiments. It should be understood that the scope of the present disclosure is covered by the scope of the claims of the present disclosure, and those skilled in the art should understand that certain changes may be made to the embodiments of the present disclosure.

### SPECIFIC EMBODIMENT

### 1. Synthesis of Compounds

### Example 1

The synthetic route of the compound 1 is shown as follows:

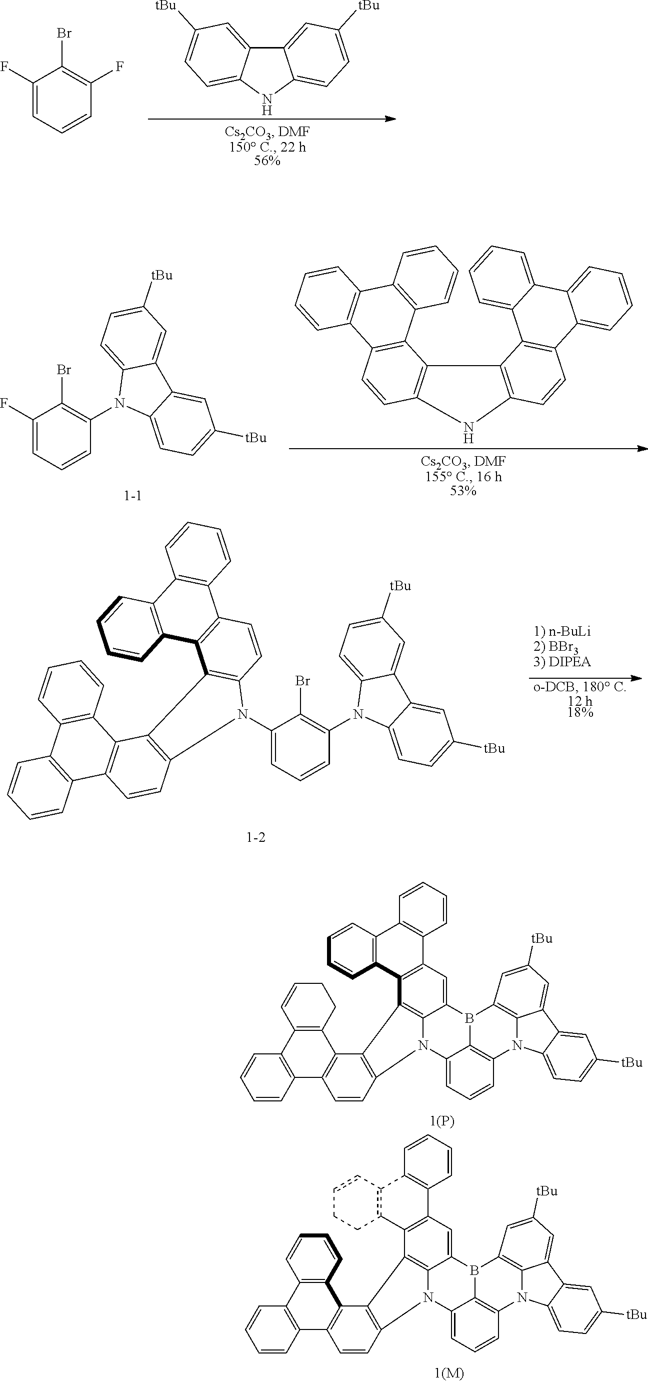

The procedure is as follows.

### Synthesis of Compound 1-1:

3,6-Di-tert-butylcarbazole (5.58 g, 20.0 mmol), cesium carbonate (9.77 g, 30.0 mmol), 1-bromo-2,6-difluorobenzene (5.64 g, 30.0 mmol), and 60 mL of ultradry DMF were added to a 250 mL single-necked flask under argon atmosphere, then stirred at 150° C. for 22 h. After the reaction was cooled to room temperature and then poured into water, the resulting mixture was filtered, the obtained crude product was purified by column chromatography (eluent: PE), then the result was recrystallized with dichloromethane and methanol to yield 5.03 g (yield: 56%) of white solid (compound 1-1). ¹H NMR (400 MHz, CDCl₃, 297 K, ppm) δ 8.16 (d, J=2.0 Hz, 2H), 7.50-7.43 (m, 3H), 7.34-7.26 (m, 2H), 7.00 (dd, J=8.8 Hz, 2.4 Hz, 2H), 1.48 (s, 18H). ¹³C NMR (101 MHz, CDCl₃, 297 K, ppm) δ 143.25, 139.50, 139.30, 129.22, 129.13, 126.42, 123.83, 123.51, 116.52, 116.24, 111.60, 109.62, 34.90, 32.17. ¹⁹F NMR (376 MHz, CDCl₃, 297 K, ppm) 6-102.47. HRMS (MALDI) m/z: Calcd. for C₂₆H₂₇BrFN: 451.1311; Found: 451.1305 [M]⁺.

### Synthesis of Compound 1-2:

Compound 1-1 (321 mg, 0.710 mmol), 7H-dibenzo[c,g]carbazole (500 mg, 1.07 mmol), cesium carbonate (1.16 g, 3.56 mmol), and 12 mL of ultradry DMF were added to a 50 mL schlenk flask under argon atmosphere, then stirred at 155° C. for 16 h. After the reaction was cooled to room temperature, the resulting mixture was extracted with dichloromethane three times, the organic phase was washed with water and saturated brine, then the result was dried with anhydrous magnesium sulfate. After the filtration, the obtained crude product was purified by column chromatography (eluent: PE:CH₂Cl₂=10:1), then the resulting product was recrystallized with dichloromethane and methanol to yield 338 mg (yield: 53%) of pale-yellow solid (compound 1-2). ¹H NMR (400 MHz, CD₂Cl₂, 297 K, ppm) δ 8.91-8.81 (m, 2H), 8.80-8.70 (m, 4H), 8.48 (t, J=8.0 Hz, 2H), 8.23-8.18 (m, 2H), 8.08-7.84 (m, 6H), 7.78-7.67 (m, 5H), 7.65-7.53 (m, 3H), 7.31-7.20 (m, 3H), 6.42-6.34 (m, 2H). 1.47 (s, 18H). ¹³C NMR (101 MHz, CDCl₃, 297 K, ppm) δ 143.46, 143.44, 141.24, 140.87, 140.21, 139.34, 139.27, 138.86, 132.02, 131.64, 130.84, 130.64, 129.78, 129.55, 129.52, 128.73, 128.68, 128.44, 128.16, 127.86, 127.28, 127.25, 127.11, 127.09, 126.58, 126.18, 126.14, 124.98, 124.89, 124.67, 124.03, 124.02, 123.76, 123.69, 123.68, 123.61, 123.42, 123.38, 121.96, 121.87, 118.98, 118.79, 116.72, 116.67, 110.38, 110.26, 109.64, 109.56, 34.97, 32.20. HRMS (MALDI) m/z: Calcd. for C₆₂H₄₇BrN₂: 898.2923; Found: 898.2936 [M]⁺.

### Synthesis of Compound 1:

Compound 1-2 (300 mg, 0.334 mmol) and 4 mL of 1,2-dichlorobenzene were added to a 50 mL schlenk tube under argon atmosphere, n-butyllithium (0.668 mmol, 1.6 M in hexane) was added to the above mixture at 0° C. After stirring for 2 h, boron tribromide (10.8 mmol, 1.0 M in heptane) was added dropwise to the reaction system at 0° C., the reaction mixture was moved to room temperature and stirred for 16 h. After removing the low-boiling solvent under reduced pressure, N,N-diisopropylethylamine (0.1 mL) was added dropwise to the reaction system at 0° C. and stirred at 180° C. for 12 h. After the reaction system was cooled to room temperature, the solvent was removed under reduced pressure, the result was purified by column chromatography (eluent: PE:CH₂Cl₂=5:1), then recrystallized with dichloromethane and methanol to yield 50 mg (yield: 18%) of orange solid (compound 1). ¹H NMR (400 MHz, CD₂Cl₂, 297 K, ppm) δ 10.03 (s, 1H), 9.03 (d, J=1.6 Hz, 1H), 8.84 (d, J=8 Hz, 1H), 8.61-8.53 (m, 2H), 8.48-8.44 (m, 1H), 8.42 (d, J=1.6 Hz, 1H), 8.37-8.31 (m, 4H), 8.20 (d, J=2.4 Hz, 1H), 8.10 (d, J=8.8 Hz, 1H), 7.98 (t, J=7.6 Hz, 2H), 7.77-7.72 (m, 2H), 7.68-7.63 (m, 1H), 7.61-7.50 (m, 5H), 7.19-7.12 (m, 2H), 6.26-6.20 (m, 2H), 1.69 (s, 9H), 1.55 (s, 9H). ¹³C NMR (101 MHz, CD₂Cl₂, 297 K, ppm) δ 145.88, 145.16, 144.09, 143.65, 142.59, 141.90, 140.21, 138.70, 133.33, 131.41, 130.70, 130.57, 130.52, 130.04, 129.94, 129.84, 129.36, 129.33, 129.27, 128.17, 127.96, 127.86, 127.77, 127.60, 127.56, 127.46, 126.84, 125.91, 125.75, 125.16, 125.11, 124.96, 124.34, 124.08, 124.03, 123.78, 123.50, 123.25, 122.43, 122.36, 122.27, 121.74, 121.55, 121.25, 118.94, 117.85, 114.74, 114.16, 109.64, 109.57, 35.65, 35.24, 32.51, 32.16. HRMS (MALDI) m/z: Calcd. for C₆₂H₄₅BN₂: 828.3676; Found: 828.3675 [M]⁺.

### Example 2

The synthetic route of the compound 2 is shown as follows:

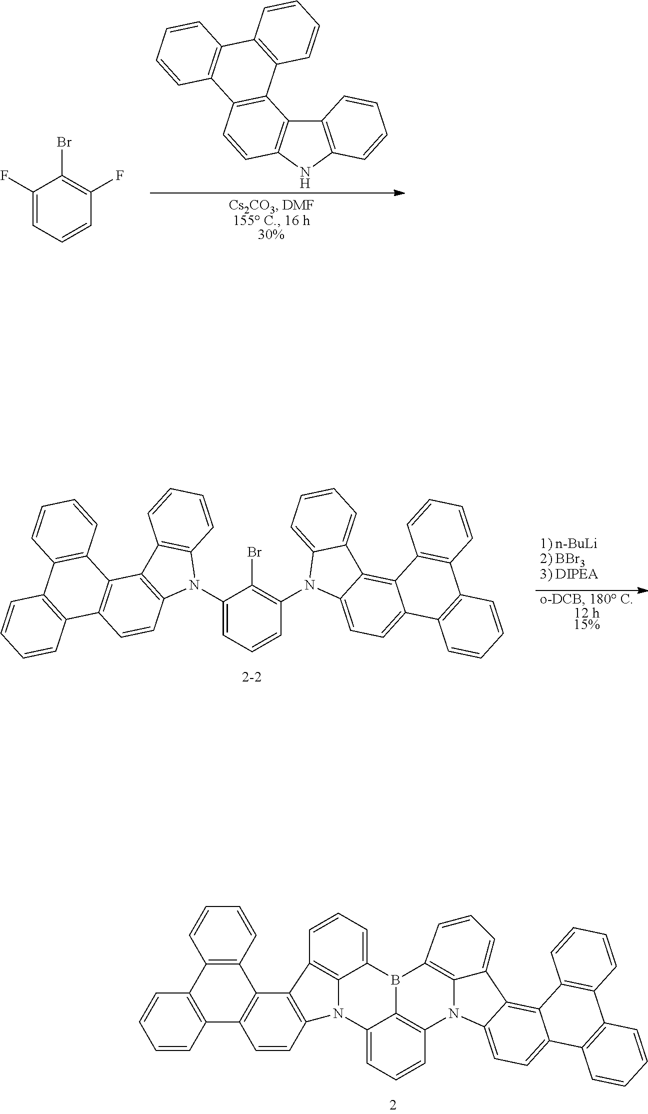

The procedure is as follows.

### Synthesis of Compound 2-2:

The synthetic procedure was similar to that of the compound 1-2, the compound 2-2 (yield: 30%) was formed under the action of alkali, MS(ASAP)=787.76.

### Synthesis of Compound 2:

The synthetic procedure was similar to that of the compound 1, Li salt was formed under the action of n-butyllithium, and then under the action of BBr₃, the final product compound 2 was formed with a yield of 15%, MS(ASAP)=716.65.

### Example 3

The synthetic route of the compound 3 is shown as follows:

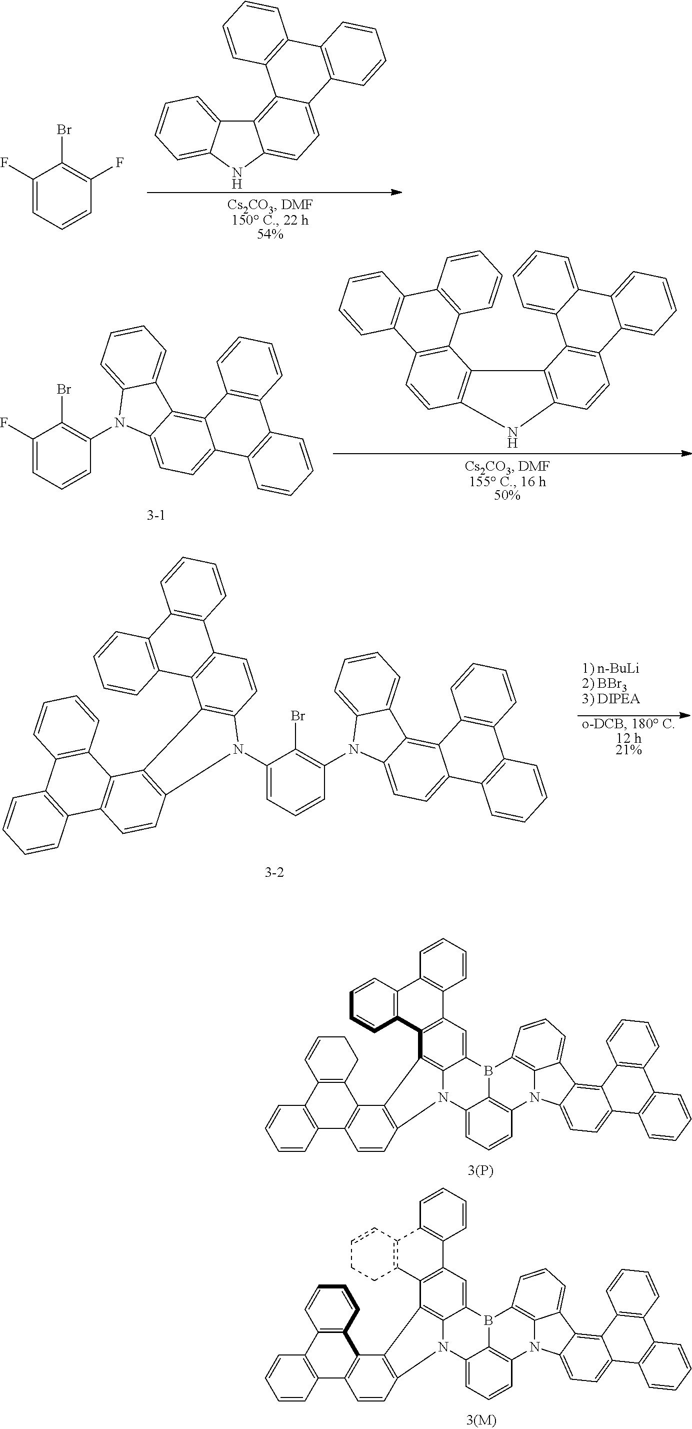

### Synthesis of Compound 3-1:

The synthetic procedure was similar to that of the compound 1-1, the compound 3-1 (yield: 54%) was formed under the action of alkali, MS(ASAP)=490.38.

### Synthesis of Compound 3-2:

The synthetic procedure was similar to that of the compound 1-2, the compound 3-2 (yield: 50%) was formed under the action of alkali, MS(ASAP)=937.94.

### Synthesis of Compound 3:

The synthetic procedure was similar to that of the compound 1, Li salt was formed under the action of n-butyllithium, and then under the action of BBr₃, the final product compound 3 was formed with a yield of 21%, MS(ASAP)=866.83.

### Example 4

The synthetic route of the compound 4 is shown as follows:

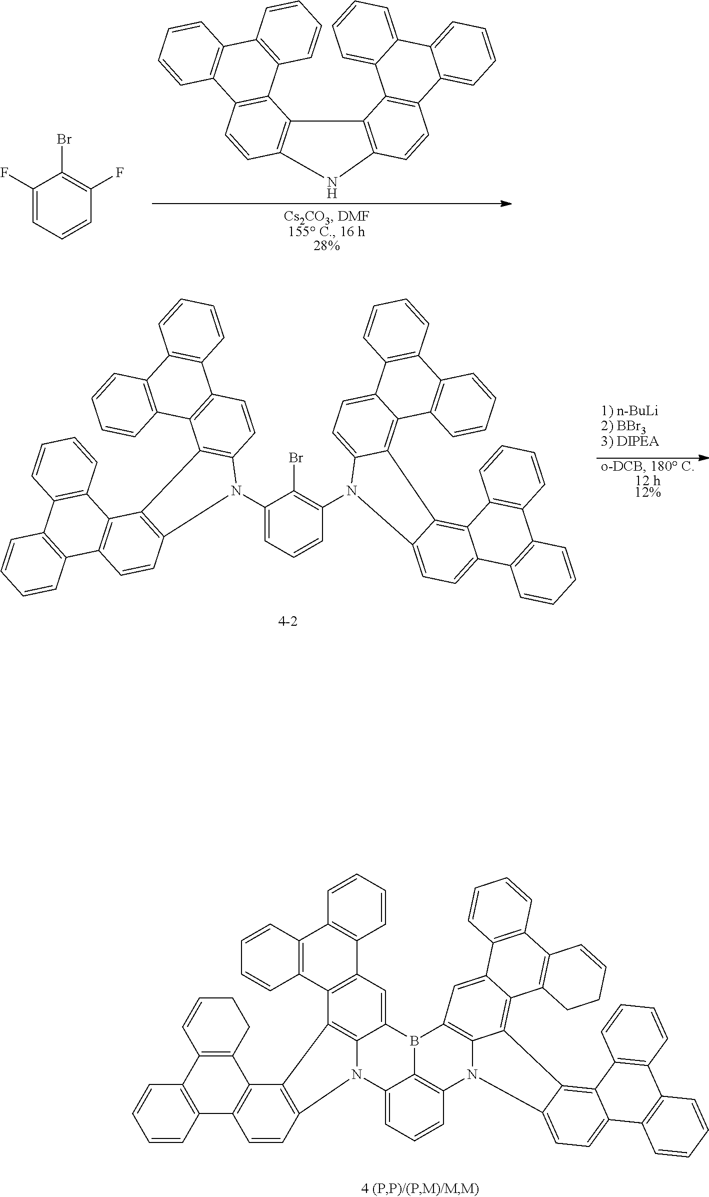

### Synthesis of Compound 4-2:

The synthetic procedure was similar to that of the compound 1-2, the compound 4-2 (yield: 28%) was formed under the action of alkali, MS(ASAP)=1088.12.

### Synthesis of Compound 4:

The synthetic procedure was similar to that of the compound 1, Li salt was formed under the action of n-butyllithium, and then under the action of BBr₃, the final product compound 4 was formed with a yield of 12%, MS(ASAP)=1003.99.

### Example 5

The synthetic route of the compound 5 is shown as follows:

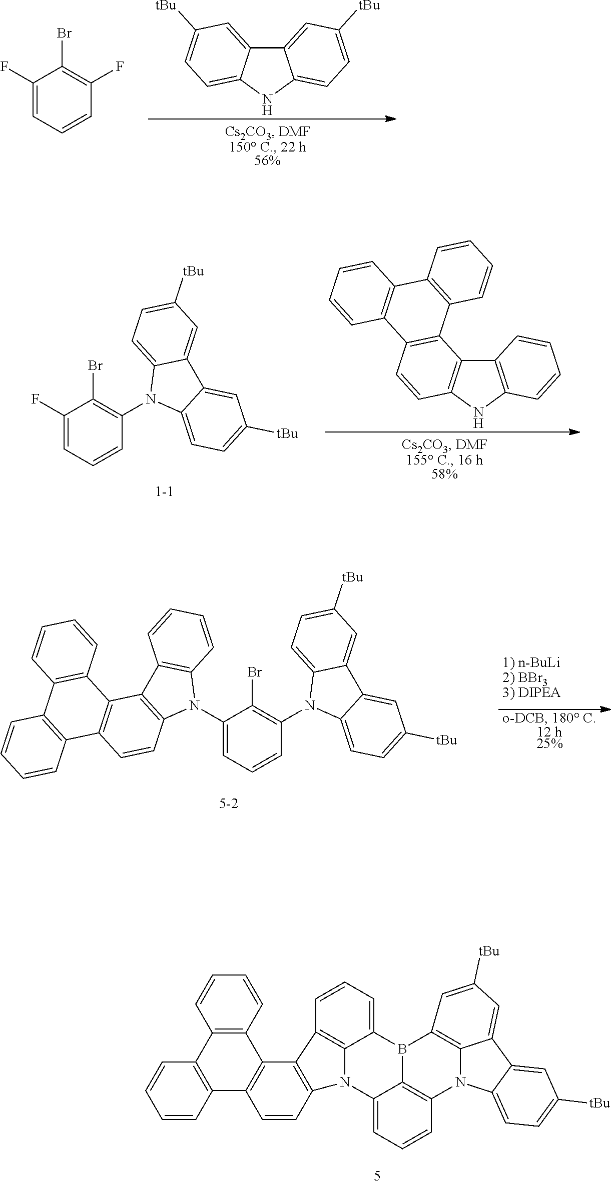

### Synthesis of Compound 5-2:

The synthetic procedure was similar to that of the compound 1-2, the compound 5-2 (yield: 58%) was formed under the action of alkali, MS(ASAP)=749.80.

### Synthesis of Compound 5:

The synthetic procedure was similar to that of the compound 1, Li salt was formed under the action of n-butyllithium, and then under the action of BBr₃, the final product compound 5 was formed with a yield of 25%, MS(ASAP)=678.69.

### Example 6

The synthetic route of the compound 6 is shown as follows:

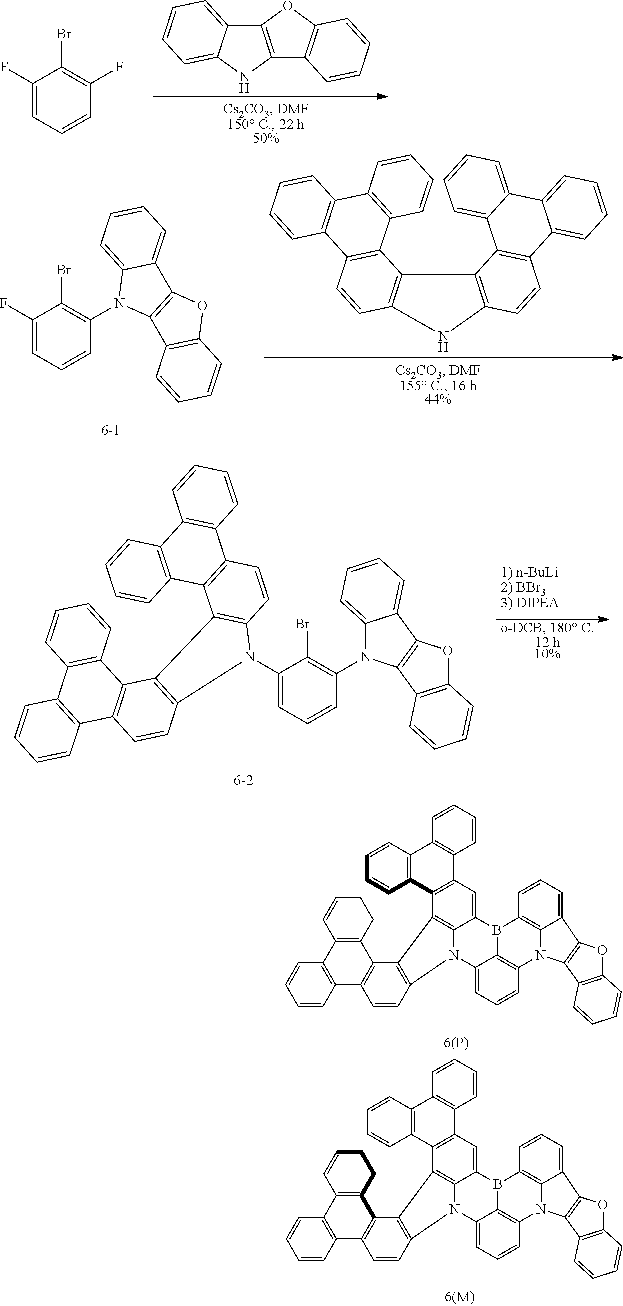

### Synthesis of Compound 6-1:

The synthetic procedure was similar to that of the compound 1-1, the compound 6-1 (yield: 50%) was formed under the action of alkali, MS(ASAP)=380.22.

### Synthesis of Compound 6-2:

The synthetic procedure was similar to that of the compound 1-2, the compound 6-2 (yield: 44%) was formed under the action of alkali, MS(ASAP)=827.78.

### Synthesis of Compound 6:

The synthetic procedure was similar to that of the compound 1, Li salt was formed under the action of n-butyllithium, and then under the action of BBr₃, the final product compound 6 was formed with a yield of 10%, MS(ASAP)=756.67.

### Example 7

The synthetic route of the compound 7 is shown as follows:

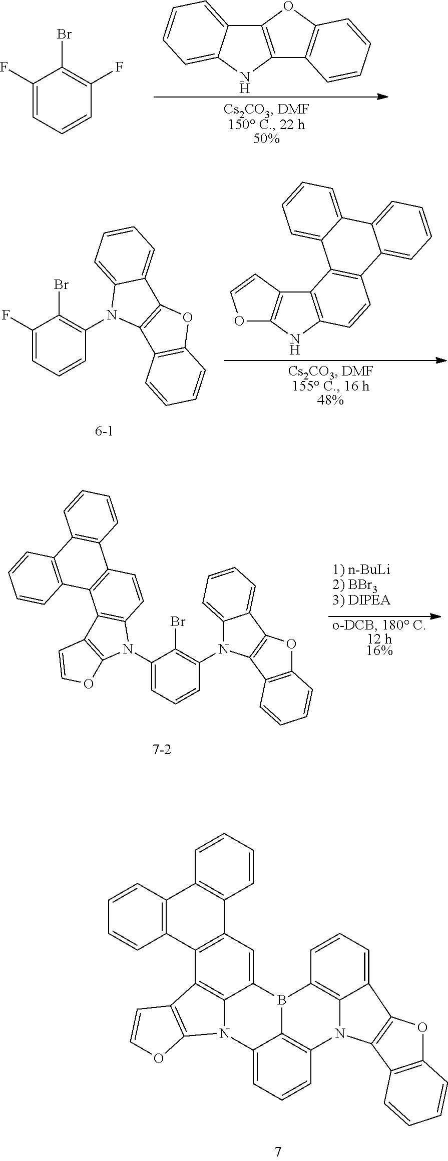

### Synthesis of Compound 7-2:

The synthetic procedure was similar to that of the compound 1-2, the compound 7-2 (yield: 48%) was formed under the action of alkali, MS(ASAP)=667.56.

### Synthesis of Compound 7:

The synthetic procedure was similar to that of the compound 1, Li salt was formed under the action of n-butyllithium, and then under the action of BBr₃, the final product compound 7 was formed with a yield of 16%, MS(ASAP)=596.45.

### Example 8

The synthetic route of the compound 8 is shown as follows:

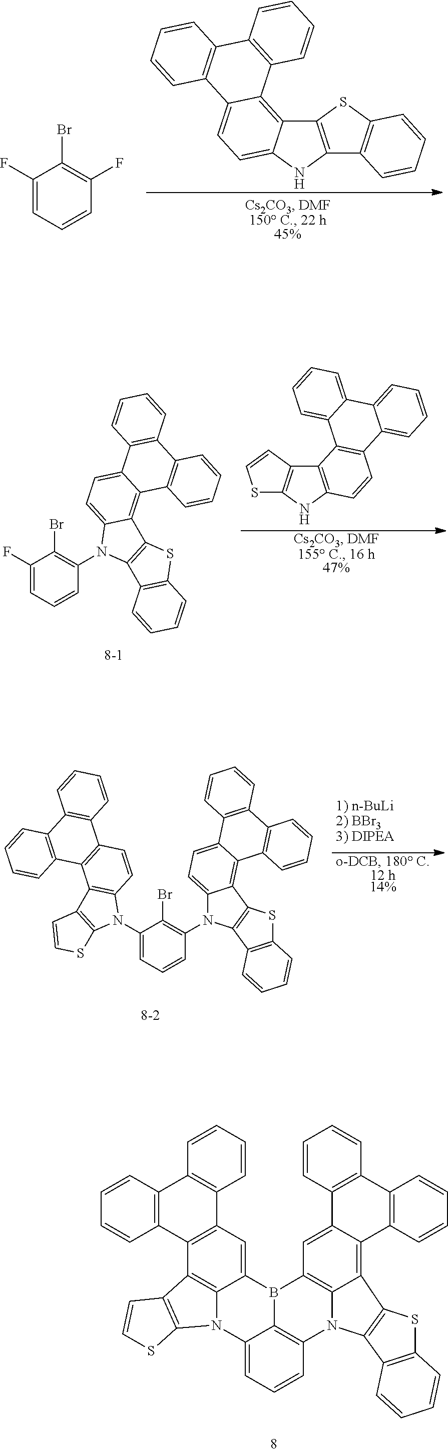

### Synthesis of Compound 8-1:

The synthetic procedure was similar to that of the compound 1-1, the compound 8-1 (yield: 45%) was formed under the action of alkali, MS(ASAP)=546.46.

### Synthesis of Compound 8-2:

The synthetic procedure was similar to that of the compound 1-2, the compound 8-2 (yield: 47%) was formed under the action of alkali, MS(ASAP)=849.86.

### Synthesis of Compound 8:

The synthetic procedure was similar to that of the compound 1, Li salt was formed under the action of n-butyllithium, and then under the action of BBr₃, the final product compound 8 was formed with a yield of 14%, MS(ASAP)=778.75.

### Example 9

The synthetic route of the compound 9 is shown as follows:

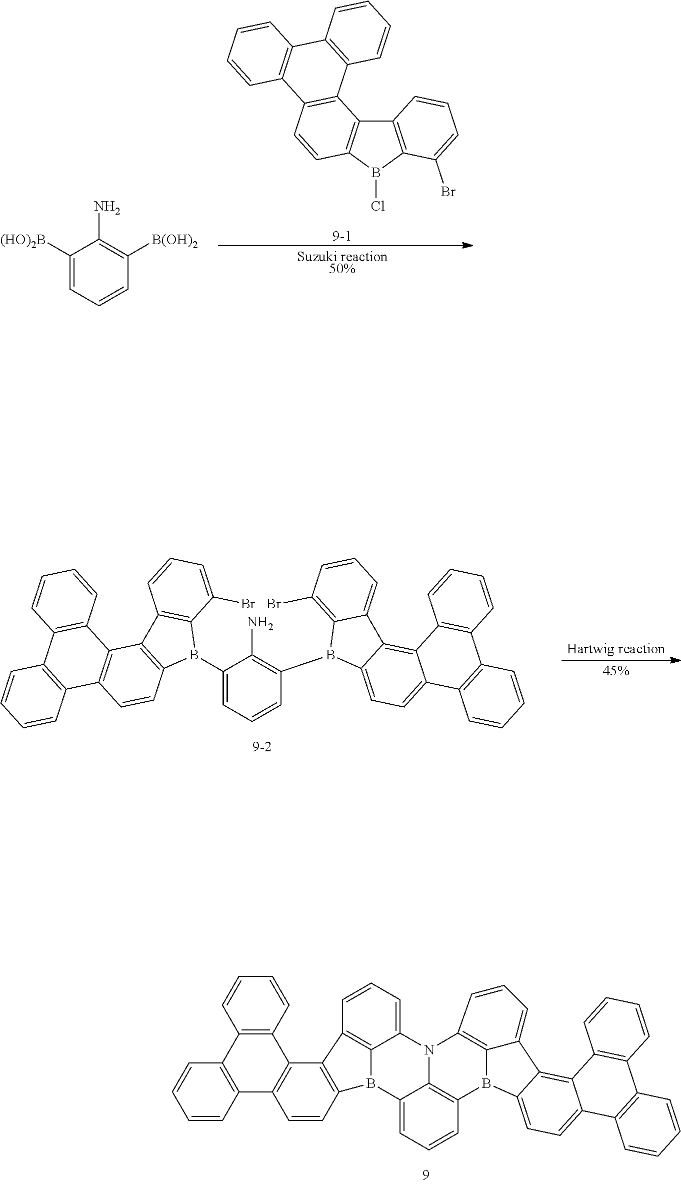

### Synthesis of Compound 9-2:

Compound 9-2 was synthesized via the classical Suzuki reaction, which utilizing the electron withdrawing effect of B atom, it preferentially reacts with chlorine to form C—N bond and was Pd-catalyzed to obtain compound 9-2 (yield: 50%), MS(ASAP)=855.10.

### Synthesis of Compound 9:

The synthetic procedure was similar to that of the compound 1, Li salt was formed under the action of n-butyllithium, and then under the action of BBr₃, the final product compound 9 was formed with a yield of 45%, MS(ASAP)=713.45.

### Example 10

The synthetic route of the compound 10 is shown as follows:

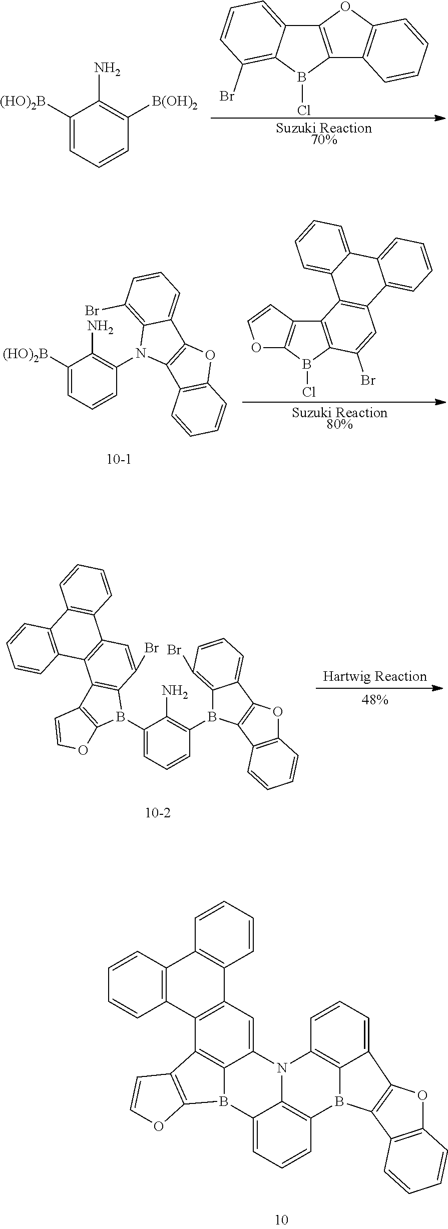

### Synthesis of Compound 10-1:

The synthetic procedure was similar to that of the compound 9-2, the compound 10-1 (yield: 70%) was synthesized via the classical Suzuki reaction, MS(ASAP)=364.24.

### Synthesis of Compound 10-2:

The synthetic procedure was similar to that of the compound 9-2, the compound 10-2 (yield: 80%) was synthesized via the classical Suzuki reaction, MS(ASAP)=735.48.

### Synthesis of Compound 10:

The synthetic procedure was similar to that of the compound 9, Li salt was formed under the action of n-butyllithium, and then under the action of BBr₃, the final product compound 10 was formed with a yield of 48%, MS(ASAP)=593.26.

### Example 11

The synthetic route of the compound 11 is shown as follows:

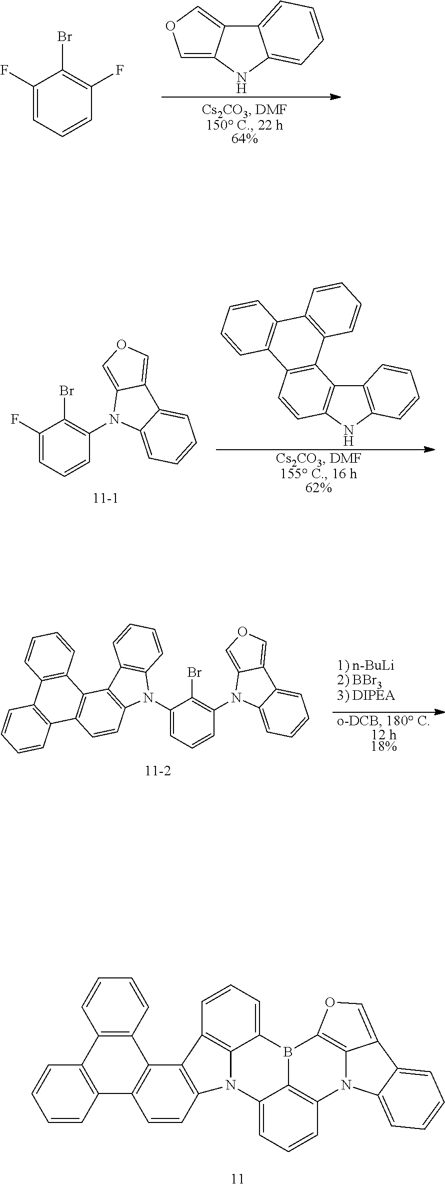

### Synthesis of Compound 11-1:

The synthetic procedure was similar to that of the compound 1-1, the compound 11-1 (yield: 64%) was formed under the action of alkali, MS(ASAP)=330.16.

### Synthesis of Compound 11-2:

The synthetic procedure was similar to that of the compound 1-2, the compound 11-2 (yield: 62%) was formed under the action of alkali, MS(ASAP)=627.54.

### Synthesis of Compound 11:

The synthetic procedure was similar to that of the compound 1, Li salt was formed under the action of n-butyllithium, and then under the action of BBr₃, the final product compound 11 was formed with a yield of 18%, MS(ASAP)=556.43.

### Example 12

The synthetic route of the compound 12 is shown as follows:

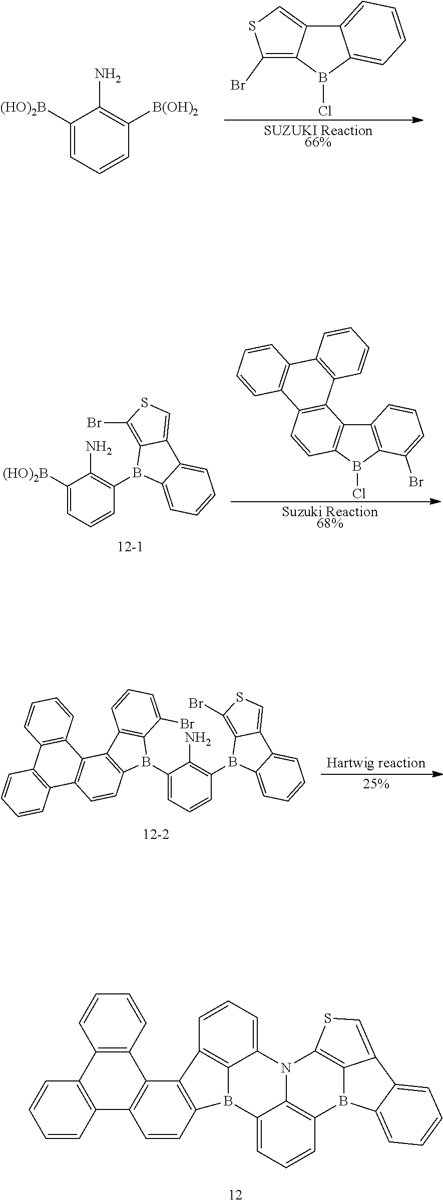

### Synthesis of Compound 12-1:

The synthetic procedure was similar to that of the compound 9-2, the compound 12-1 (yield: 66%) was synthesized via the classical Suzuki reaction, MS(ASAP)=330.24.

### Synthesis of Compound 12-2:

The synthetic procedure was similar to that of the compound 9-2, the compound 12-2 (yield: 68%) was synthesized via the classical Suzuki reaction, MS(ASAP)=711.52.

### Synthesis of Compound 12:

The synthetic procedure was similar to that of the compound 9, Li salt was formed under the action of n-butyllithium, and then under the action of BBr₃, the final product compound 12 was formed with a yield of 25%, MS(ASAP)=569.30.

### Example 13

The synthetic route of the compound 13 is shown as follows:

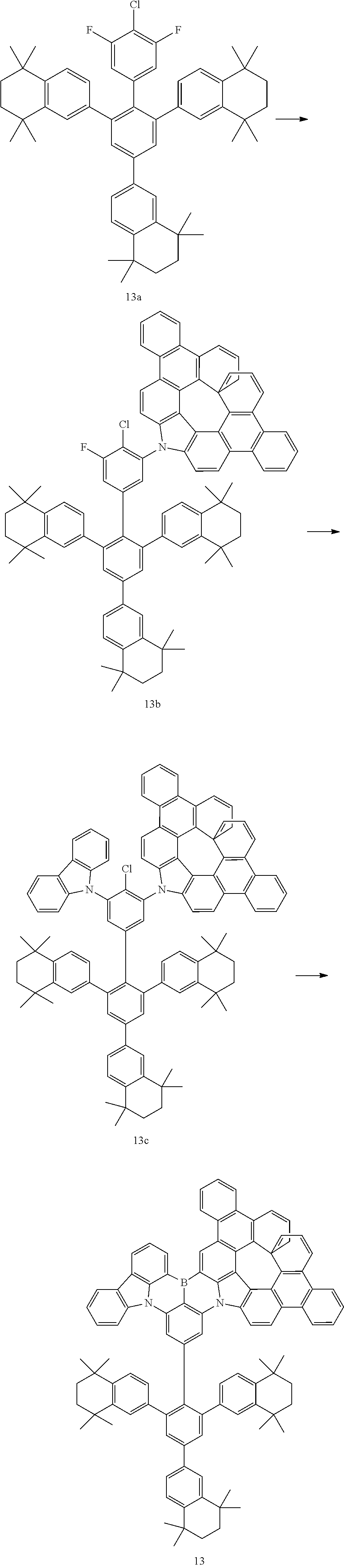

The procedure is as follows.

### Synthesis of Compound 13b:

7H-dibenzo[c,g]carbazole (5 g, 10.7 mmol), cesium carbonate (20 g, 300.0 mmol), compound 13a, and 300 mL of ultradry DMF were added to a 5000 mL single-necked flask under argon atmosphere, then stirred at 150° C. for 22 h. After the reaction was cooled to room temperature and then poured into water, the resulting mixture was filtered, the obtained crude product was purified by column chromatography (eluent: PE), then the result was recrystallized with dichloromethane and methanol to yield 4.03 g (yield: 42%) of white solid (compound 13b).

### Synthesis of Compound 13c:

Compound 13b (3 g, 2.4 mmol), carbazole (1 g, 2.14 mmol), cesium carbonate (1.16 g, 3.56 mmol), and 12 mL of ultradry DMF were added to a 50 mL schlenk flask under argon atmosphere, then stirred at 155° C. for 16 h. After the reaction was cooled to room temperature, the resulting mixture was extracted with dichloromethane three times, the organic phase was washed with water and saturated brine, then the result was dried with anhydrous magnesium sulfate. After the filtration, the obtained crude product was purified by column chromatography (eluent: PE:CH₂Cl₂=10:1), then the resulting product was recrystallized with dichloromethane and methanol to yield 2.1 g (yield: 53%) of pale-yellow solid (compound 13c).

### Synthesis of Compound 13:

Compound 13c (300 mg, 0.114 mmol) and 4 mL of 1,2-dichlorobenzene were added to a 50 mL schlenk tube under argon atmosphere, n-butyllithium (0.3 mmol, 1.6 M in hexane) was added to the above mixture at 0° C. After stirring for 2 h, boron tribromide (5.4 mmol, 1.0 M in heptane) was added dropwise to the reaction system at 0° C., the reaction mixture was moved to room temperature and stirred for 16 h. After removing the low-boiling solvent under reduced pressure, N,N-diisopropylethylamine (0.1 mL) was added dropwise to the reaction system at 0° C. and stirred at 180° C. for 12 h. After the reaction system was cooled to room temperature, the solvent was removed under reduced pressure, the result was purified by column chromatography (eluent: PE:CH₂Cl₂=5:1), then recrystallized with dichloromethane and methanol to yield 50.12 mg (yield: 10%) of orange solid (compound 13).

### Example 14

The synthetic route of the compound 14 is shown as follows:

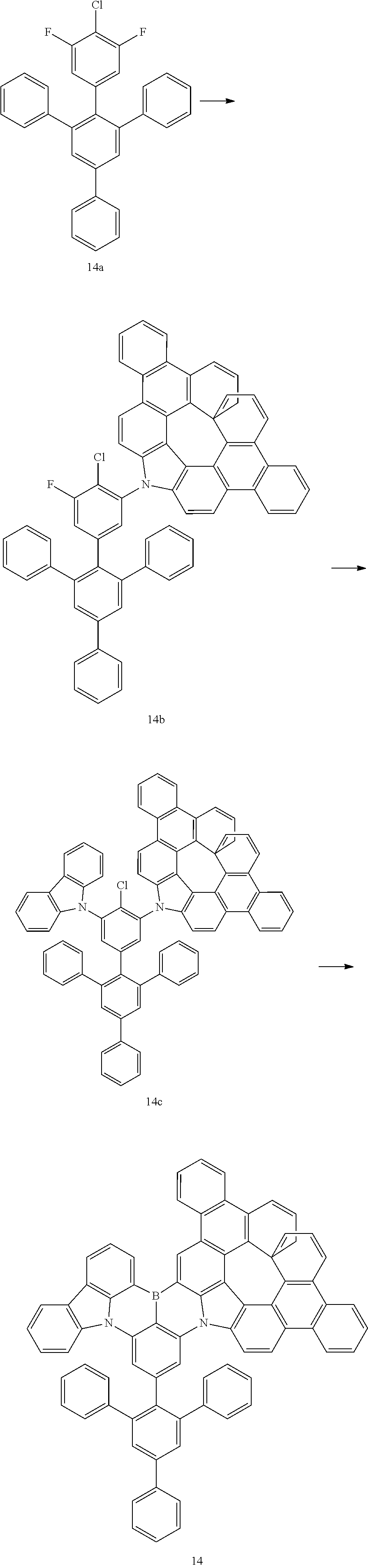

The procedure is as follows.

### Synthesis of Compound 14b:

7H-dibenzo[c,g]carbazole (5 g, 10.7 mmol), cesium carbonate (20 g, 300.0 mmol), compound 14a, and 300 mL of ultradry DMF were added to a 5000 mL single-necked flask under argon atmosphere, then stirred at 150° C. for 22 h. After the reaction was cooled to room temperature and then poured into water, the resulting mixture was filtered, the obtained crude product was purified by column chromatography (eluent: PE), then the result was recrystallized with dichloromethane and methanol to yield 4.12 g (yield: 43%) of white solid (compound 14b).

### Synthesis of Compound 14c:

Compound 14b (3 g, 2.7 mmol), carbazole (1.5 g, 3.21 mmol), cesium carbonate (1.16 g, 3.56 mmol), and 12 mL of ultradry DMF were added to a 50 mL schlenk flask under argon atmosphere, then stirred at 155° C. for 16 h. After the reaction was cooled to room temperature, the resulting mixture was extracted with dichloromethane three times, the organic phase was washed with water and saturated brine, then the result was dried with anhydrous magnesium sulfate. After the filtration, the obtained crude product was purified by column chromatography (eluent: PE:CH₂Cl₂=10:1), then the resulting product was recrystallized with dichloromethane and methanol to yield 2.18 mg (yield: 53%) of pale-yellow solid (compound 14c).

### Synthesis of Compound 14:

Compound 14c (300 mg, 0.114 mmol) and 4 mL of 1,2-dichlorobenzene were added to a 50 mL schlenk tube under argon atmosphere, n-butyllithium (0.3 mmol, 1.6 M in hexane) was added to the above mixture at 0° C. After stirring for 2 h, boron tribromide (5.4 mmol, 1.0 M in heptane) was added dropwise to the reaction system at 0° C., the reaction mixture was moved to room temperature and stirred for 16 h. After removing the low-boiling solvent under reduced pressure, N,N-diisopropylethylamine (0.1 mL) was added dropwise to the reaction system at 0° C. and stirred at 180° C. for 12 h. After the reaction system was cooled to room temperature, the solvent was removed under reduced pressure, the result was purified by column chromatography (eluent: PE:CH₂Cl₂=5:1), then recrystallized with dichloromethane and methanol to yield 50.23 mg (yield: 11%) of orange solid (compound 14).

### Example 15

The synthetic route of the compound 15 is shown as follows:

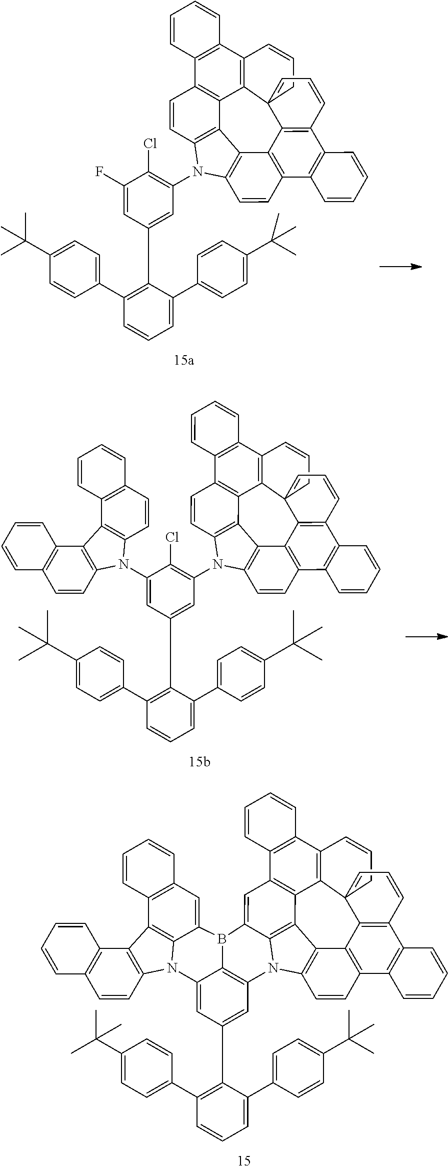

### Synthesis of Compound 15b:

The synthetic procedure was similar to that of the compound 14c, the compound 15b (yield: 51%) was formed under the action of alkali, MS(ASAP)=1183.

### Synthesis of Compound 15:

The synthetic procedure was similar to that of the compound 14, Li salt was formed under the action of n-butyllithium, and then under the action of BBr₃, the final product compound 15 was formed with a yield of 12%, MS(ASAP)=1157.

### Example 16

The synthetic route of the compound 16 is shown as follows:

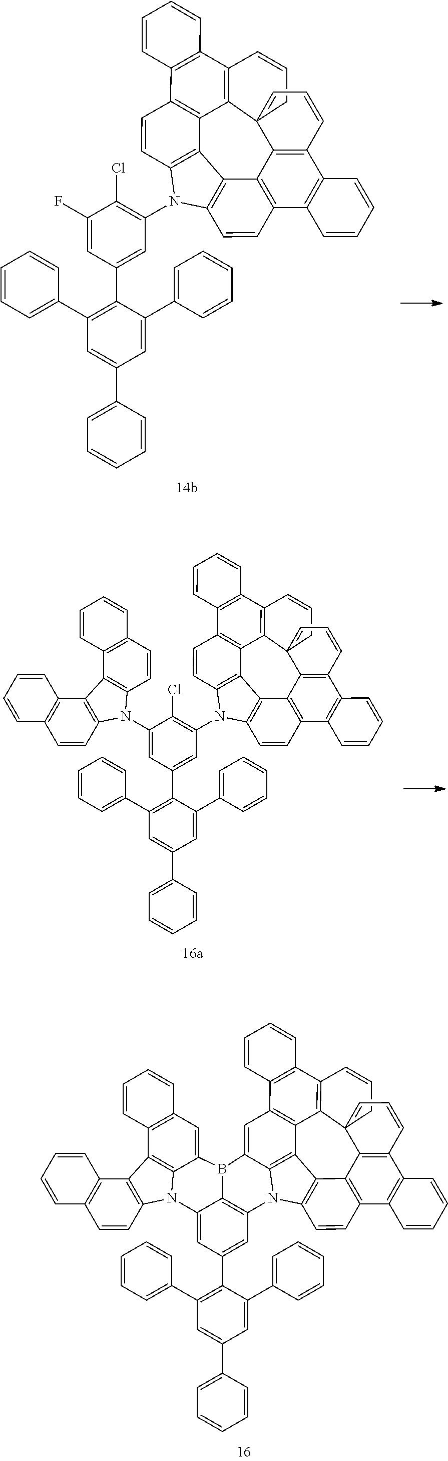

### Synthesis of Compound 16a:

The synthetic procedure was similar to that of the compound 14c, the compound 16a (yield: 51%) was formed under the action of alkali, MS(ASAP)=1147.

### Synthesis of Compound 16:

The synthetic procedure was similar to that of the compound 14, Li salt was formed under the action of n-butyllithium, and then under the action of BBr₃, the final product compound 16 was formed with a yield of 12%, MS(ASAP)=1121.

### Example 17

The synthetic route of the compound 17 is shown as follows:

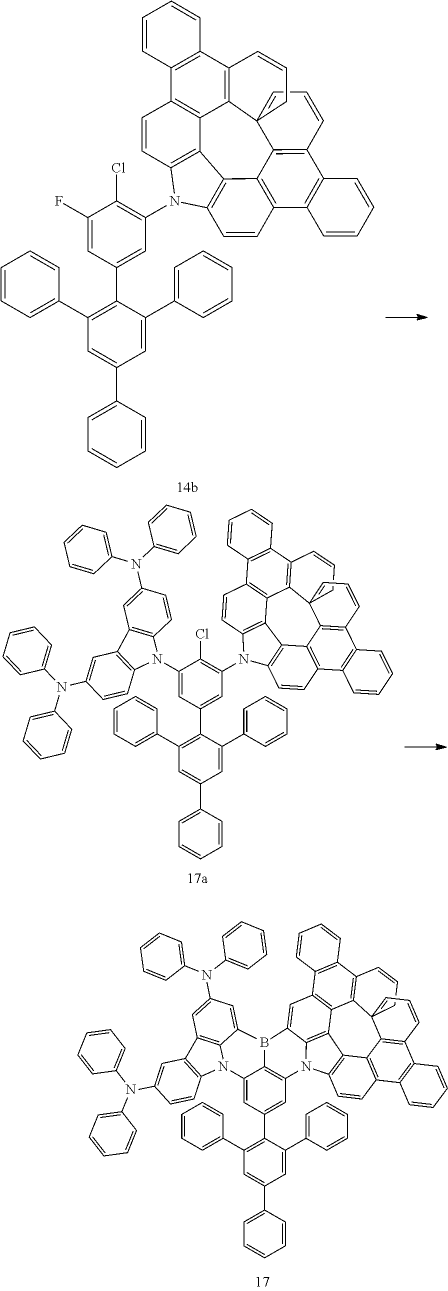

### Synthesis of Compound 17a:

The synthetic procedure was similar to that of the compound 14c, the compound 17a (yield: 51%) was formed under the action of alkali, MS(ASAP)=1382.

### Synthesis of Compound 17:

The synthetic procedure was similar to that of the compound 14, Li salt was formed under the action of n-butyllithium, and then under the action of BBr₃, the final product compound 17 was formed with a yield of 11%, MS(ASAP)=1357.

### Example 18

The synthetic route of the compound 18 is shown as follows:

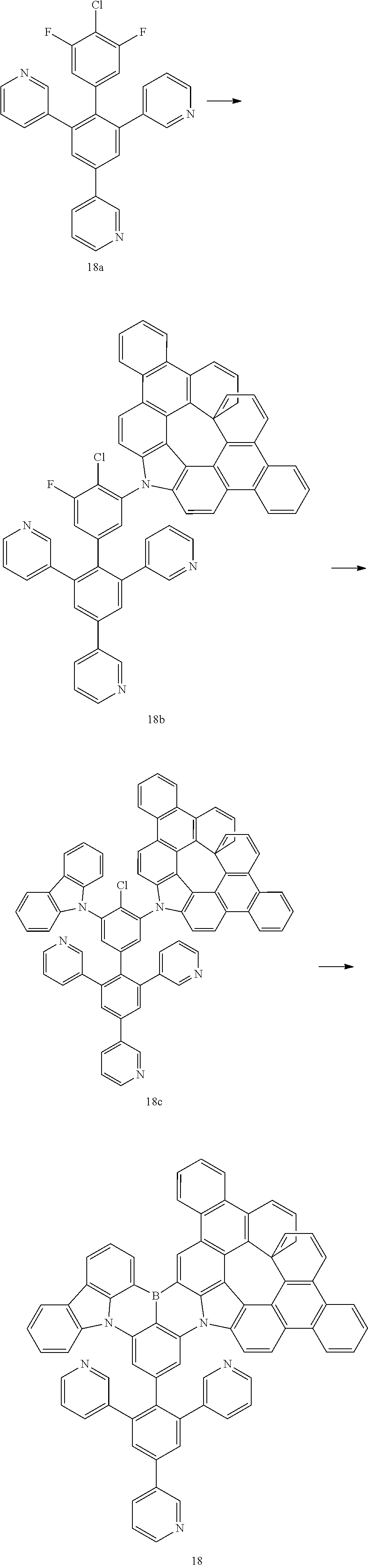

### Synthesis of Compound 18b:

The synthetic procedure was similar to that of the compound 14b, the compound 18b (yield: 50%) was formed under the action of alkali, MS(ASAP)=903.46.

### Synthesis of Compound 18c:

The synthetic procedure was similar to that of the compound 14c, the compound 18c (yield: 51%) was formed under the action of alkali, MS(ASAP)=1050.

### Synthesis of Compound 18:

The synthetic procedure was similar to that of the compound 14, Li salt was formed under the action of n-butyllithium, and then under the action of BBr₃, the final product compound 18 was formed with a yield of 10%, MS(ASAP)=1024.

### Example 19

The synthetic route of the compound 19 is shown as follows:

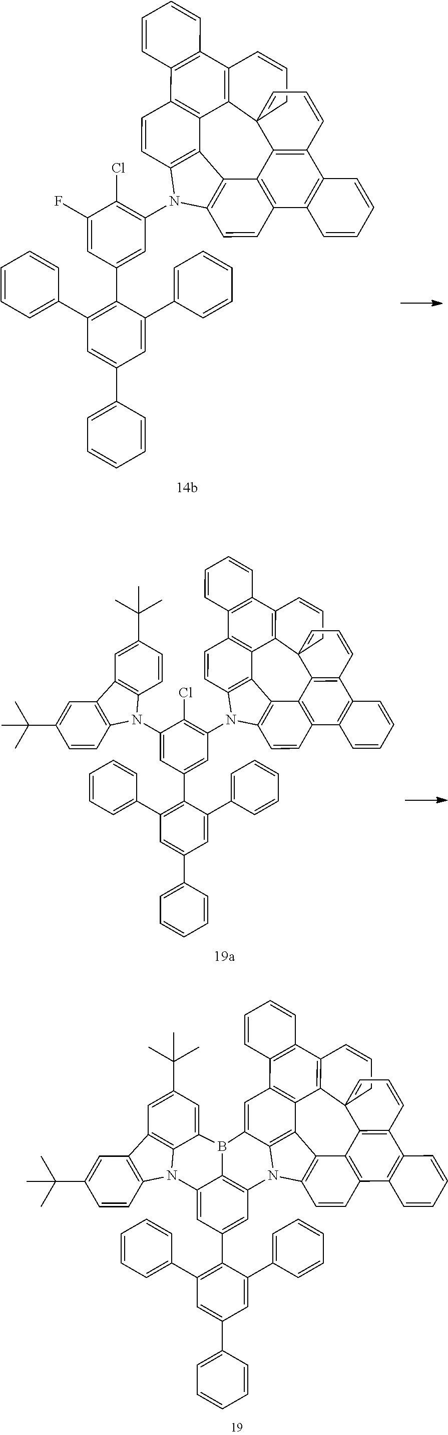

### Synthesis of Compound 19a:

The synthetic procedure was similar to that of the compound 14c, the compound 19a (yield: 52%) was formed under the action of alkali, MS(ASAP)=1159.

### Synthesis of Compound 19:

The synthetic procedure was similar to that of the compound 14, Li salt was formed under the action of n-butyllithium, and then under the action of BBr₃, the final product compound 19 was formed with a yield of 12%, MS(ASAP)=1133.

### Example 20

The synthetic route of the compound 20 is shown as follows:

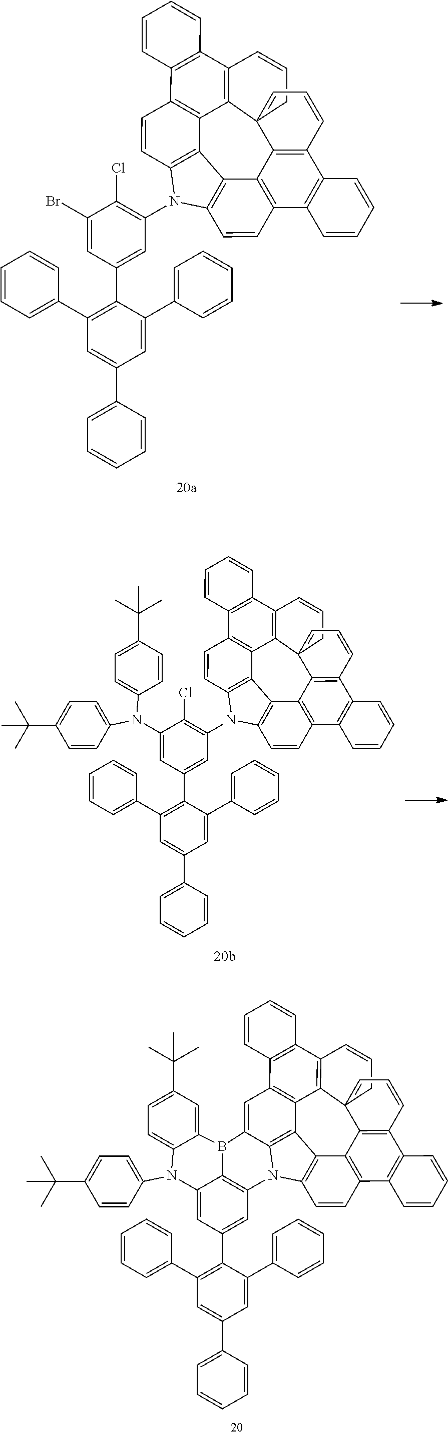

### Synthesis of Compound 20b:

The compound 20b (yield: 66%) was synthesized via the classical Buchwald-Hartwig reaction with 20a and bis(4-tert-butylphenyl)amine, MS(ASAP)=1161.

### Synthesis of Compound 20:

The synthetic procedure was similar to that of the compound 14, Li salt was formed under the action of n-butyllithium, and then under the action of BBr₃, the final product compound 20 was formed with a yield of 11%, MS(ASAP)=1135.

### Example 21

The synthetic route of the compound 21 is shown as follows:

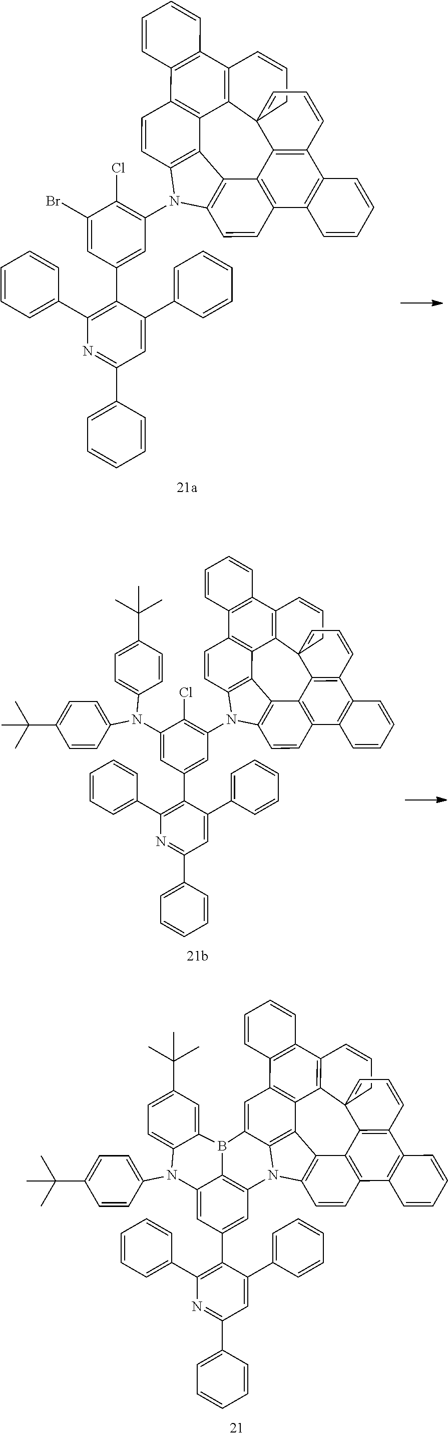

### Synthesis of Compound 21b:

The synthetic procedure was similar to that of the compound 20b, the compound 21b (yield: 67%) was synthesized via the classical Buchwald-Hartwig reaction, MS(ASAP)=1162.

### Synthesis of Compound 21:

The synthetic procedure was similar to that of the compound 14, Li salt was formed under the action of n-butyllithium, and then under the action of BBr₃, the final product compound 21 was formed with a yield of 11%, MS(ASAP)=1136.

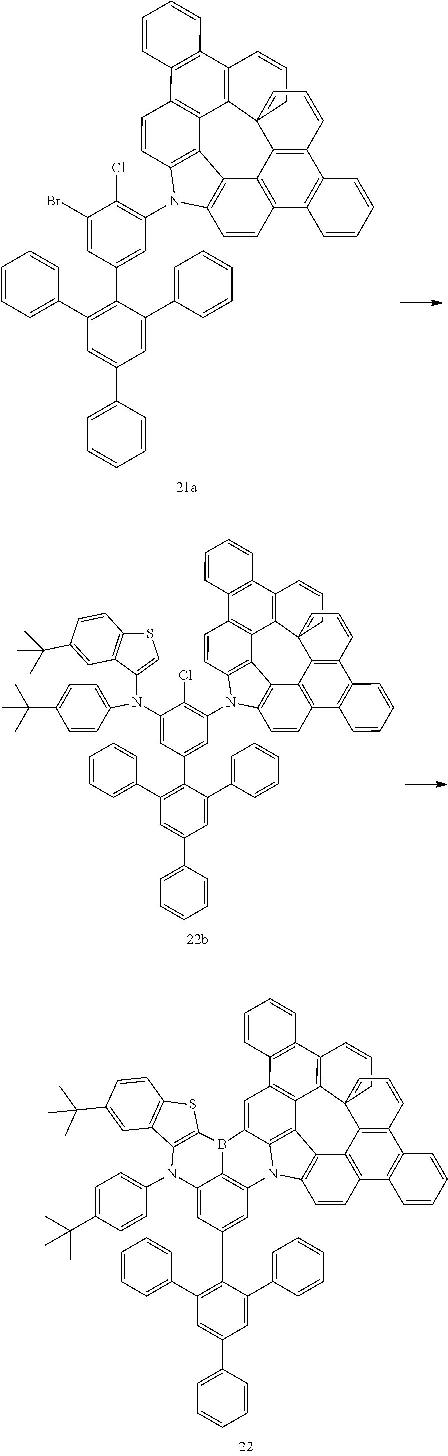

### Example 22

The synthetic route of the compound 22 is shown as follows:

### Synthesis of Compound 22b:

The synthetic procedure was similar to that of the compound 20b, the compound 22b (yield: 78%) was synthesized via the classical Buchwald-Hartwig reaction, MS(ASAP)=1218.

### Synthesis of Compound 22:

The synthetic procedure was similar to that of the compound 14, Li salt was formed under the action of n-butyllithium, and then under the action of BBr₃, the final product compound 22 was formed with a yield of 10%, MS(ASAP)=1191.

### Example 23

The synthetic route of the compound 23 is shown as follows:

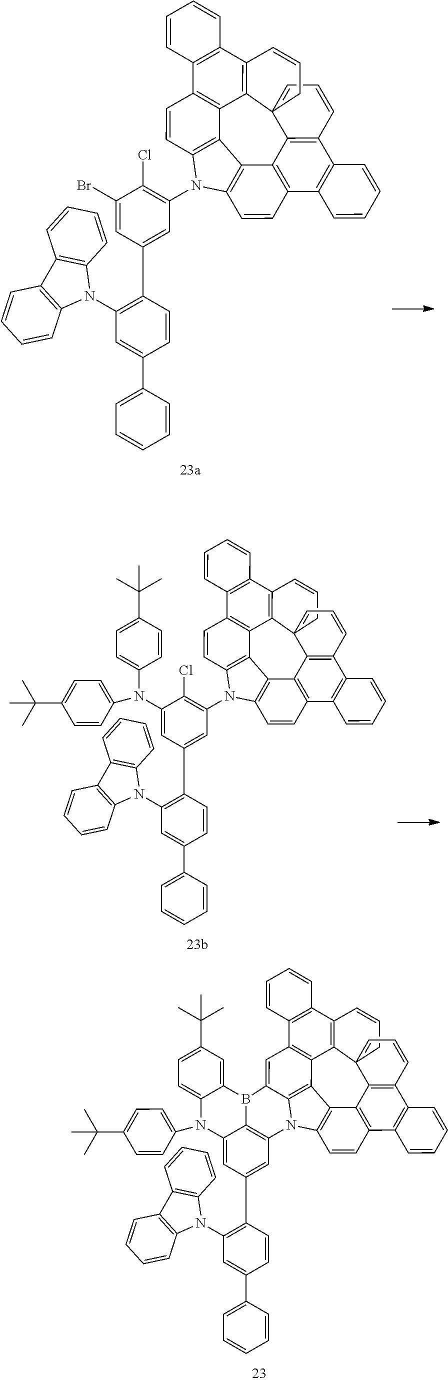

### Synthesis of Compound 23b:

The synthetic procedure was similar to that of the compound 20b, the compound 23b (yield: 67%) was synthesized via the classical Buchwald-Hartwig reaction, MS(ASAP)=1174.

### Synthesis of Compound 23:

The synthetic procedure was similar to that of the compound 14, Li salt was formed under the action of n-butyllithium, and then under the action of BBr₃, the final product compound 23 was formed with a yield of 10%, MS(ASAP)=1148.

### Example 24

The synthetic route of the compound 24 is shown as follows:

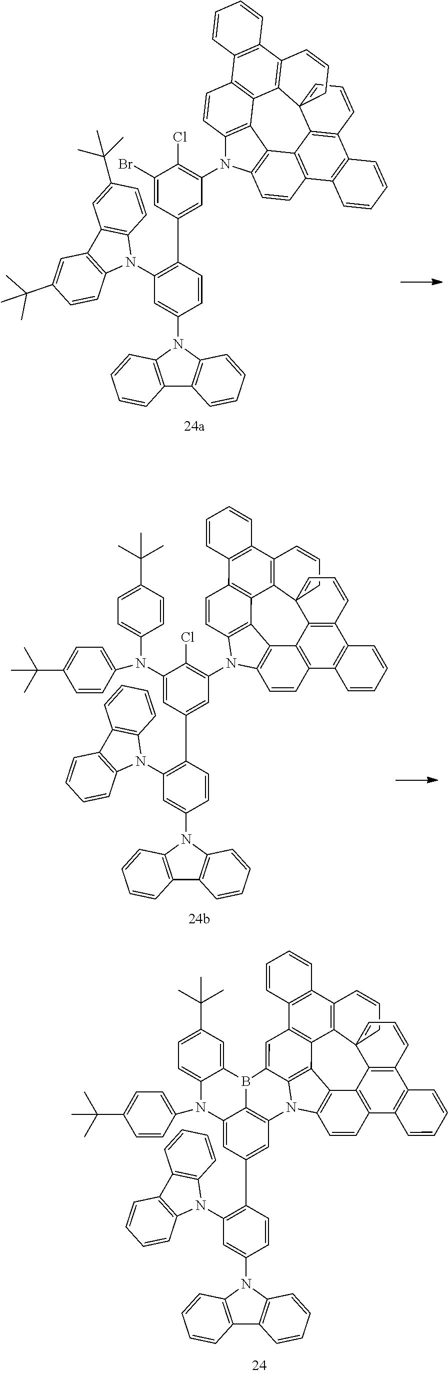

### Synthesis of Compound 24b:

The synthetic procedure was similar to that of the compound 20b, the compound 24b (yield: 67%) was synthesized via the classical Buchwald-Hartwig reaction, MS(ASAP)=1264.

### Synthesis of Compound 24:

The synthetic procedure was similar to that of the compound 14, Li salt was formed under the action of n-butyllithium, and then under the action of BBr₃, the final product compound 24 was formed with a yield of 12%, MS(ASAP)=1237.

### 2. Energy Structure of Compounds

The energy level of the organic compound material can be calculated by quantum computation, for example, using TD-DFT (time-dependent density functional theory) by Gaussian 09W (Gaussian Inc.), the specific simulation methods of which can be found in WO2011141110. Firstly, the molecular geometry is optimized by semi-empirical method “Ground State/Semi-empirical/Default Spin/AM1” (Charge 0/Spin Singlet), and then the energy structure of organic molecules is calculated by TD-DFT (time-dependent density functional theory) “TD-SCF/DFT/Default Spin/B3PW91” and the basis set “6-31G (d)” (Charge 0/Spin Singlet). The HOMO and LUMO energy levels are calculated using the following calibration formula, where S₁, T₁, and resonant factor f(S₁) are used directly.

HOMO(eV)=((HOMO(G)×27.212)−0.9899)/1.1206

LUMO(eV)=((LUMO(G)×27.212)−2.0041)/1.385

Where HOMO(G) and LUMO(G) are the direct calculation results of Gaussian 09W, in units of Hartree. The results are shown in Table 1 below.

TABLE 1

| | | Δ | | | | |
|---|---|---|---|---|---|---|
| | HOMO | HOMO | LUMO | Δ LUMO | | |
| Materials | [eV] | [eV] | [eV] | [eV] | S₁ [eV] | f(S₁) |
| 1 | −5.53 | 0.26 | −3.04 | 0.58 | 2.54 | 0.481 |
| 2 | −5.62 | 0.37 | −2.97 | 0.45 | 2.72 | 0.636 |
| 3 | −5.58 | 0.24 | −3.10 | 0.51 | 2.52 | 0.593 |
| 4 | −5.55 | 0.27 | −3.19 | 0.49 | 2.37 | 0.640 |
| 5 | −5.55 | 0.23 | −2.87 | 0.56 | 2.78 | 0.529 |
| 6 | −5.60 | 0.32 | −3.12 | 0.74 | 2.53 | 0.408 |
| 7 | −5.61 | 0.29 | −3.03 | 0.72 | 2.66 | 0.354 |
| 8 | −5.62 | 0.25 | −3.16 | 0.68 | 2.51 | 0.473 |
| 9 | −5.89 | 0.05 | −3.28 | 0.33 | 2.54 | 0.010 |
| 10 | −5.77 | 0.06 | −3.34 | 0.34 | 2.21 | 0.011 |
| 11 | 5.53 | 0.42 | −2.78 | 0.41 | 2.91 | 0.520 |
| 12 | −5.96 | 0.04 | −3.27 | 0.50 | 2.57 | 0.012 |
| 13 | −5.53 | 0.24 | −3.1 | 0.4 | 2.5 | 0.3 |
| 14 | −5.525 | 0.234 | −3.022 | 0.549 | 2.5603 | 0.4025 |
| 15 | −5.569 | 0.051 | −3.127 | 0.533 | 2.4752 | 0.4365 |
| 16 | 5.573 | 0.060 | −3.164 | 0.567 | 2.4317 | 0.4553 |
| 17 | −5.171 | 0.229 | −3.051 | 0.559 | 2.1850 | 0.3011 |
| 18 | −5.642 | 0.215 | −3.148 | 0.524 | 2.5270 | 0.4173 |
| 19 | −5.456 | 0.268 | −3.002 | 0.565 | 2.5146 | 0.4569 |
| 20 | −5.331 | 0.328 | −2.848 | 0.516 | 2.5848 | 0.3894 |
| 21 | −5.378 | 0.317 | −2.887 | 0.438 | 2.5859 | 0.3966 |
| 22 | −5.288 | 0.350 | −2.840 | 0.485 | 2.5753 | 0.4830 |
| 23 | −5.334 | 0.276 | −2.863 | 0.475 | 2.5667 | 0.3668 |
| 24 | −5.416 | 0.320 | −2.930 | 0.516 | 2.5726 | 0.3902 |

The “planarity” of the organic molecules can measure the overall planarity of molecules by theoretically calculating their molecular planarity parameter (MPP) values. The MPP values of some molecules are shown in Table 2, and it can be seen that the planarity of the molecules can be significantly improved by introducing different large steric hindrance groups, which further improves the stacking effect of the molecules in devices, and enhances the efficiency and spectrum stability of the molecules in devices.

TABLE 2

| Materials | 1 | 2 | 3 | 18 | 19 | 20 |
|---|---|---|---|---|---|---|
| MPP | 0.841 | 1.091 | 0.871 | 1.367 | 1.372 | 1.493 |

### 3. Preparation and Performance of OLED Devices

### Preparation of OLED Devices

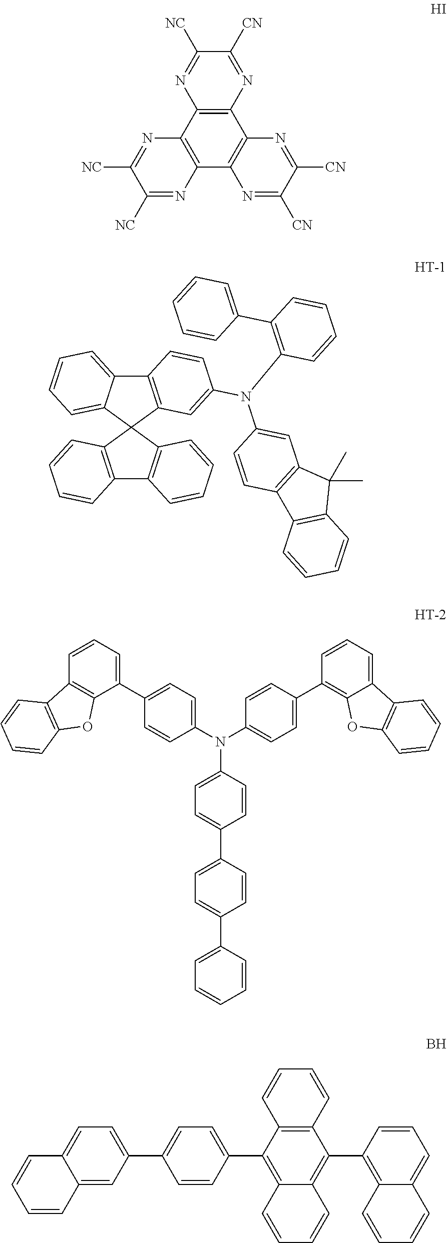

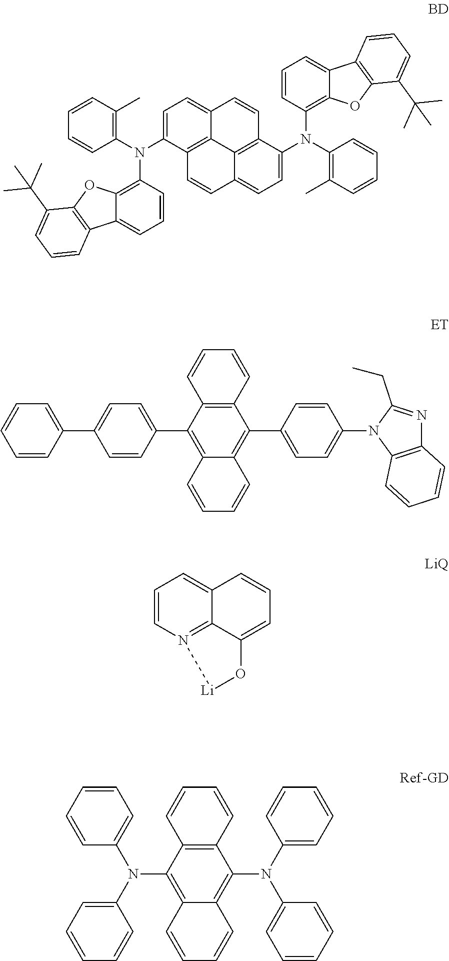

a. Cleaning of the ITO (Indium Tin Oxide) conductive glass substrate: the substrates are washed with various solvents (such as one or more of chloroform, ketone, or isopropyl alcohol), and then treated with UV and ozone.

b. Evaporation: the resultant ITO substrate was mounted on a vacuum deposition apparatus in high vacuum (1×10⁻⁶ mbar), and HI was then vacuum-deposited on the anode to form a hole-injection layer having a thickness of 30 nm, then two hole-transport layers, HT-1 (50 nm) and HT-2 (10 nm) were deposited on the HIL in vacuum deposition sequentially. Then BH, BD, and GD in two different evaporation sources were deposited at a weight ratio of 94:3:3 to form a light-emitting layer having a thickness of 50 nm. Subsequently, a first electron-transport layer (ET) was evaporated, then compound ET and LiQ were placed in two different evaporation units, and co-deposited at a weight ratio of 50:50 to form a second electron-transport layer having a thickness of 25 nm. LiQ was then deposited on the second electron-transport layer to form an electron-injection layer having a thickness of 1 nm, and Al was deposited on the electron-injection layer to form a cathode having a thickness of 100 nm.

c. Encapsulation: encapsulating the device in a nitrogen-regulated glove box with UV curable resin.

The OLEDs were fabricated based on the device structure of HI(10)/HT-1(50)/HT-2(10)/BH:BD:GD=94:3:3(50)/first electron-transport layer(5)/second electron-transport layer ET:LiQ=50:50(25)/LiQ(1)/Al(100).

As shown in Table 3, the device performance of the device examples and the comparative example were tested; where the driving voltage and the current efficiency were measured at a current density of 10 mA/cm²; T95 refers to the relative value of the time at which the luminance of the device examples decreases to 95% of the initial luminance at a constant current density of 20 mA/cm². Both the current efficiency and T95 are referenced to Comparative Example 1.

TABLE 3

| | | | Driving | Current | |
|---|---|---|---|---|---|
| | | FWHM | Voltage | Efficiency | |
| | GD | (nm) | (V) | (cd/A) | T95 |
| Device | Compound 1 | 25 | 4.28 | 210% | 243% |
| Example 1 | | | | | |
| Comparative | Ref-GD | 45 | 4.37 | 100% | 100% |
| Example 1 | | | | | |

Device Example 1 has a narrow FWHM and a significant improvement in current efficiency and lifetime compared to Comparative Example 1. This is due to the presence of the benzophenanthrene groups and the BN fused-ring resonance systems, which can better balance the electron- and hole-transport characteristics of the material, as well as improve the luminescence efficiency of the device and enhance the stability of the material.

### 4. Preparation and Characterization of Color Converters

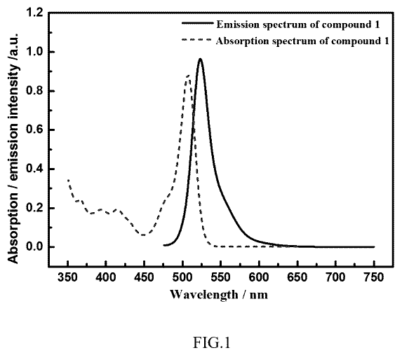

The absorption and emission spectrums of compound 1 in 0.5 mol/L of toluene solution are shown in FIG. 1.

The color converter is prepared with reference to WO2022213993A1. The dopant used is compound 1, the host structure is as follows, the synthesis of which is described in WO2022213993A1:

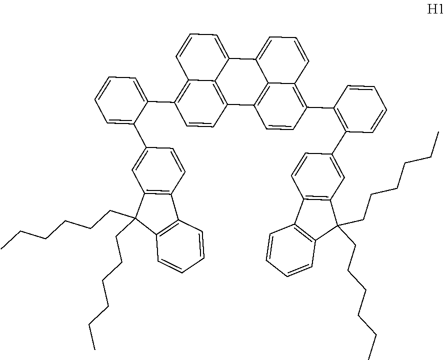 [SMILES: CCCCCCC1(CCCCCC)c2ccccc2-c2ccc(-c3ccccc3-c3ccc4c5ccc(-c6ccccc6-c6ccc7c(c6)C(CCCCCC)(CCCCCC)c6ccccc6-7)c6cccc(c7cccc3c74)c65)cc21]

100 mg of polymethyl methacrylate (PMMA), 50 mg of the host material (H1), and 5 mg of compound 1 (i.e., the dopant material for green color conversion) were dissolved in 1 mL of n-butyl acetate to obtain a clear solution (i.e., a printing ink). Using a KW-4a spin coater, the above clear solution was spun-coated on the surface of the quartz glass to form an uniform thin film, which is an organic functional film (i.e., a color conversion film). When the thickness of the most color conversion films is about 3 μm, most of the obtained color conversion films have an optical density reach 3 or more.

The green color conversion film can be disposed in a blue self-emitting unit that exhibits blue emission at 460 nm. Through the green color converter, the blue light could change to a green light ranging from 523 nm to 525 nm, and the FWHM is 28 nm.

### 5. Color Converter with Chirality

### Separation of Chiral Molecules:

The compound 1 was dissolved in an organic solvent, then the chiral compounds with P and M configurations were split and purified by chiral split column chromatography to yield chiral molecular compound with P configuration (1-P).

A chiral color converter comprising the chiral molecular compound (1-P) was prepared in the same way as in Example 4. Its chiral asymmetry factor (g)=5.2×10⁻⁴ was measured, where g=(I_{left}−I_{right}), (I_{left}+I_{right}), I_{right} and I_{left} represent the intensities of right-handed and left-handed rotation, respectively.

It will be understood that the application of the present disclosure is not limited to the foregoing examples, and may be improved or transformed in accordance with the foregoing description to one of ordinary skill in the art, all these modifications and improvements are within the scope of the present disclosure.

What is claimed is:

1. A benzophenanthrene-containing organic compound, comprising a structure of formula (I): 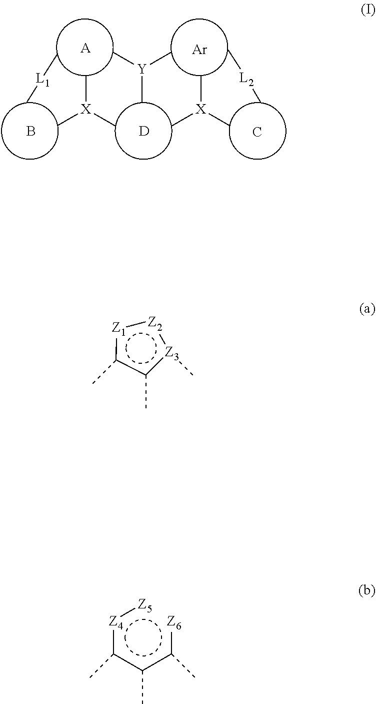
wherein:
A, B, C, and D are each independently selected from a substituted/unsubstituted C₆-C₆₀ aromatic ring, a substituted/unsubstituted C₅-C₀₀ heteroaromatic ring, or a substituted/unsubstituted C₁₀-C₆₀ fused-ring structural unit, and at least one of A, B, and C is a benzophenanthrene;
each of X and Y is independently N or B, and X is different from Y;
Ar is selected from formula (a) or formula (b), each dotted line independently represents a bonding position, when Ar is formula (a), each of L₁ and L₂ is independently selected from null or a single bond, and when Ar is formula (b), each of L₁ and L₂ is a single bond;
Z₁, Z₂, Z₃, Z₄, Z₅, and Z₆ are each independently selected from CR₁, NR₁, N, O, S, S═O, S(═O)₂, or C═O, such that formula (a) is a five-membered heteroaromatic ring, and formula (b) is a six-membered aromatic or heteroaromatic ring, wherein any two adjacent substituents of Z₁-Z₆ form a monocyclic or polycyclic aliphatic or aromatic ring system with each other and/or with the rings bonded thereto;
R₁ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof,
the benzophenanthrene-containing organic compound according to formula (I) is further arbitrarily substituted with Rs; R at each occurrence is independently selected from a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof.

2. The benzophenanthrene-containing organic compound according to claim 1, wherein the benzophenanthrene-containing organic compound comprises a structure of one of formulas (I-1)-(I-14):

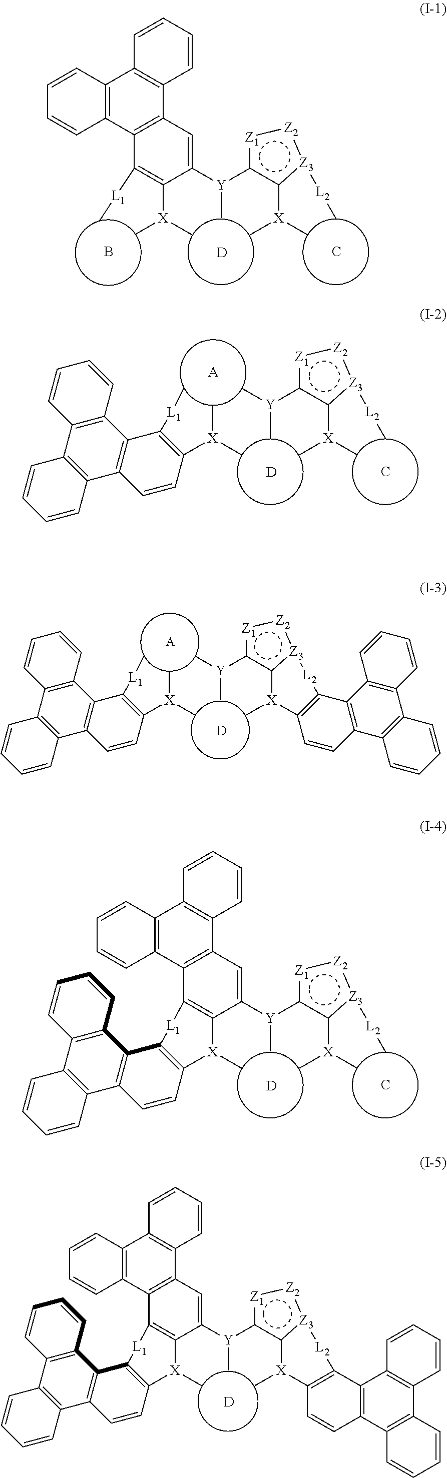

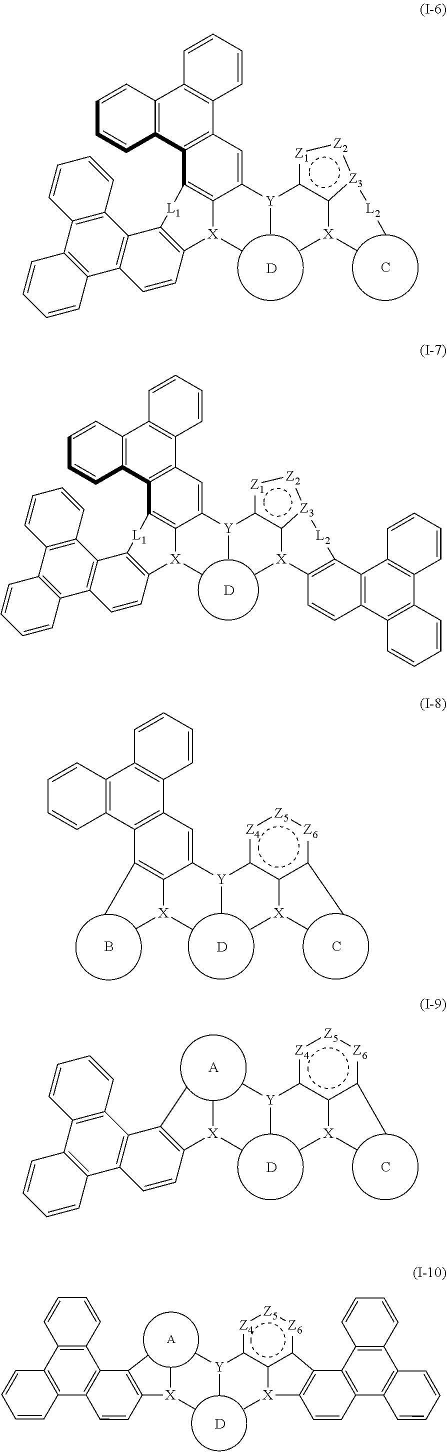

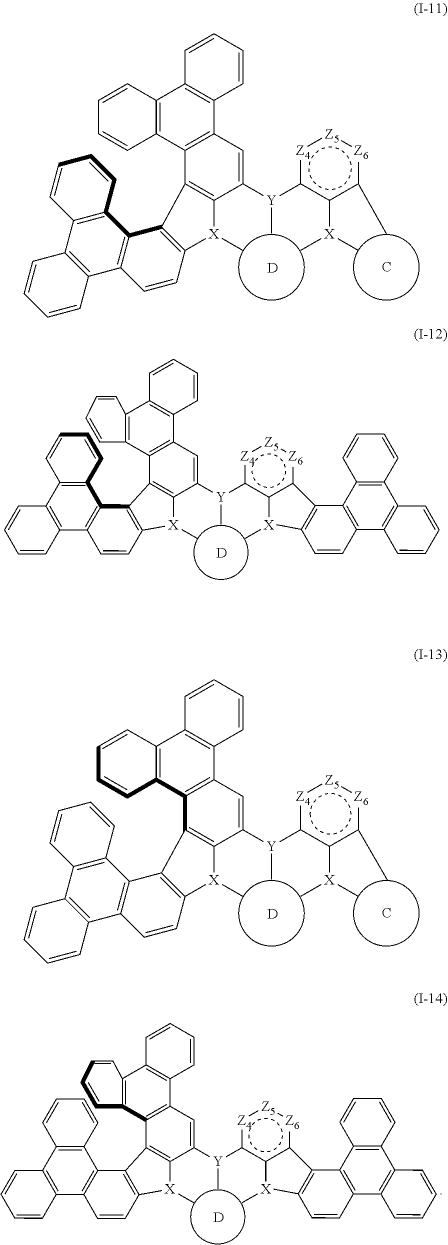

3. The benzophenanthrene-containing organic compound according to claim 1, wherein A, B, C, and D are each independently selected from the following groups: 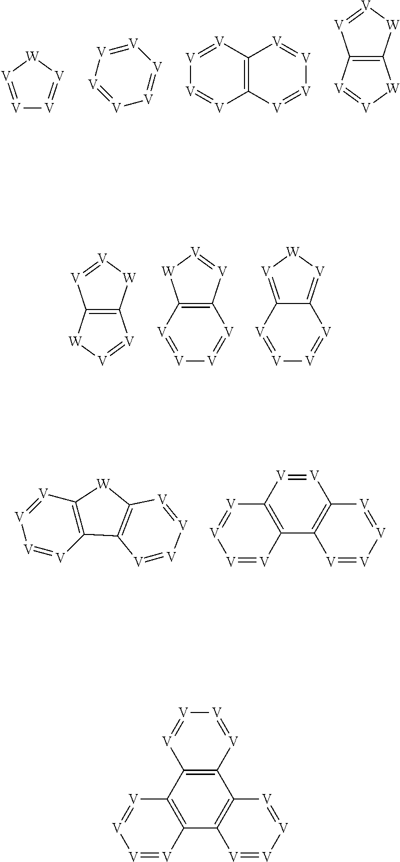
wherein:
w at each occurrence is independently selected from CR₁R², NR¹, O, S, SiR¹R², PR¹, P(═O)R¹, S═O, S(═O)₂, or C═O;
v at each occurrence is independently selected from CR³ or N;
each of R¹ to R³ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 60 ring atoms, an aryloxy or heteroaryloxy group containing 5 to 60 ring atoms, or any combination thereof.

4. The benzophenanthrene-containing organic compound according to claim 2, wherein A, B, C, and D are each independently selected from the following groups: 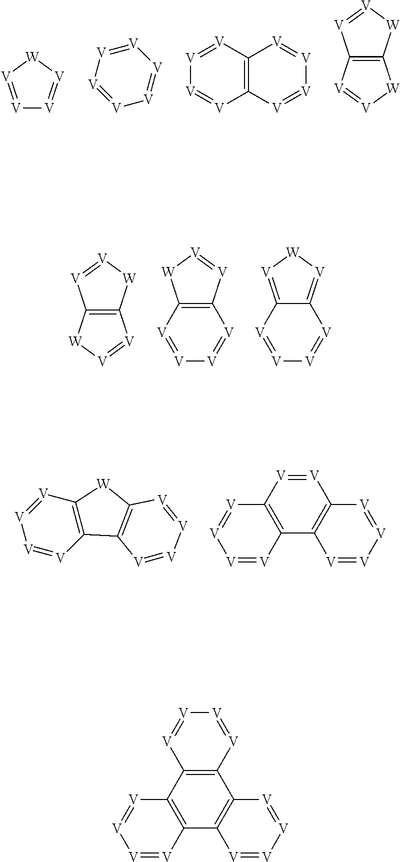
wherein:
w at each occurrence is independently selected from CR¹R², NR¹, O, S, SiR¹R², PR¹, P(═O)R¹, S═O, S(═O)₂, or C═O;
v at each occurrence is independently selected from CR³ or N;
each of R¹ to R³ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 60 ring atoms, an aryloxy or heteroaryloxy group containing 5 to 60 ring atoms, or any combination thereof.

5. The benzophenanthrene-containing organic compound according to claim 1, wherein each D is independently selected from a C₆-C₆₀ aromatic ring, a C₅-C₆₀ heteroaromatic ring, or a C₅-C₆₀ fused-ring structural unit, which is substituted with Zs, and each Z is a large steric hindrance group of formula (IIIa) or formula (IIIb): 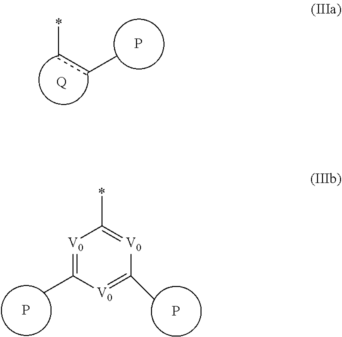
wherein: each of P and Q is independently selected from a substituted/unsubstituted C₆-C₆₀ aromatic ring, a substituted/unsubstituted C₅-C₆₀ heteroaromatic ring, or a substituted/unsubstituted C₁₀-C₆₀ fused-ring structural unit; V₀ at each occurrence is independently selected from CR⁴ or N; R⁴ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof, and each * independently represents a linkage site.

6. The benzophenanthrene-containing organic compound according to claim 2, wherein each D is independently selected from a C₆-C₆₀ aromatic ring, a C₅-C₆₀ heteroaromatic ring, or a C₅-C₆₀ fused-ring structural unit, which is substituted with Zs, and each Z is a large steric hindrance group of formula (IIIa) or formula (IIIb): 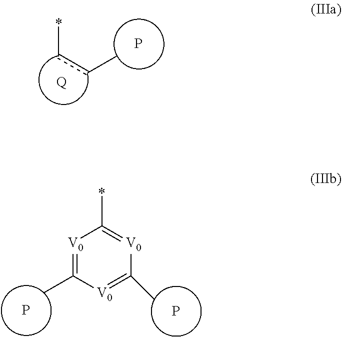
wherein: each of P and Q is independently selected from a substituted/unsubstituted C₆-C₆₀ aromatic ring, a substituted/unsubstituted C₅-C₆₀ heteroaromatic ring, or a substituted/unsubstituted C₁₀-C₆₀ fused-ring structural unit; V₀ at each occurrence is independently selected from CR⁴ or N; R⁴ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof, and each * independently represents a linkage site.

7. The benzophenanthrene-containing organic compound according to claim 3, wherein each D is independently selected from a C₆-C₆₀ aromatic ring, a C₅-C₆₀ heteroaromatic ring, or a C₅-C₆₀ fused-ring structural unit, which is substituted with Zs, and each Z is a large steric hindrance group of formula (IIIa) or formula (IIIb): 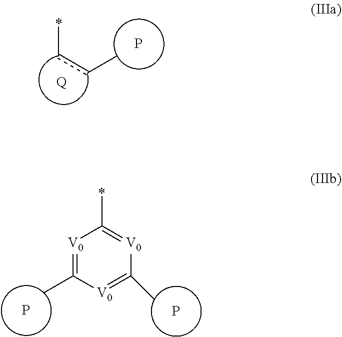
wherein: each of P and Q is independently selected from a substituted/unsubstituted C₆-C₆₀ aromatic ring, a substituted/unsubstituted C₅-C₆₀ heteroaromatic ring, or a substituted/unsubstituted C₁₀-C₆₀ fused-ring structural unit; V₀ at each occurrence is independently selected from CR⁴ or N; R⁴ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof, and each * independently represents a linkage site.

8. The benzophenanthrene-containing organic compound according to claim 4, wherein each D is independently selected from a C₆-C₆₀ aromatic ring, a C₅-C₆₀ heteroaromatic ring, or a C₅-C₆₀ fused-ring structural unit, which is substituted with Zs, and each Z is a large steric hindrance group of formula (IIIa) or formula (IIIb): 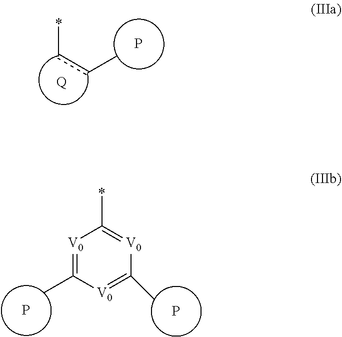
wherein: each of P and Q is independently selected from a substituted/unsubstituted C₆-C₆₀ aromatic ring, a substituted/unsubstituted C₅-C₆₀ heteroaromatic ring, or a substituted/unsubstituted C₁₀-C₆₀ fused-ring structural unit; V₀ at each occurrence is independently selected from CR⁴ or N; R⁴ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof, and each * independently represents a linkage site.

9. A formulation, comprising the benzophenanthrene-containing organic compound according to claim 1, and at least one organic solvent.

10. A color conversion layer, comprising an emitter, wherein the emitter is a chiral molecule.

11. The color conversion layer according to claim 10, wherein the emitter is the benzophenanthrene-containing organic compound with chirality, the benzophenanthrene-containing organic compound comprises a structure of formula (I): 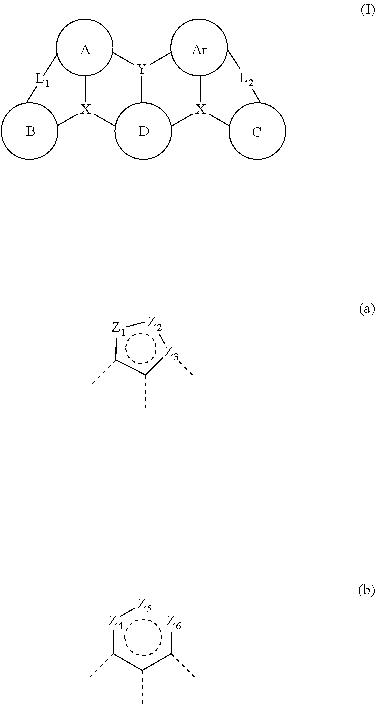
wherein:
A, B, C, and D are each independently selected from a substituted/unsubstituted C₆-C₆₀ aromatic ring, a substituted/unsubstituted C₅-C₆₀ heteroaromatic ring, or a substituted/unsubstituted C₁₀-C₆₀ fused-ring structural unit, and at least one of A, B, and C is a benzophenanthrene;
each of X and Y is independently N or B, and X is different from Y;
Ar is selected from formula (a) or formula (b), each dotted line independently represents a bonding position, when Ar is formula (a), each of L₁ and L₂ is independently selected from null or a single bond, and when Ar is formula (b), each of L₁ and L₂ is a single bond;
Z₁, Z₂, Z₃, Z₄, Z₅, and Z₆ are each independently selected from CR₁, NR₁, N, O, S, S═O, S(═O)₂, or C═O, such that formula (a) is a five-membered heteroaromatic ring, and formula (b) is a six-membered aromatic or heteroaromatic ring, wherein any two adjacent substituents of Z₁-Z₆ form a monocyclic or polycyclic aliphatic or aromatic ring system with each other and/or with the rings bonded thereto;
R₁ at each occurrence is independently selected from —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof,
the benzophenanthrene-containing organic compound according to formula (I) is further arbitrarily substituted with Rs; R at each occurrence is independently selected from a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ ketone group, a C₂-C₂₀ alkoxycarbonyl group, a C₄-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, or any combination thereof.
